(19) United States
(12) Patent Application Publication
(10) Pub. No.: US 2024/0291483 A1
(43) Pub. Date: Aug. 29, 2024

(54) METHODS, DEVICES, AND SYSTEMS FOR SEQUENCED OPERATION OF NON-DISSIPATIVE ELEMENTS IN A CAPACITIVE ELEMENT DRIVER

(71) Applicant: Neolith LLC, Tampa, FL (US)

(72) Inventors: Tsz Yin Man, Shatin (HK); Chi Fan YUNG, Ma On Shan (HK); Bruce C. LARSON, Tampa, FL (US)

(21) Appl. No.: 18/597,858

(22) Filed: Mar. 6, 2024

Related U.S. Application Data
(63) Continuation-in-part of application No. 18/090,469, filed on Dec. 28, 2022, now Pat. No. 11,955,962.
Application No. 18/090,469 is a continuation of application No. 17/032,409, filed on Sep. 25, 2020, now Pat. No. 11,575,376.
(60) Provisional application No. 62/907,530, filed on Sep. 27, 2019.
(60) Provisional application No. 63/075,083, filed on Sep. 4, 2020.
(60) Provisional application No. 63/082,556, filed on Sep. 24, 2020.

(51) Int. Cl. H03K 17/687; H03K 17/0812; H03K 17/0814

(52) U.S. Cl. CPC H03K 17/6871; H03K 17/0812; H03K 17/0814

(57) ABSTRACT

A circuit for driving output of a capacitive element between two voltage levels has at least one driver cell with a first switch pair connected in series between a first voltage source terminal and the capacitive element and a second switch pair connected in series between a second voltage source terminal and the capacitive element. One or more non-dissipative elements may be connected between a first common node of the first switch pair and a second common node of the second switch pair. Combinations of driver cell switches are activated and deactivated in sequences to provide step-wise transfer of energy to the capacitive element, subtracting from an input voltage, bypassing a driver cell, and adding to the input voltage. Switching stages to reach a high voltage output may be identical to but organized in reverse order from the switching stages to reach a low voltage output.

### CROSS-REFERENCE TO RELATED APPLICATION

This application is a continuation-in-part application of U.S. patent application Ser. No. 18/090,469, filed Dec. 28, 2022 (Attorney Docket No. N03-P01-05US) entitled ARRANGEMENTS OF NON-DISSIPATIVE ELEMENTS IN NON-DISSIPATIVE ELEMENT-ENABLED CAPACITIVE ELEMENT DRIVERS, which is a continuation application of U.S. patent application Ser. No. 17/032,409, filed Sep. 25, 2020, which issued as U.S. Pat. No. 11,575,376 on Feb. 7, 2023 (Attorney Docket No. N03-P01-04US) entitled IMPROVEMENTS IN NON-DISSIPATIVE ELEMENT-ENABLED CAPACITIVE ELEMENT DRIVING. This application claims the priority of:
U.S. Patent Application No. 62/907,530, filed Sep. 27, 2019 (Attorney Docket No. N03-P01-00US), entitled IMPROVEMENTS IN NON-DISSIPATIVE ELEMENT-ENABLED CAPACITIVE ELEMENT DRIVING;
U.S. Patent Application No. 63/075,083, filed Sep. 4, 2020 (Attorney Docket No. N03-P01-01US), entitled IMPROVEMENTS IN NON-DISSIPATIVE ELEMENT-ENABLED CAPACITIVE ELEMENT DRIVING;
U.S. Patent Application No. 63/082,556, filed Sep. 24, 2020 (Attorney Docket No. N03-P01-03US), entitled IMPROVEMENTS IN NON-DISSIPATIVE ELEMENT-ENABLED CAPACITIVE ELEMENT DRIVING;
U.S. patent application Ser. No. 17/032,409, filed Sep. 25, 2020 (Attorney Docket No. N03-P01-04US), entitled IMPROVEMENTS IN NON-DISSIPATIVE ELEMENT-ENABLED CAPACITIVE ELEMENT DRIVING, which issued as U.S. Pat. No. 11,575,376 on Feb. 7, 2023; and
U.S. patent application Ser. No. 18/090,469, filed Dec. 28, 2022 (Attorney Docket No. N03-P01-05US) entitled ARRANGEMENTS OF NON-DISSIPATIVE ELEMENTS IN NON-DISSIPATIVE ELEMENT-ENABLED CAPACITIVE ELEMENT DRIVERS; the disclosures of all five of which are incorporated by reference in their entireties.

### FIELD

The present invention relates to the field of circuits, and particularly to circuits and systems for capacitive driving.

### BACKGROUND

This invention relates to methods and systems for driving the voltage of a capacitive element between two voltage levels such as ground and supply voltage. Non-dissipative elements such as capacitors may be used to improve the energy efficiency of capacitive element driving.

The control of an electronic or electrical device is normally performed by applying a voltage at its control terminal, for example, to activate or deactivate the device. The control terminal may be the control gate of a transistor of any type, including but not limited to a Metal Oxide Semiconductor Field Effect Transistor (MOSFET), a Gallium Nitride Field Effect Transistor (GaN-FET), a Silicon Carbide Field Effect Transistor (SiC-FET), a Junction Field Effect Transistor (JFET), or an Insulated Gate Bipolar Transistor (IGBT). The control terminal may also be a control input of another sort of electronic or electrical device, including but not limited to an electrostatic actuator or other systems such as micro motors, micro mirrors, and micro switches based on Micro-Electro-Mechanical Systems (MEMS) technology, memory and logic circuits based on multiferroic/magnetoelectric materials, ultrasonic transducers, piezoelectric actuators, electronic paper displays (E-paper), and actuators based on electroactive polymers.

In an electronic or electrical system in which devices have control terminals with capacitive elements, drivers, also herein referred to as driving circuits, are used to drive the voltage of those control terminals between two voltage levels to activate or deactivate those devices. Systems employing drivers include switch mode power converters, motor drivers, electrostatic actuators, electroactive polymer actuators, and multiferroic/magnetoelectric devices. Periodic switching is helpful in maintaining the average voltage of those storage capacitors at an unchanged level.

In conventional methods of capacitive element driving, a circuit 100 such as shown in FIG. 1A, with the operation of circuit 100 shown in the waveforms of FIG. 1B, may have two switches, SW_{1[1]}, SW_{1[2]}, with switch SW_{1[1]} connected between the capacitive element C_{O1} and one terminal of the voltage source V_{DD1}, and with switch SW_{1[2]} connected between the capacitive element C_{O1} and another terminal of the voltage source V_{DD1}, which are switched on and off alternately to drive the voltage of the capacitive element C_{O1} between two levels (e.g. 0V and V_{DD1}). However, such driving methods are not energy efficient.

The waveforms of FIG. 1B show the operation of the circuit 100, in which, when the capacitive element voltage (V_{O1}) is driven from ground (or supply voltage) to the driving circuit's supply voltage (or ground), transient current flows through the switch SW_{1[1]} (or SW_{1[2]}) until the voltage V_{O1} is settled. Then energy E_{CAP1}=½C_{O1}V_{DD1}² is stored in (or taken away from) the capacitive element C_{O1}. When transient current I_{SW1[1]} (or I_{SW1[2]}) flows through switch SW_{1[1]} (or SW_{1[2]}), a voltage difference appears across the switch and energy is absorbed. Switch SW_{1[1]} (or SW_{1[2]}) is a dissipative element, so that the absorbed energy (E_{DISS1}=½C_{O1}V_{DD1}²) is dissipated. The energy loss per driving cycle (E_{LOSS1}) is CV_{DD1}².

One method for avoiding energy dissipation of circuit 100 is to introduce a resonant capacitive element driver in which an inductor is added to the input of a capacitive element, and to periodically drive capacitive elements between two voltage levels. One circuit 200 for resonant capacitive element driving is shown in FIG. 2A, with the operation of circuit 200 shown in the waveforms of FIG. 2B.

As shown in FIG. 2A, switches SW_{2[1]} and SW_{2[2]} are connected in series between the terminals of the voltage source V_{DD2}, diodes D_{2[1]} and D_{2[4]} are also connected in series between the terminals of the voltage source V_{DD2}, and diodes D_{2[3]} and D_{2[2]} are also connected in series between the terminals of the voltage source V_{DD2}. Switch SW_{2[1]}, diode D_{2[4]}, and diode D_{2[2]} share a common node 202, which is electrically connected to the positive terminal of the voltage source V_{DD2}. Switch SW_{2[2]}, diode D_{2[1]}, and diode D_{2[3]} share a common node 204, which is electrically connected to the negative terminal of the voltage source V_{DD2}; and switch SW_{2[1]}, SW_{2[2]}, diode D_{2[4]}, and diode D_{2[1]} share a common node 206. An inductor L₂ may be disposed between the common-node 206 and a common node 208 shared by the diodes D_{2[2]} and D_{2[3]} and the capacitive element C_{O2}.

In operation, the circuit 200 stores the energy E_{DISS2} in the inductor L₂. The use of a non-dissipative element such as the inductor L₂ in circuit 200 allows energy to be stored in the non-dissipative element instead of dissipated as heat on resistive element. Diodes D_{2[1]} and D_{2[2]} (or D_{2[3]} and D_{2[4]}) may transfer the stored energy E_{DISS2} back to the voltage source V_{DD2} after the capacitive element voltage V_{O2} is driven from ground to the driving circuit's supply voltage V_{DD2} (or from supply voltage V_{DD2} to ground).

Therefore, the inclusion of the inductor L₂ into the circuit 200 reduces the dissipation of energy, storing E_{CAP2}=½C_{O2}V_{DD2}² in the non-dissipative element, thus rendering the circuit 200 more energy efficient. However, there is a tradeoff between ramp rate of V_{O2} and peak inductor current. The inductor L₂ and capacitive element C_{O2} form a resonant network, which has its resonant period and characteristic impedance proportional to the value of the square root of L₂. To increase the V_{O2} ramp rate, an inductor with a smaller value than the inductor L₂ may be used, but its substitution into circuit 200 also introduces a higher peak inductor current. Also, the inclusion of an additional element (inductor L₂) in circuit 200 introduces extra current and hence conduction loss due to resonant behaviour, rendering the circuit 200 bulky and costly.

A network with a capacitor and inductor may also be used as a resonant capacitive element driver in circuits designed to avoid dissipation energy. One circuit 300 for resonant capacitive element driving using an LC network is shown in FIG. 3A, with the operation of circuit 300 shown in the waveforms of FIG. 3B.

As shown in FIG. 3A, an inductor and a capacitor (LC) network LC₃ is inserted between common-node 310 of switches SW_{3[1]} and SW_{3[2]}, and ground. Energy E_{CAP3} may be transferred from the capacitive element CO₃ to the LC network LC₃ once voltage V_{O3} is changed from supply voltage −V_{DD3} to ground; and transferred back from the LC network LC₃ to the capacitive element C_{O3} when voltage V_{O3} changes from ground to the driving circuit's supply voltage.

As with circuit 200, while the LC network LC₃ incorporated into the circuit 300 renders the circuit 300 more energy efficient because it prevents dissipation of energy E_{CAP3}=½C_{O3}V_{DD3}² stored in the capacitive element C_{O3}, the tradeoff between ramp rate of V_{O2} and peak inductor current still exists in the circuit 300. Further, the additional element (LC network LC₃) still introduces extra current and hence conduction loss due to resonant behavior into the circuit 300, rendering the circuit 300 even more bulky and costly than circuit 200.

U.S. Pat. No. 11,575,376 issued on Feb. 7, 2023 (Attorney Docket No. N03-P01-04US) entitled IMPROVEMENTS IN NON-DISSIPATIVE ELEMENT-ENABLED CAPACITIVE ELEMENT DRIVING, to which this application claims priority, discloses a capacitive element driver for driving a capacitive element between voltage levels, with the capacitive element having capacitive functionality, and with and the voltage supplied to the capacitive element driver by a voltage source.

U.S. Pat. No. 11,575,376 disclosed that the capacitive element driver has a plurality of switches with a first switch electrically connectable in series directly or indirectly between a first terminal of the voltage source and an input terminal of the capacitive element, and a second switch electrically connectable in series directly or indirectly between a second terminal of the voltage source and the input terminal of the capacitive element. The capacitive element driver also has and a non-dissipative element arranged to store and transfer energy for driving the capacitive element between the voltage levels. The non-dissipative element is electrically connectable directly or indirectly at a first end to a first node between the first terminal of the voltage source and the input terminal of the capacitive element, and at a second end to a second node between the second terminal of the voltage source and the input terminal of the capacitive element. The plurality of switches is arranged to open or close in combinations in a sequence of switching stages to step-wise transfer the energy to the capacitive element. In U.S. Pat. No. 11,575,376, selected sequences are described for driving the voltage of a capacitive element between two voltage levels, with the sequence of switching stages further comprising a switching pattern having a voltage change portion arranged to cause a change in an output voltage of the capacitive element driver during application thereof on the capacitive element driver.

It is desirable to improve switching sequences for use in methods, circuits, devices, and systems for sequenced operation of switching non-dissipative elements in capacitive element driving systems. It is desirable to define sequencing switching in a capacitive element driver to render sequencing operation of non-dissipative elements in a capacitive element driver simpler, more convenient, and more energy-efficient for driving capacitive elements that simply and efficiently store energy in at least one non-dissipative element, that transfer the energy to drive a capacitive element between two voltage levels, and that may transfer the energy in a series of steps. Further, it may be desirable to develop simple, convenient, energy-efficient methods, circuits, and systems for driving capacitive elements in which non-dissipative elements are sequentially operated. It is also desirable to have selectable switching sequences for use in operating non-dissipative elements in a capacitive element driver, with the selection of the switching sequence based on a desired mode of operation of the capacitive element driver.

### SUMMARY

Methods, circuits, and systems for driving the voltage of a capacitive element between two voltage levels such as ground and supply voltage are disclosed in which a capacitive element driver, also known as a driver or a circuit, simply and efficiently stores energy in at least one non-dissipative element, transfers the energy to drive a capacitive element between two voltage levels, and may transfer the energy in a series of steps through operation of a sequence of stages on the at least one non-dissipative element, alternatingly turning on and off switches in sequential order to drive the voltage of the capacitive element between the two levels in step-wise fashion.

The capacitive element driver may have a first switch electrically connected between an input terminal of the capacitive element and a negative terminal of the voltage source, and a last switch electrically connected between the input terminal of the capacitive element and a positive terminal of the voltage source. In certain embodiments, the one or more non-dissipative elements may be connectable in series between terminals of the voltage source and the two or more switches are connectable at one of their ends to an input of the capacitive element. A first switch may be electrically connectable at its other end to a common node between the negative terminal of the voltage source and a first non-dissipative element, and a last switch may be electrically connectable at its other end to a common node between a positive terminal of the voltage source and a last non-dissipative element.

Further, the driver may have more than one driver cell be arranged to supply the step-wise transfers of energy through operation of its own sequence of stages so that switches in the cells open and close in combinations in the sequences of switching stages to deliver an output voltage of the capacitive element driver between the two voltage levels while maintaining an average voltage level value of the non-dissipative element unchanged over time.

In certain embodiments, switching may be applied to the capacitive element driver by activating and deactivating selected switches in the plurality of switches to reduce the energy loss when a capacitive element is driven from one voltage to another.

In another embodiments, switching may be applied to the capacitive element driver by activating and deactivating selected switches in a sequence of switching stages defined to ensure that the average value of storage capacitor voltage remains unchanged over time. The switch sequencing may be further defined to form a capacitive element voltage driving cycle so that the combinations of switch activation operates to hold the average value of voltage of the storage capacitor(s) unchanged over time.

In certain embodiments, a capacitive element driver is disclosed for driving a capacitive element between voltage levels, with the capacitive element being an element having capacitive functionality and with the capacitive element driver arranged to drive the capacitive element from a high voltage level to a low voltage level or from a low voltage level to a high voltage level. The capacitive element driver may have a plurality of switches with a first pair of switches electrically connectable in series between a first input terminal of the capacitive element driver and an output terminal of the capacitive element driver, with the first input terminal of the capacitive element driver electrically connectable directly or indirectly to a first terminal of a voltage source for supplying a selected voltage to the capacitive element driver, and with the output terminal of the capacitive element driver electrically connectable directly or indirectly to an input of the capacitive element.

The plurality of switches may also have a second pair of switches electrically connectable in series between a second terminal of the voltage source and the output terminal of the capacitive element driver; and a non-dissipative element arranged to store and transfer energy for driving the capacitive element between the voltage levels, wherein the non-dissipative element is electrically connectable between a common node of the first pair of switches and a common node of the second pair of switches. The plurality of switches may be arranged to open and close in combinations in a sequence of switching stages to maintain an average voltage level value of the non-dissipative element unchanged over time.

In further embodiments, a controller may be electrically connectable to the plurality of switches to control the operation of the switches to open and close in combinations in the sequence of switching stages, the sequence of switching stages is arranged to provide step-wise transfer of the energy to the capacitive element, and the capacitive element driver may be arranged to drive the capacitive element from a high voltage level to a low voltage level or from a low voltage level to a high voltage level.

In other embodiments, the capacitive element driver may be a first driver cell in a capacitive element driving circuit, which may have a second driver cell electrically connectable between the first driver cell and the capacitive element. The second driver cell may have a second cell first input terminal electrically connectable to the first cell output terminal, a second cell output terminal electrically connectable directly or indirectly to the capacitive element, and a second plurality of switches with a second cell first pair of switches electrically connectable in series between the second cell first input terminal and the second cell output terminal, and a second cell second pair of switches electrically connectable in series between the first cell output terminal and the second cell output terminal. The second driver cell may also have a second non-dissipative element for storing and transferring additional energy for driving the capacitive element between the two voltage levels, with the second non-dissipative element electrically connectable between a common node of the second cell first pair of switches and a common node of the second cell second pair of switches.

In still further embodiments, the sequence of switching stages is a first sequence of stages; and the second plurality of switches is arranged to open or close in combinations in a second sequence of switching stages to maintain the average voltage level value of the second non-dissipative element unchanged over time.

In further embodiments, a circuit-wide sequence of switching for providing step-wise transfer of the energy to the capacitive element.is disclosed in which the first plurality of switches and the second plurality of switches are selectively opened or closed in order to drive the capacitive element from the high voltage level to the low voltage level or from the low voltage level to the high voltage level. The controller is further electrically connectable to the second plurality of switches to control opening or closing of the second plurality of switches based on the circuit-wide sequence of switching stages.

In other embodiments, methods and systems are disclosed for driving the voltage of a capacitive element between two voltage levels such as ground and supply voltage. In the disclosed methods and systems, a first pair of a plurality of switches may be connected in series between a first terminal of a voltage source and an input of a capacitive element; and a second pair of the plurality of switches may be connected in series between a second terminal of the voltage source and the input of the capacitive element. In addition, a non-dissipative element such as a storage capacitor may be arranged to store and transfer energy when the capacitive element is being driven between the two voltage levels, with the non-dissipative element connected between the common node of the first pair of switches and the common node of the second pair of switches.

In other embodiments, processes for driving a capacitive element between two voltage levels are disclosed in which a first input terminal of a first capacitive element driver may be electrically connected directly or indirectly to a first terminal of a voltage source, an output terminal of the first capacitive element driver may be electrically connected directly or indirectly to an input of the capacitive element, and a second input terminal of the first capacitive element driver may be electrically connected directly or indirectly to a second terminal of the voltage source.

In further embodiments, in the process for driving a capacitive element between two voltage levels, the average voltage level value of the non-dissipative element may be maintained unchanged over time while the first capacitive element driver is operated through the first sequence of stages.

Additional energy may be stored in a non-dissipative element of the first capacitive element driver, with the non-dissipative element electrically connected between the first input terminal and the output terminal, and electrically connected between the second input terminal and the output terminal. The first capacitive element driver may be operated through a first sequence of stages, with the first sequence arranged to transfer the energy in a first set of voltage steps directly or indirectly to the capacitive element from a first high voltage level to a first low voltage level or from the first low voltage level to the first high voltage level. In further embodiments, in the process for driving a capacitive element between two voltage levels, the average voltage level value of the non-dissipative element may be maintained unchanged over time while the first capacitive element driver is operated through the first sequence of stages.

In other embodiments, the first capacitive element driver may be a first driver cell, and a second driver cell may be electrically connected between the first driver cell and the capacitive element. The second driver cell may have:
a second cell first input terminal electrically connected directly or indirectly to the first terminal of the voltage source through the first driver cell,
a second cell output terminal electrically connected directly or indirectly to the input of the capacitive element,
a second cell second input terminal electrically connecting directly or indirectly to a second terminal of the voltage source through the first driver cell, and
a non-dissipative element electrically connected between the second cell first input terminal and the second cell output terminal, and between the second cell second input terminal and the second cell output terminal.

Additional energy may be stored in the non-dissipative element of a second capacitive element driver, and the second driver cell may be operated through a second sequence of stages to transfer the additional energy in a second set of voltage steps directly or indirectly to the capacitive element from a second high voltage level to a second low voltage level or from the second low voltage level to the second high voltage level. Further, the second driver cell may be operated through the second sequence of stages in combination and cooperation with the first driver cell as it is operated through the first sequence of stages, with the cooperation further comprising sustaining an application of a first portion of a first pattern of activations of the first driver cell for a duration of an application of a second pattern of activations of the second driver cell.

The energy efficiency of capacitive element driving is improved by the disclosed apparatuses, methods and systems because they allow the non-dissipative element(s) store and transfer energy while the capacitive element is being driven between two voltage levels. In other embodiments, energy efficiency is further improved with a switching methodology in which selected switches are activated and deactivated in a sequence of switching stages in a driving cycle, the stages defined to hold the average value of the voltage across the non-dissipative element(s) unchanged over time.

The disclosed non-dissipative element-enabled capacitive element driving thus minimizes E_{LOSS} without using relatively expensive larger-sized conductors or other inductors employed in conventional resonant capacitive element driving. In addition, the non-dissipative element(s), which in certain embodiments are storage capacitor(s), and switch(es) that are employed in the disclosed apparatuses, methods and systems are relatively area-efficient and inexpensive compared to the inductors employed in conventional resonant capacitive element driving.

Additional objects and advantages of the invention will be set forth in part in the description which follows, and in part will be obvious from the description, or may be learned by practice of the invention. The objects and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

The accompanying drawings, which are incorporated in and constitute a part of this specification, illustrate one (several) embodiment(s) of the invention and together with the description, serve to explain the principles of the invention.

### BRIEF DESCRIPTION OF THE DRAWINGS

FIG. 1A is a diagram of a conventional circuit 100 for driving the voltage of a capacitive element between two voltage levels such as ground and supply voltage, and FIG. 1B is a diagram showing waveforms associated with the operation of circuit 100;

FIG. 2A is a circuit diagram of a conventional circuit 200 for resonant capacitive element driving between two voltage levels, and FIG. 2B is a diagram showing waveforms associated with the operation of circuit 200;

FIG. 3A is a circuit diagram of a conventional circuit 300 for capacitive element driving between two voltage levels using an inductor and a capacitor (LC) network LC3, and FIG. 3B is a diagram showing waveforms associated with the operation of circuit 300;

FIG. 4 is a circuit diagram of a capacitive element driver 400 for one embodiment of a storage capacitor-enabled capacitive element driver of the current invention;

FIGS. 5A-5F are circuit diagrams showing the capacitive element driver 400 in operation through a complete VO4 driving cycle through a switching methodology 500;

FIG. 5G is a chart showing the switching sequences in the switching methodology 500 of the capacitive element driver 400 during the stages of a complete V_{O4} driving cycle;

FIG. 5H is a circuit diagram of the capacitive element driver 400 in operation when the switches SW4[3], SW4[1] are closed (and the switches SW4[0], SW4[2] are kept open) in a complete VO4 driving cycle;

FIG. 5I is a circuit diagram of the capacitive element driver 400 in operation when the switches SW4[0], SW4[2] are closed (and the switches SW4[3], SW4[1] are kept open) in a complete VO4 driving cycle;

FIG. 6A is a graph 600 illustrating a waveform 602 of the voltage VO4 inputted to the capacitive element 430 during a complete VO4 driving cycle for the capacitive element driver 400;

FIG. 6B is a graph 650 illustrating the waveform 602 of FIG. 6A with a more detailed y-axis label;

FIG. 7A is a circuit diagram of a capacitive element driver 700A, which constitutes a more generalized embodiment of the driver 400, with more than one non-dissipative element (NDE) electrically connected in series, with one terminal of a first NDE in the series electronically connected at a first node to one terminal of the voltage source, with one terminal of a last NDE in the series electronically connected at a last node to the other terminal of the voltage source, and with switches SW_{7A[0]} and SW_{7A[n+2]} disposed between the first node and the negative terminal of the voltage source and between the last node and the positive terminal of the voltage source, respectively;

FIG. 7B is a circuit diagram of a capacitive element driver 780, which is a three-NDE embodiment of the driver 700A;

FIG. 7C-1 is a circuit diagram of a capacitive element driver 700C-1, which is a modification of the driver 700A in which its switches SW_{7A[0]} and SW_{7A[n+2]} are closed or removed;

FIG. 7C-2 is a circuit diagram of a capacitive element driver 700C-2, which is a three-NDE embodiment of the driver 700C-1;

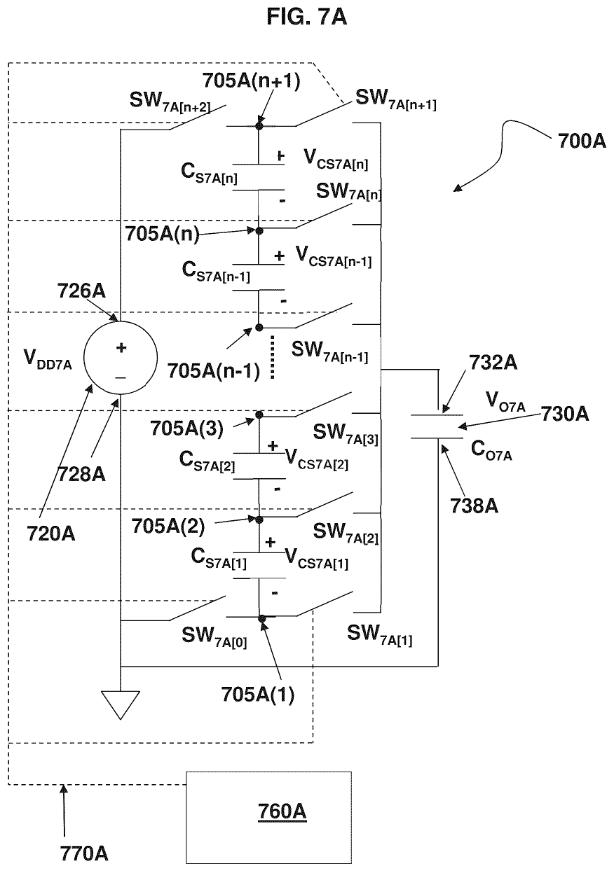

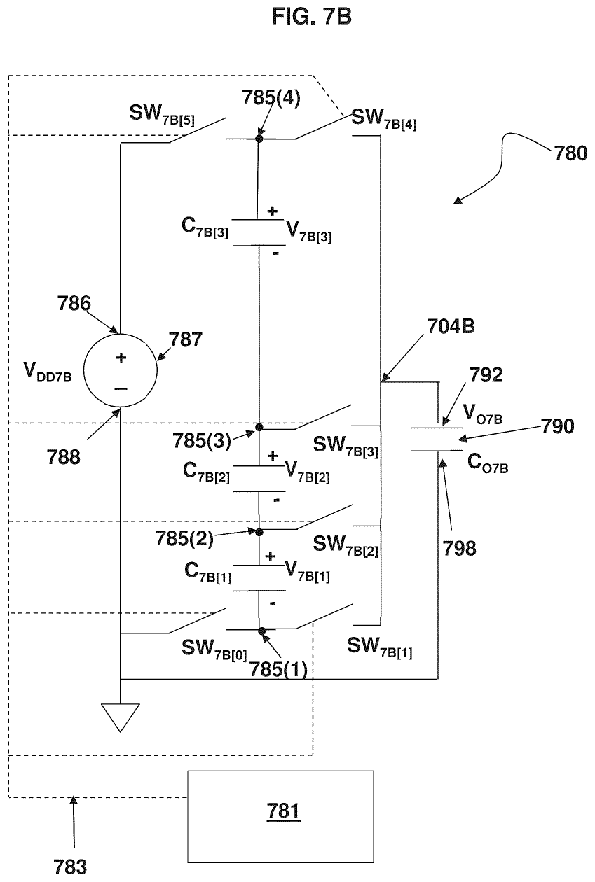

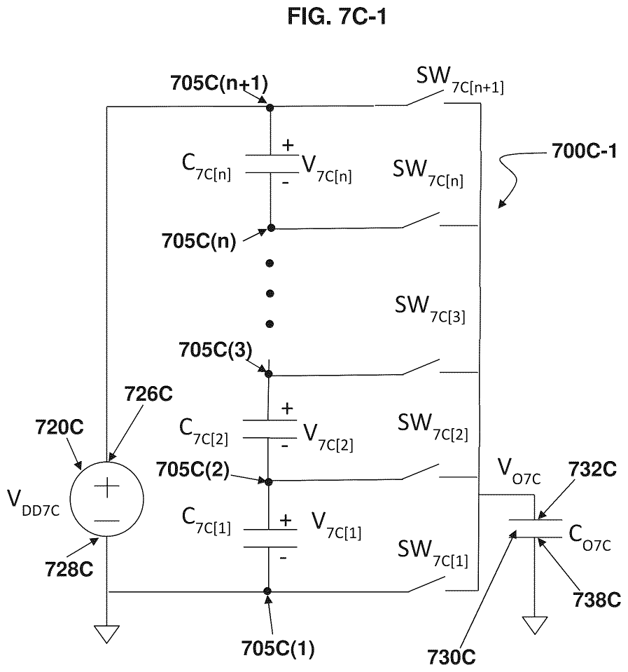

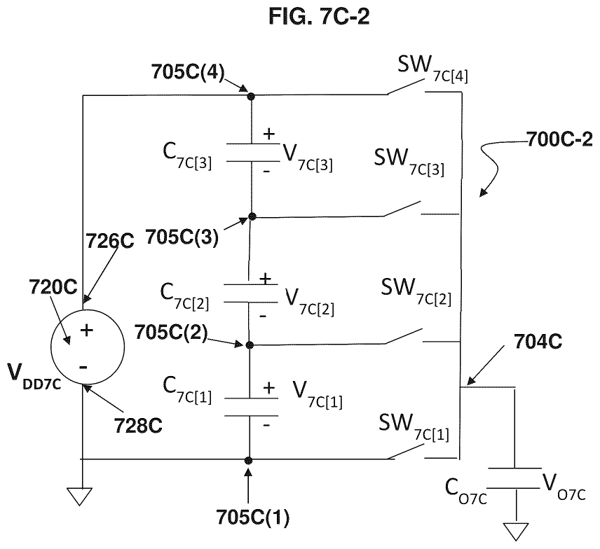

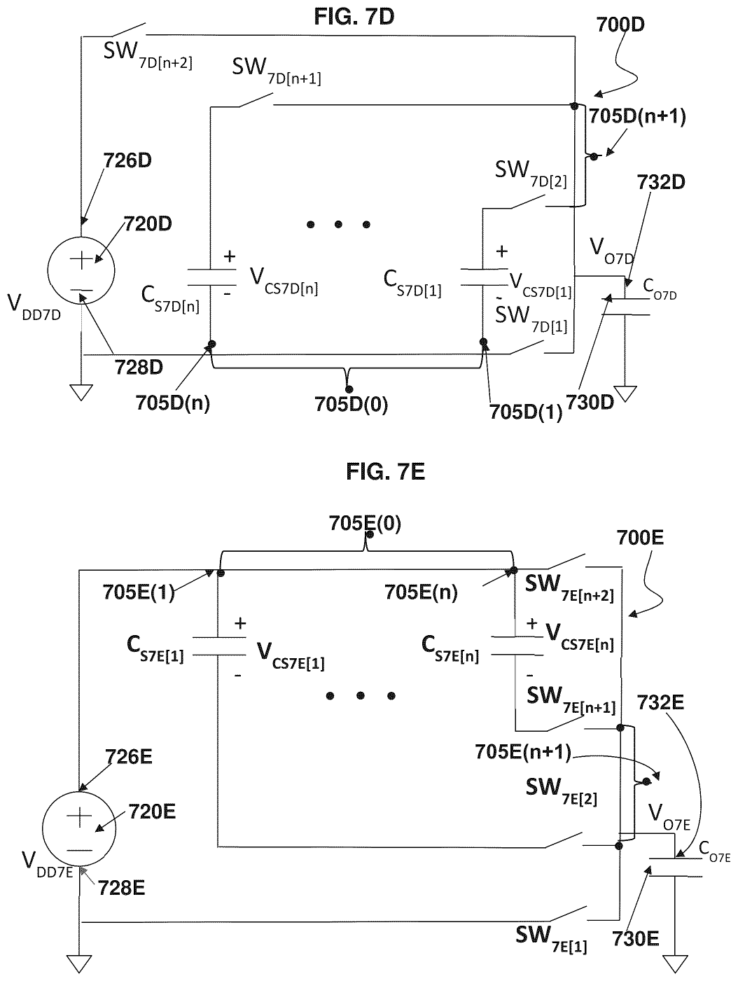

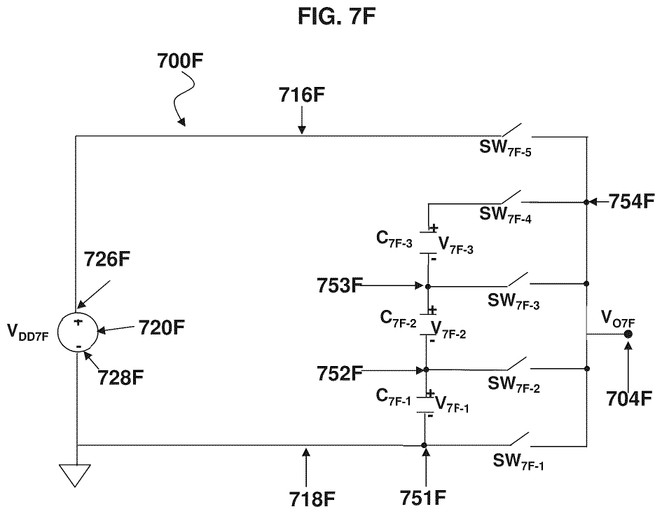

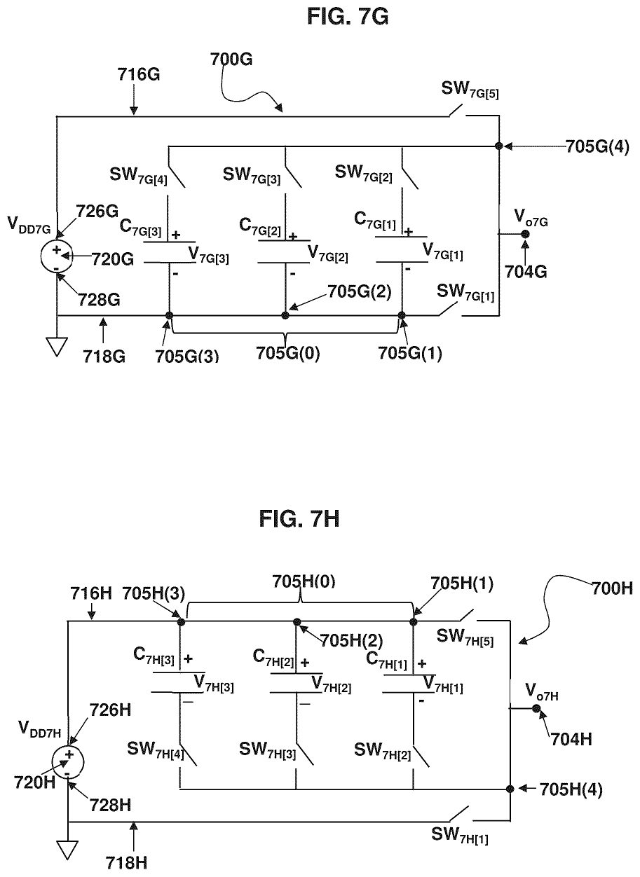

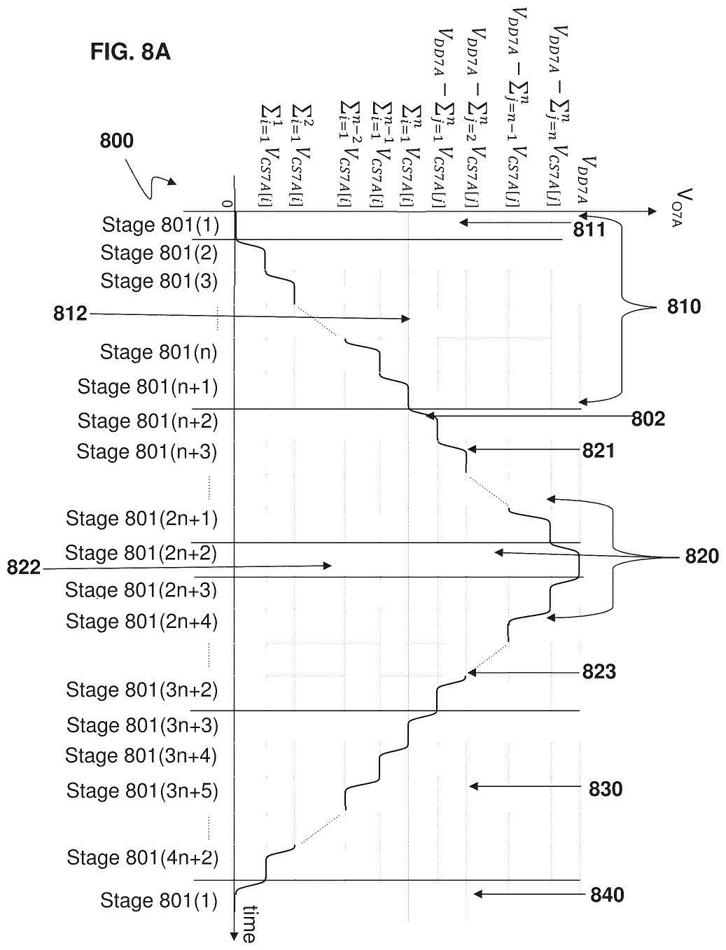

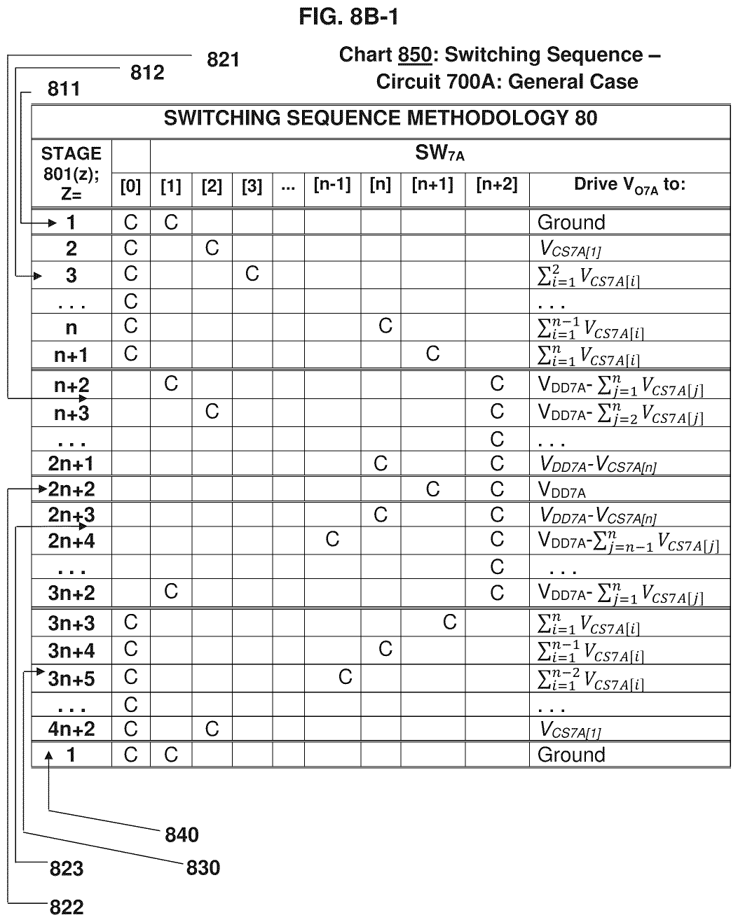

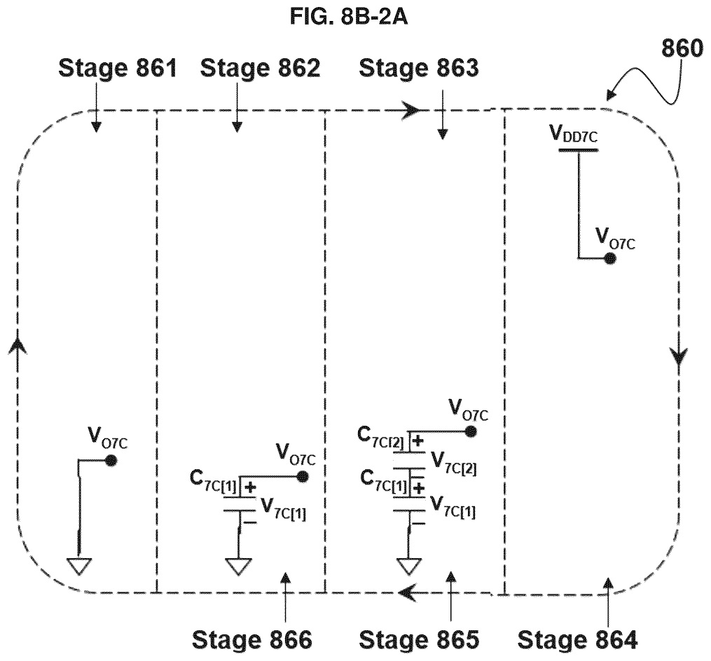

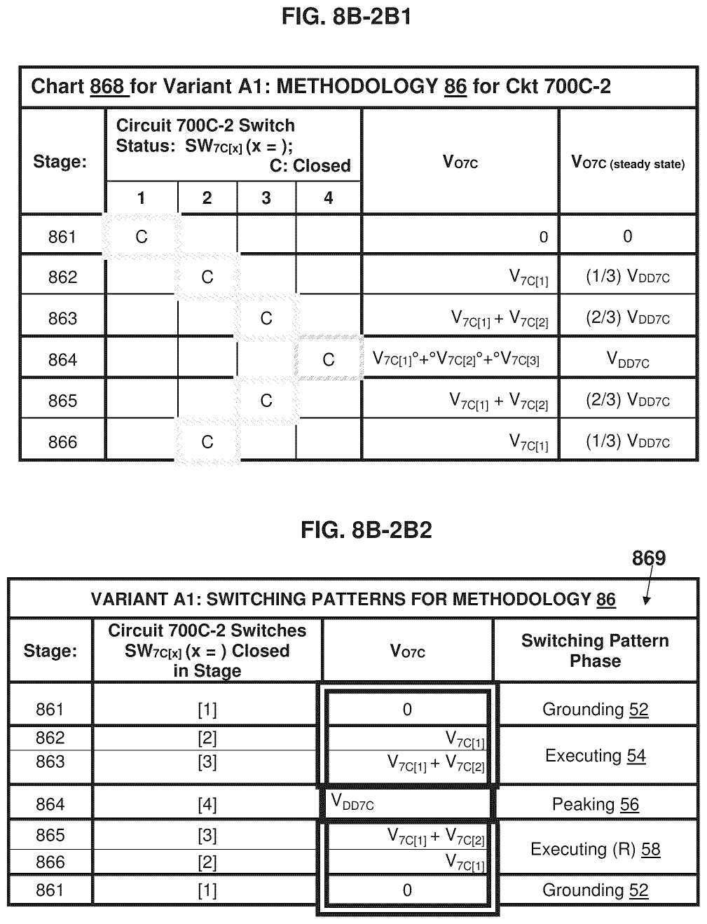

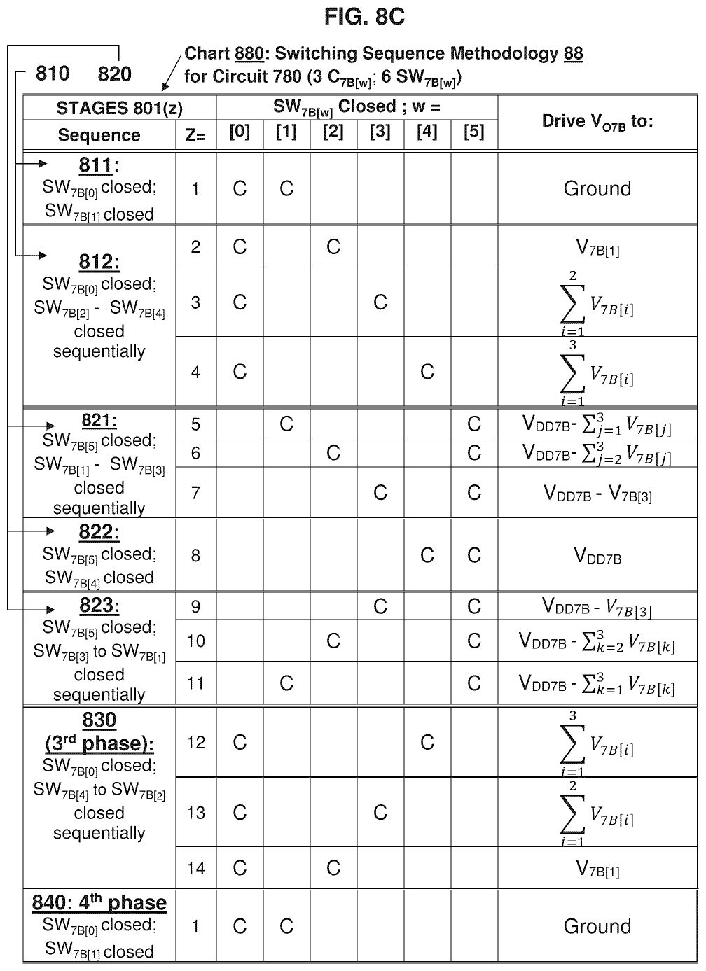

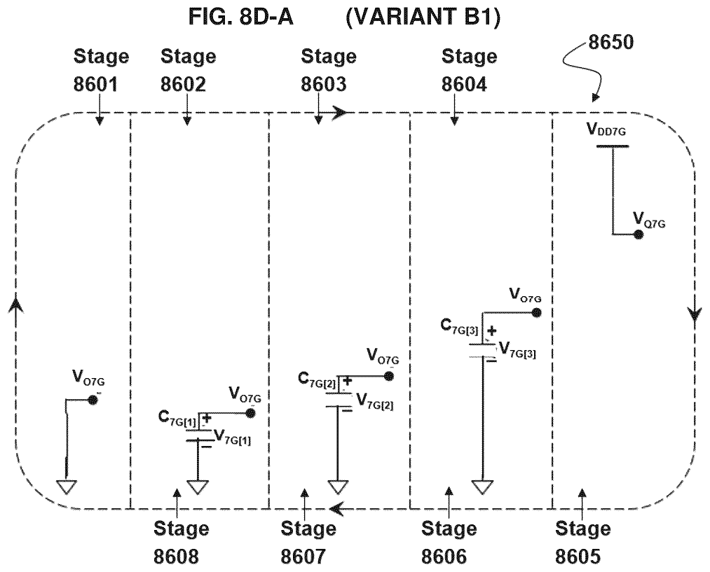

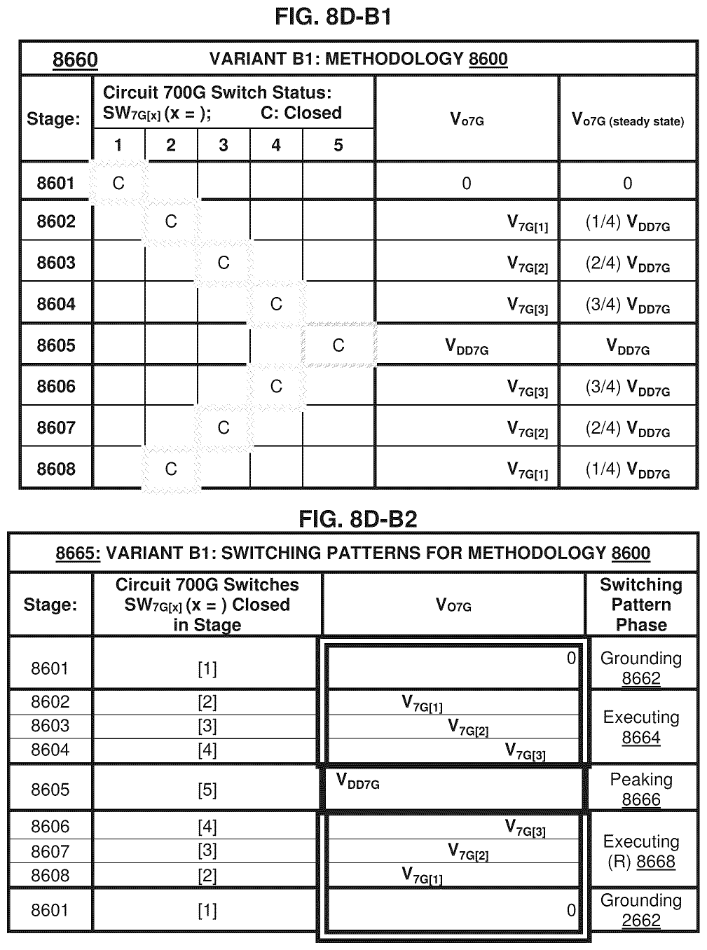

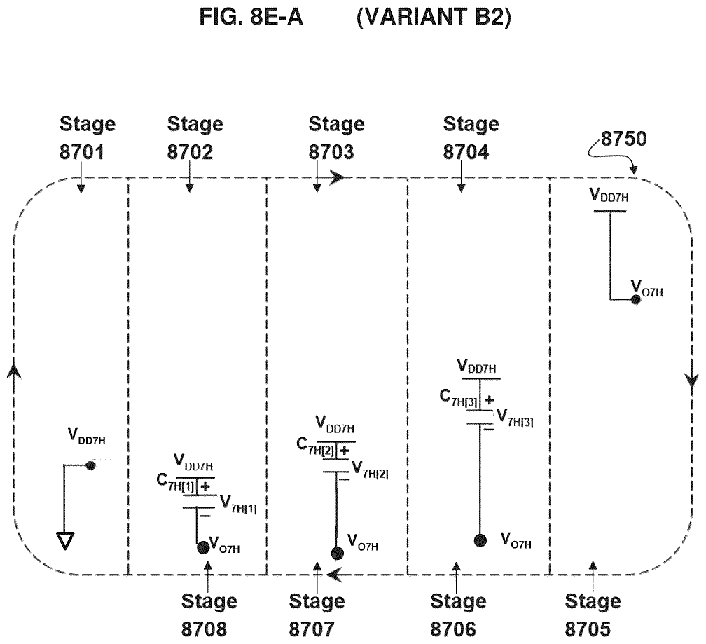

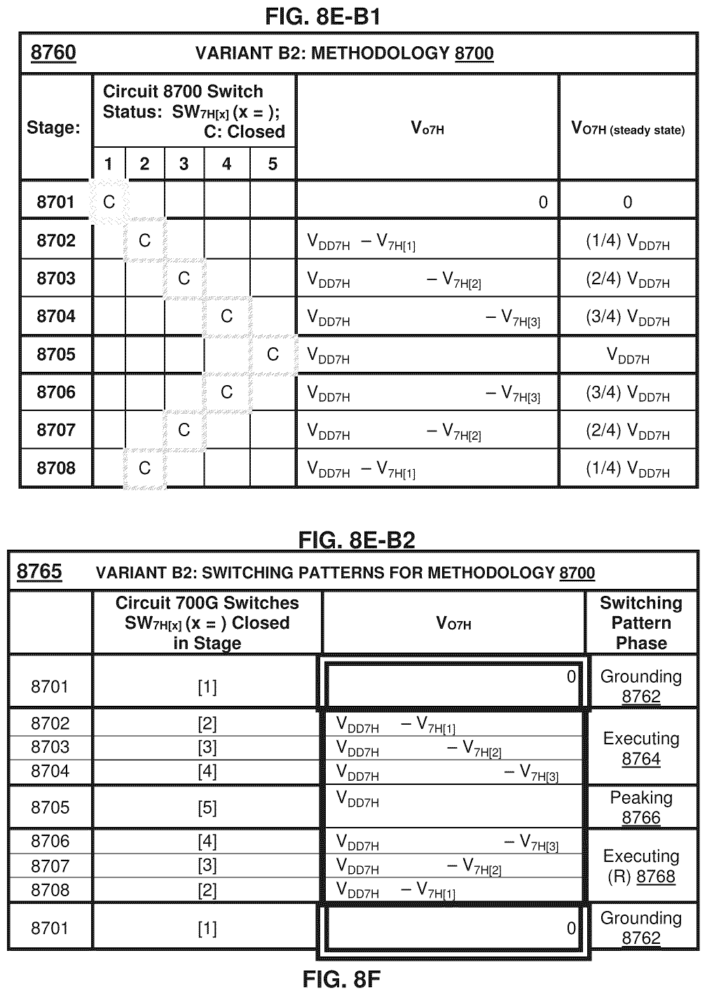

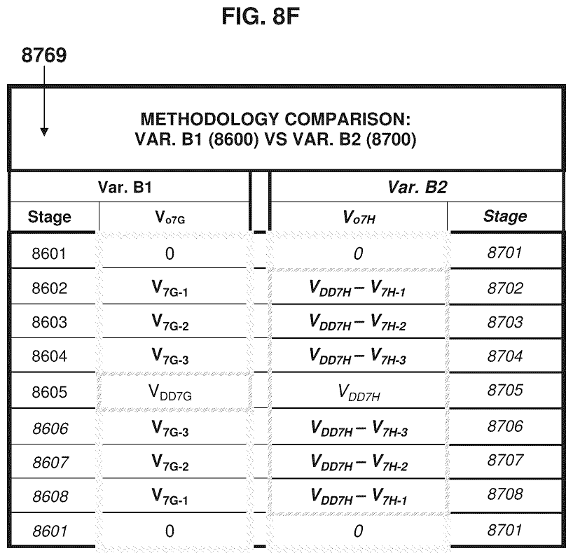

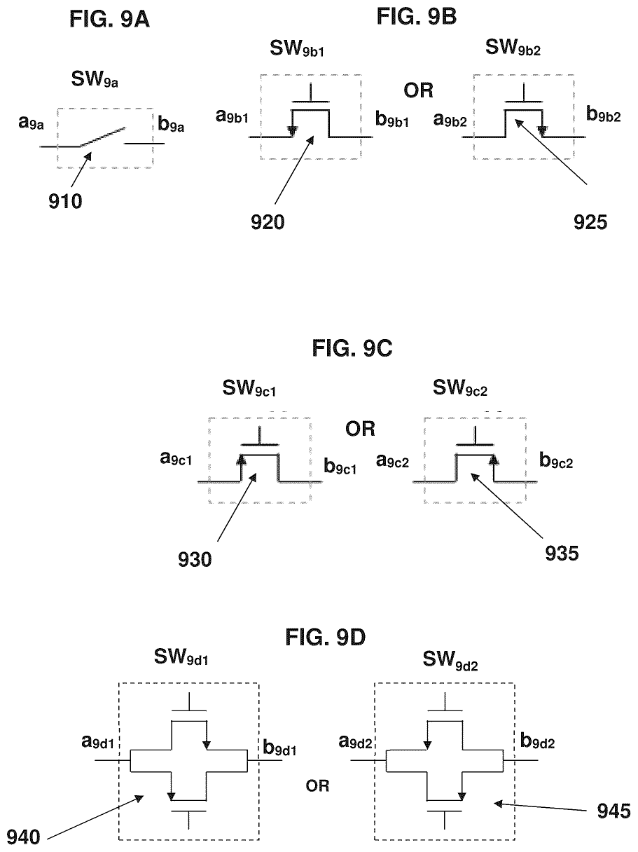

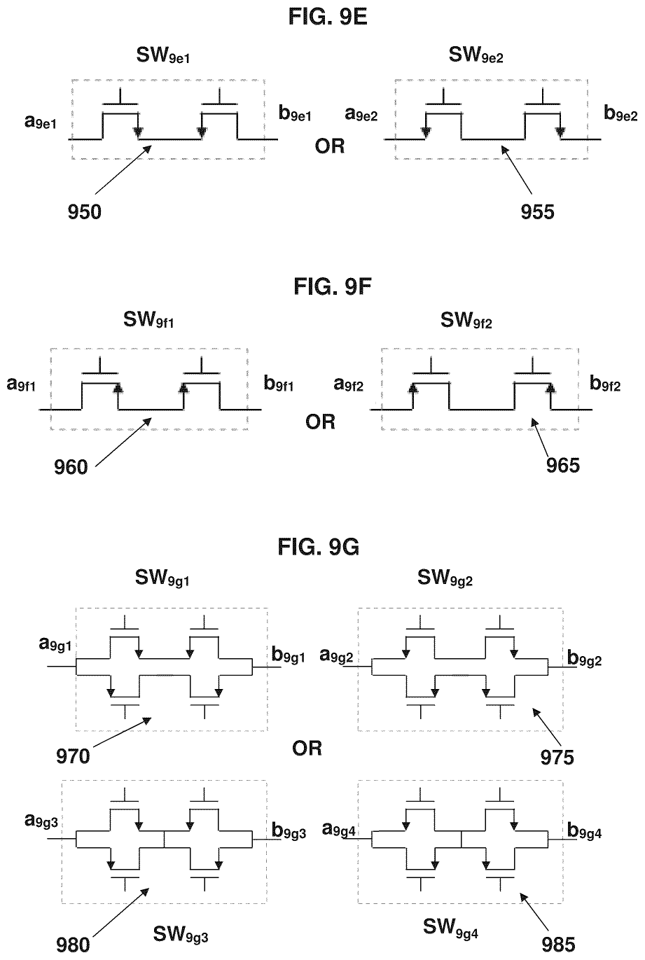

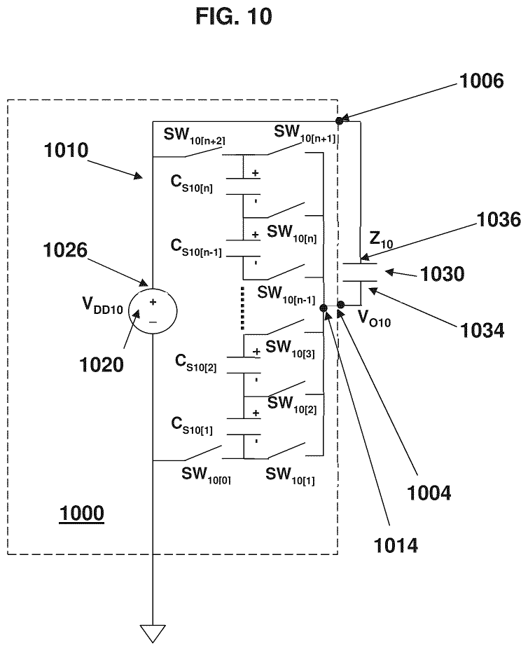

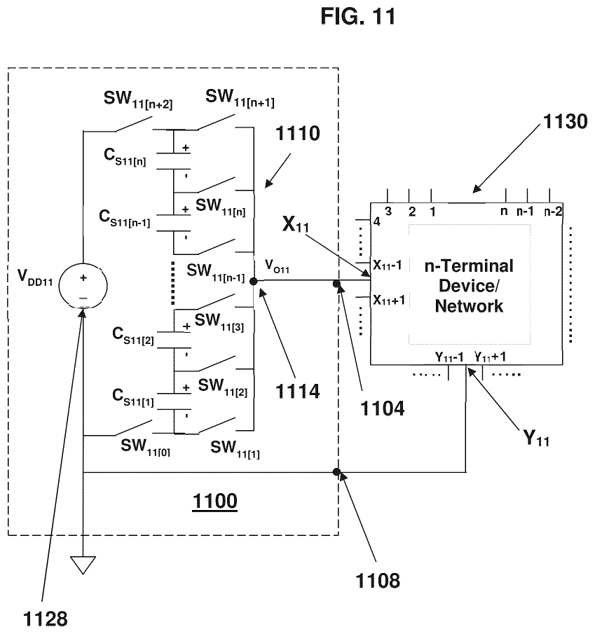

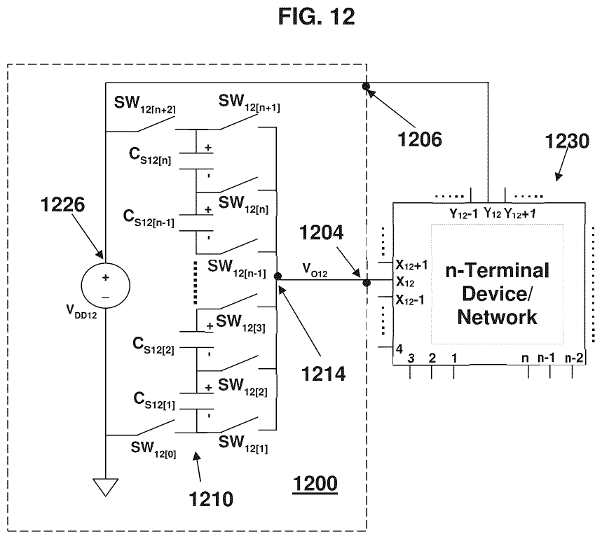

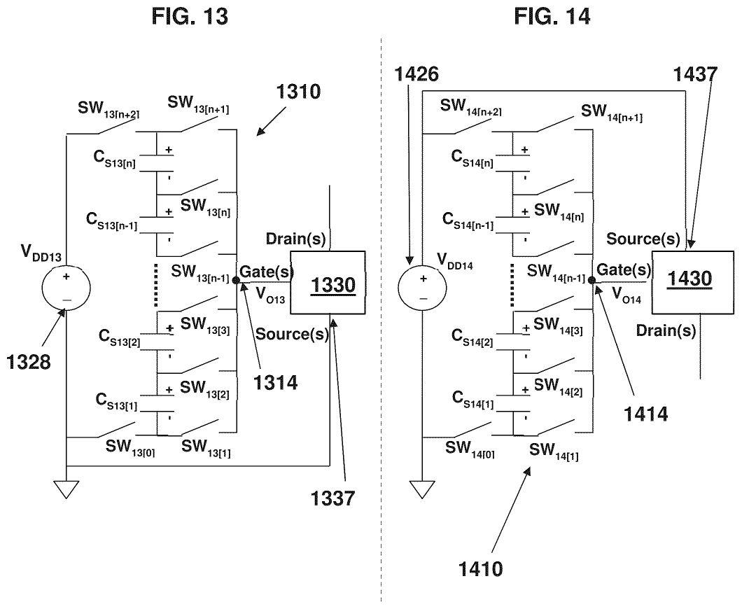

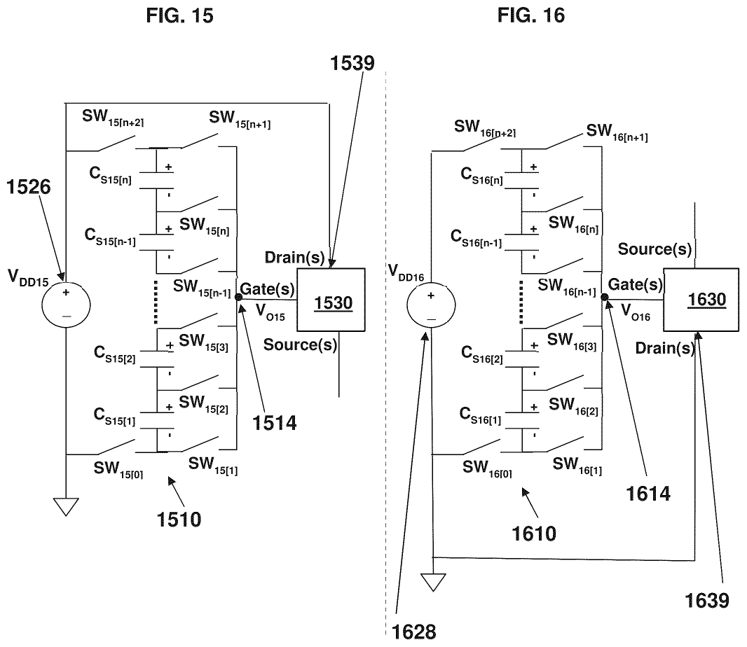

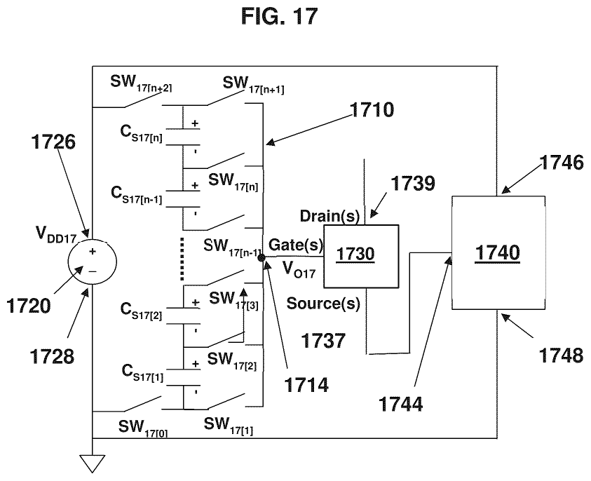

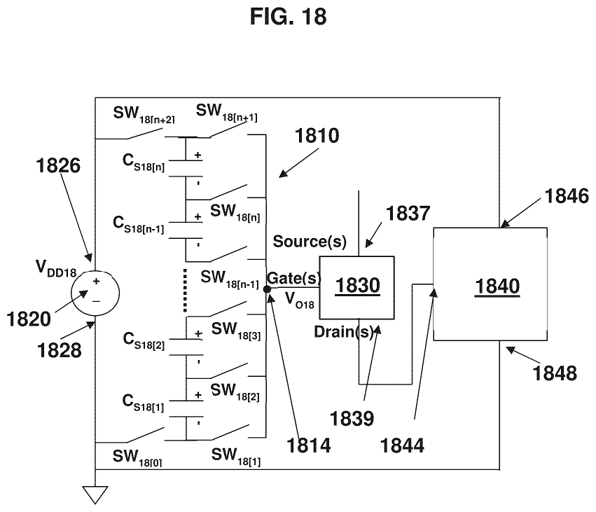

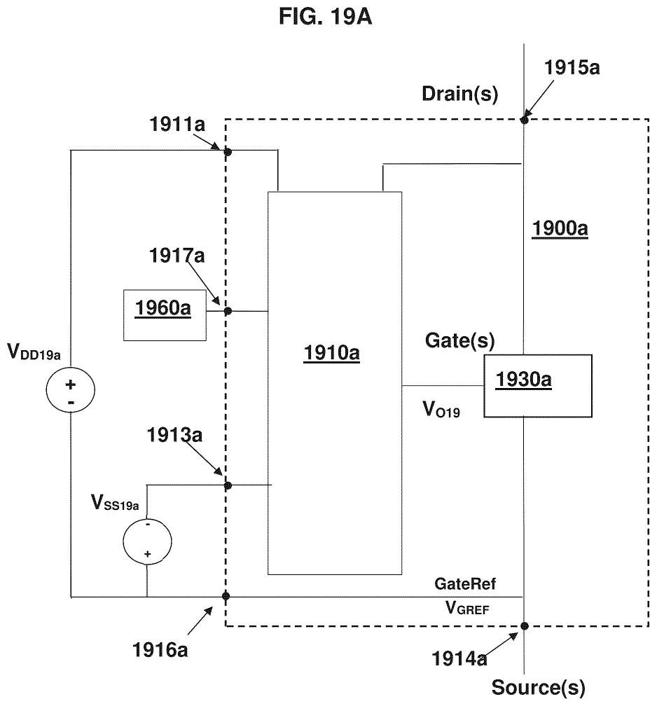

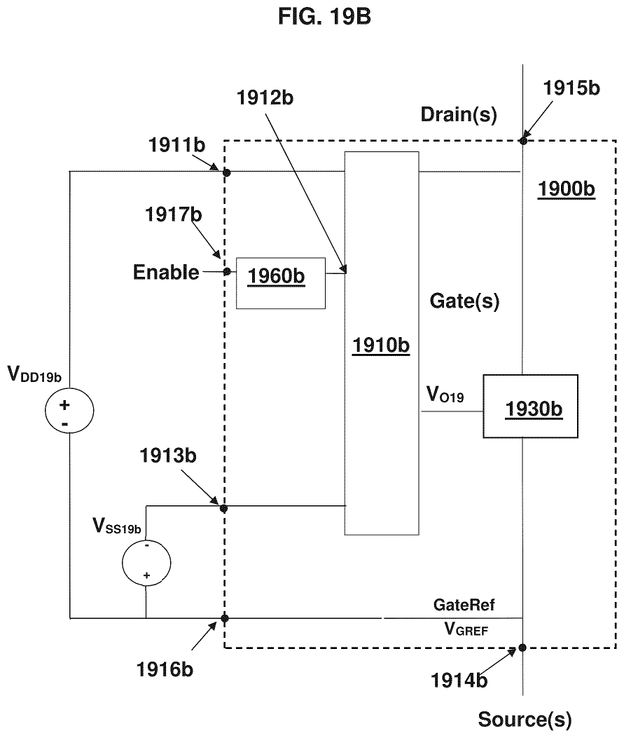

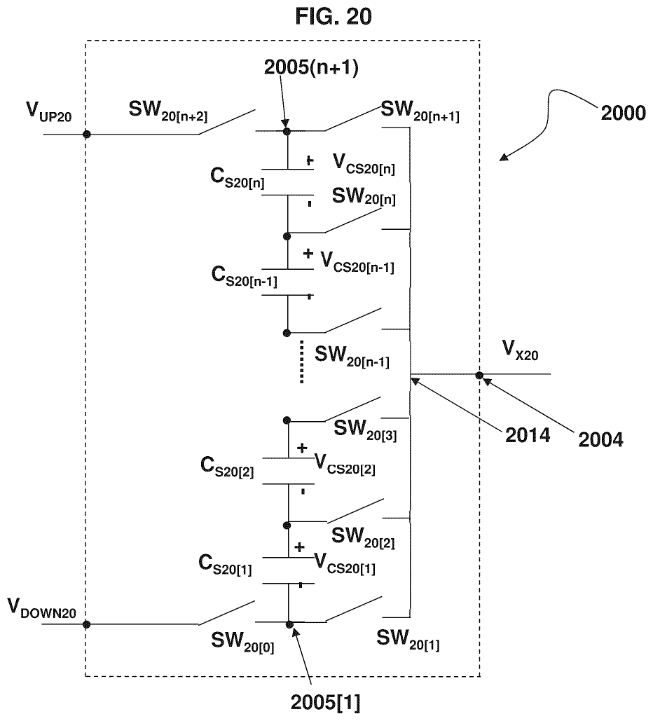

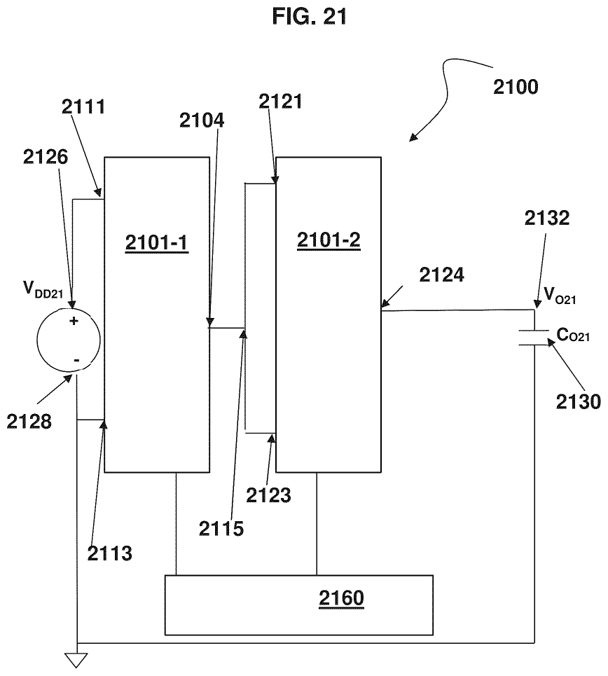

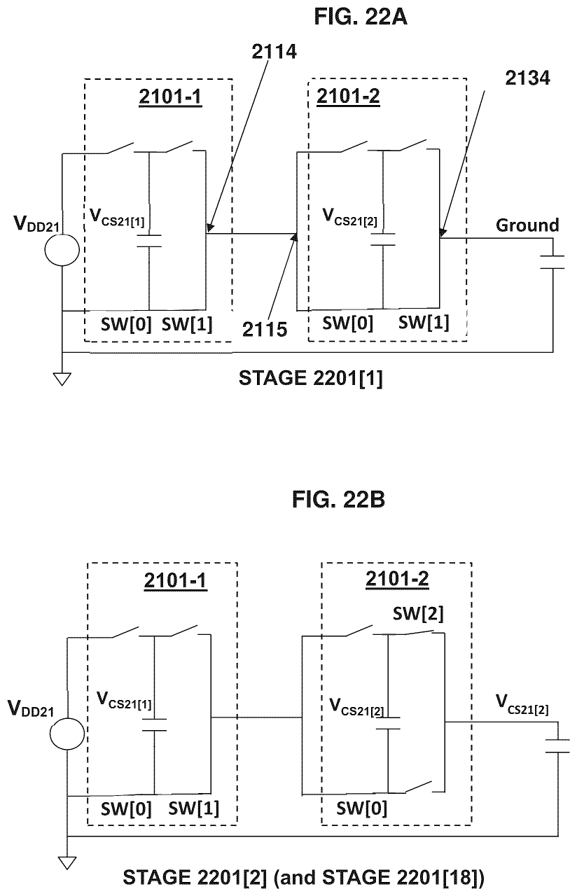

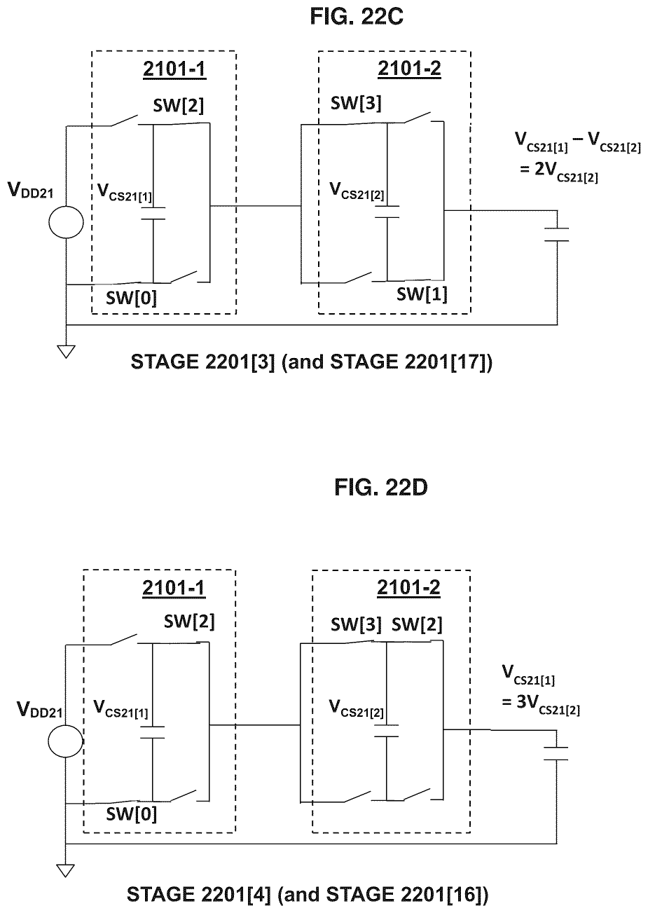

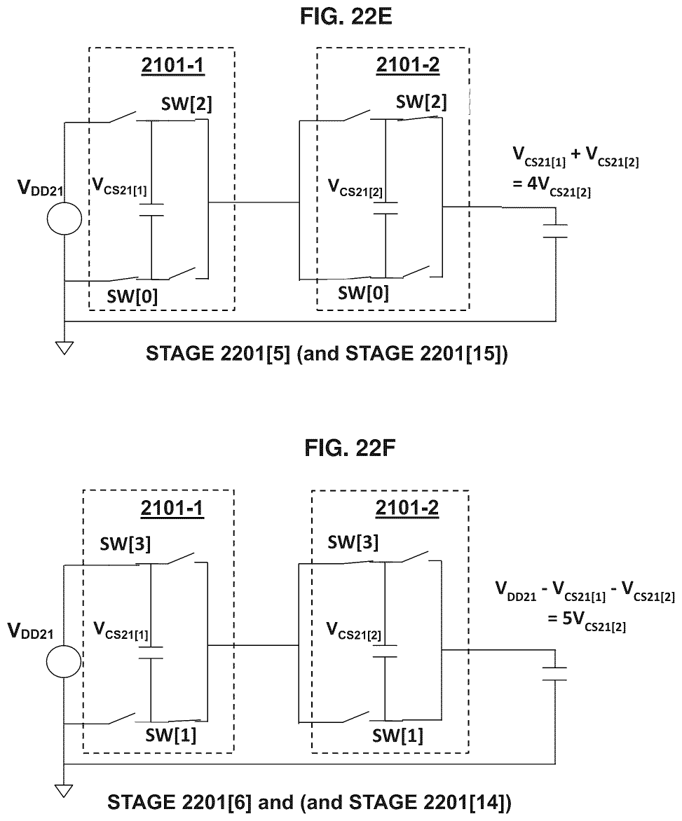

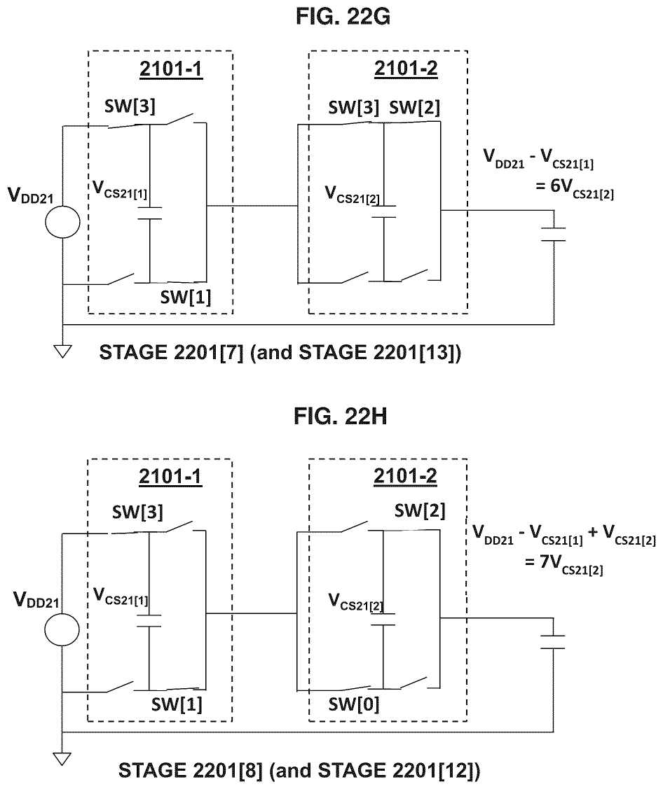

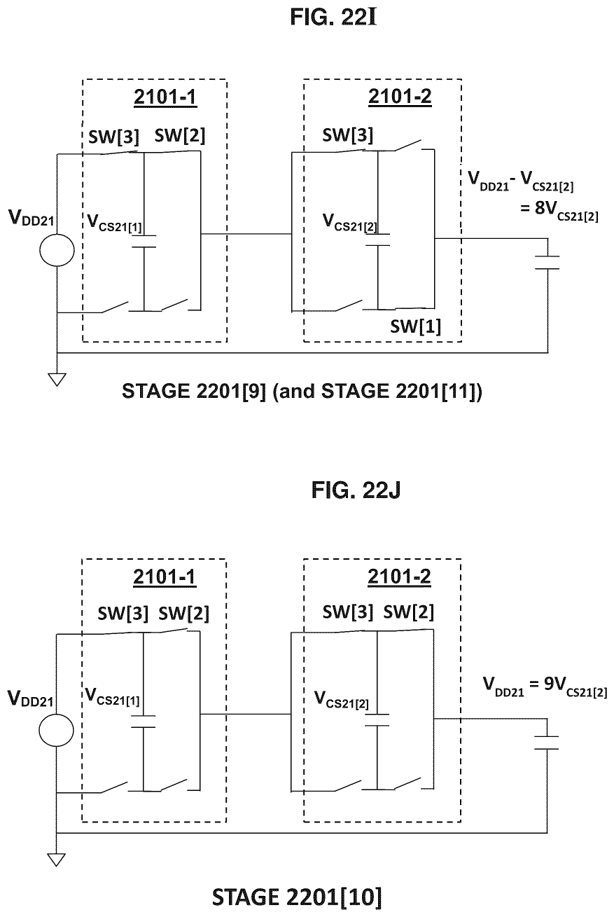

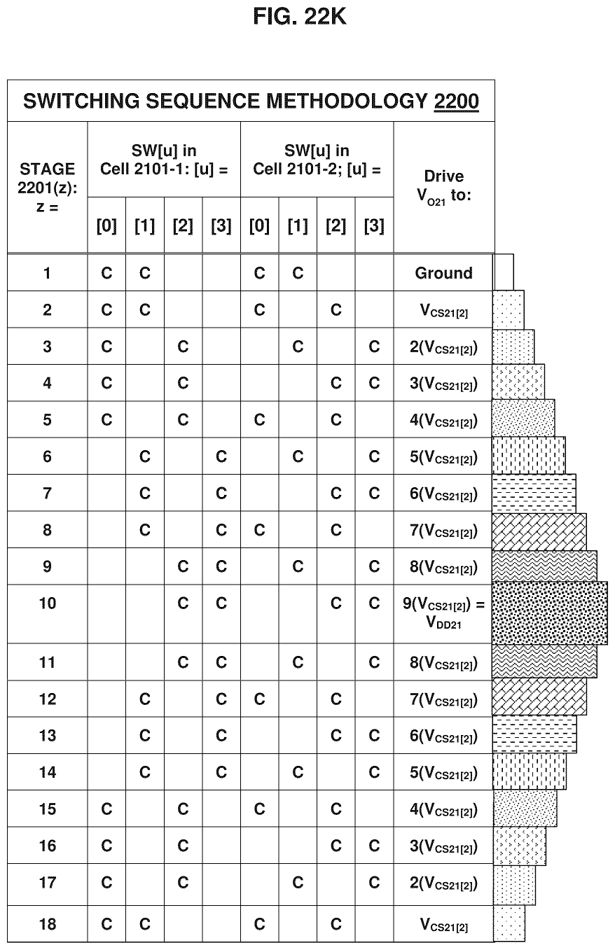

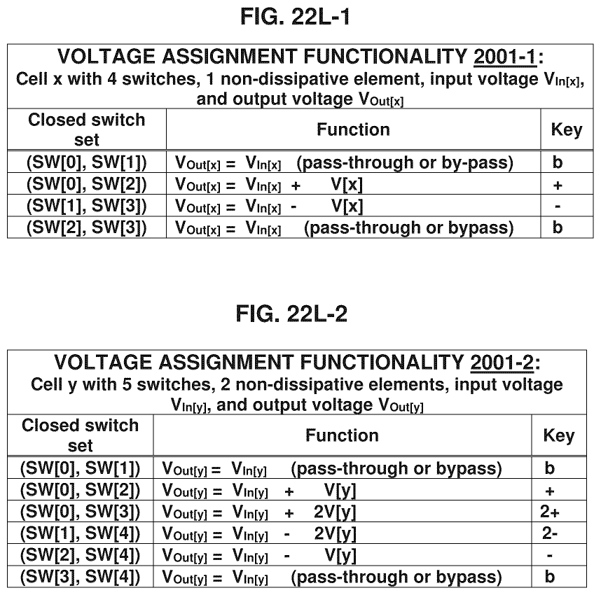

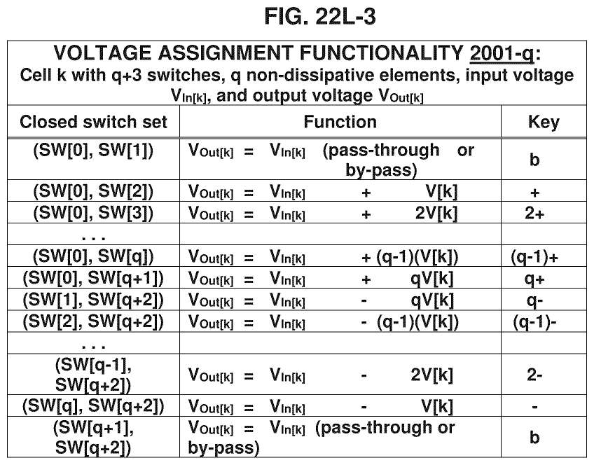

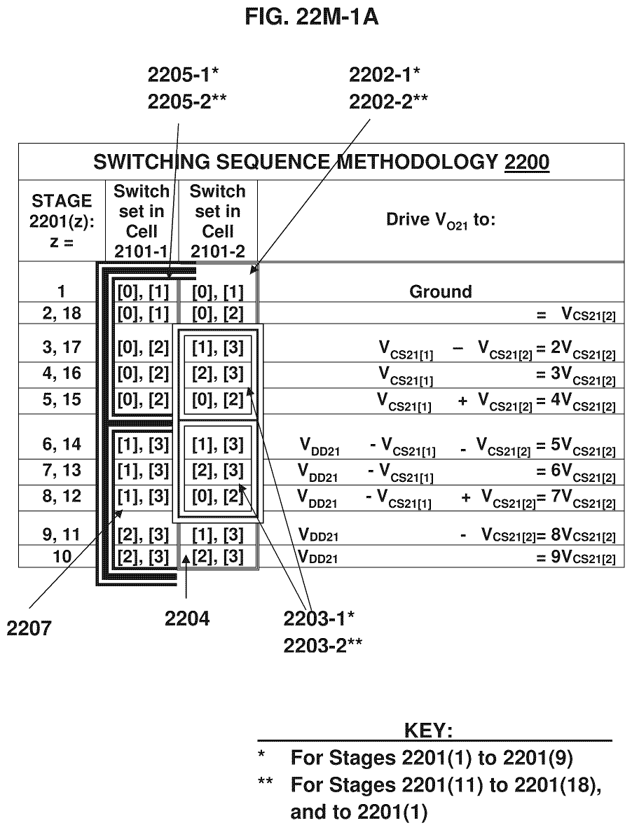

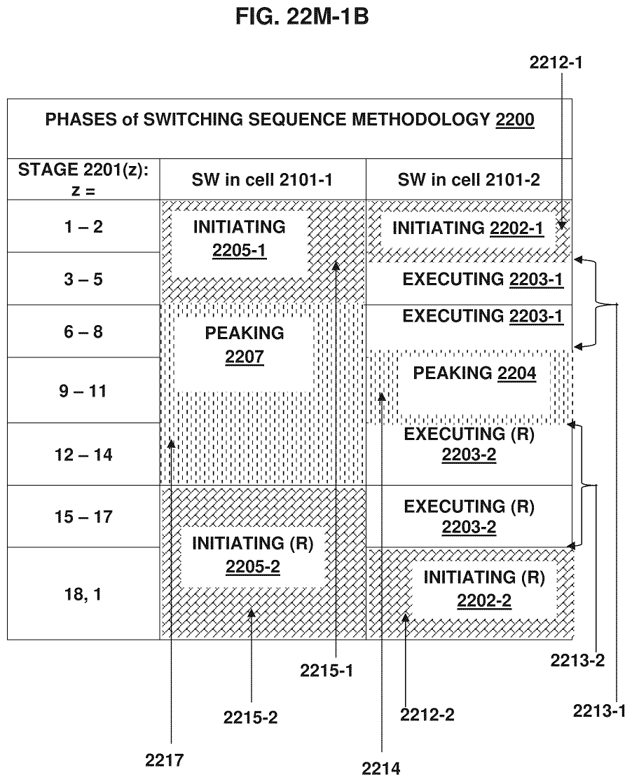

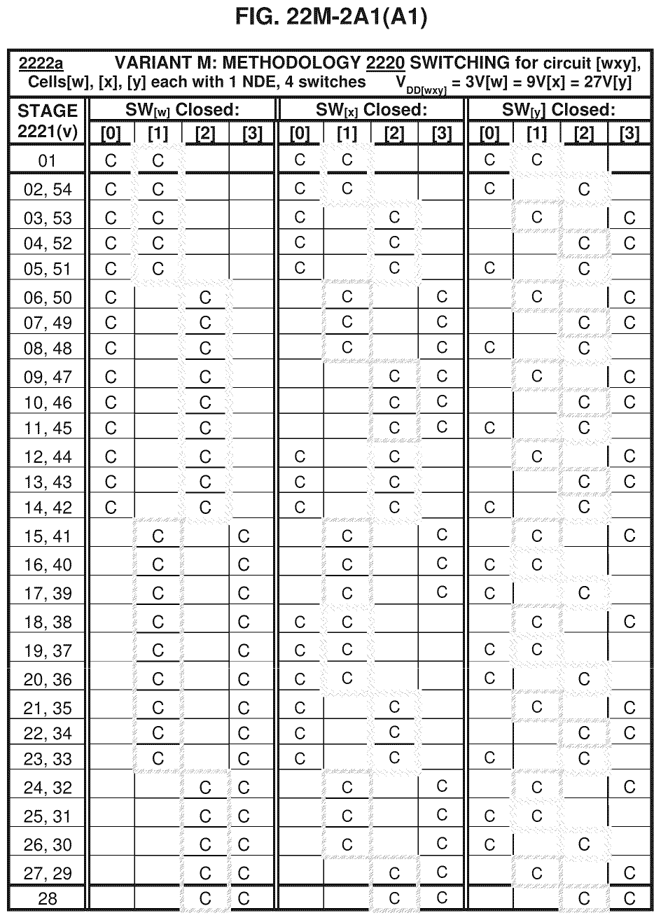

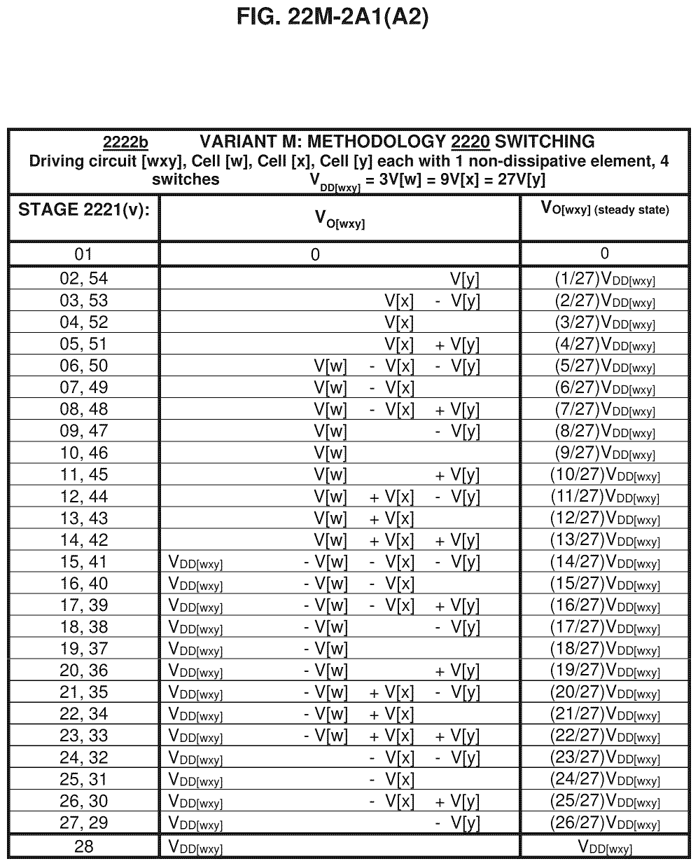

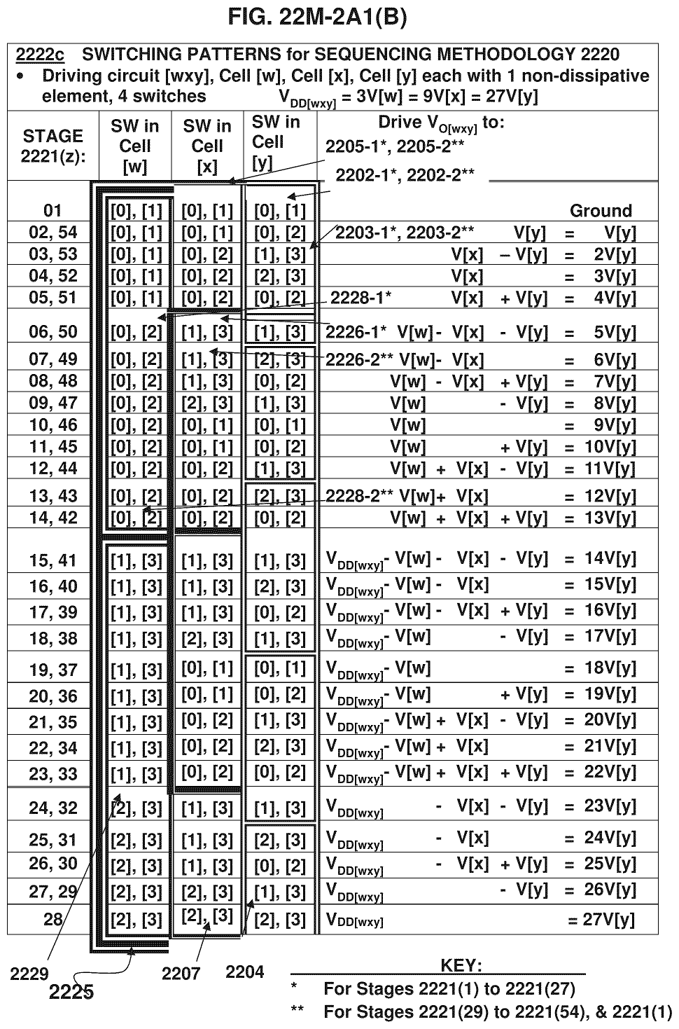

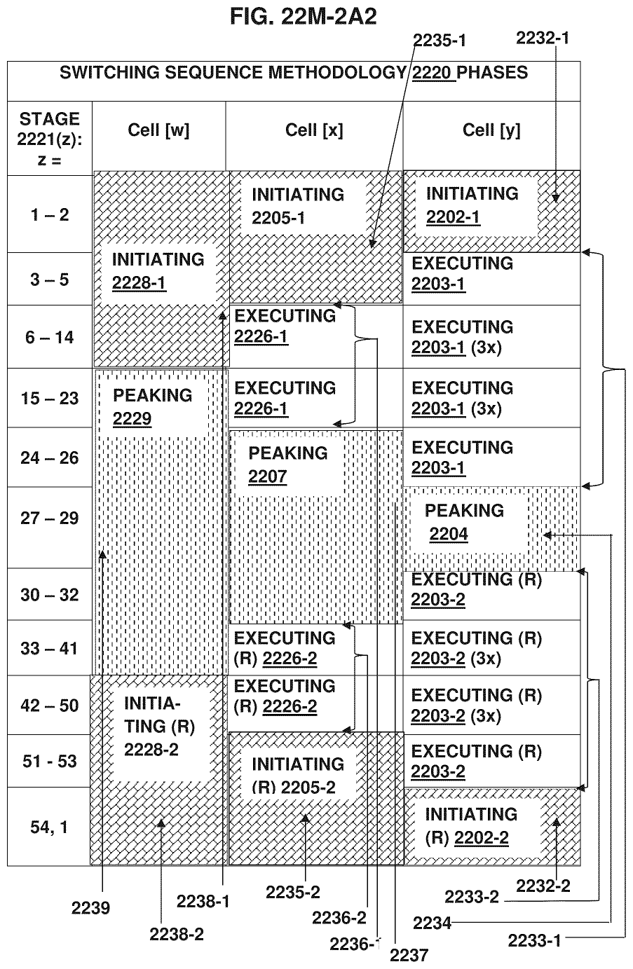

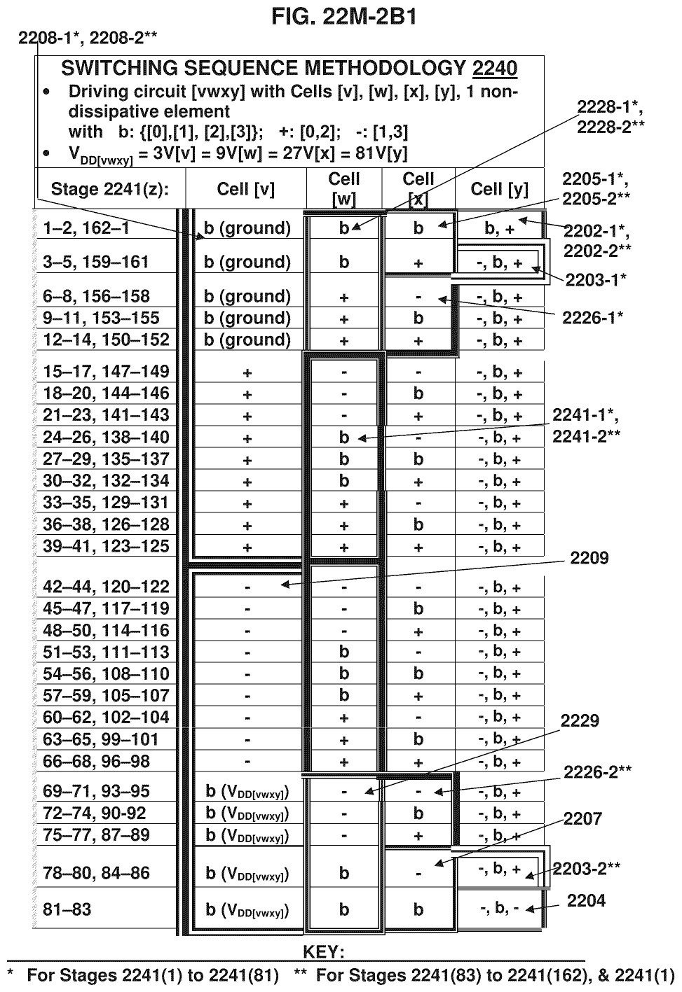

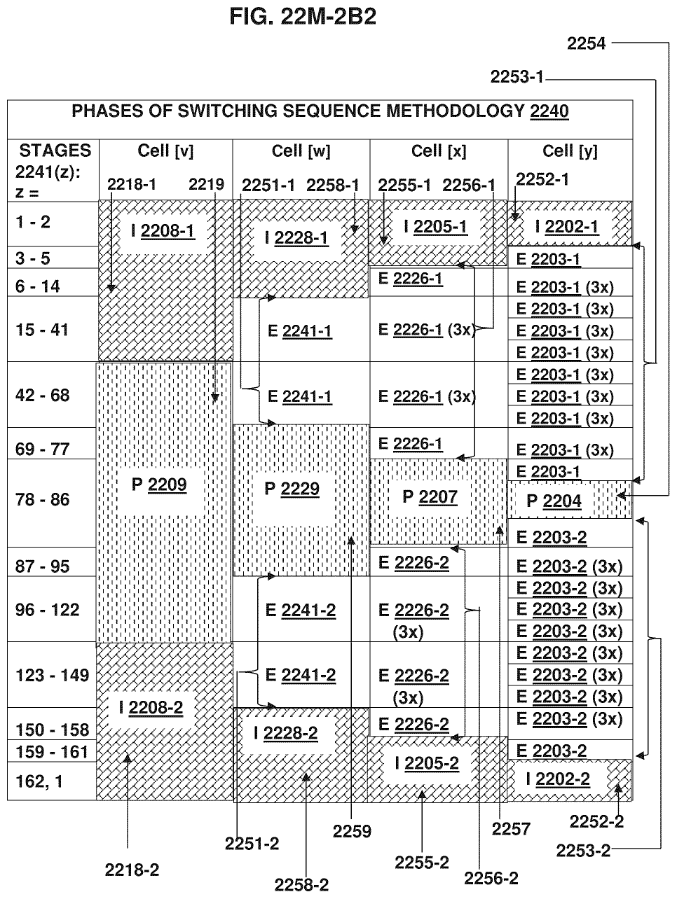

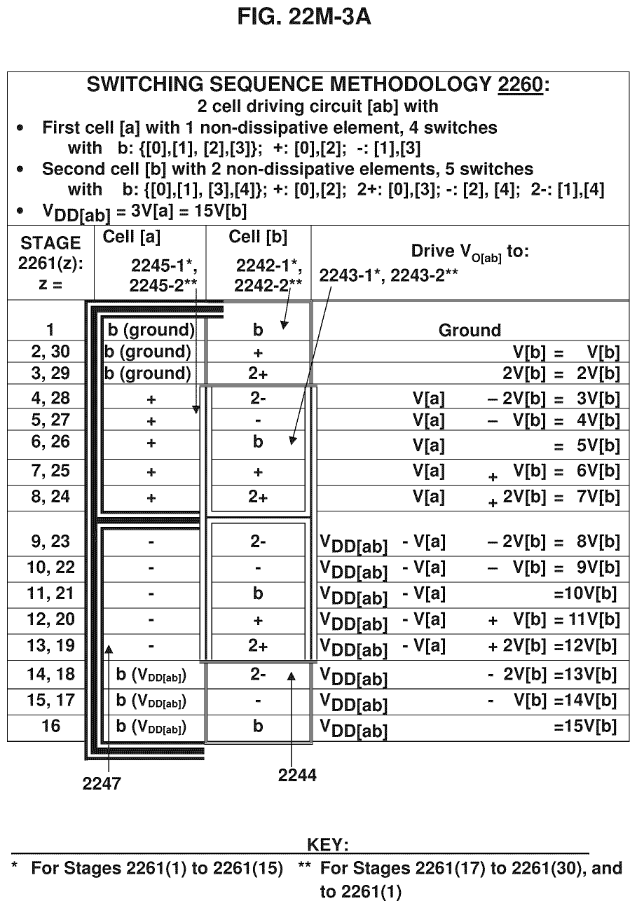

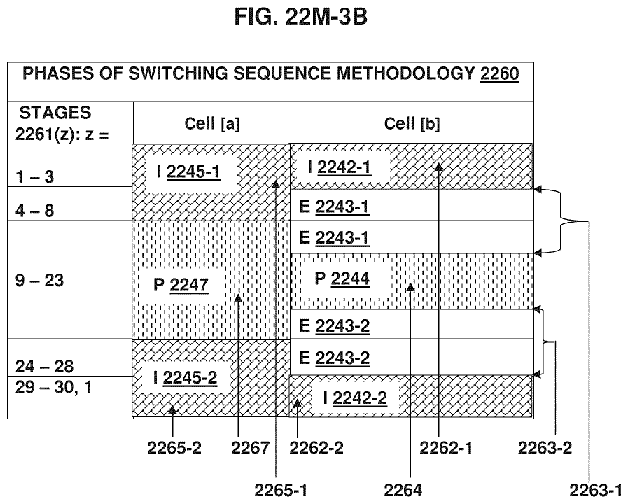

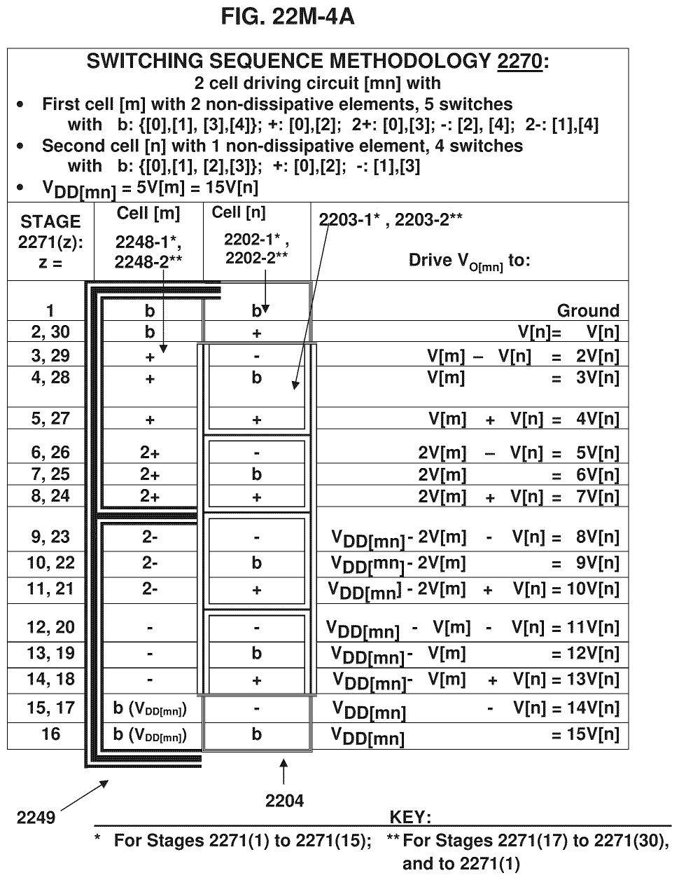

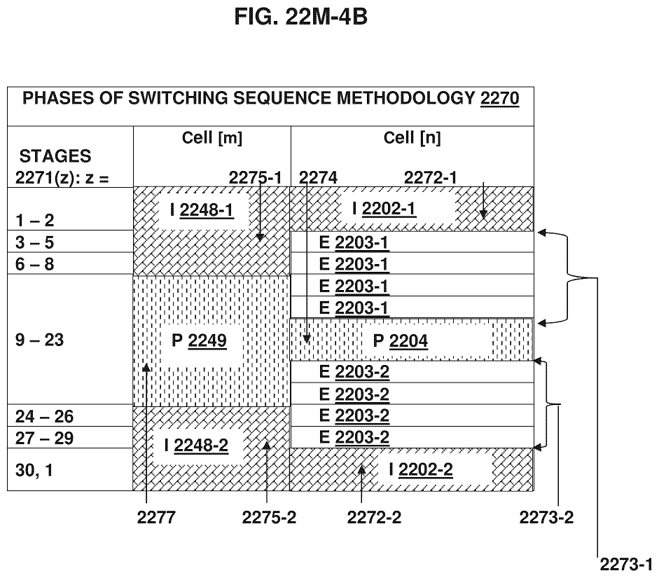

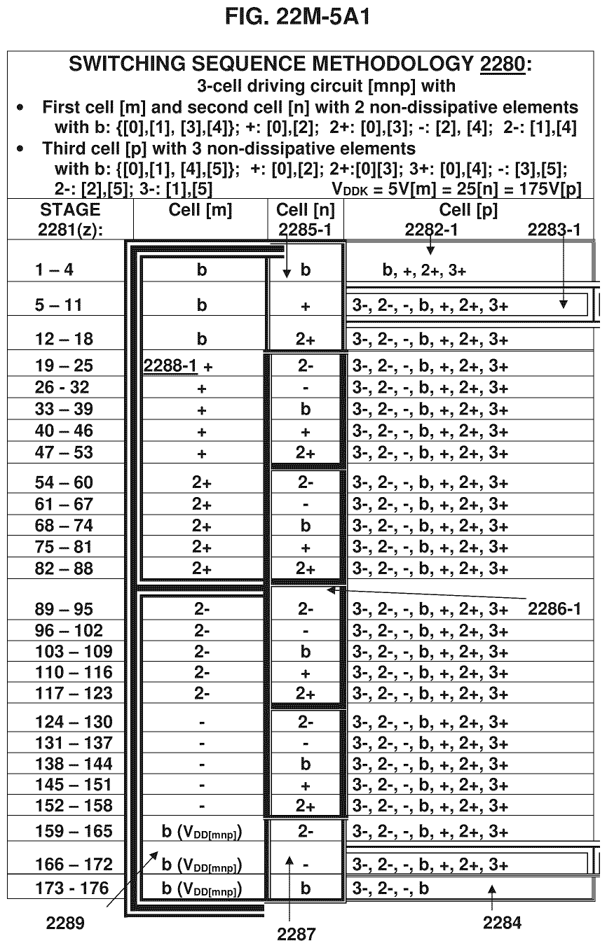

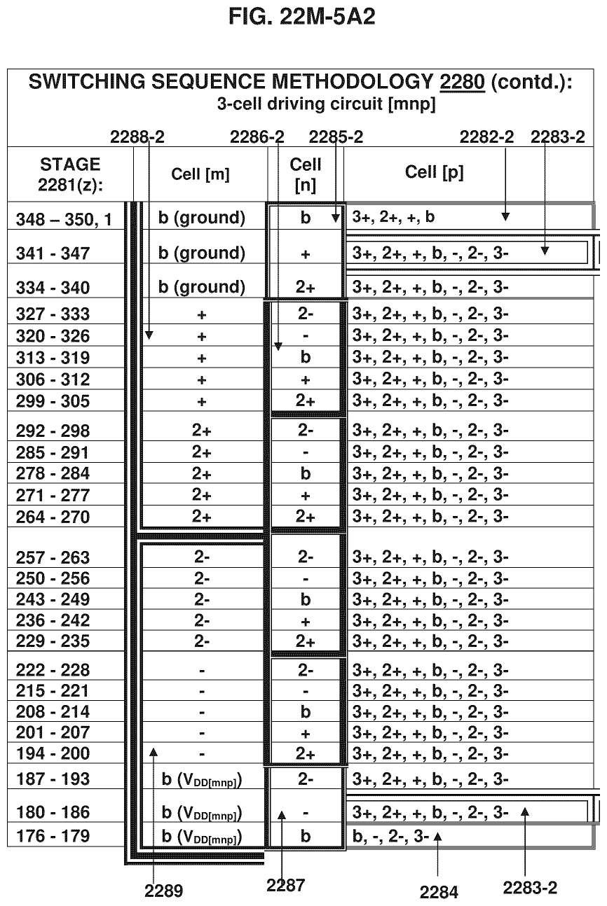

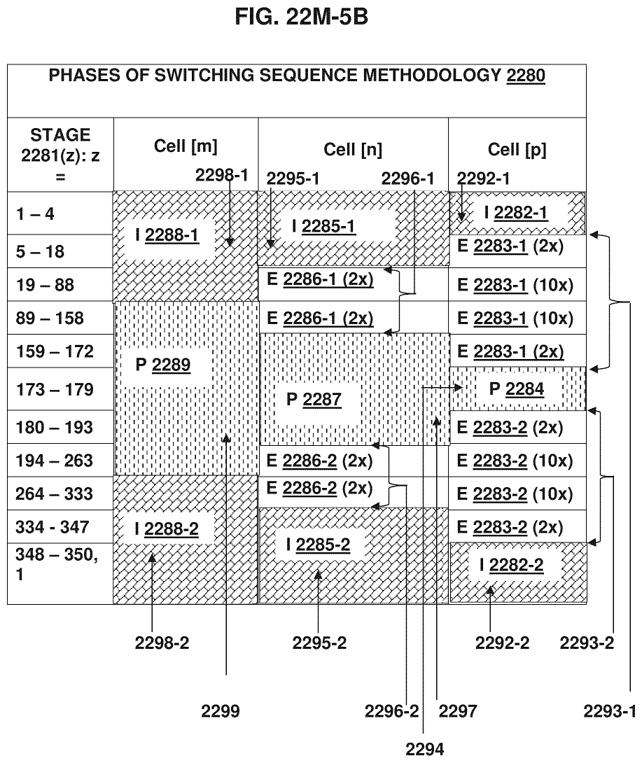

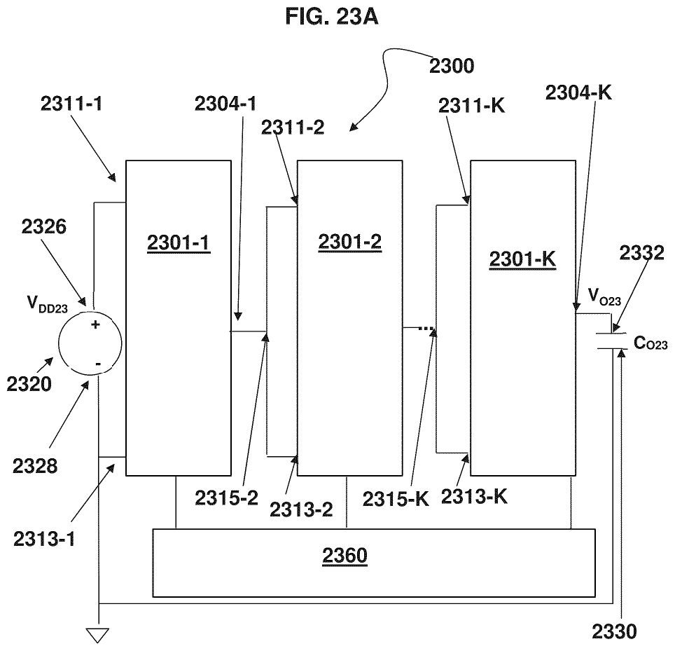

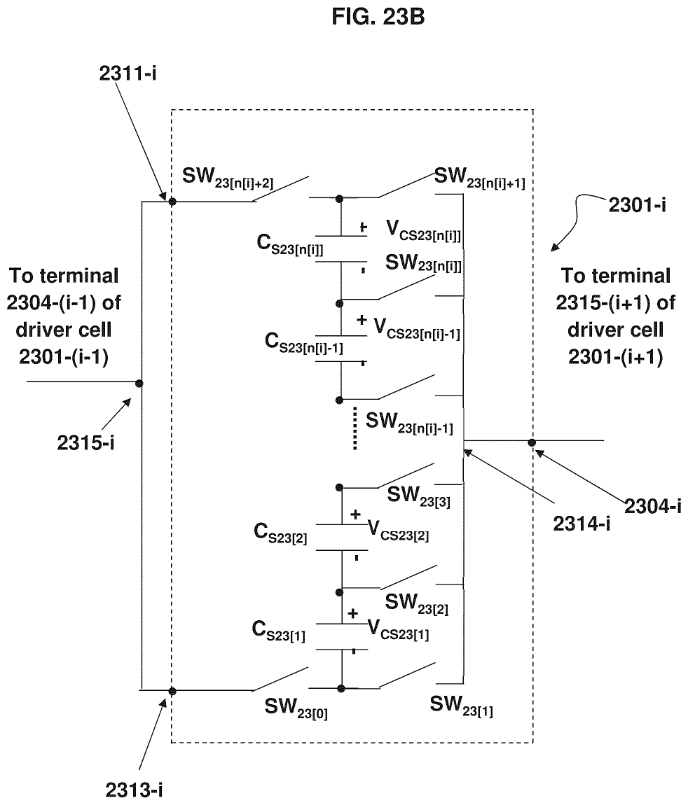

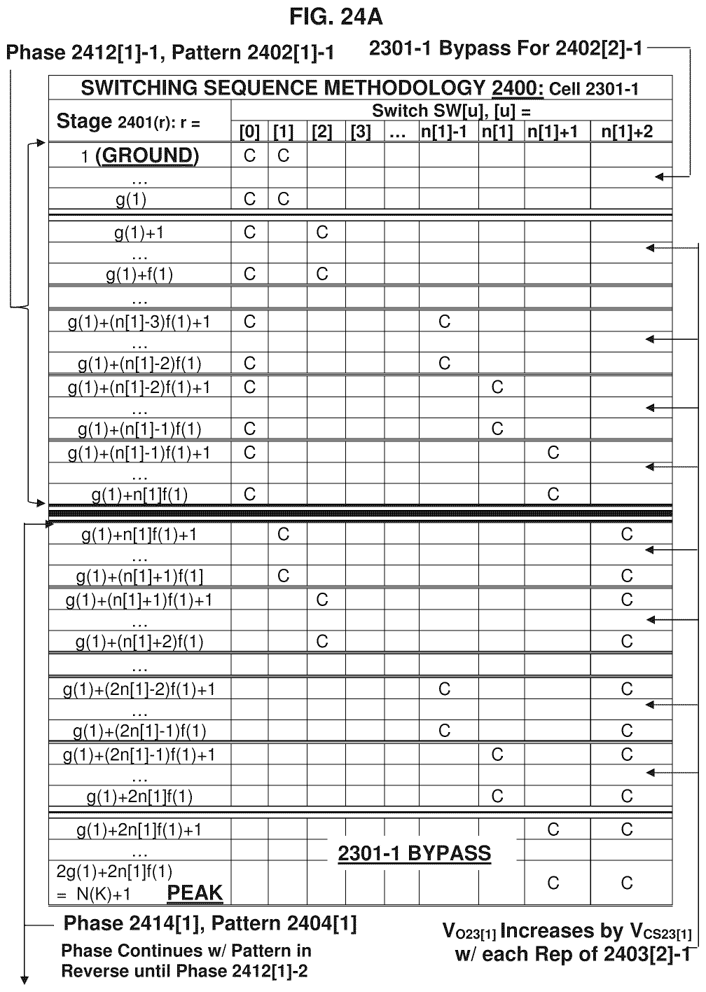

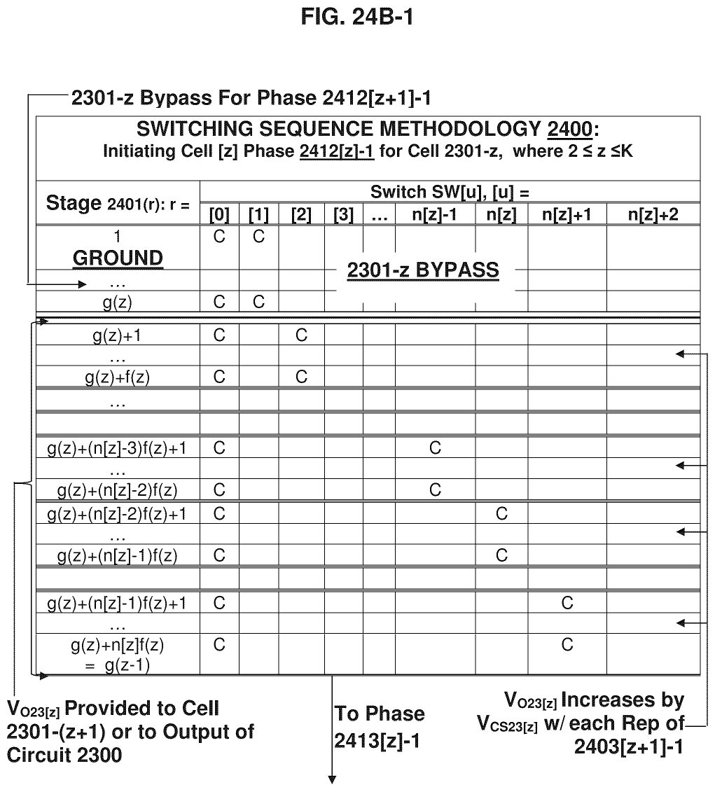

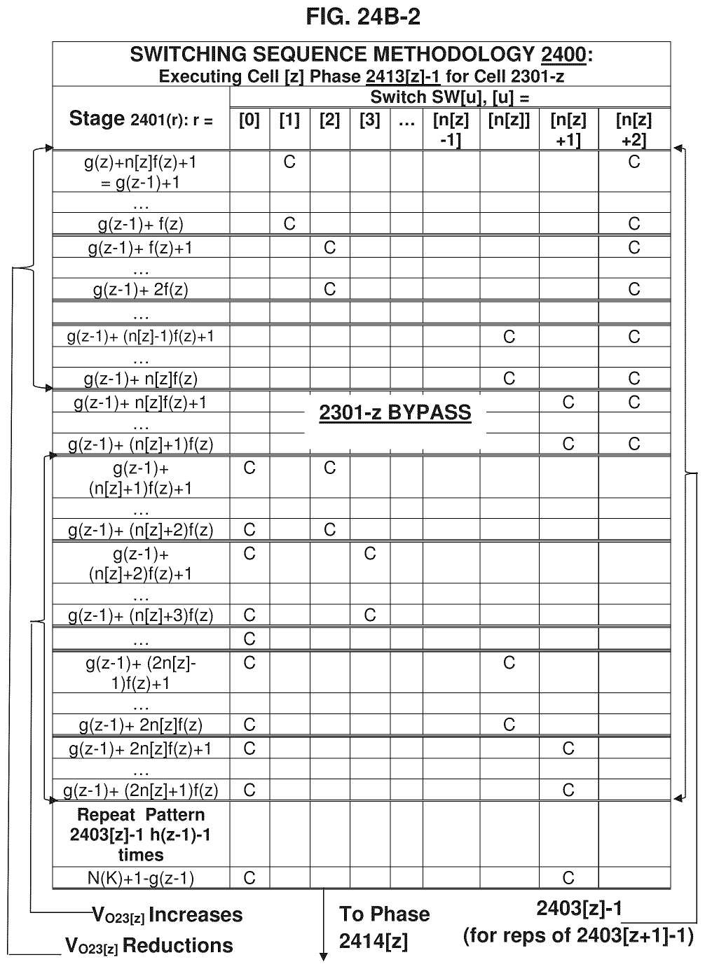

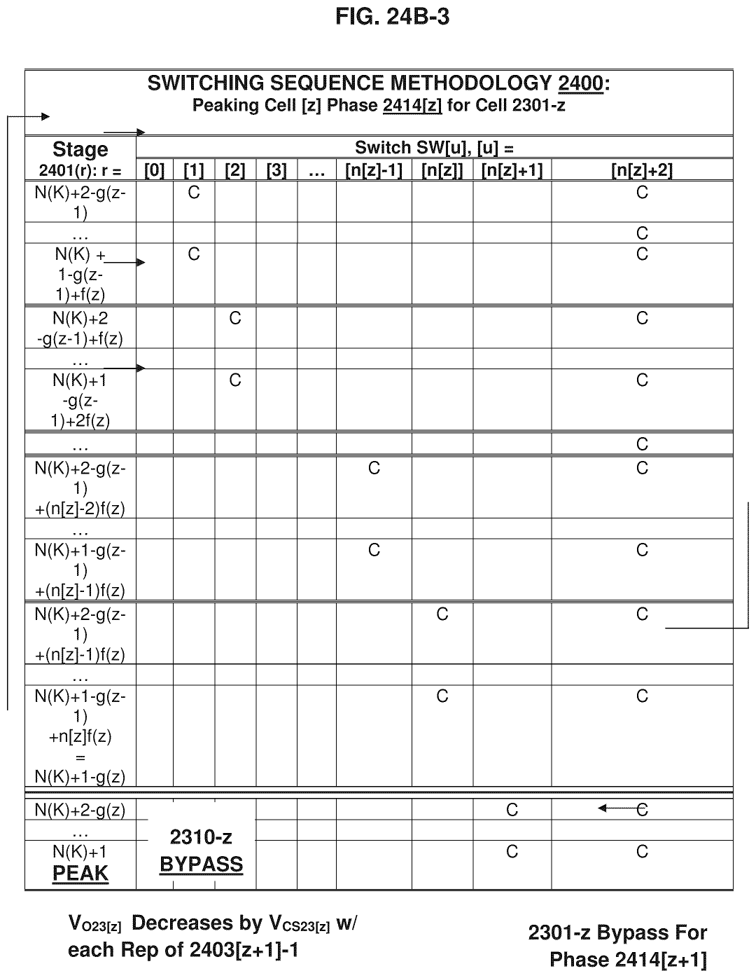

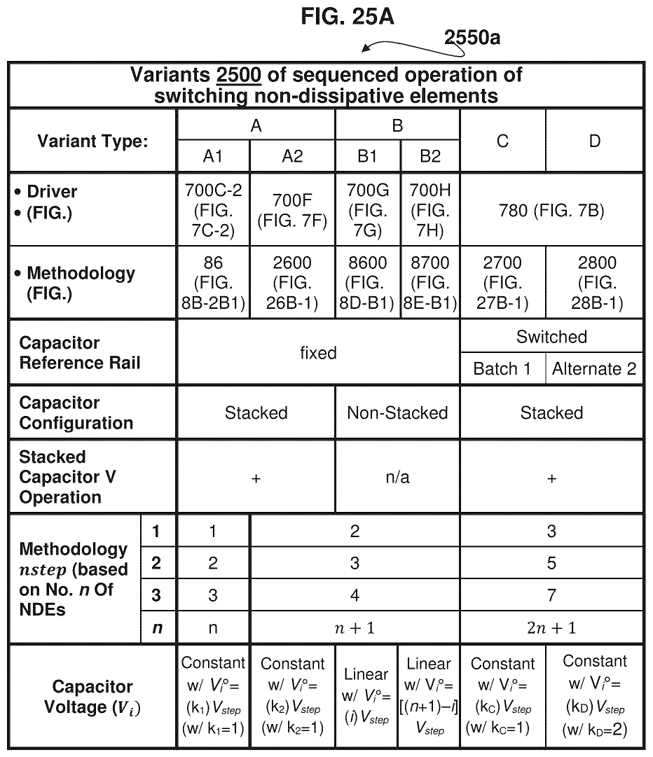

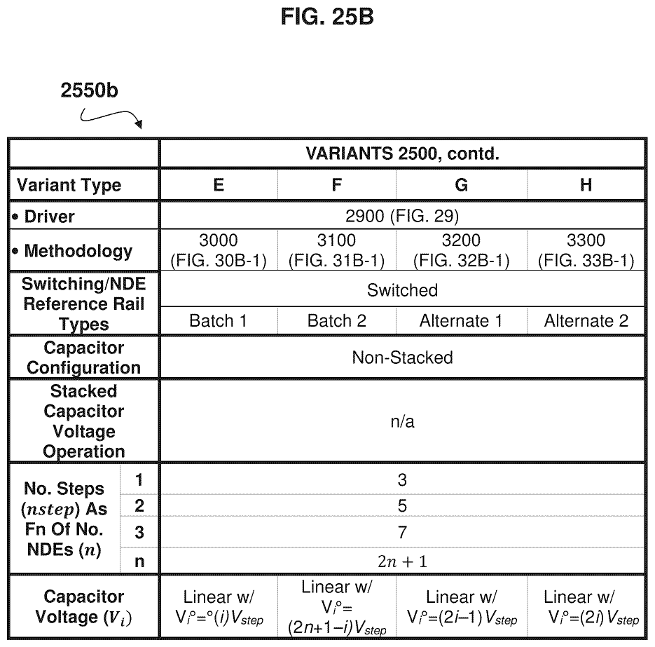

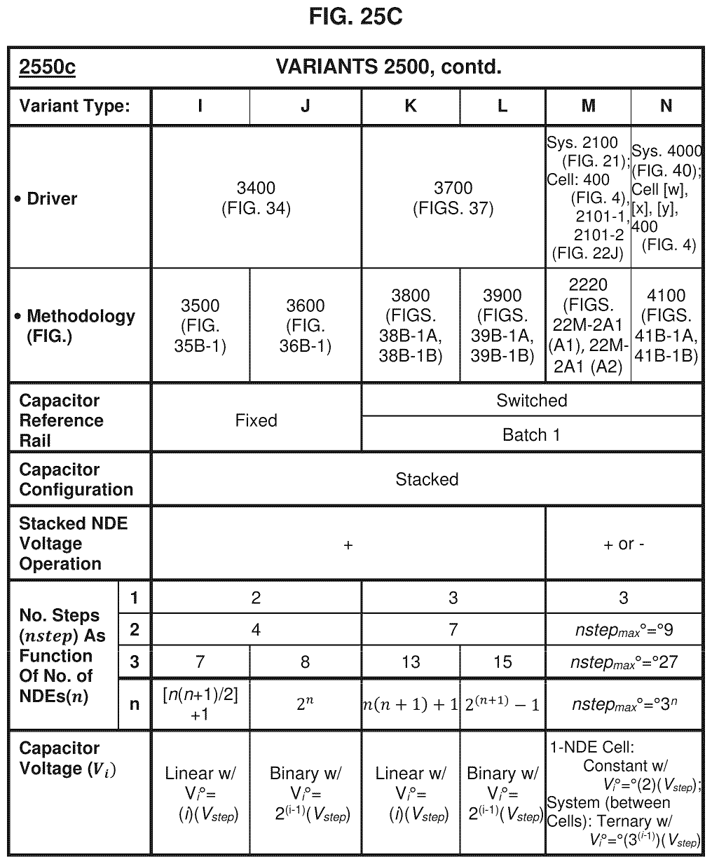

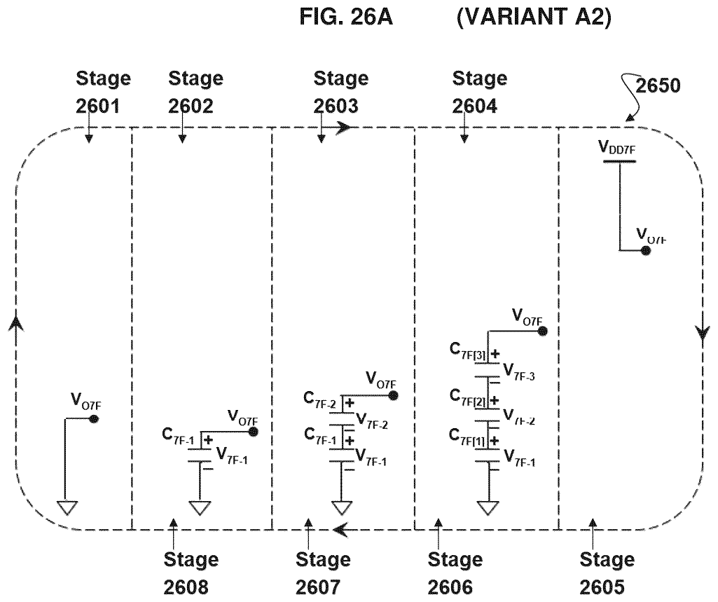

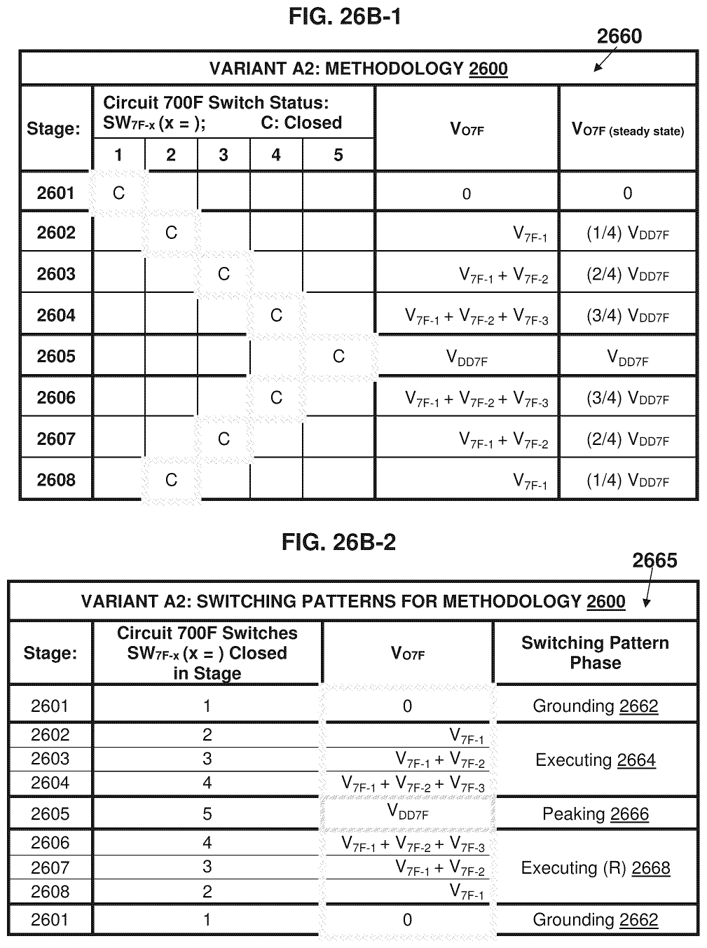

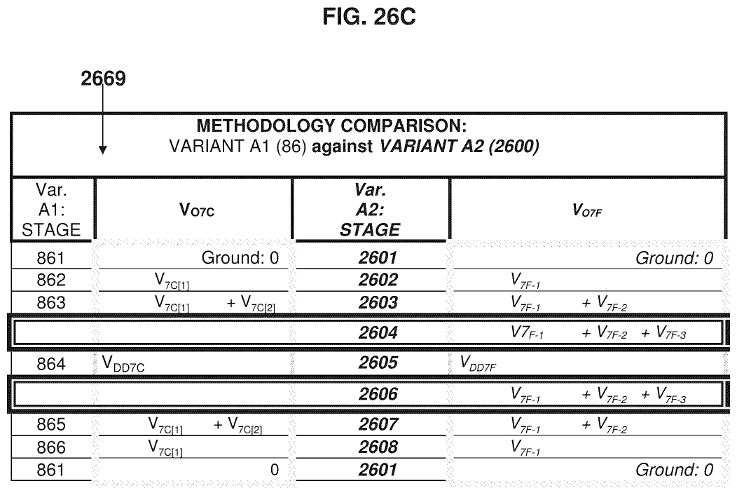

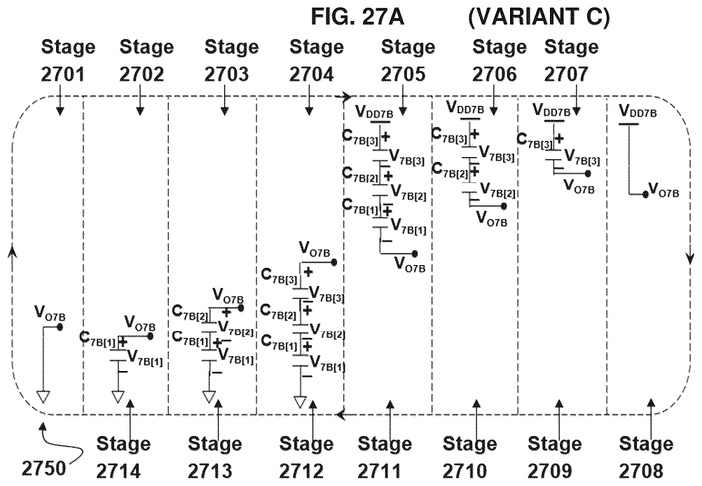

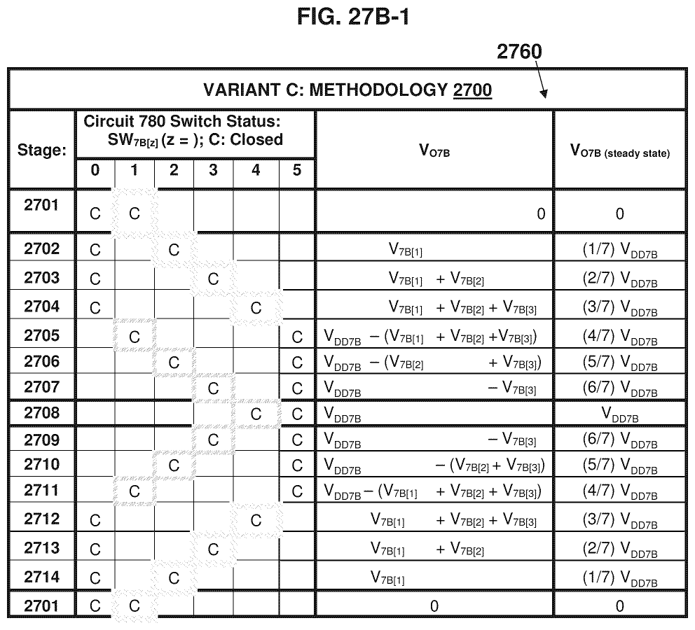

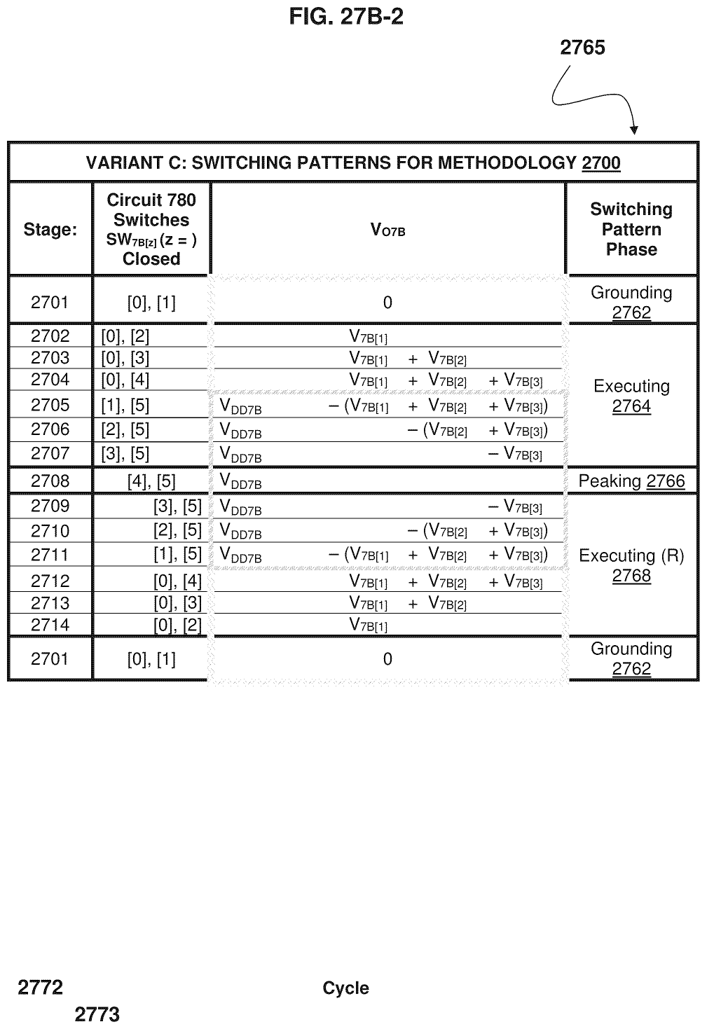

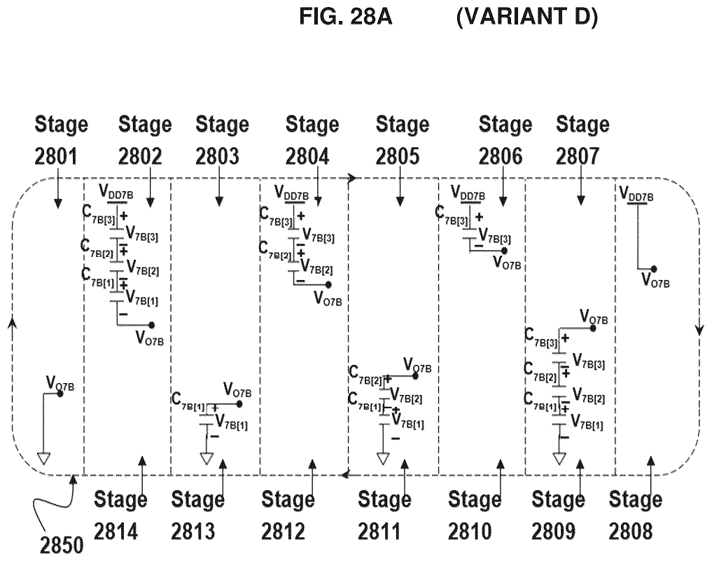

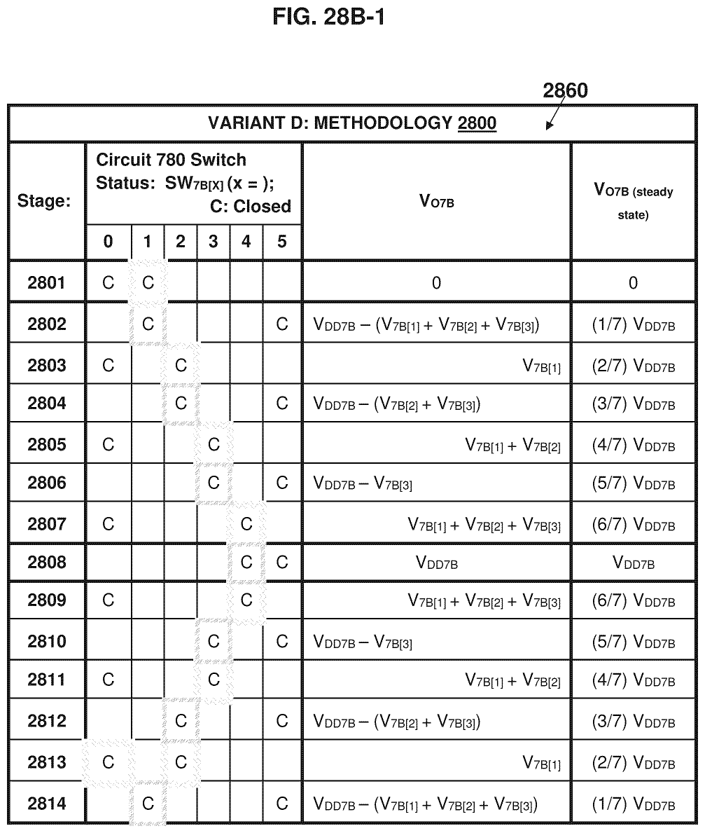

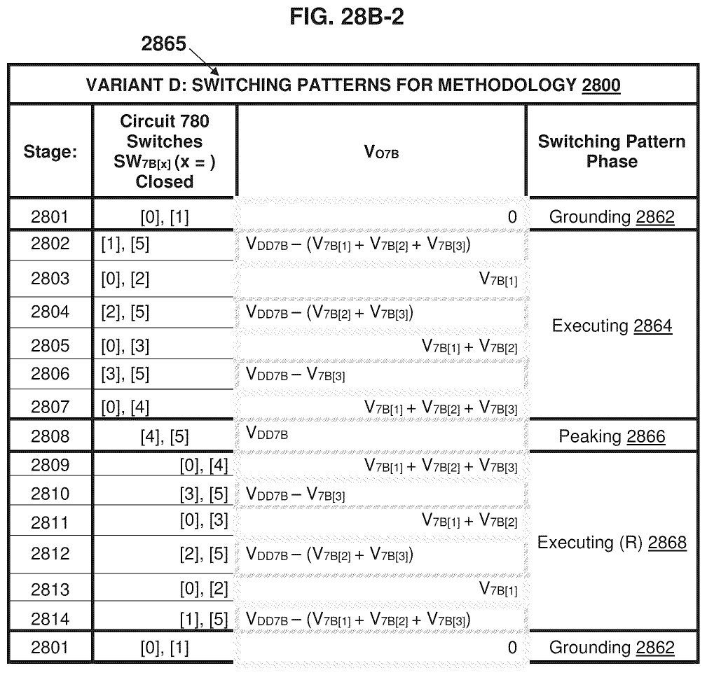

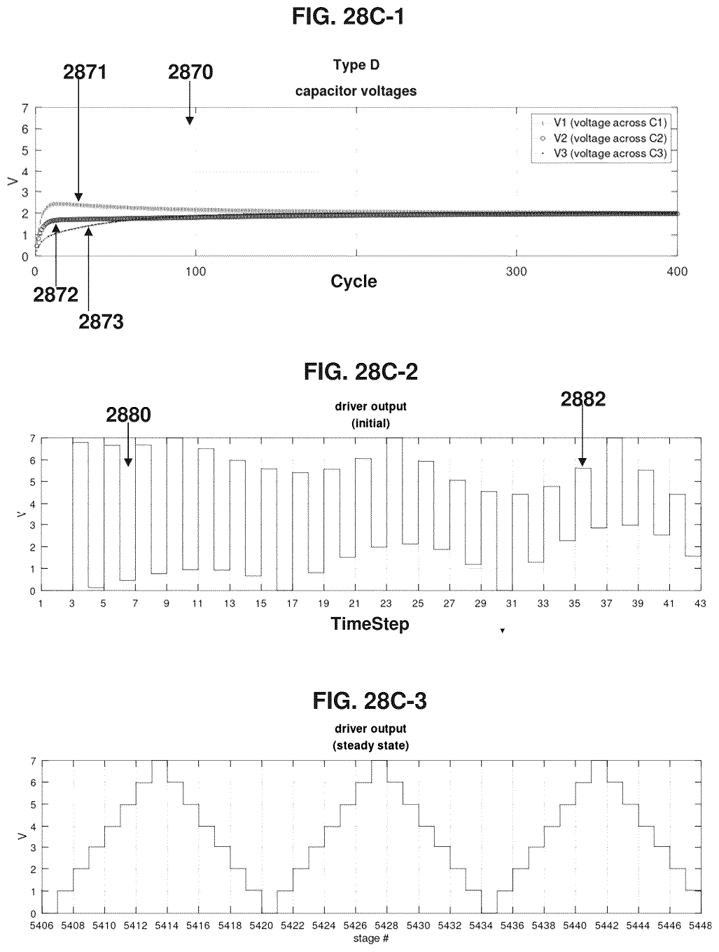

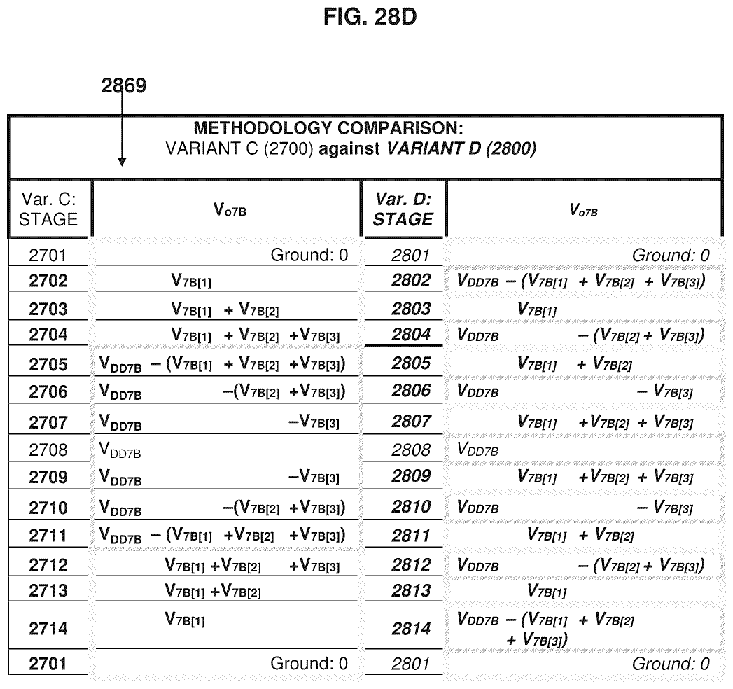

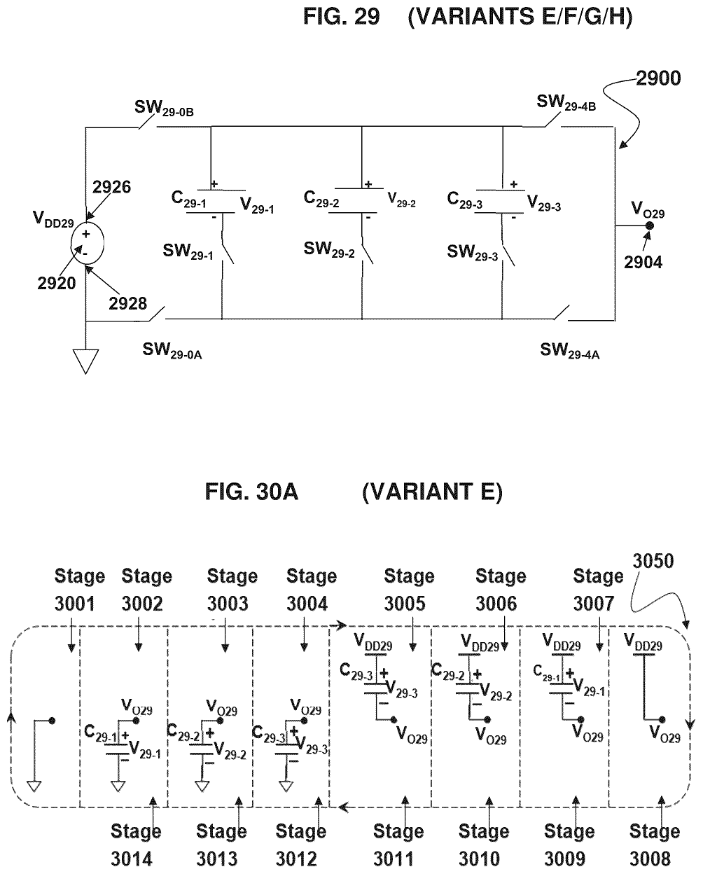

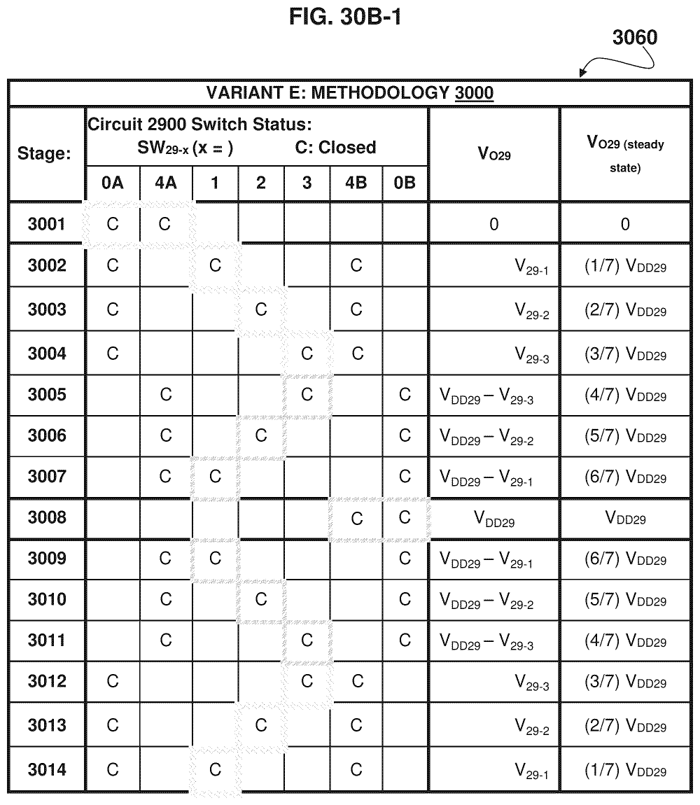

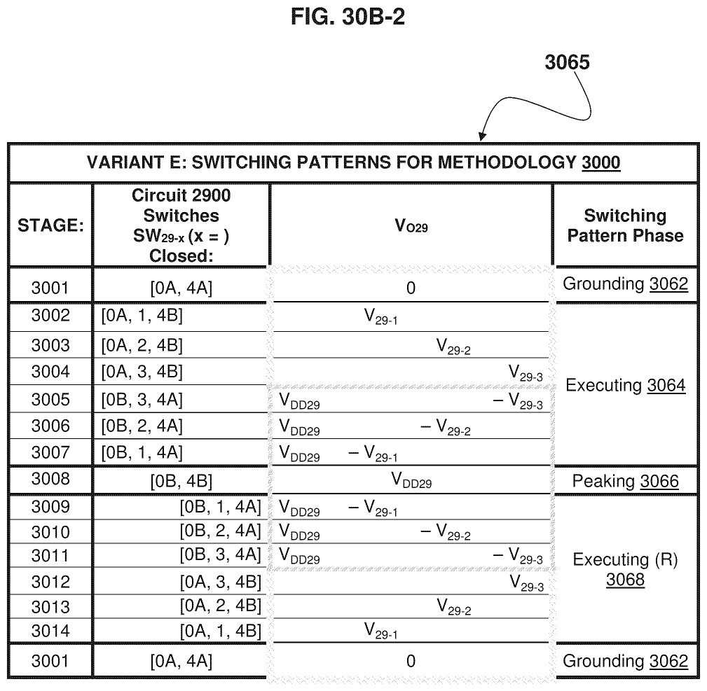

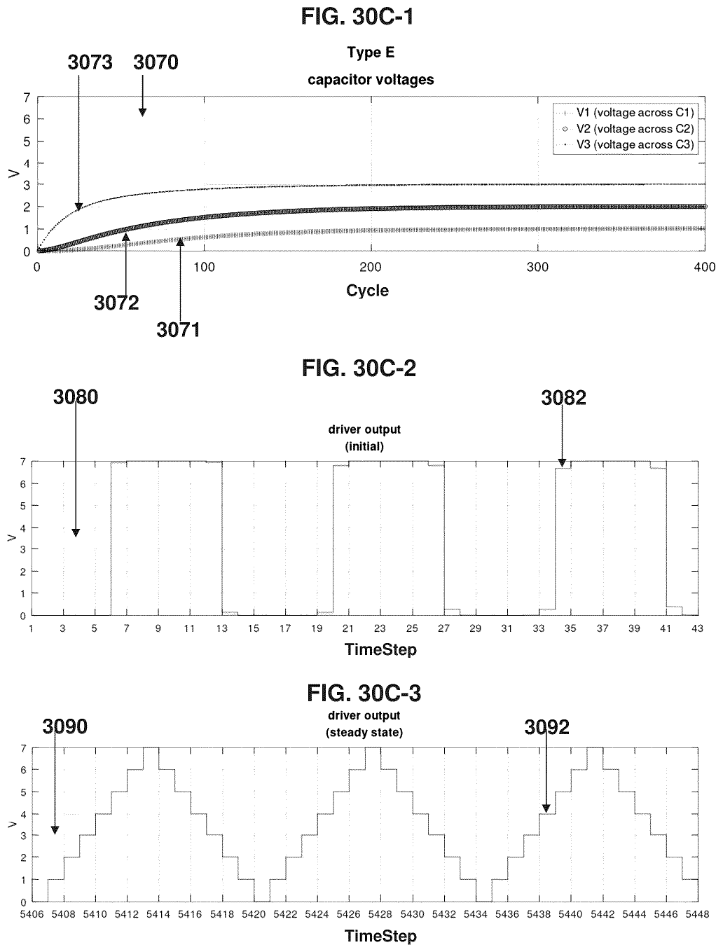

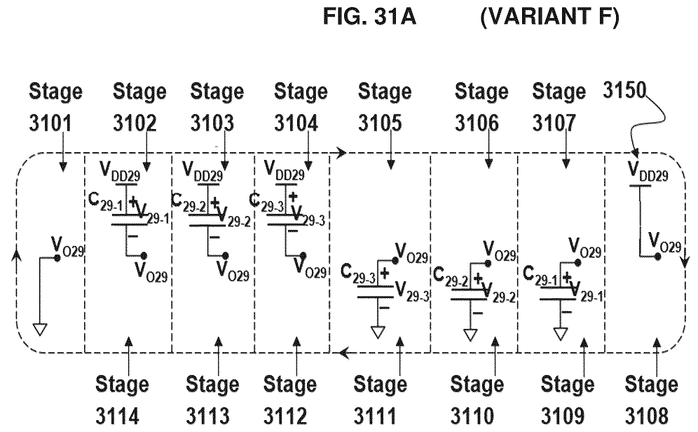

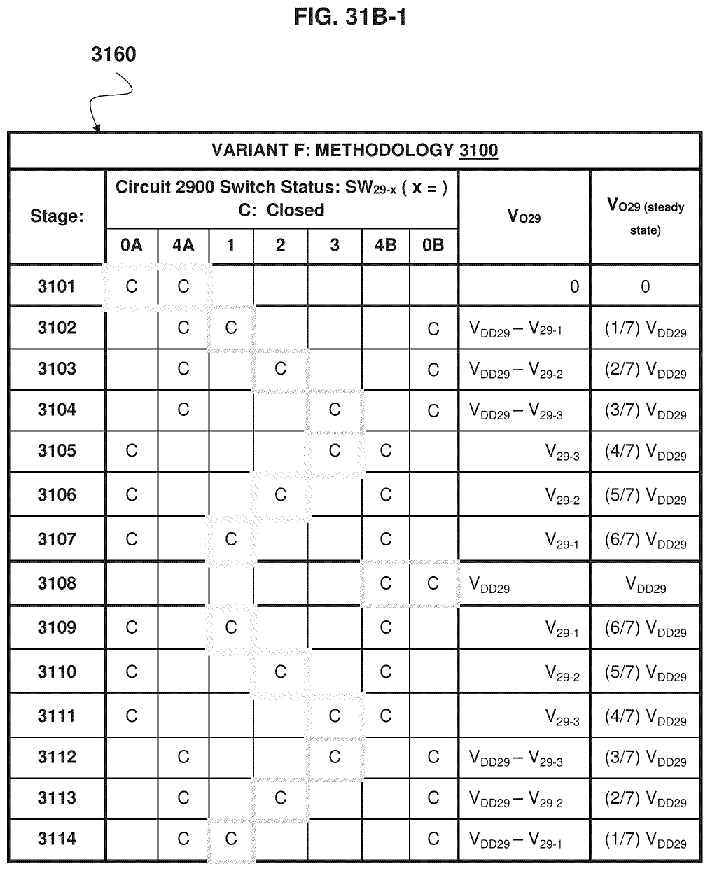

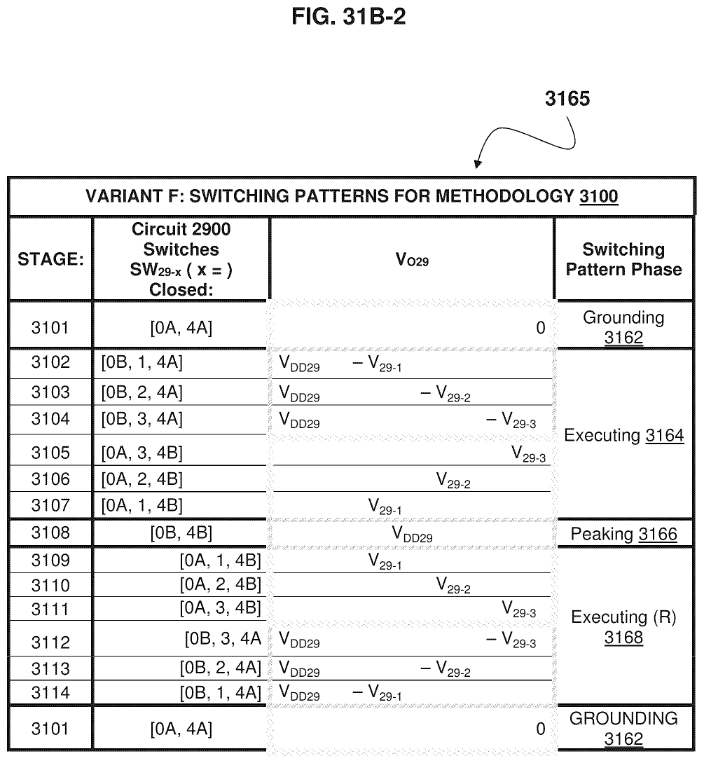

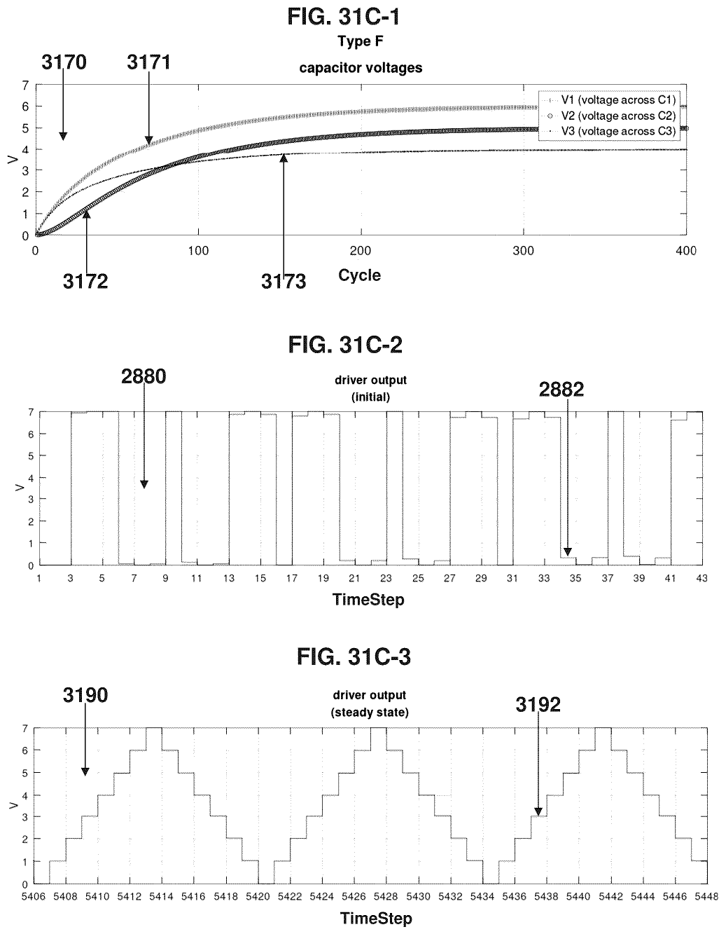

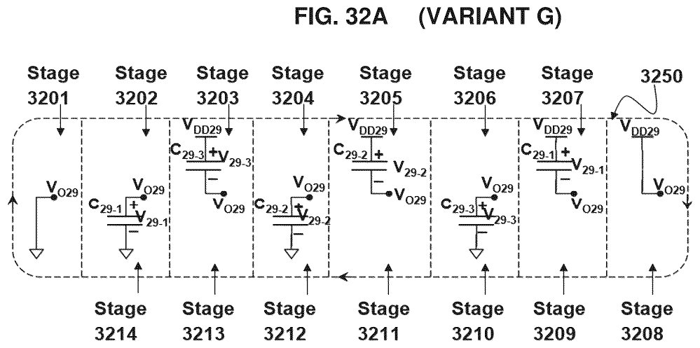

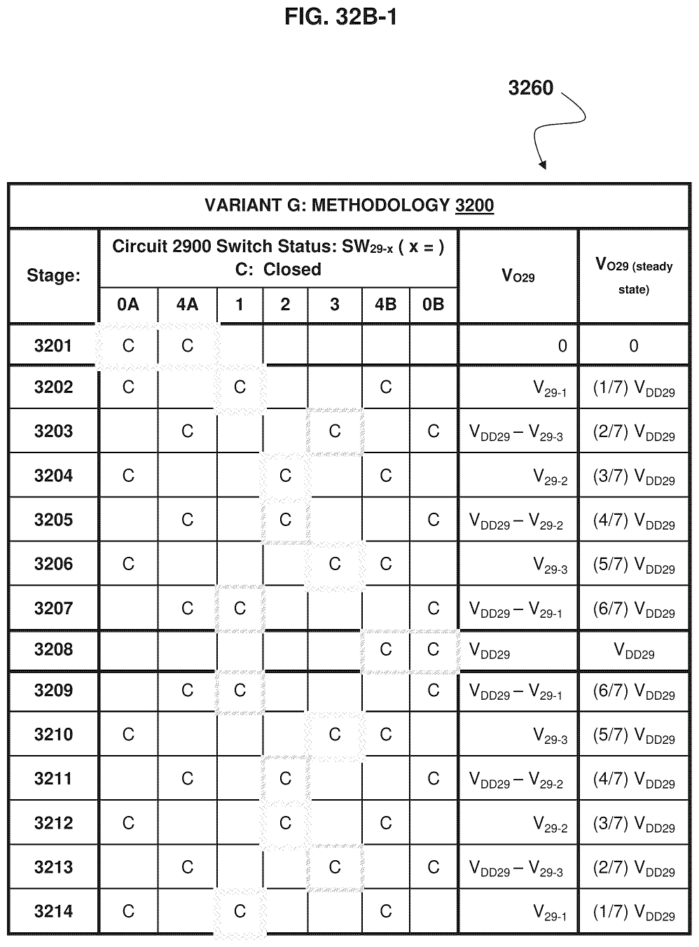

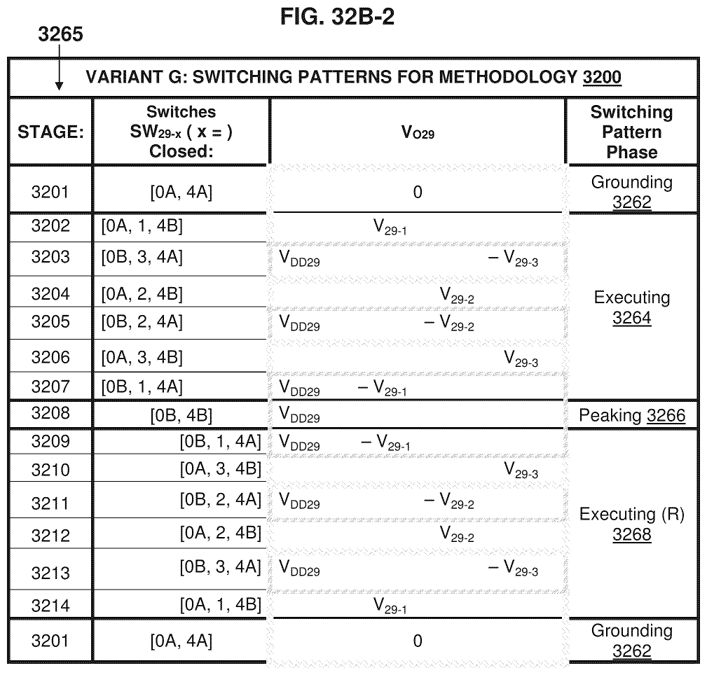

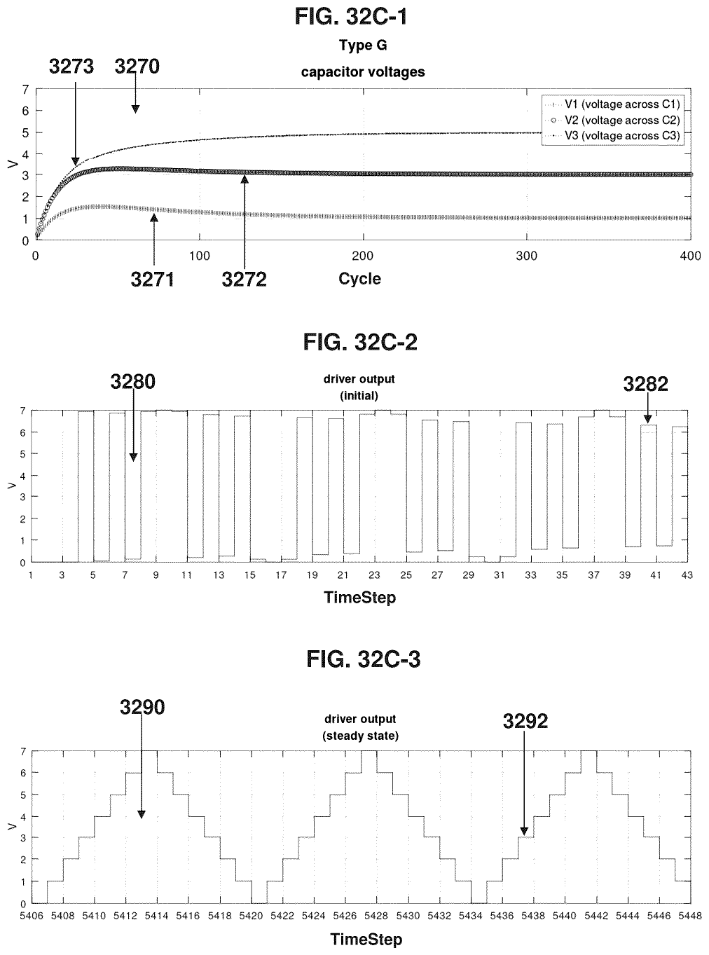

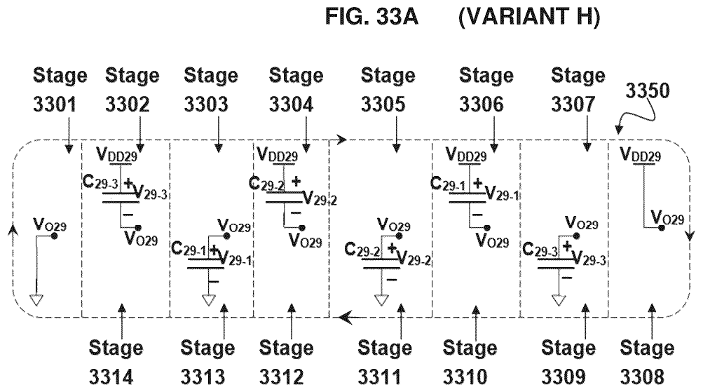

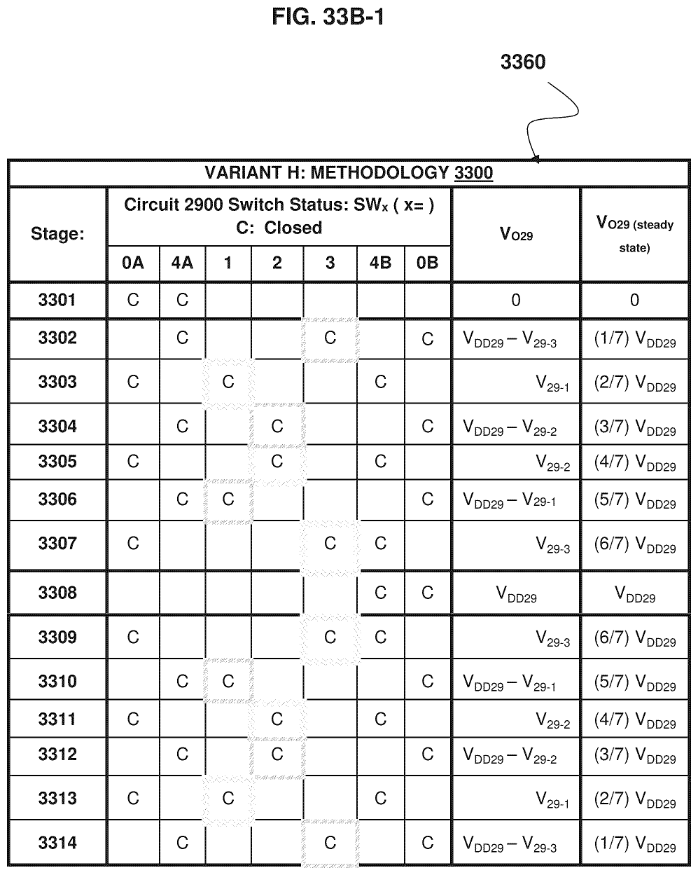

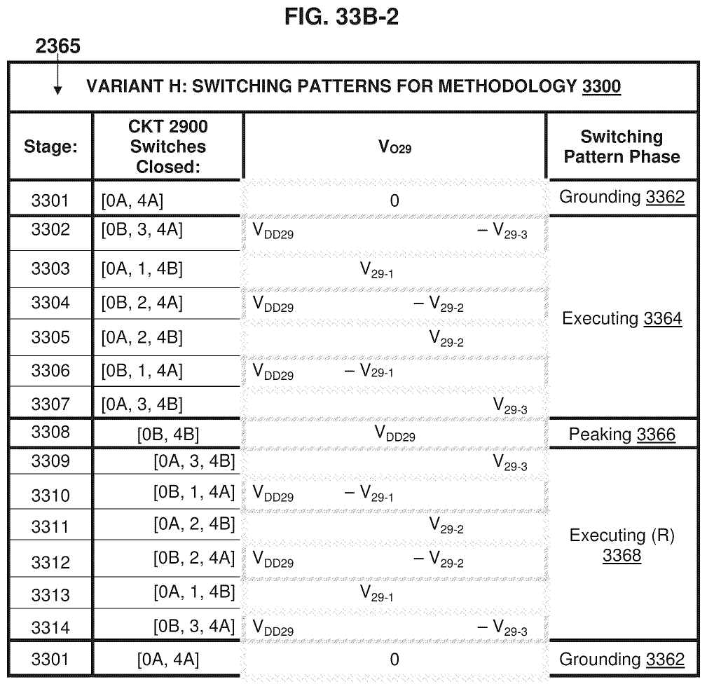

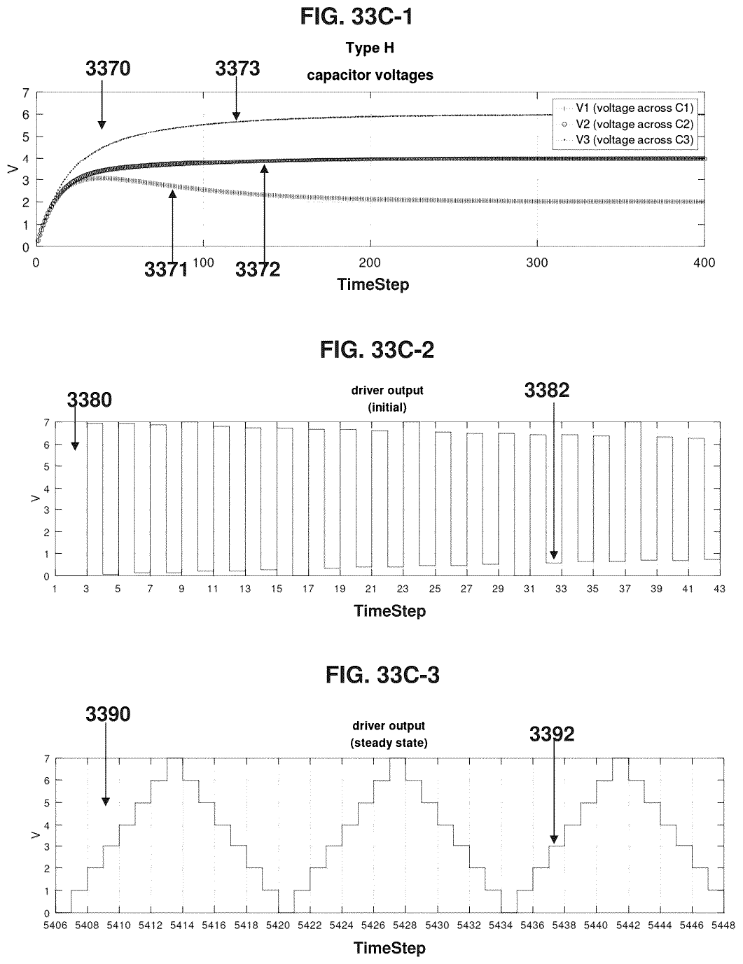

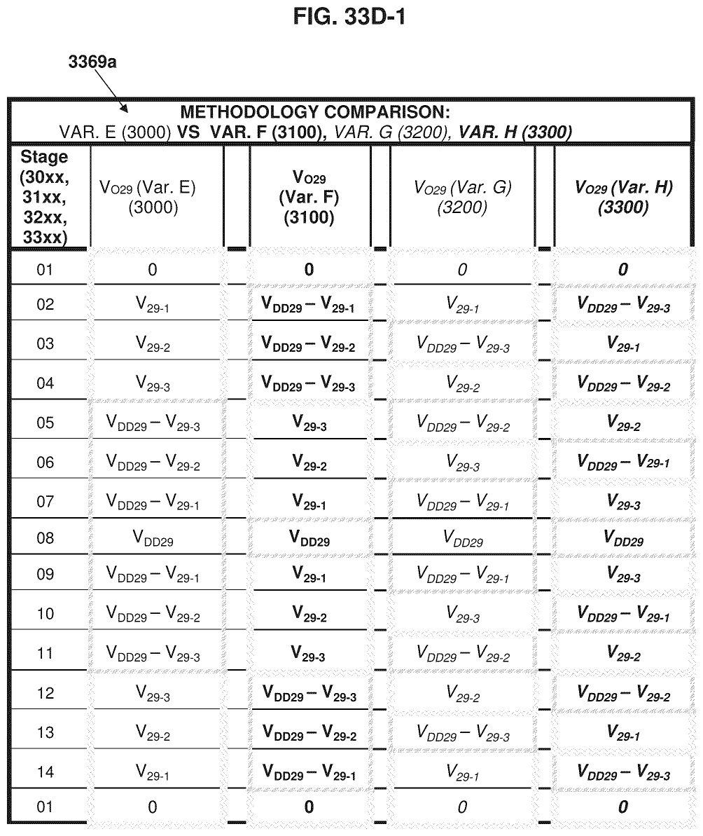

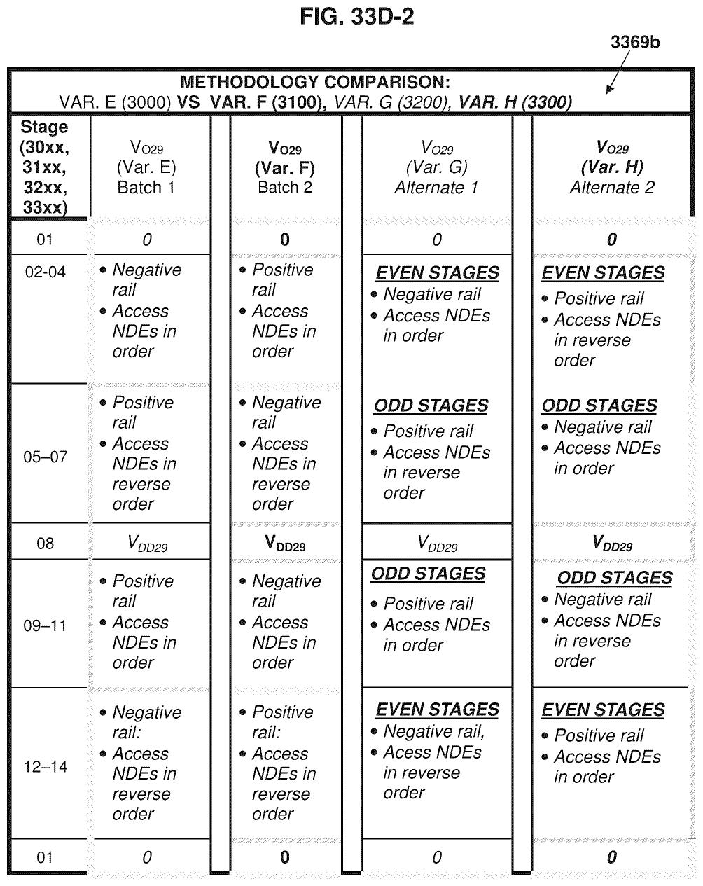

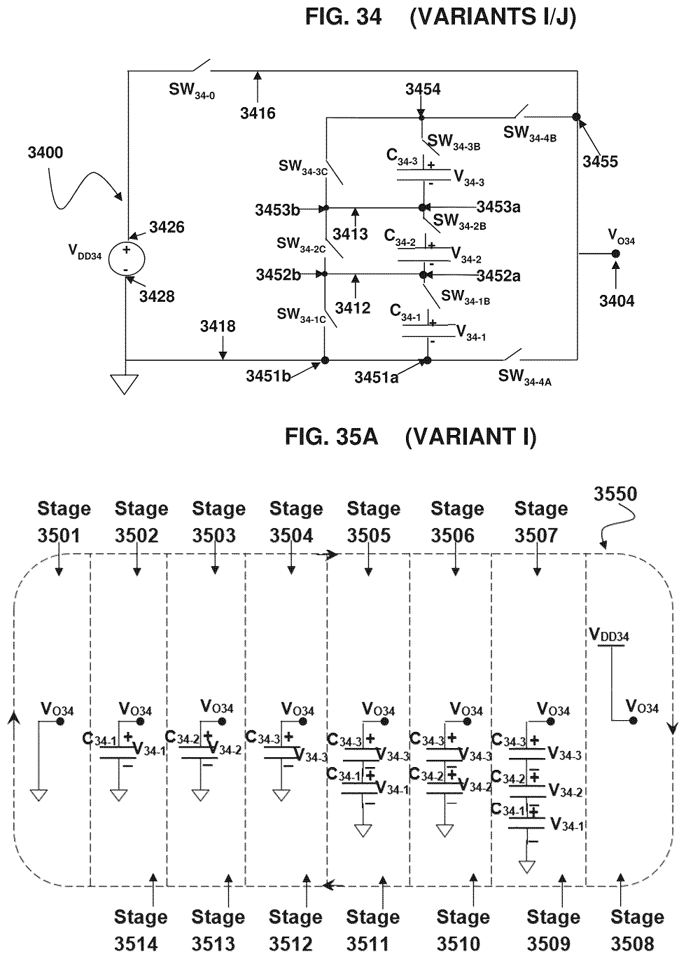

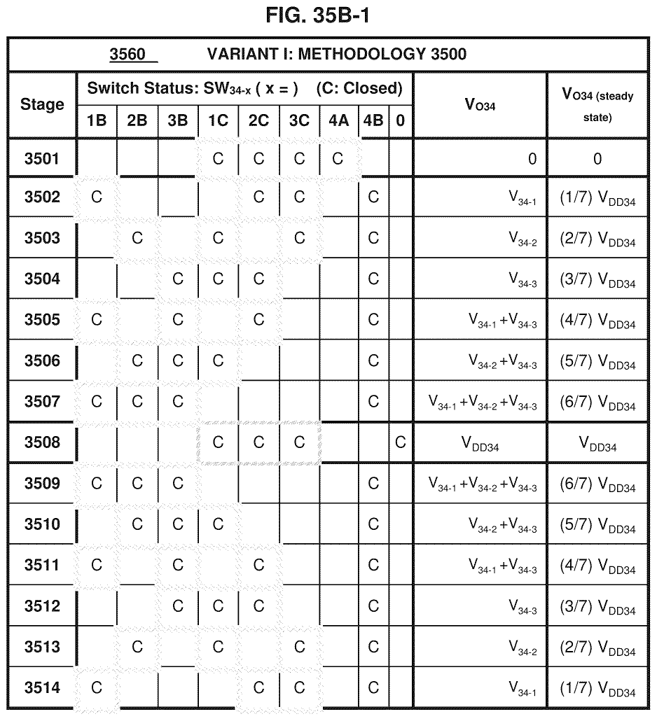

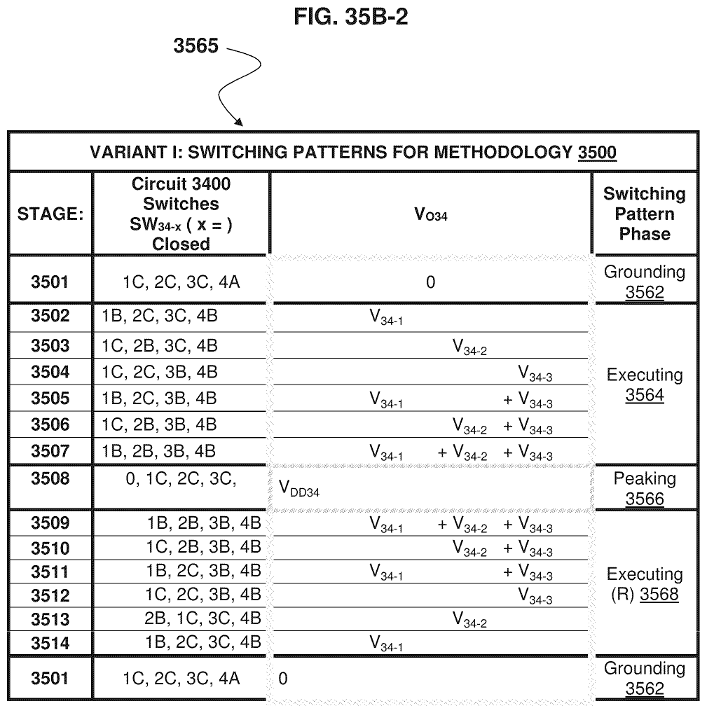

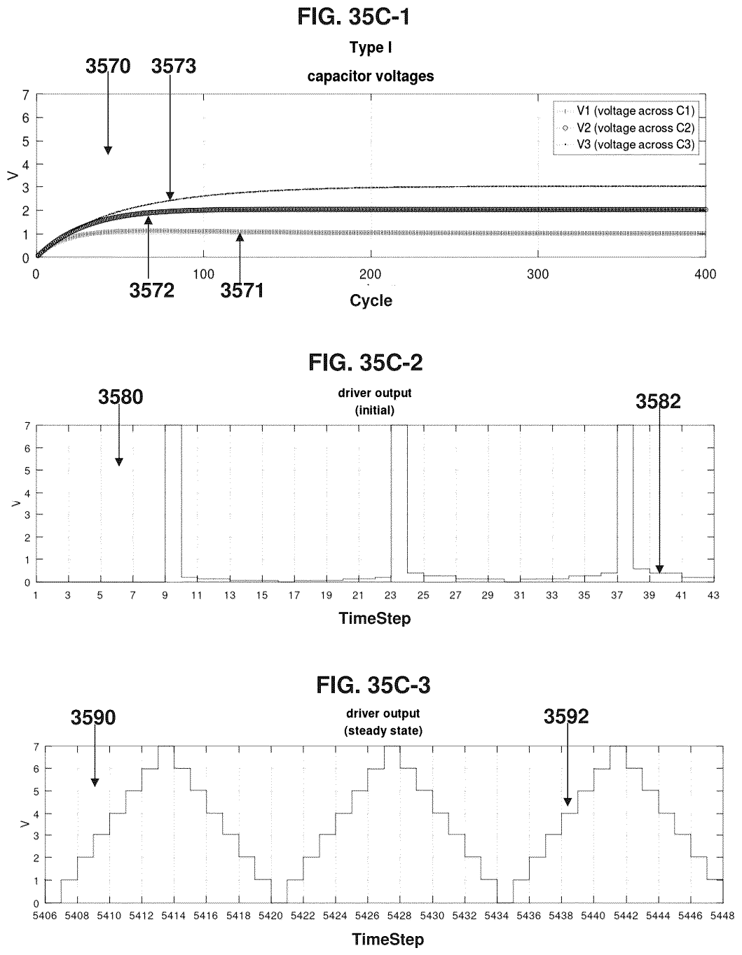

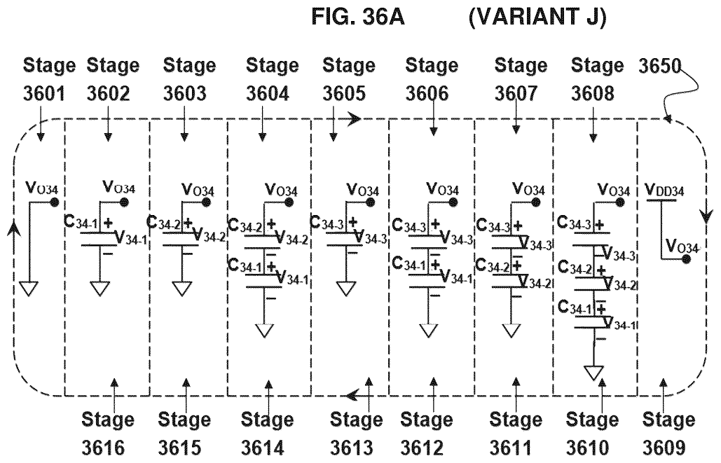

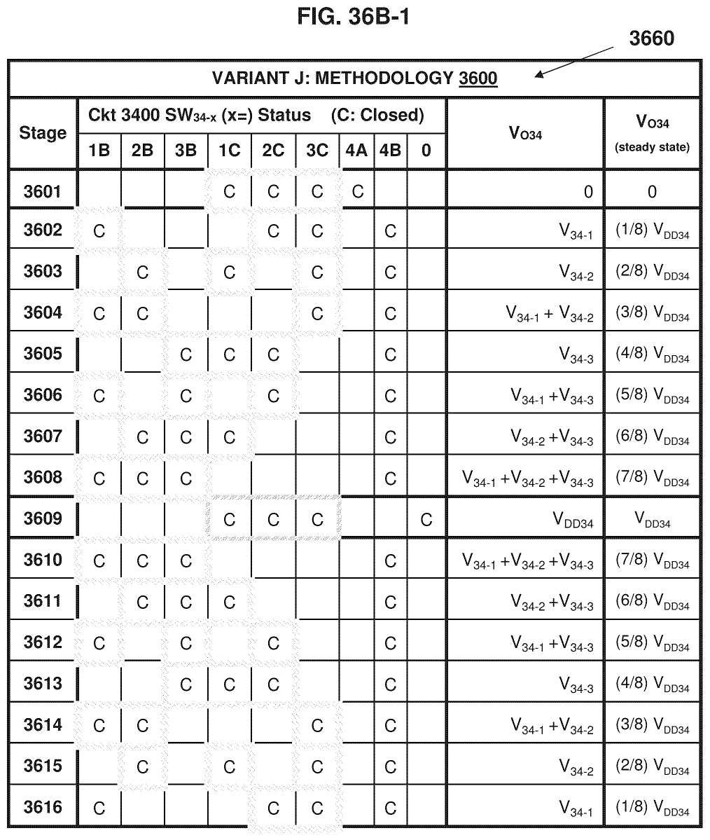

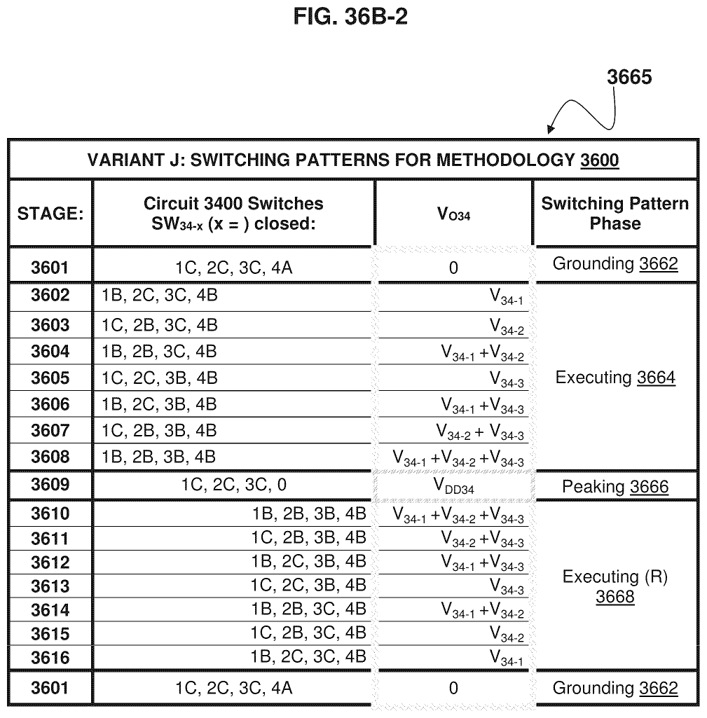

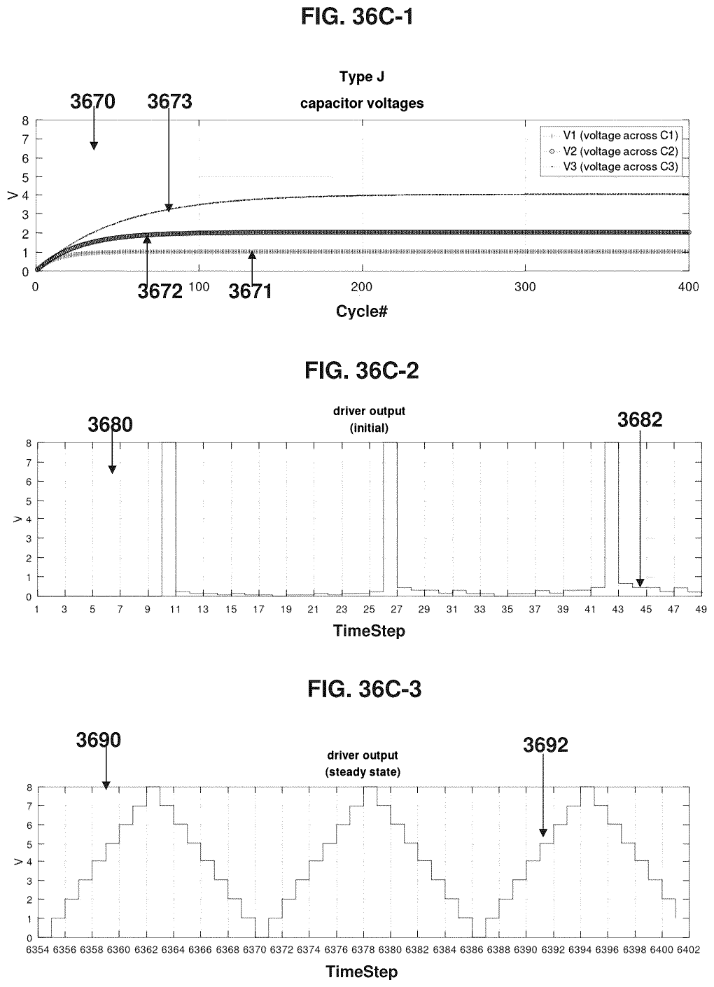

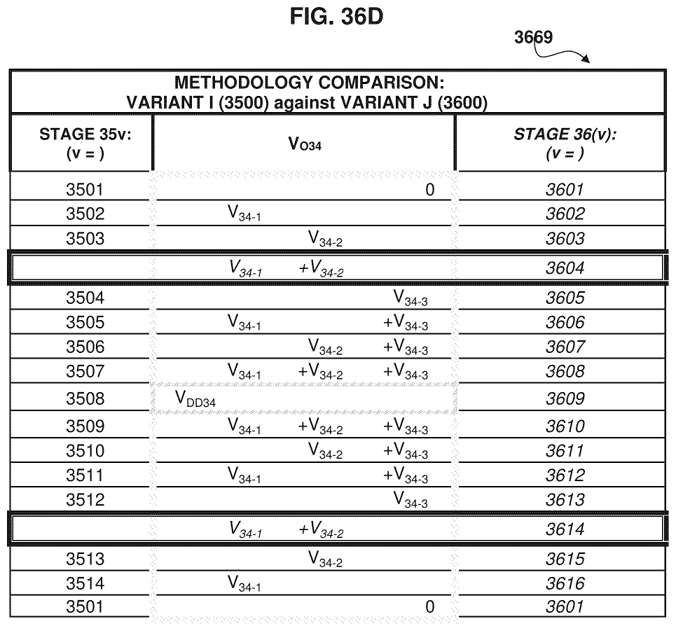

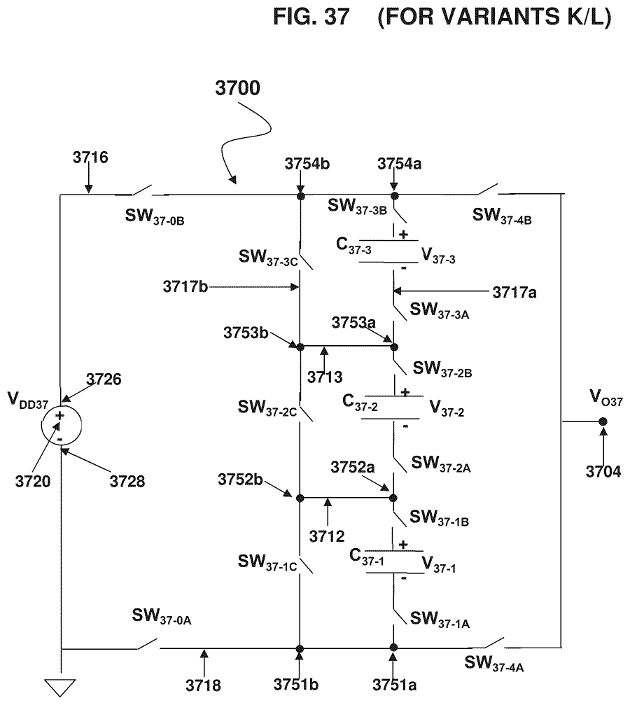

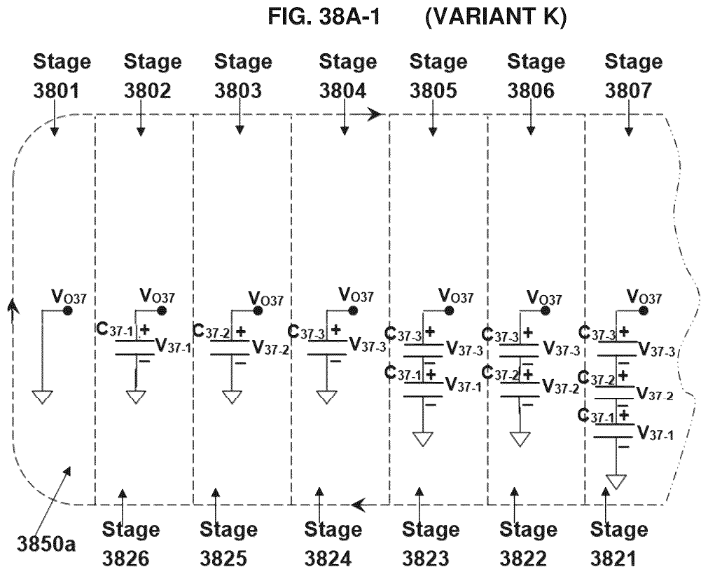

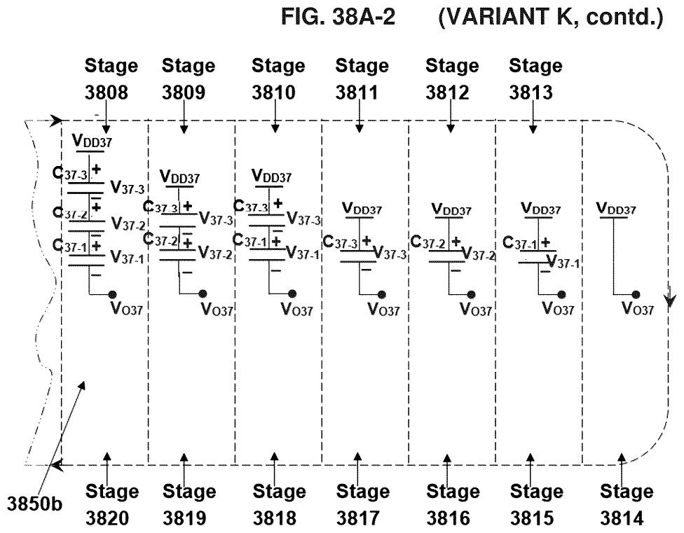

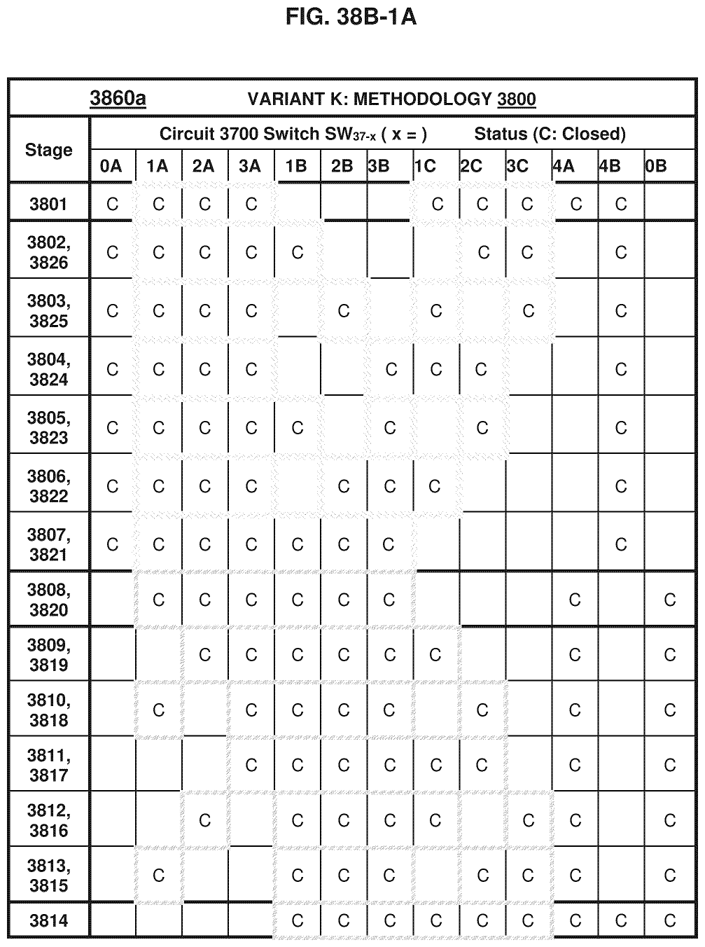

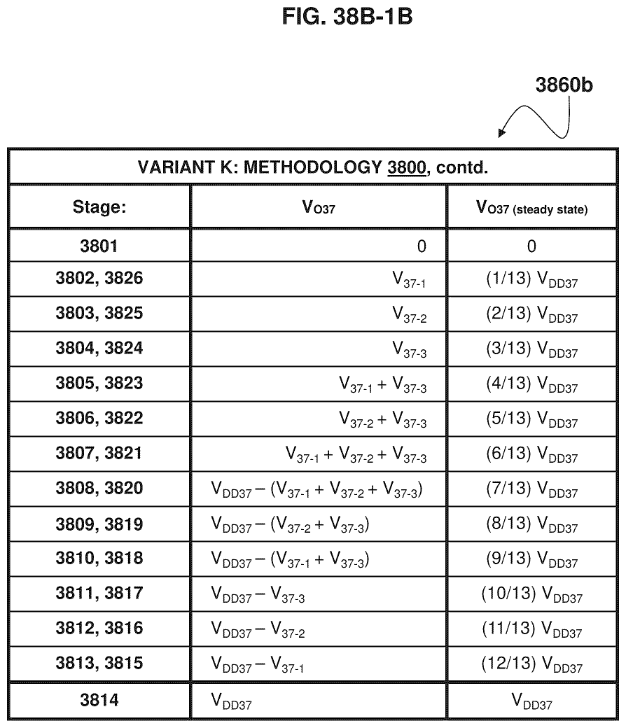

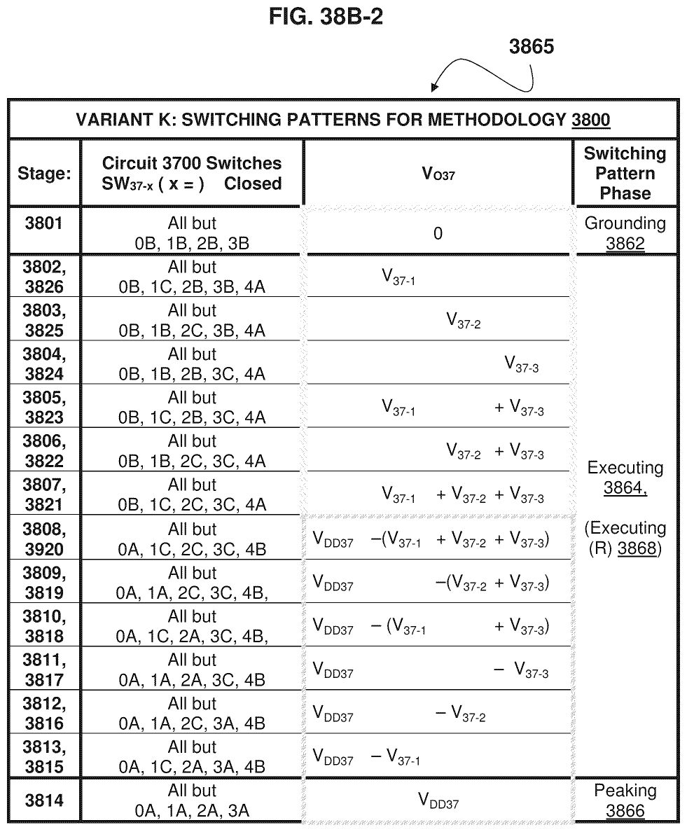

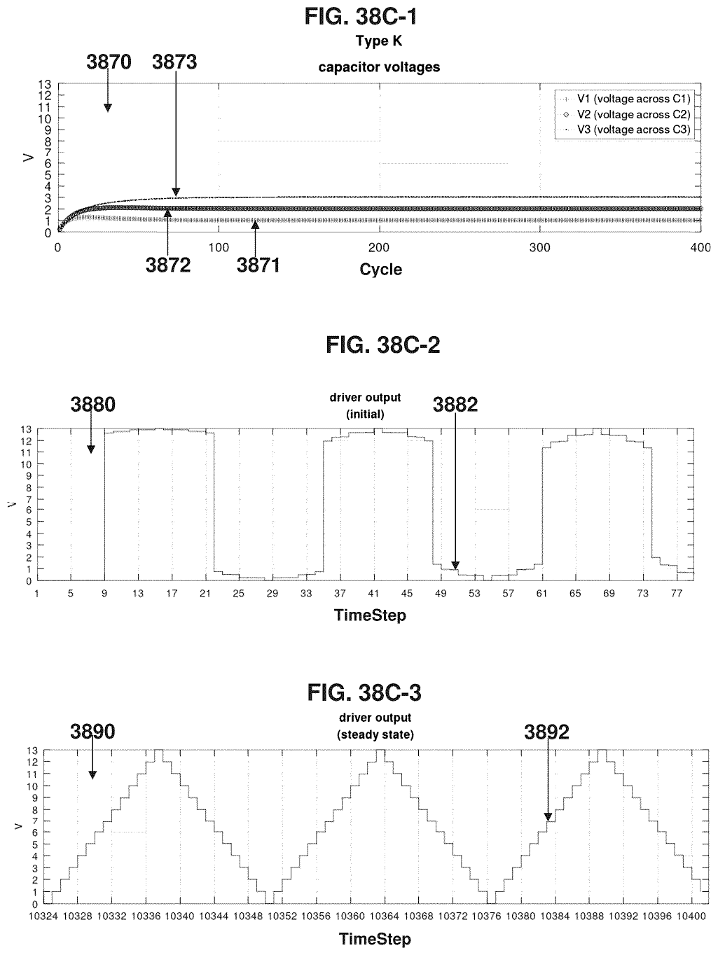

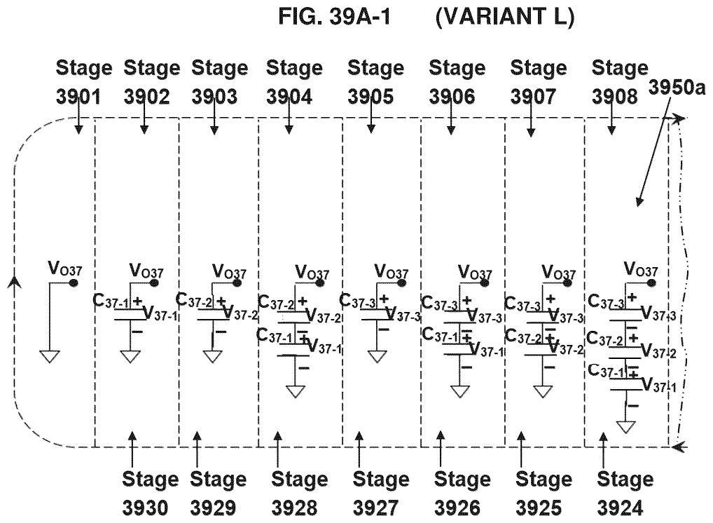

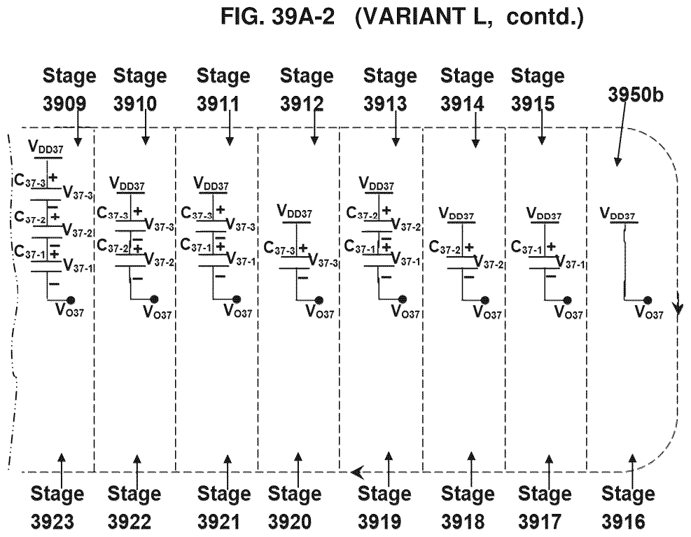

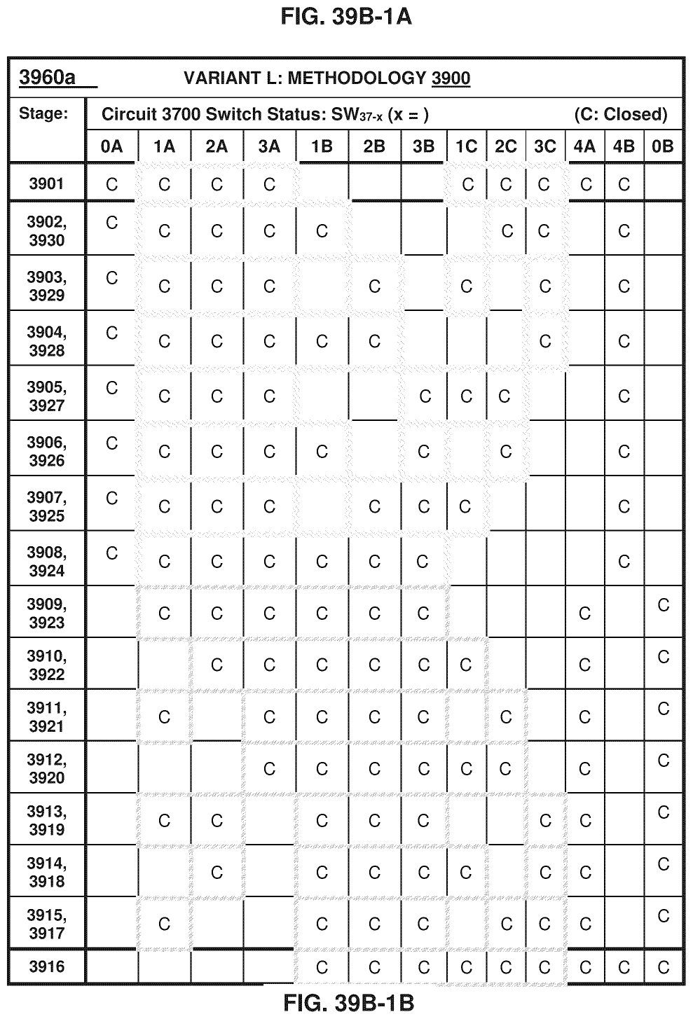

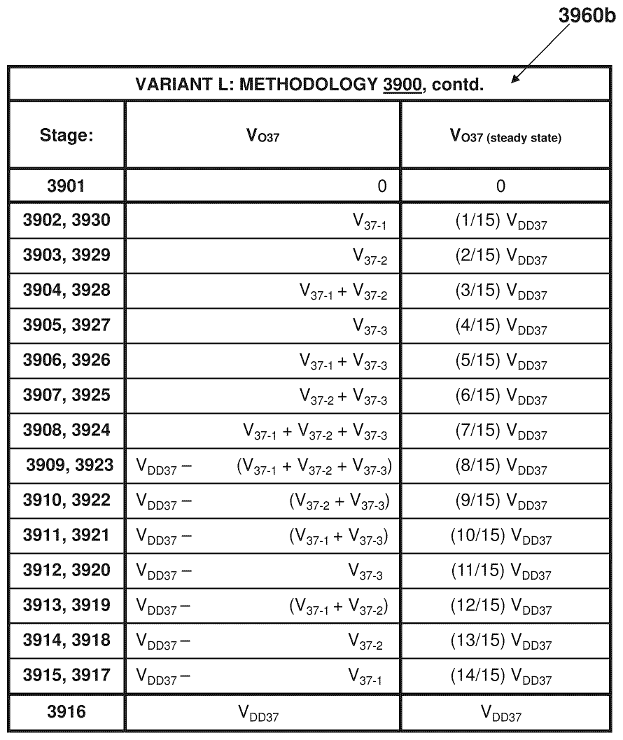

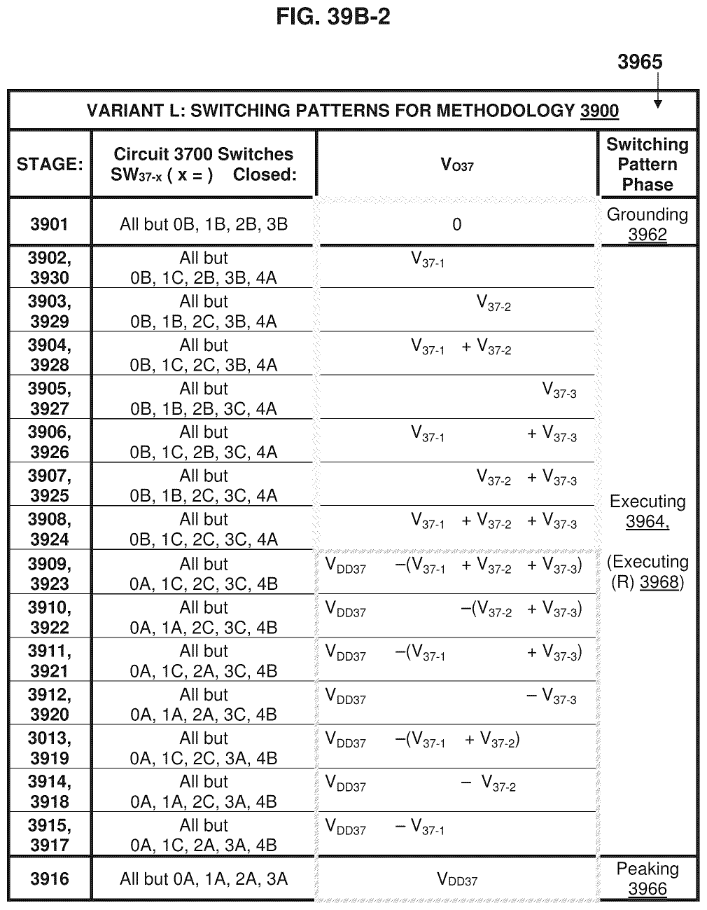

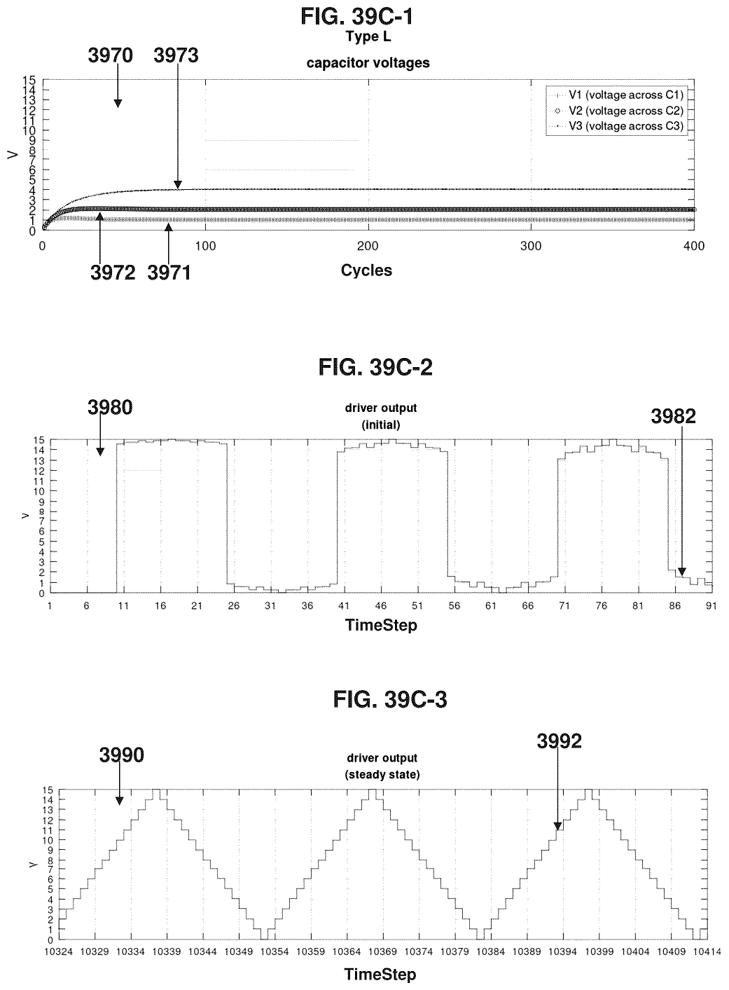

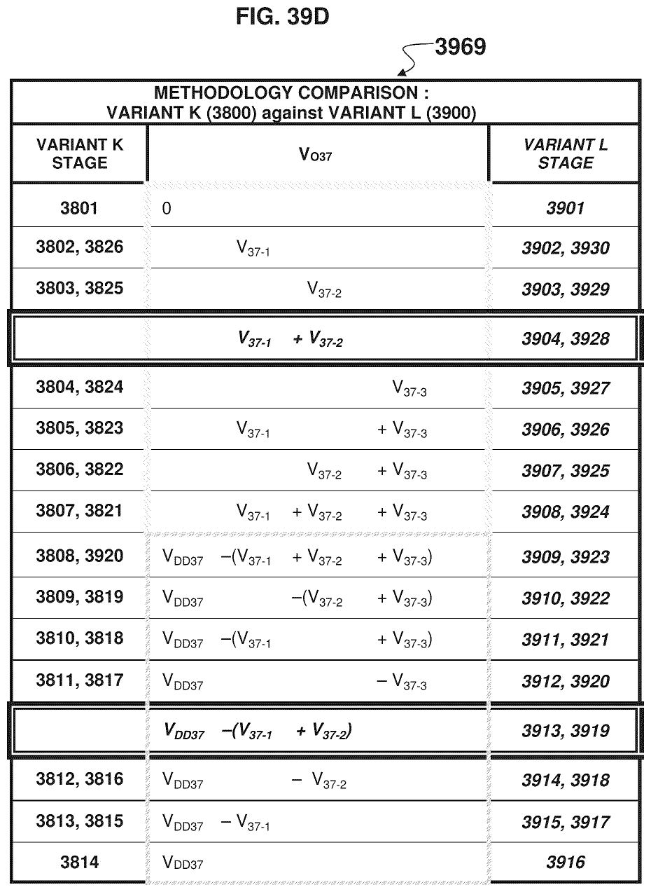

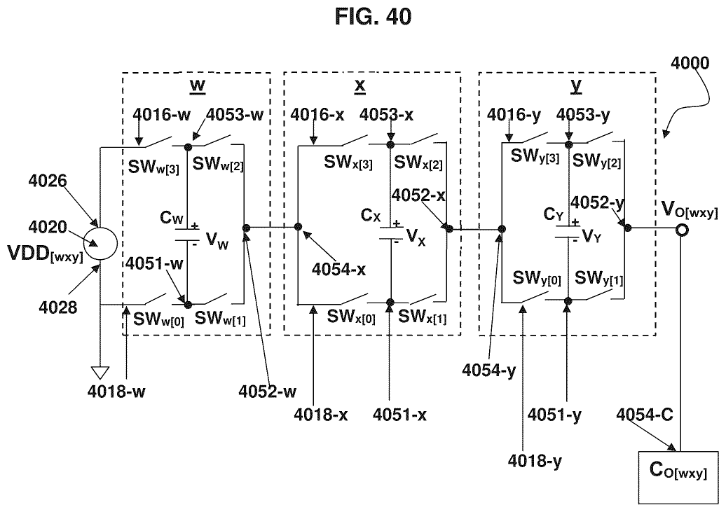

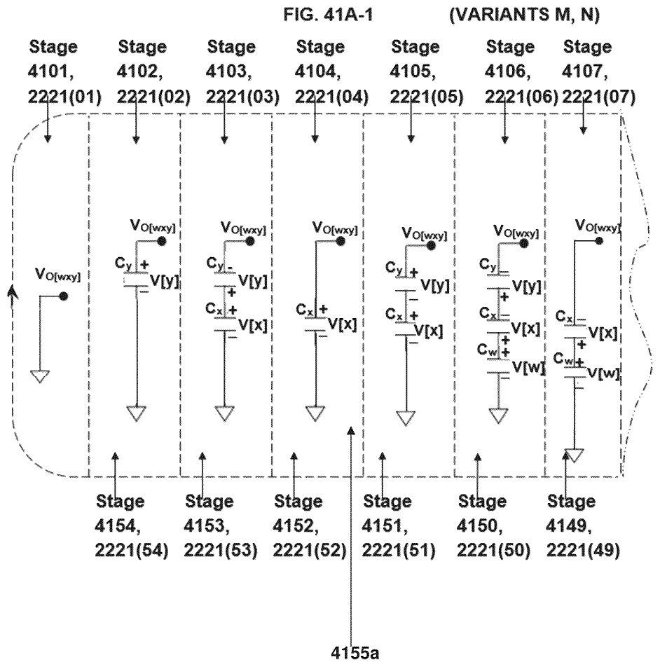

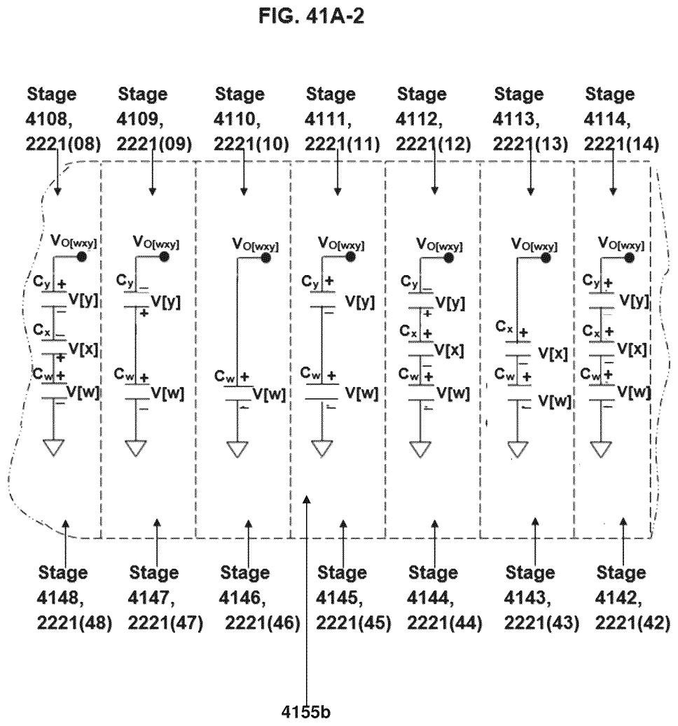

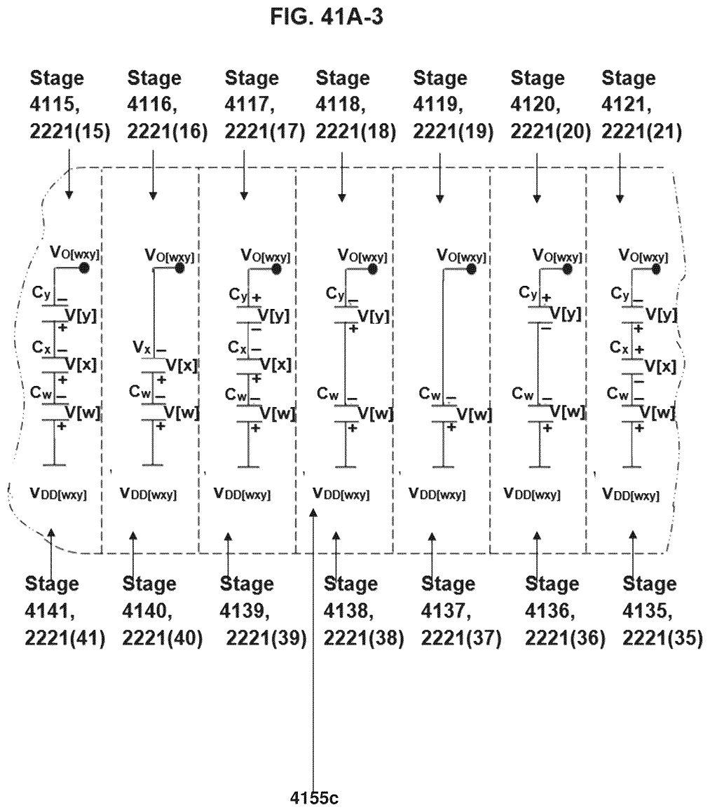

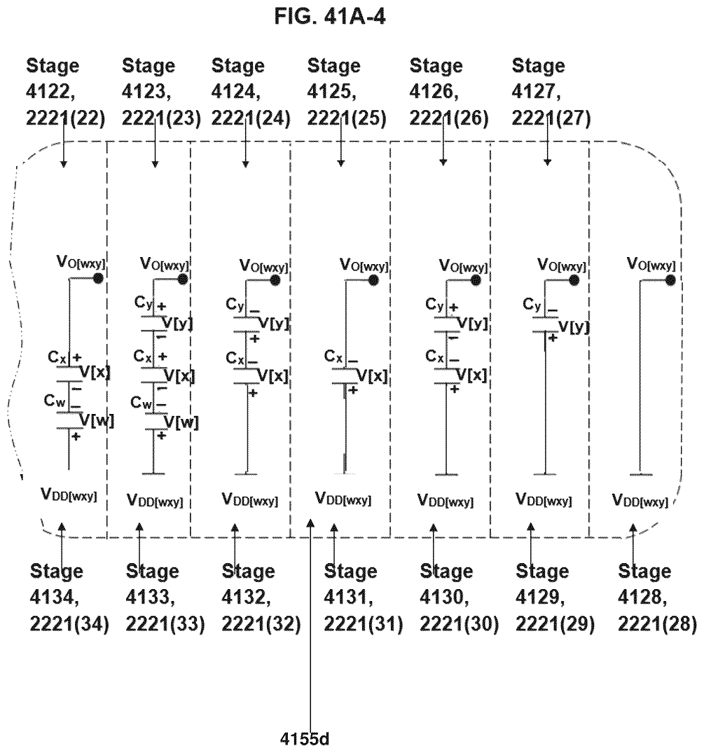

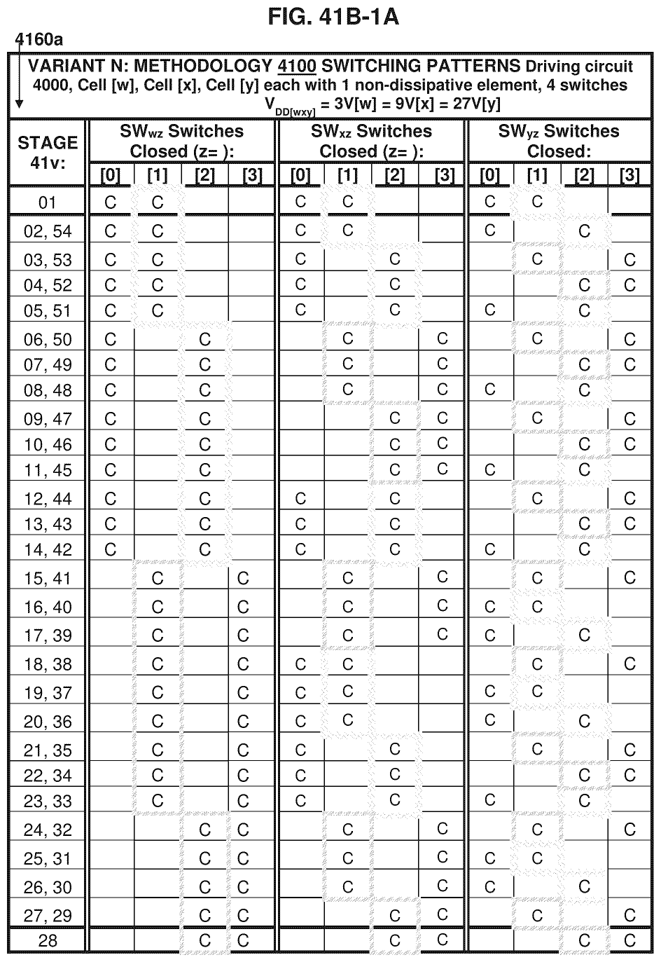

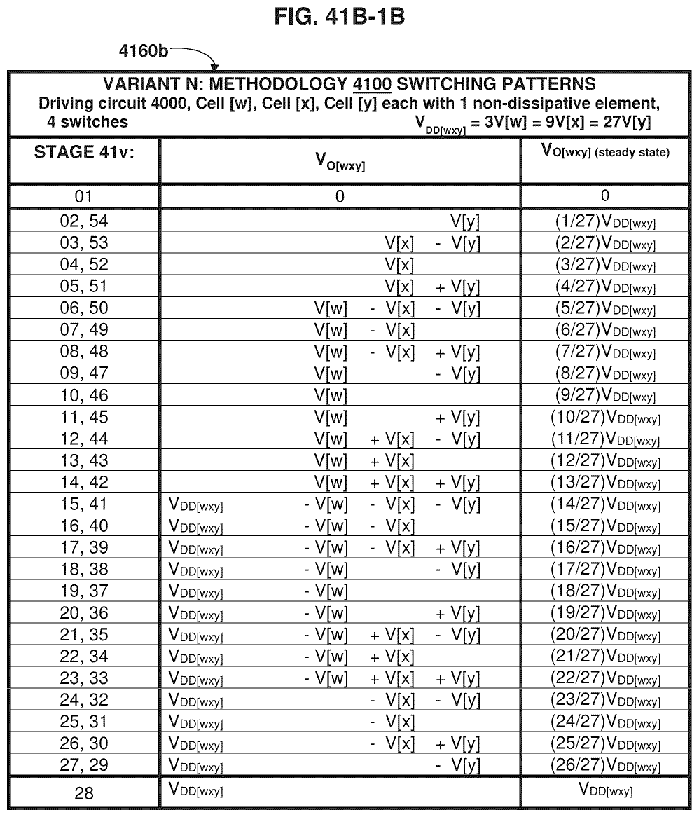

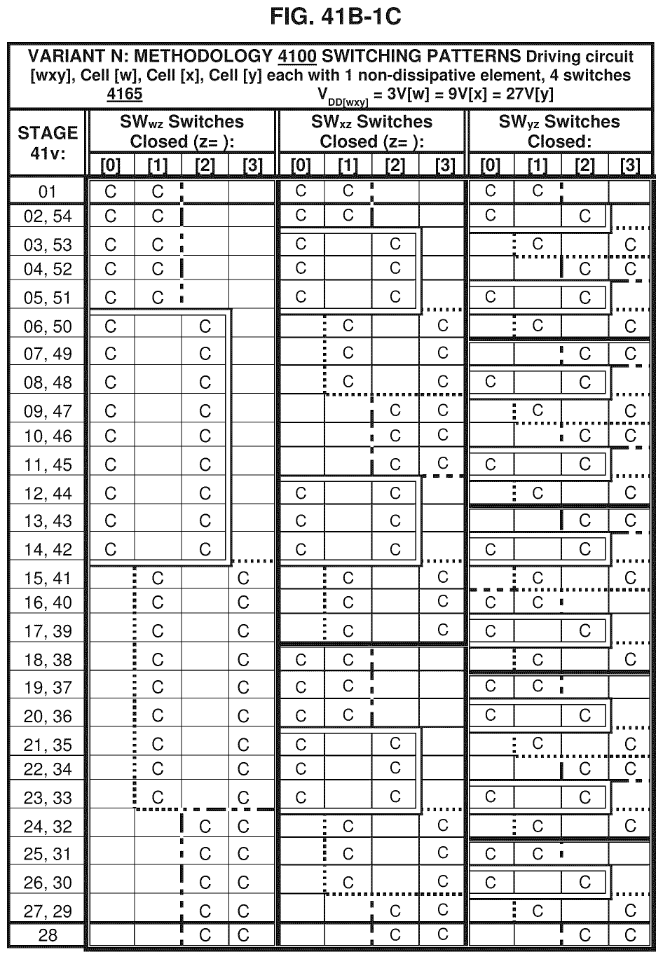

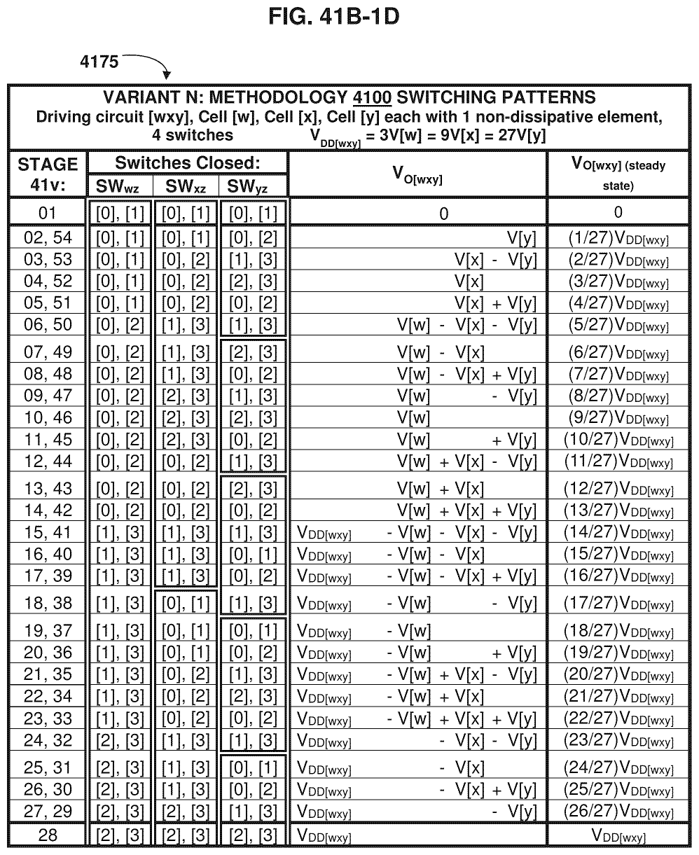

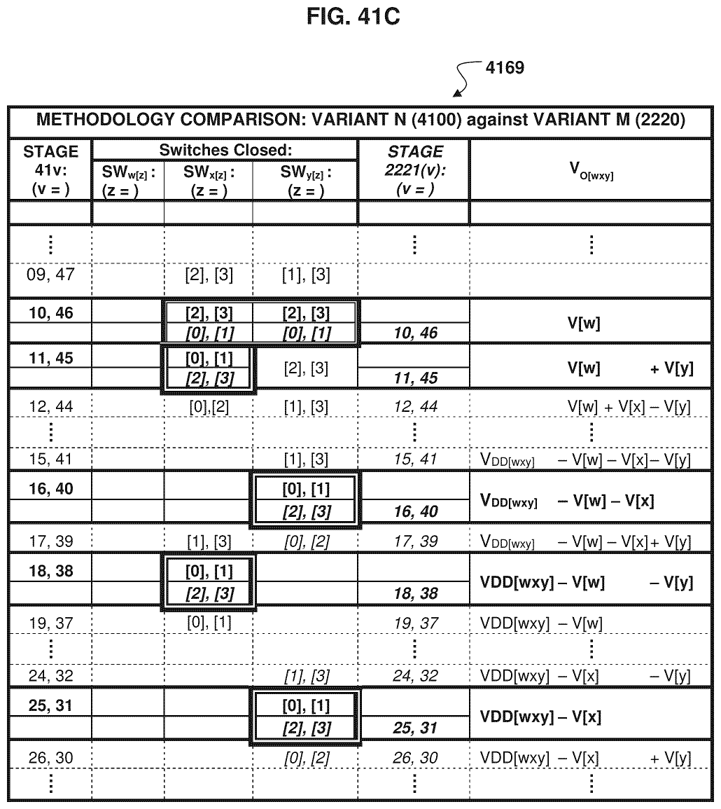

FIGS. 7D and 7E are circuit diagrams of other embodiments of the driver 700A in which NDEs are electrically connected in parallel, each NDE having one terminal electronically connected directly to one terminal of the voltage source and having another terminal electronically connected indirectly to the other terminal of the voltage source, and with:
FIG. 7D being a circuit diagram of a capacitive element driver 700D, with a selected non-dissipative element having one terminal electronically connected directly to the negative terminal of the voltage source and another terminal electronically connected indirectly to the positive terminal of the voltage source; and
FIG. 7E being a circuit diagram of a capacitive element driver 700E, with a selected non-dissipative element having one terminal electronically connected directly to the positive terminal of the voltage source and another terminal electronically connected indirectly to the negative terminal of the voltage source.

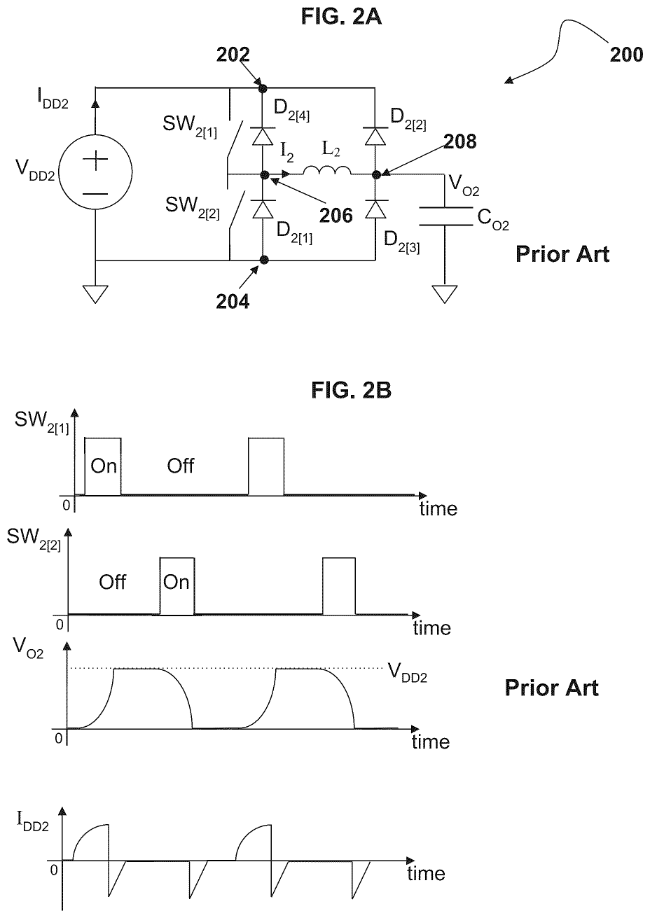

FIG. 7F is a circuit diagram of a capacitive element driver 700F, which is similar to the driver 700C-2 of FIG. 7C-2, with the following modifications:
an interconnection is removed between the positive terminal of the voltage source and the final node,
an interconnection is added between the positive terminal of the voltage source and a switch disposed between a terminal of the last NDE in the series and the outlet terminal, and
a final switch SW_{7F-5} is disposed in the added interconnection;

FIGS. 7G, 7H are circuit diagrams of capacitive element drivers which are three-NDE embodiments of FIGS. 7D, 7E, respectively;

FIG. 8A is a graph 800 illustrating a waveform 802 of the voltage V_{O7A} inputted to the capacitive element 730A during a complete V_{O7A} driving cycle for the capacitive element driver 700A;

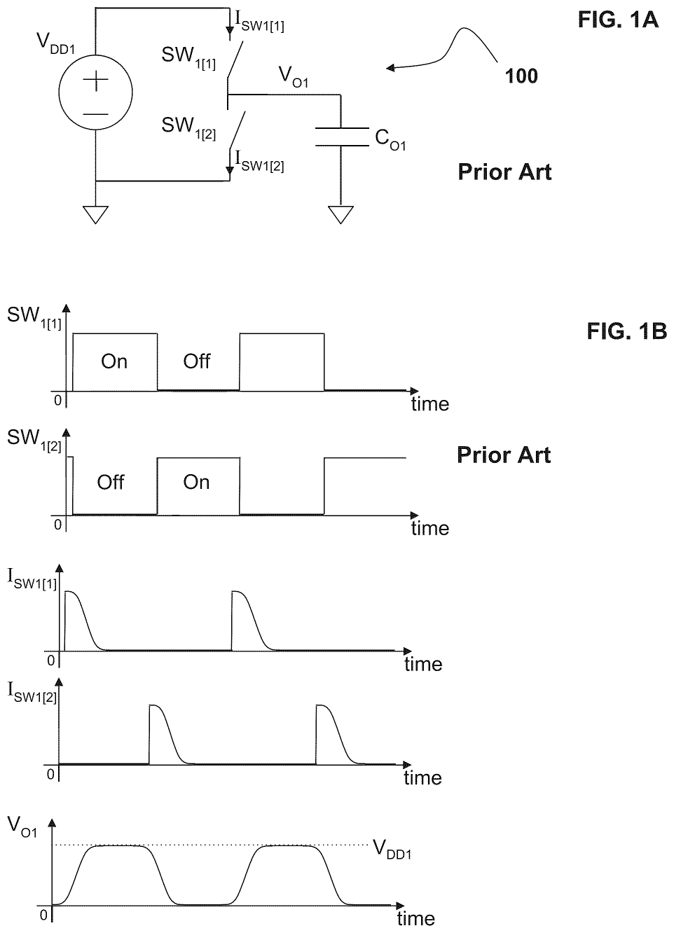

FIG. 8B-1 is a chart 850 showing an illustrative switching sequence methodology 80 for the capacitive element driver 700A during the stages of a complete V_{O7A} driving cycle;

FIGS. 8B-2A to 8B-2B2 illustrate a methodology 86 for operating the driver 700C-2 during the stages of a complete V_{07C} driving cycle, in which:
FIG. 8B-2A is a graphical representation 860 showing the methodology 86 for opening and closing the switches of the driver 700C-2, and
FIGS. 8B-2B1, 8B-2B2 are table 868, 869 detailing the stages 861-866 of the methodology 86;

FIG. 8C is a chart 880 showing the methodology 88 defining the switching sequences of the capacitive element driver 780 during the stages of a complete V_{O7B} driving cycle;

FIGS. 8D-A to 8D-B2 illustrate a methodology 8600 for operating the driver 700G during the stages of a complete V_{O7G} driving cycle, in which:
FIG. 8D-A is a graphical representation 8650 showing the methodology 8600 for opening and closing the switches of the driver 700G, and
FIG. 8D-B1, 8D-B2 are tables 8660, 8665 detailing the stages 8601-8608 of the methodology 8600;

FIGS. 8E-A-8E-B2 illustrate a methodology 8700 for operating the driver 700H during the stages of a complete V_{07H} driving cycle, in which:
FIG. 8E-A is a graphical representation 8750 showing the methodology 8700 for opening and closing the switches of the driver 700H, and
FIG. 8E-B1, 8E-B2 are tables 8760, 8765 detailing the stages 8701-8708 of the methodology 8700;

FIG. 8F is a table 8769 comparing the stages of methodologies 8600, 8700 and the output voltages resulting from their applications on the drivers 700G, 700H, respectively;

FIGS. 9A-9G are circuit diagrams of switches illustrative of embodiments of switches that may be deployed in the capacitive element driver 700A;

FIGS. 10-12 are circuit diagrams of electrical systems illustrative of embodiments of the present invention, in which capacitive driving circuits are electrically connected to electrical device/networks having capacitive functionality, with:
FIG. 10 showing a capacitive element driver 1000 having a voltage source 1020 and a capacitive driving circuit 1010 electrically connected to an electrical device/network 1030 through one terminal of one impedance to a node 1004 of the driver 1000, and through a node 1006 of the driver 1000, and with the node 1006 electrically connected to the positive terminal 1026 of the voltage source V_{DD10} (also known as voltage source 1020) of the driver 1000,
FIG. 11 showing a capacitive element driver 1100 having a voltage source and a capacitive driving circuit 1110 electrically connected to an n-terminal device/network 1130 through one terminal to a node 1104 of the driver 1100 and through a node 1108 of the driver 1100, with the node 1108 of a capacitive driving circuit 1110 electrically connected to the negative terminal 1128 of a voltage source V_{DD11} of the driver 1100, and
FIG. 12 showing a capacitive element driver 1200 having a voltage source and a capacitive driving circuit 1210 electrically connected to an n-terminal device/network 1230 through one terminal to a node 1204 of the driver 1200 and through a node 1206 of the driver 1200, with the node 1206 electrically connected to the positive terminal 1226 of a voltage source V_{DD12} of the capacitive element driver 1200;

FIGS. 13-16 are circuit diagrams of electrical systems in which capacitive driving circuits 1310, 1410, 1510, 1610 are electrically connected to gate terminal(s) of transistor(s), with:
FIG. 13 showing transistor(s) 1330 connected through source terminal(s) to the negative terminal of a voltage source V_{DD13} of the capacitive driving circuit 1310,
FIG. 14 showing the transistor(s) 1430 connected through source terminal(s) to the positive terminal of a voltage source V_{DD14} of the capacitive driving circuit 1410,
FIG. 15 showing transistor(s) 1530 connected through drain terminal(s) to the positive terminal of a voltage source V_{DD15} of the capacitive driving circuit 1510, and
FIG. 16 showing transistor(s) 1630 connected through drain terminal(s) to the negative terminal of a voltage source V_{DD16} of the capacitive driving circuit 1610;

FIGS. 17-18 are circuit diagrams of electrical systems in which elements 1740, 1840 may be driven by capacitive driving circuits 1710, 1810, respectively, through transistor(s) 1730, 1830, respectively, with capacitive driving circuits 1710, 1810 electrically connected to gate terminal(s) of transistor(s) 1730, 1830, and with:
FIG. 17 showing the element 1740 connected through terminal(s) to source terminal(s) of the transistor(s) 1730 and through other terminals between the positive and negative terminals of the voltage source V_{DD17} of the circuit 1710, and
FIG. 18 showing the element 1840 connected through terminal(s) to drain terminal(s) of the transistor(s) 1830 and through other terminal(s) between the positive and negative terminals of the voltage source V_{DD18} of the circuit 1810;

FIGS. 19A and 19B are circuit diagrams showing high-efficiency switches systems 1900a, 1900b, in which a capacitive driving element 1910a, 1910b may be electrically connected to the gate of a power switch such as a high-frequency power switch 1930a, 1930b;

FIG. 20 is a circuit diagram showing a capacitive element driver cell 2000 that may be combined with other capacitive element driver cells to construct a capacitive element driving circuit for further reducing the total energy dissipation of a capacitive element driver per one output voltage driving cycle;

FIG. 21 is a circuit diagram showing one embodiment of a 2-driver cell capacitive element driving circuit 2100 in which cells 2101-1, 2101-2, are electrically connected with the input terminal of the driver cell 2101-2 being connected to an output terminal of the driver cell 2101-1;

FIGS. 22A-22J are circuit diagrams of the two-cell capacitive element driving circuit 2100 in operation, illustrating an embodiment of switching that may be deployed in the driving circuit 2100 during the stages of a complete V_{O21} driving cycle;

FIG. 22K is a chart illustrating an embodiment of the switching sequence methodology 2200 shown in the circuit diagrams of FIGS. 22A-22J;

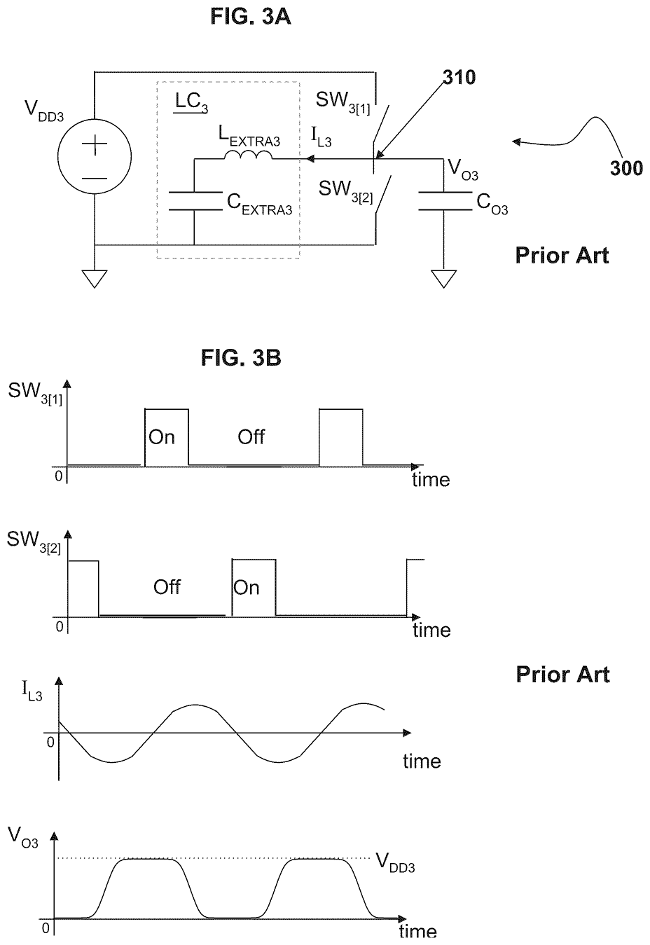

FIGS. 22L-1-22L-3 are charts illustrating the voltage assignment functionality of sets of closed switches in an embodiment of switching sequences of driver cells in selected driving circuits, with:
FIG. 22L-1 showing the voltage assignment functionality 2001-1 of sets of closed switches in a driver cell x with one non-dissipative element (and four switches),
FIG. 22L-2 showing the voltage assignment functionality 2001-2 of sets of closed switches in a driver cell y with two non-dissipative elements (and five switches), and
FIG. 22L-3 showing the voltage assignment functionality 2001-q of sets of closed switches in a generalized driver cell k with q non-dissipative elements (and q+3 switches);

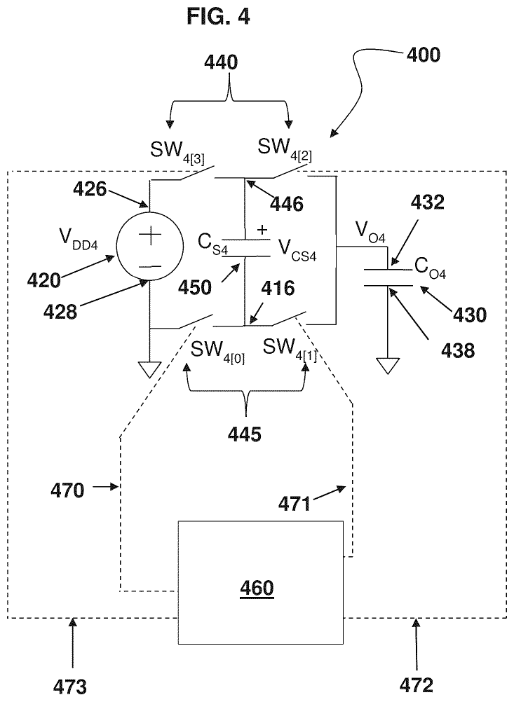

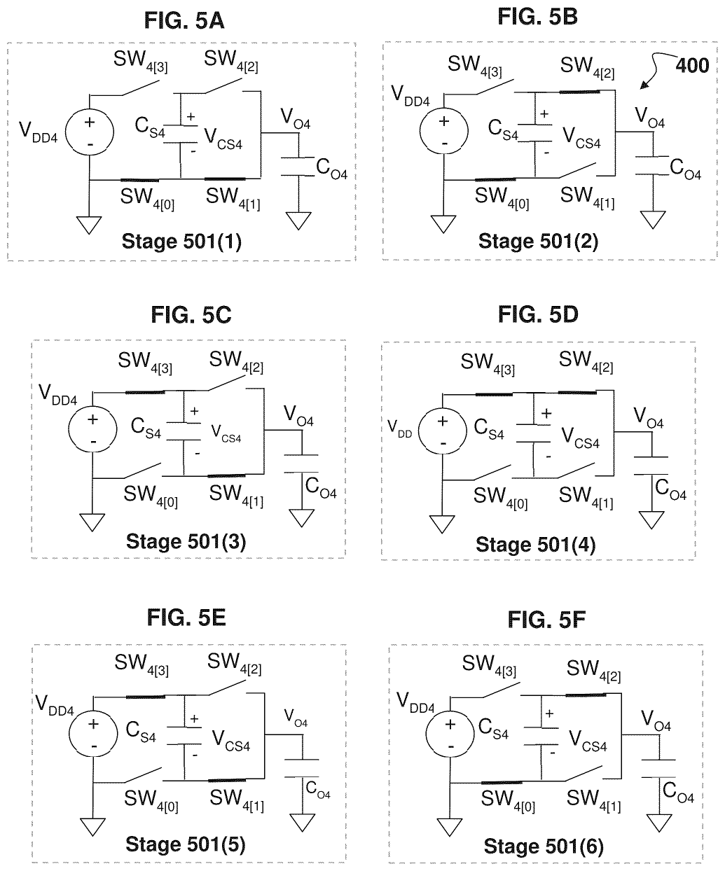

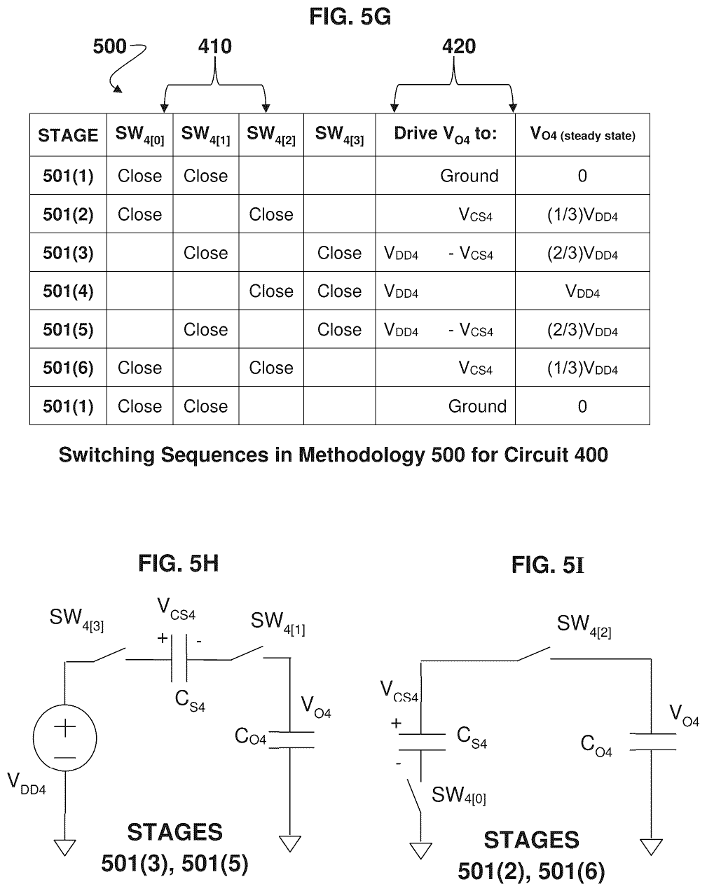

FIGS. 22M-1A-22M-5B are charts illustrating switching sequence methodologies for selected driving circuits showing phases and patterns of switching using the notation for operation of sets of closed switches outlined in the voltage assignment functionalities 2001-1, 2001-2, 2001-q shown in FIGS. 22L-1, 22L-2, 22L-3, respectively, with
FIG. 22M-1A showing a more detailed specification of the voltage assigned by each stage of the switching sequence methodology 2200 of FIG. 22K for operating a driving circuit 2100 through the stages of a complete output voltage driving cycle, with FIG. 22M-1B showing phases of and switching patterns in the methodology 2200;
FIGS. 22M-2A1(A1)-22M-2A2 showing a switching sequence methodology 2220 for a driving circuit [wxy] through the stages of a complete output voltage driving cycle, with the circuit [wxy] having three driver cells, each with one non-dissipative element, with:
   FIGS. 22M-2A1 (A1), 22M-2A1(A2) showing switching charts 2222(a), 2222(b), respectively, detailing the closed switches and output voltages of the circuit [xyz], during application of the stages 2221(1)-2221(54) of a switching sequence methodology 2220,
   FIG. 22M-2A1(B) showing a sequence pattern chart 2225 detailing the switch sets that are closed on the circuit [xyz] and the circuit's output voltages during application of the stages 2221(1)-2221(54), and
   FIG. 22M-2A2 showing the phases of and switching patterns in the methodology 2220;
FIG. 22M-2B1 showing a switching sequence methodology 2240 for a driving circuit [vwxy] through the stages of a complete output voltage driving cycle, with the circuit [vwxy] having four driver cells, each with one non-dissipative element, and FIG. 22M-2B2 showing the phases of and switching patterns in the methodology 2240;
FIG. 22M-3A showing a switching sequence methodology 2260 for a driving circuit [ab] through the stages of a complete output voltage driving cycle, with the circuit [ab] having a first cell [a] with one non-dissipative element and a second cell [b] with two non-dissipative elements, and FIG. 22M-3B showing the phases of and switching patterns in the methodology 2260;
FIG. 22M-4A showing a switching sequence methodology 2270 for a driving circuit [mn] through the stages of a complete output voltage driving cycle, with the circuit [mn] having a first cell [m] having two non-dissipative elements and a second cell [n] with one non-dissipative element, and FIG. 22M-4B showing the phases of and switching patterns in the methodology 2270; and
FIG. 22M-5A1, 22M-5A2, and FIG. 22M-5B showing a switching sequence methodology 2280 for a driving circuit [mnp] through the stages of a complete output voltage driving cycle, with the driving circuit [mnp] having a first cell [m] and second cell [n] with two non-dissipative elements each and a third cell [p] with three non-dissipative elements, and with:
   FIG. 22M-5A1 showing the methodology 2280 for driving the circuit [mnp] from ground to its peak voltage,
   FIG. 22M-5A2 showing the methodology 2280 for driving the circuit [mnp] from its peak voltage to ground, and
   FIG. 22M-5B showing the phases of and switching patterns in the methodology 2280;

FIG. 23A is a circuit diagram showing one embodiment of a capacitive element driving circuit 2300 that constitutes a more generalized embodiment of the storage capacitor-enabled capacitive element driver 2100 with circuit 2300 having K cells, each with at least one non-dissipative element (the embodiment also known as a K-cell driving circuit 2300);

FIG. 23B is a circuit diagram showing one embodiment of a cell 2301-i (for 2≤i≤(K−1)), for a K-cell driving circuit 2300;

FIGS. 24A-24B-3 are charts illustrating the portion of a switching sequence methodology 2400 for operating the generalized driving circuit 2300 through the stages of a V_{O23} driving cycle in which the multi-cell circuit 2300 drives its output voltage from ground to its peak voltage, with:
FIG. 24A showing the methodology phases and cell switching patterns for driving the cell 2301-1 from ground to its peak voltage, namely an initiating cell [1] phase 2412[1]-1 and a portion of a peaking cell [1] phase 2414[1], and
FIGS. 24B-1, 24B-2, and 24B-3 showing the methodology phases and cell switching patterns for driving the remainder of the cells 2301-z, where 2≤z≤K, from ground to its peak voltage, with FIGS. 24B-1 illustrating an initiating cell [z] phase 2412[z]-1, FIG. 24B-2 illustrating an executing cell [z] phase 2413[z]-1, and FIG. 24B-3 illustrating a portion of the peaking cell [z] phase 2414[z];

FIGS. 25A, 25B, 25C are summaries of certain methods, circuits, devices, and systems for sequenced operation of switching non-dissipative elements in capacitive element driving systems, summarizing certain circuit/circuit switching methodology combinations that were earlier disclosed in U.S. Pat. No. 11,575,376 and U.S. patent application Ser. No. 18/090,469, or that are disclosed below;

FIG. 26A-26B-2 illustrate a methodology 2600 for operating the driver 700F during the stages 2601-2608 of a complete V_{7F} driving cycle, in which FIG. 26A is a graphical representation 2650 of the operation of the circuit 700F at each stage of the methodology, FIG. 26B-1, 26B-2 are tables 2660, 2665 detailing the stages of the methodology 2600;

FIG. 26C is a table 2669 comparing the stages of methodologies 86, 2600 and the output voltages resulting from their applications on the drivers 700C-2, 700F, respectively;

FIG. 27A-27C-3, 28A-28C-3 illustrate methodologies 2700, 2800 for operating the driver 780 during the stages of a complete V_{O7B} driving cycle, in which:
FIGS. 27A, 28A are graphical representations 2750, 2850, respectively, of the operation of the circuit 780 at each stage of the methodologies,
FIGS. 27B-1, 27B-2 are tables 2760, 2765 detailing the stages 2701-2714 of the methodology 2700, and FIGS. 28B-1, 28B-2 are tables 2860, 2865 detailing the stages 2801-2014 of the methodology 2800,
FIGS. 27C-1-27C-3 and 28C-1-28C-3 are screen shots of simulation results related to application of the methodologies 2700, 2800, respectively, on the driver 780;

FIG. 28D is a table 2869 comparing the stages of methodologies 2700, 2800 and the output voltages resulting from their applications on the driver 780;

FIG. 29 is a circuit diagram of a capacitive element driver 2900, which constitutes an alternative embodiment of a storage capacitor-enabled capacitive element driver, having three non-dissipative elements connected in series and seven switches;

FIG. 30A-30C-3, 31A-31C-3, FIG. 32A-32C-3, 33A-33C-3 illustrate methodologies 3000, 3100, 3200, 3300, respectively, for operating the driver 2900 during the stages of a complete V₂₉ driving cycle, in which:
FIGS. 30A, 31A, 32A, 33A are graphical representations 3050, 3150, 3250, 3350, respectively, of the operation of the circuit 2900 at each stage of the methodologies,
FIGS. 30B-1 to 30B-2, 31B-1 to 31B-2, 32B-1 to 32B-2, 33B-1 to 33B-2 are tables detailing the stages of the methodologies 3000, 3100, 3200, 3300, respectively, with:
   tables 3060, 3065 (FIGS. 30B-1 to 30B-2) detailing stages 3001-3014 of methodology 3000,
   tables 3160, 3165 (FIGS. 31B1-1 to 31B-2) detailing stages 3101-3114 of methodology 3100,
   tables 3260, 3265 (FIGS. 32B-1 to 32B-2) detailing stages 3201-3214 of methodology 3200, and
   tables 3360, 3365 (FIGS. 33B-1 to 33B-2) detailing the stages 3301-3314 of methodology 3300, and
FIG. 30C-1 to 30C-3, 31C-1 to 31C-3, FIG. 32C-1 to 32C-3, and 33C-1 to 33C-3 are screen shots of simulation results related to application of the methodologies 3000, 3100, 3200, and 3300, respectively, on the driver 2900;

FIG. 33D-1, 33D-2 are tables 3369a, 3369b comparing the methodologies 3000, 3100, 3200, 3300, and the output voltages resulting from their applications on the driver 2900;

FIG. 34 is a circuit diagram of a capacitive element driver 3400, which constitutes an embodiment of a storage capacitor-enabled capacitive element driver having three non-dissipative elements connected in series and nine switches;

FIG. 35A-35C-3, 36A-36C-3 illustrate methodologies 3500, 3600, respectively, for operating the driver 2400 during the stages of a complete V₃₄ driving cycle, in which:
FIGS. 35A, 36A are graphical representations 3550, 3650, respectively, of the operation of the circuit 3400 at each stage of the methodologies 3500, 3600,
FIGS. 35B-1 35B-2 are tables 3560, 3565, respectively, detailing the stages 3501-3514 of the methodology 3500, and FIGS. 36B-1, 36B-2 are tables 3660, 3665, respectively, detailing the stages 3601-3616 of the methodology 3600, and
FIG. 35C-1-35C-3, 36C-1-36C-3 are screen shots of simulation results related to application of the methodologies 3500, 3600, respectively, on the driver 3400;

FIG. 36D is a table 3669 comparing the stages of the methodologies 3500, 3600, and the output voltages resulting from their applications on the driver 3400;

FIG. 37 is a circuit diagram of a capacitive element driver 3700, which constitutes an embodiment of a storage capacitor-enabled capacitive element driver having three non-dissipative elements connected in series and thirteen switches;

FIG. 38A-1-38C-3 illustrate methodology 3800 for operating the driver 3700 during the stages of a complete V_{O37} driving cycle, in which:
FIGS. 38A-1, 38A-2 are graphical representations 3850a, 3850b, respectively, of the operation of the circuit 3700 at each stage of the methodology 3800,
FIGS. 38B-1A, 38B-1B are tables 3860a, 3860b, respectively, detailing the closed switches and output voltages of the circuit 3700 during application of the stages 3801-3826 of the methodology 3800 on the circuit 3700,
FIGS. 38B-2 is a table 3865 detailing the switch sets that are open on the circuit 3700 and the circuit's output voltages during application of the stages 3801-3826 of the methodology 3800 on the circuit 3700, and
FIGS. 38C-1-38C-3 are screen shots of simulation results related to application of the methodology 3800 on the driver 3700;

FIGS. 39A-1-39C-3 illustrate the methodology 3900 for operating the driver 3700 during the stages of a complete V_{O37} driving cycle, in which:
FIGS. 39A-1, 39A-2 are graphical representations 3950a, 3950b, respectively, of the operation of the circuit 3700 at each stage of the methodology 3900,
FIGS. 39B-1A, 39B-1B are tables 3960a, 3960b, respectively, detailing the closed switches and output voltages of the circuit 3700 during application of the stages 3901-3930 of the methodology 3900 on the circuit 3700,
FIGS. 39B-2 is a table 3965 detailing the switch sets that are open on the circuit 3700 and the circuit's output voltages during application of the stages 3901-3930 of the methodology 3900 on the circuit 3700, and
FIGS. 39C-1-39C-3 are screen shots of simulation results related to application of the methodology 3900 on the driver 3700;

FIG. 39D is a table 3969 comparing the stages of the methodologies 3800, 3900 on the driver 3700 and the output voltages resulting from their applications on the driver 3700;

FIG. 40 is a circuit diagram of a capacitive element driver system 4000, which constitutes an embodiment of a storage capacitor-enabled capacitive element driver system formed of a series of three 1-NDE cell drivers [w], [x], [y];

FIG. 41A-1-41B-2 illustrate the methodology 4100 for operating the 3-cell driver system 4000 during the stages of a complete V_{[wxy]} driving cycle, in which:
FIGS. 41A-1-41A-4 are graphical representations 4155a-4155d, respectively, of the operation of the circuit 4000 at each stage of the methodologies 2220, 4100,
FIGS. 41B-1A, 41B-1B are tables 4160a, 4160b, respectively, detailing the closed switches and output voltages of the circuit 4000 during application of the stages 4101-4154 of the methodology 4100 on the circuit 4000, and
FIG. 41B-2 is a table 4165, detailing the switch sets that are open on the circuit 4000 and the circuit's output voltages during application of the stages 4101-4154 of the methodology 4100 on the circuit 4000;

FIG. 41C is a table 4169 comparing the stages of methodologies 2220, 4100 and the output voltages resulting from their applications on the driver system 4000.

### DETAILED DESCRIPTION

Reference will now be made in detail to the present exemplary embodiments, examples of which are illustrated in the accompanying drawings. Wherever possible, the same reference numbers will be used throughout the drawings to refer to the same or like parts.

### 1. A Basic Non-Dissipative Element-Enabled Capacitive Element Driver

### Capacitive Element Driver 400

One embodiment of the present invention, shown in FIG. 4, has a capacitive element driver 400, also known as a non-dissipative element-enabled capacitive element driver (or, in an illustrative but not necessarily preferred embodiment in which the non-dissipative elements may be storage capacitors, a storage capacitor-enabled capacitive element driver), which also may be known as a fractional capacitive element driver or a green capacitive element driver, for driving the voltage of a capacitive element 430 between two voltage levels such as ground and supply voltage.

The capacitive element driver 400 may have a first pair 445 of switches SW4[0] and SW4[1] connected in series and disposed between a voltage source 420 (also known as voltage supply and the voltage source V_{DD4} for supplying a voltage of a value V_{DD4} to the capacitive element driver 400) and a capacitive element 430 (also known as capacitive element C_{O4}, element, or C_{O4}), which is sized to hold a voltage of a value V_{O4} thereacross. In the embodiment of FIG. 4, the voltage source V_{DD4} is a component of the capacitive element driver 400, but in other embodiments, it may be a unit separate from and electronically attachable to the capacitive driving circuit of the capacitive element driver 400.

The capacitive element 430 may be a capacitor or any element capable of being positioned at an output terminal of a circuit and there function as a capacitor. It is also to be understood that the non-dissipative element in the driving circuit 400 discussed here may be any kind of non-dissipative element, such as a capacitor, and that, for simplicity with describing circuit 400 and the other circuits described herein, a non-dissipative element may also be referred to herein as a “capacitor element,” “capacitor,” or with a capital C.

For example, the capacitive element 430 may be one or more capacitive loading elements. In the embodiment of FIG. 4, the capacitive element 430 is a unit separate from and electronically attachable to the capacitive driving circuit of the capacitive element driver 400, but in other embodiments, it may be a component of the capacitive element driver 400,

The switch SW_{4[0]} is electrically connected to a negative terminal 428 of the voltage source 420 and a common node 416 between the switches SW_{4[0]} and SW_{4[1]}; and the switch SW_{4[1]} is electrically connected to the common node 416 and a terminal 432 of the capacitive element 430 (a terminal may also be referred to as an input or node). The other terminal 438 of the capacitive element C_{O4} may be connected to ground or to the negative terminal 428 of the voltage source.

The capacitive element driver 400 may have a second pair 440 of switches SW_{4[2]} and SW_{4[3]} connected in series and disposed between the voltage source 420 and the capacitive element 430. The switch SW_{4[3]} is disposed to and electrically connected to a positive terminal 426 of the voltage source 420 and a common node 446 between the switches SW_{4[3]}, SW_{4[2]}; and the switch SW_{4[2]} is disposed between and connected to the common node 446 and the input 432 of the capacitive element 430.

The capacitive element driver 400 also may have a non-dissipative element 450, which (in an illustrative but not necessarily preferred embodiment) may be a storage capacitor C_{S4} disposed between and electrically connected to the common nodes 416, 446. Energy may be either stored in or transferred from the storage capacitor 450 when transient current flows through the capacitive element 430.

The capacitive element driver 400 also may have or be electrically connected to a controller 460 for controlling the activation and deactivation of the switches SW_{4[0]}, SW_{4[1]}, SW_{4[2]}, SW_{4[3]} so that the switches are switched on and off in combinations in a switching sequence of stages within one complete V_{O4} driving cycle that is defined to ensure the average value of voltage V_{CS4} of the storage capacitor 450 remains unchanged over time. The controller 460 may be electrically connected to the switches SW_{4[0]}, SW_{4[1]}, SW_{4[2]}, SW_{4[3]} through paths 470, 471, 472, 473 respectively (shown in FIG. 4 in broken lines) to provide control signals to signal the capacitive element driver 400 to start or stop a switching sequence methodology, such as is described below.

### Switch Sequencing

The controller 460 controls the activation and deactivation of the switches SW_{4[0]}, SW_{4[1]}, SW_{4[2]}, SW_{4[3]} to drive the capacitive element driver 400 through a complete V_{O4} driving cycle using a set of stages as shown in FIGS. 5A-5G:
In Stage 501(1), the switches SW_{4[0]}, SW_{4[1]} are closed (and the switches SW_{4[2]}, SW_{4[3]} are open) to drive the voltage V_{O4} to ground (FIG. 5A);
In Stage 501(2), the switches SW_{4[0]}, SW_{4[2]} are closed (and the switches SW_{4[1]}, SW_{4[3]} are open), to drive V_{O4} to V_{CS4} (FIG. 5B);
In Stage 501(3), the switches SW_{4[1]}, SW_{4[3]} are closed (and the switches SW_{4[0]}, SW_{4[2]} are open) to drive V_{O4} to (V_{DD4}−V_{CS4}) (FIG. 5C);
In Stage 501(4), the switches SW_{4[2]}, SW_{4[3]} are closed (and the switches SW_{4[0]}, SW_{4[1]} are open) to drive V_{O4} to V_{DD4} (FIG. 5D);
In Stage 501(5), the switches SW_{4[1]}, SW_{4[3]} are closed (and the switches SW_{4[0]}, SW_{4[2]} are open) to drive V_{O4} to (V_{DD4}−V_{CS4}) (FIG. 5E); and
In Stage 501(6), the switches SW_{4[0]}, SW_{4[2]} are closed (and the switches SW_{4[1]}, SW_{4[3]} are open) to drive V_{O4} to V_{CS4} (FIG. 5F).

The controller 460 may then return to Stage 501(1) to repeat the switching sequence. FIG. 5G is a chart showing the methodology 500, including its switching sequence and the resultant value of V_{O4} to which the voltage across the capacitive element 430 is driven during one complete V_{O4} driving cycle. FIG. 5G adopts the standard switching convention of illustrating a switching pattern by identifying switches that are closed with the term “Closed.” Unless specified in the following description of the stages and phases, the switches not labelled “Closed” are open. In later charts herein, the term “Closed” may be abbreviated to “C.”

FIG. 5H is an illustration of the capacitive element driver 400 in operation when the switches SW_{4[3]}, SW_{4[1]} are closed (and the switches SW_{4[0]}, SW_{4[2]} are kept open), as in Stages 501(3), 501(5). Referring to FIG. 5H, the storage capacitor C_{S4} is in series between the capacitive element C_{O4} and the voltage source V_{DD4} through closure of the switches SW_{4[3]}, SW_{4[1]}. Energy is stored in the storage capacitor C_{S4} when transient current flows through the capacitive element C_{O4}.

FIG. 5I is an illustration of the capacitive element driver 400 in operation when the switches SW_{4[0]}, SW_{4[2]} are closed (and the switches SW_{4[3]}, SW_{4[1]} are kept open), as in Stages 501(2), 501(6). Referring to FIG. 5I, the storage capacitor C_{S4} is in parallel with the capacitive element C_{O4} through closure of the switches SW_{4[0]} and SW_{4[2]}. Energy stored in the storage capacitor C_{S4} is transferred to the capacitive element C_{O4}.

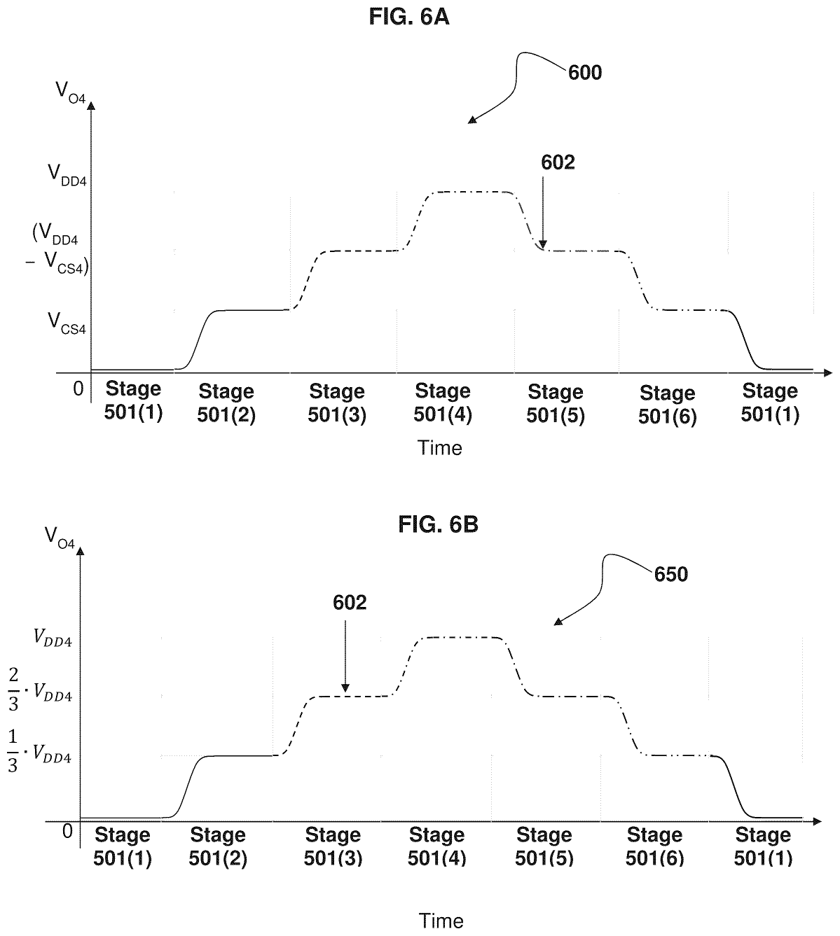

A switching sequence, applied in Stages 501(1) through 501(6), holds the average current across the storage capacitor 450 at zero and maintains the average value of the voltage at the storage capacitor 450 unchanged over time, while proceeding through a complete V_{O4} driving cycle. FIG. 6A is a graph 600 illustrating a waveform 602 of the voltage V_{O4} inputted to the capacitive element 430 corresponding to operation of the capacitive element driver 400 in accordance with the Stages 501(1)-501(6). Graph 600 shows the V_{O4} driving cycle provided by operation of the Stages 501(1)-501(6) as having a step-wise increase of the voltage V_{O4} to a peak voltage V_{DD4} (the voltage supplied by the voltage source 420), and then a step-wise decrease of the voltage V_{O4} to ground.

This switching sequence of Stages 501(1)-501(6) ensures that the average current, hence net charge, of storage capacitor C_{S4} holds at zero. Equating the net charge going into the storage capacitor 450 under one complete V_{O4} driving cycle to zero, the average value of V_{CS4} (equation 2) may be computed as following:

$$Net charge of {C}_{S4} = [ \text{} - {C}_{O4} {V}_{CS 4} + {C}_{O4} ( {V}_{DD 4} - 2 {V}_{CS 4} ) - {C}_{O4} {V}_{CS 4} + {C}_{O 4} ( {V}_{DD 4} - 2 {V}_{CS 4} ) ] \qquad ( 1 )$$

Equating the net charge of C_{S4}=0:

$$( 2 )$$

$$[ - {C}_{O 4} {V}_{CS 4} + {C}_{O 4} ( {V}_{DD 4} - 2 {V}_{CS 4} ) - {C}_{O 4} {V}_{CS 4} + {C}_{O 4} ( {V}_{DD 4} - 2 {V}_{CS 4} ) ] = 0$$

$$\to {V}_{CS 4} = {V}_{DD 4} / 3.$$

Thus the voltage V_{O4} is changed per stage with a delta of V_{DD4}/3. The energy dissipated on switches per stage may be shown algorithmically in equation 3 as

$$\frac{1}{2} {{C}_{O 4} ( \frac{{V}_{DD4}}{3} )}^{2} = \frac{1}{18} {C}_{O 4} {V}_{DD 4}^{2} \qquad ( 3 )$$

FIG. 6B is a graph 650 showing the waveform 602 of FIG. 6A with the y-axis label modified accordingly.

As shown in FIGS. 5A-5G, six stages of switching sequences in one complete V_{O4} driving cycle may be defined, to achieve total energy dissipation (equation 4):

$${E}_{{t}_{-} {circuit}_{-} 400} = 6 \times \frac{1}{18} {C}_{O 4} {V}_{DD 4}^{2} = \frac{1}{3} {C}_{O 4} {V}_{DD 4}^{2} . \qquad ( 4 )$$

In the conventional driving device, system, and process embodied in the circuit 100, the total energy dissipation of one complete V_{O1} driving cycle is E_{t_circuit_100}=C_{O1}V_{DD1}². Therefore, the capacitive element driving device, system, and process embodied in the capacitive element driver 400 (FIG. 4) reduces the total energy dissipation per one V_{O4} driving cycle by 3 times. Further, the driving device, system, and process embodied in the capacitive element driver 400 do not introduce extra current and hence extra conduction loss caused by the inclusion of inductor(s) in conventional resonant capacitive element drivers such as is shown in the driving device, system, and process embodied in the circuit 200 (FIG. 2A) and the circuit 300 (FIG. 3A). In addition, unlike the conventional resonant capacitive element driving illustrated in the circuit 200 and the circuit 300, the switch(es) used in the capacitive element driver 400 may be built on the same substrate (e.g. silicon), further minimizing the cost and size of capacitive element driving.

The energy saving provided by the use of the storage capacitor in capacitive element driver 400 results because of the average of the storage capacitor voltage V_{CS4} remains between the supply voltage and ground. When the average voltage V_{CS4} was equal to either the supply voltage or to ground, no energy saving would be achieved. For the case in capacitive element driver 400, when the average of V_{CS4}=⅓ of the supply voltage V_{DD4}, the energy saving is optimum.

### 2. Generalized Non-Dissipative Element-Enabled Capacitive Element Driver

### Capacitive Element Driver 700A

While FIG. 4 shows an embodiment of an improved capacitive element driver in which a single non-dissipative element 450 and four switches are included in a capacitive element driver 400, FIG. 7A illustrates a generalized embodiment of a non-dissipative element-enabled capacitive element driver in which a capacitive element driver 700A has n non-dissipative elements (which in an illustrative but not necessarily preferred embodiment may be storage capacitors) (C_{S7A[1]}, C_{S7A[2]}, C_{S7A[3]}, . . . , C_{S7A[n+1]}, C_{S7A[n]}); n+3 switches (SW_{7A[0]}, SW_{7A[1]}, SW_{7A[2]}, . . . , SW_{7A[n]}, SW_{7A[n+1]}, SW_{7A[n+2]}); a voltage source 720A for supplying a voltage V_{DD7A}, and a capacitive element 730A (also known as capacitive element C_{O7A}, element, or C_{O7A}) are included in a capacitive element driver 700A. The number n may be any positive integer. As noted above with respect to capacitive element 430, a capacitive element 730A may be a capacitor or any element capable of being positioned at the output terminal of a circuit and functioning as a capacitor. For example, the capacitive element 730A may be one or more capacitive loading elements.

As with the capacitive element driver 400, the capacitive element driver 700A may have the voltage source 720A (also known as the voltage source V_{DD7A}) for supplying a voltage of a value as a component of the capacitive element driver 700A, but in other embodiments, it may be a unit separate from and electronically attachable to the capacitive driving circuit of the capacitive element driver 700A. Also, as with the capacitive element 430, the capacitive element 730A is a unit separate from and electronically attachable to the capacitive driving circuit of the capacitive element driver 700A, but in other embodiments, it may be a component of the capacitive element driver 700A.

The switches SW_{7A[0]}, SW_{7A[1]} are connected in series and are electrically connected to and disposed between a negative terminal 728A of a voltage source 720A (for supplying a voltage V_{DD7A}) and one terminal 732A of the capacitive element 730A, for holding a voltage V_{O7A} thereacross. The switches SW_{7A[n+1]}, SW_{7A[n+2]} are also connected in series, and are electrically connected to and disposed between a positive terminal 726A of the voltage source 720A and the input 732A of the capacitive element 730A. The other terminal 738A of the capacitive element C_{O7A} may be electrically connected to ground or to the negative terminal 728A of the voltage source 720A.

The switch SW_{7A[0]} may be disposed between and electrically connected to a negative terminal 728A of the voltage source 720A and a common node 705A(1) between the switches SW_{7A[0]}, SW_{7A[1]}. The switch SW_{7A[n+2]} may be disposed between and electrically connected to a positive terminal 726A of the voltage source 720A and a common node 705A(n+1) between the switches SW_{7A[n+1]}, SW_{7A[n+2]}.

The n storage capacitors may be electrically connected in series and disposed between the common nodes 705A(1), 705A(n+1), with a storage capacitor C_{S7A[x]}, where x is from 1 to n, disposed between and electrically connected to nodes 705A(x), 705A(x+1). Further, the switch SW_{7A[x]}, where x is from 1 to n+1, may be disposed between and electrically connected to the node 705A(x) and the input 732A of the capacitive element C_{O7A}. Specifically,
one terminal of switch SW_{7A[1]} may be electrically connected to the input 732A of capacitive element C_{O7A}, and the other terminal may be electrically to the common node 705A(1) of the switches SW_{7A[0]} and SW_{7A[1]};
one terminal of switch SW_{7A[2]} may be electrically connected to the input 732A of capacitive element C_{O7A}, and the other one terminal may be electrically connected to the common node 705A(2) of storage capacitors CS_{7A[1]} and CS_{7A[2]};
one terminal of switch SW_{7A[3]} may be electrically connected to the input 732A of capacitive element C_{O7A}, and the other one terminal may be electrically connected to the common node 705A(3) of storage capacitors CS_{7A[2]} and CS_{7A[3]} (not shown);
one terminal of switch SW_{7A[n-1]} may be electrically connected to the input 732A of capacitive element C_{O7A}, and the other terminal may be electrically connected to the common node 705A(n−1) of storage capacitors CS_{7A[n-2]} (not shown) and CS_{7A[n-1]};
one terminal of switch SW_{7A[n]} may be electrically connected to the input 732A of capacitive element C_{O7A}, and the other terminal may be electrically connected to the common node 705A(n) of storage capacitors CS_{7A[n-1]} and CS_{7A[n]}; and
one terminal of switch SW_{7A[n+1]} may be electrically connected to the input 732A of capacitive element C_{O7A}, and the other terminal may be electrically connected to the common node 705A(n+1) of the switches SW_{7A[n+1]}, SW_{7A[n+2]}.

The capacitive element driver 700A also has or is electrically connected via a path system 770A to a controller 760A, which is arranged to provide control signals to signal the capacitive element driver 700A to start or stop a switching sequence methodology, The path system 770A electrically connects the controller 760A to the switches to allow the controller 760A to selectively connect the storage capacitors, voltage source 720A, and the capacitive element in stages within one complete V_{O7A} driving cycle in which switches are switched on and off in combinations in a sequence of stages within one complete V_{O7A} driving cycle. The stages may be implemented in a sequencing methodology having a plurality of phases; the methodology is defined to ensure the average value of voltage of the storage capacitors remains unchanged over time.

### Switch Sequencing

Referring to FIG. 8A, a graph 800 illustrates a waveform 802 of the voltage V_{O7A} inputted to the capacitive element 730A corresponding to operation of the capacitive element driver 700A in accordance with the Stages 801(1)-801(4n+2) and the switching sequence methodology disclosed herein. Graph 800 shows the V_{O7A} driving cycle as having a step-wise increase of the voltage V_{O7A} to a peak voltage V_{DD7A} (the voltage supplied by the voltage source 720A), and then a step-wise decrease of the voltage V_{O7A} to ground.

The switching sequence methodology 80 calls for switches to be activated in combinations within one complete V_{O7A} driving cycle to ensure that the average value of the voltage V_{CS7A[1]}, V_{CS7A[2]}, V_{CS7A[3]}, . . . , V_{CS7A[n-1]}, and V_{CS7A[n]} of the storage capacitors does not change over time. Referring to FIG. 8B-1, a chart 850 illustrates the stages that may be used to control the n+3 switches throughout a V_{O7A} driving cycle, including the phase of the switching methodology associated with the selected stage, the switches that are activated during the selected state, the voltage to which V_{O7A} at the capacitive element 730A is driven during the selected stage.

FIG. 8B-2B1 identifies switches that are closed with the term “C,” which, as noted above, is an abbreviation of “Closed.” Unless specified in the following description of the stages and phases, the switches not labelled “C” are open.

Switching Sequence Phase 810 for Stages 801(1) to 801(n+1): Phase 810 constitutes a first phase of the switching sequence methodology 80, in which the switch SW_{7A[0]} (the switch electrically connected to the negative terminal 728A of voltage source V_{DD7A}) is closed and remains closed, and the switch SW_{7A[n+2]} (the switch electrically connected to the positive terminal 726A of voltage source V_{DD7A}) is open until the end of Stage 801(n+1).
Switching Sequence Sub-Phase 811 for Stage 801(1): Switch SW_{7A[1]} is closed until V_{O7A} is driven to ground level (e.g. 0V).
Switching Sequence Sub-Phase 812 for Stages 801(2) to 801(n+1): The switches SW_{7A[2]} to SW_{7A[n+1]} are closed sequentially. The stages operate sequentially and, during a Stage 801(s), with s from 2 to n+1, the switch SW_{7A[w]}, with w also from 2 to n+1, is closed until V_{O7A} is driven to a voltage level=Σᵢ₌₁^{w-1}V_{CS7A[i]}.

It can be seen that, through the sub-phase 812, the value of w increments as s increments. To illustrate for capacitive element driver 700A:
In a Stage 801(2), switch SW_{7A[2]} is closed first, which drives V_{O7A} to V_{CS7A[1]}.
In a Stage 801(3), switch SW_{7A[3]} is closed, which drives V_{O7A} to Σᵢ₌₁²V_{CS7A[i]}.
In a Stage 801(4), switch SW_{7A[4]} is closed, which drives V_{O7A} to Σᵢ₌₁³V_{CS7A[i]}.
The switch sequencing in sub-phase 812 continues until switch SW_{7A[n+1]} is closed, which drives V_{O7A} to Σᵢ₌₁ⁿV_{CS7A[i]}.

Switching sequence Phase 820 for Stages 801(n+2) to 801(3n+2): Phase 820 constitutes a second phase of the switching sequence methodology 80, in which the switch SW_{7A[0]} is open and switch SW_{7A[n+2]} is closed until the end of Stage 801(3n+2). The conventional practice of opening a currently closed switch, then closing a currently open switch is described for this and later-described switch activation transitions; opening the currently closed switch SW_{7A[n+2]} first and then closing the currently open switch SW_{7A[0]} prevents current flowing from the voltage source through all the non-dissipative elements during the switch activation transition. Switching sequence sub-phase 821 and switching sequence sub-phase 822 constitute a first sub-phase of the second phase 820, and switching sequence sub-phase 823 constitutes a second sub-phase of the second phase 820.
Switching Sequence Sub-Phase 821 for Stages 801(n+2) to 801(2n+1): During the stages in the stage range [specifically, the Stages 801(s), with s from (n+2) to (2n+1)], the switches in the switch range (SW_{7A[1]} to SW_{7A[n]}), or more generally, switch SW_{7A[x]}, where x is from 1 to n, are closed sequentially until V_{O7A} is driven to a voltage level=V_{DD7A}−Σⱼ₌ₓⁿV_{CS7A[j]}.

It can be seen that, through the sub-phase 821, the value of x increments as s increments. To generalize, for a selected switch SW_{7A[x]}:

$$x = a + ( s - b ) ,$$

where
a is the first switch in the switch range in the selected sub-phase,
s is the current stage, and
b is the first stage in the sub-phase.
   In the switching sequence sub-phase 821, in which a=1 and b=n+2:

$$\begin{matrix}x = 1 + [ s - ( n + 2 ) ] \\ = 1 + s - n - 2 \\ = s - n + 1 - 2 \\ = s - ( n + 1 )\end{matrix}$$

$$\to {SW}_{7 A [ x ]} = {SW}_{7 A [ s - ( n + 1 ) ]} .$$

To illustrate for capacitive element driver 700A:
In a Stage 801(n+2), switch SW_{7A[1]} is closed, which drives V_{O7A} to (V_{DD7A}−Σⱼ₌₁ⁿV_{CS7A[j]}).
In a Stage 801(n+3), switch SW_{7A[2]} is closed, which drives V_{O7A} to (V_{DD7A}−Σⱼ₌₂ⁿV_{CS7A[j]}).
In a Stage 801(n+4), switch SW_{7A[3]} is closed, which drives V_{O7A} to (V_{DD7A}−Σⱼ₌₂ⁿV_{CS7A[j]}).
The switching sequence in sub-phase 821 continues until switch SW_{7A[n]} is closed to drive V_{O7A} to (V_{DD7A}−V_{CS7A[n]}).
   Switching Sequence Sub-phase 822 for Stage 801(2n+2): During the Stage 801(2n+2), the which the switch SW_{7A[0]} is open and the switch SW_{7A[n+1]} is closed until V_{O7A} is driven to the driving circuit's supply voltage V_{DD7A}.
   Switching Sequence Sub-Phase 823 for Stages 801(2n+3) to 801(3n+2): During the stages in the stage range [specifically, the Stages 801(s), with s from (2n+3) to (3n+2)], the switches in the switch range (SW_{7A[n]} to SW_{7A[1]}), or more generally switch SW_{7A[y]}, where y is from n to 1, are closed in a switching pattern to achieve a step-wise decrease from the supply voltage V_{DD7A}. The switching pattern to achieve a step-wise decrease constitutes a reversing of the order of the steps in the switching order of sub-phase 821. A Stage 801(s) operates such that an associated switch SW_{7A[y]} is closed until V_{O7A} is driven to a voltage level=V_{DD}−Σ_{k=y}ⁿV_{CS[k]}. Going forward, the practice of step-wise decrease added to a switching pattern illustrating a step-wise increase in voltage may be known as operating the switching pattern “in reverse order.” Also, herein a “switching pattern” may also be referred to as a “pattern of switching,” a “switch activation pattern,” and a “pattern of switch activation.”

It can be seen that, through the Sub-Phase 823, the value of y decrements as s increments. To generalize, for a selected switch SW_{7A[y]}:

$$y = a - ( s - b ) ,$$

where:
a is the first switch in the switch range in the selected sub-phase,
s is the current stage, and
b is the first stage in the selected sub-phase.
   In the switching sequence sub-phase 821, in which a=n and b=(2n+3):

$$\begin{matrix}y = n - [ s - ( 2 n + 3 ) ] \\ = n - s + 2 n + 3 \\ = 3 n + 3 - s\end{matrix}$$

$$\to S {W}_{7 A [ y ]} = S {W}_{7 A [ 3 n + 3 - s ]} .$$

To illustrate for capacitive element driver 700A:
In a Stage 801(2n+3), switch SW_{7A[n]} is closed first, which drive V_{O7A} to (V_{DD7A}−V_{CS7A[n]}).
In a Stage 801(2n+4), switch SW_{7A[n-1]} is closed, which drives V_{O7A} to (V_{DD7A}−Σₖ₌ₙ₋₁ⁿV_{CS7A[k]}).
In a Stage 801(2n+5), switch SW_{7A[n-2]} is closed, which drives V_{O7A} to (V_{DD7A}−Σₖ₌ₙ₋₂ⁿV_{CS7A[k]}).
The switch sequencing in sub-phase 823 continues until SW_{7A[1]} is closed to drive V_{O7A} to (V_{DD7A}−Σₖ₌₁ⁿV_{CS7A[k]}).

Switching Sequence Phase 830 for Stages 801(3n+3) to 801(4n+2): Phase 830 constitutes a third phase of the switching sequence methodology 80, in which the switch SW_{7A[n+2]} is open and switch SW_{7A[0]} is closed.

During the stages in the stage range of the switching sequence phase 830 [specifically, the Stages 801(s), with s from (3n+3) to (4n+2)], the switches in the switch range SW_{7A[n+1]} to SW_{7A[2]}, or more generally, switch SW_{7A[z]}, where z is from (n+1) to 2 are closed in a reverse order as compared to the sub-phase 812. A Stage 801(s) operates such that an associated switch SW_{7A[z]} is closed until V_{O7A} is driven to a voltage level=Σₗ₌₁^{z-1}V_{CS7A[1]}.

It can be seen that, through the phase 830, the value of z decrements as s increments. To generalize, for a selected switch SW_{7A[z]}:

$$z = a - ( s - b ) ,$$

where:
a is the first switch in the switch range in the selected phase,
s is the current stage, and
b is the first stage in the phase.
   In the switching sequence phase 830, in which a=n+1 and b=(3n+3):

$$\begin{matrix}z = ( n + 1 ) - [ s - ( 3 n + 3 ) ] \\ = n + 1 - s + 3 n + 3 \\ = 4 n + 4 - s\end{matrix}$$

$$\to S {W}_{7 A [ z ]} = S {W}_{7 A [ 4 n + 4 - s ) ]} .$$

To illustrate for capacitive element driver 700A:
In a Stage 801(3n+3), switch SW_{7A[n+1]} is closed, which drives V_{O7A} to Σₗ₌₁ⁿV_{CS7A[l]}.
In a Stage 801(3n+4), switch SW_{7A[n]} is closed, which drives V_{O7A} to Σₗ₌₁ⁿ⁻¹V_{CS7A[l]}.
In a Stage 801(3n+5), switch SW_{7A[n-1]} is closed, which drives V_{O7A} to Σₗ₌₁ⁿ⁻²V_{CS7A[l]}.
The switching sequence in Phase 830 continues until SW_{7A[2]} is closed to drive V_{O7A} to V_{CS7A[l]}.

Switching Sequence Phase 840: Phase 840, which constitutes a fourth phase of the switching sequence methodology 80, in which the switching may return to switching sequence phase 810 to restart the sequence.

In total, the switching sequence phase methodology has 2(2n+1) stages in one complete V_{O7A} driving cycle to ensure that the average current, hence net charge Q, of storage capacitor C_{S7A[u]} is held to zero (e.g. Q_{CS7A[u]}=0), where u is any integer from 1 to n. The corresponding waveform of V_{O7A} under the above 2(2n+1) stages is illustrated in FIG. 8A.

When Q_{CS7A[u]}=0 is equated under one complete V_{O7A} driving cycle, the average value of V_{CS7A[u]} may be computed as follows:

$${Q}_{C S 7 A [ u ]} = {C}_{O 7 A} \{ - {\sum }_{j = u}^{n} {V}_{C S 7 A [ j ]} + [ {V}_{D D 7 A} - {\sum }_{j = 1}^{n} {V}_{C S 7 A [ j ]} - {\sum }_{j = u}^{n} {V}_{CS 7 A [ j ]} ] - {\sum }_{1 = 1}^{u} {V}_{CS 7 A [ j ]} + [ {V}_{DD 7 A} - {\sum }_{j = 1}^{n} {V}_{CS 7 A [ j ]} - {\sum }_{j = 1}^{u} {V}_{C S 7 A [ j ]} ] \} = 0.$$

$$= {C}_{O 7 A} \{ {V}_{DD 7 A} - 2 {\sum }_{j = 1}^{n} {V}_{CS 7 A [ j ]} - {V}_{C S 7 A [ u ]} \} = 0.$$

$${V}_{CS 7 A [ u ]} = {V}_{DD 7 A} - 2 {\sum }_{j = 1}^{n} {V}_{CS 7 A [ j ]} ,$$

$$where [ {V}_{DD 7 A} - 2 {\sum }_{j = 1}^{n} {V}_{CS 7 A [ j ]} ] is independent of u .$$

$$= {V}_{CS 7 A [ v ]} for u \neq v where both u and v are any integer ranged from 1 to n .$$

$$When {V}_{CS 7 A [ u ]} = {V}_{CS 7 A} , \{ {V}_{DD 7 A} - 2 {n V}_{CS 7 A} - {V}_{CS 7 A} \} = 0 .$$

$$\to {V}_{CS 7 A [ u ]} = {V}_{CS 7 A} = \frac{{V}_{DD 7 A}}{2 n + 1} .$$

Therefore, it can be seen that the voltage V_{O7A} is changed per stage by a delta of V_{DD7A}/[2n+1]; and that the energy dissipated on switches per stage is shown in equation (5):

$$\frac{1}{2} {{C}_{O 7 A} ( \frac{{V}_{DD 7 A}}{2 n + 1} )}^{2} = \frac{1}{{2 [ 2 n + 1 ]}^{2}} {C}_{O 7 A} {V}_{DD 7 A}^{2} . \qquad ( 5 )$$

There are 2(2n+1) stages per one complete V_{O7A} driving cycle with a total energy dissipation of:

$${E}_{t\_Circuit \_ 7 A} = 2 [ 2 n + 1 ] \times \frac{1}{{2 [ 2 n + 1 ]}^{2}} {C}_{O 7 A} {V}_{DD 7 A}^{2} = \frac{1}{2 n + 1} {C}_{O 7 A} {V}_{DD 7 A}^{2} . \qquad ( 6 )$$

In the conventional driving scheme (e.g. the circuit 100 of FIG. 1A), the total energy dissipation of one complete V_{O1} driving cycle was E_{circuit1}=C_{O1}V_{DD1}². With n storage capacitors and the sequencing of switches as disclosed herein, the capacitive element driver 700A reduces total energy dissipation per one V_{O7A} driving cycle by (2n+1) times.

### 3. Other Generalized Non-Dissipative Element-Enabled Capacitive Element Drivers

As noted above, FIG. 7A illustrates a generalized embodiment of a capacitive element driver, in which a capacitive element driver 700A has a capacitive element 730A (also known as C_{O7A}), n non-dissipative elements (in an illustrative but not necessarily preferred embodiment, storage capacitors), and n+3 switches. The number n may be any positive integer.

### Capacitive Element Driver 400

The earlier-described FIG. 4 illustrates an embodiment of a capacitive element driver in which a single storage capacitor 450 (n=1) and four (n+3) switches SW_{4[0]}, SW_{4[1]}, SW_{4[2]}, SW_{4[3]}, are included in a capacitive element driver 400. During the operation of the capacitive element driver 400 through a complete V_{O4} driving cycle, the embodiment of capacitive element driver 400 undergoes the stages and switching sequence phases and sub-phases disclosed with reference to capacitive element driver 700A. For example, referring to FIG. 5G, capacitive element driver 400 is switched in six stages, which corresponds to the 2(2n+1) stages of the switching sequence phase outlined for capacitive element driver 700A. Further, the phases that the capacitive element driver 400 undergoes while switching correspond to the switching sequence phases outlined for capacitive element driver 700A. Given that n=1 for capacitive element driver 400:
Stage 501(1) corresponds to Stage 801(1) (phases 811, 840).
Stage 501(2) corresponds to Stages 801(2) and 801(n+1) (respectively, the first and last stages of phase 812).
Stage 501(3) corresponds to Stages 801(n+2) and 801(2n+1) (respectively, the first and last stages of phase 821).
Stage 501(4) corresponds to Stage 801(2n+2) (phase 822).
Stage 501(5) corresponds to Stages 801(2n+3) and 801(3n+2) (respectively, the first and last stages of phase 823).
Stage 501(6) corresponds to Stages 801(3n+3) and 801(4n+2) (respectively, the first and last stages of phase 830).

### Capacitive Element Driver 780

FIG. 7B illustrates another embodiment of the capacitive element driver for the instantiation (n=3), in which a capacitive element driver 780 has a capacitive element 790 (also known as C_{O7B}), three (n=3) storage capacitors C_{7B[1]}, C_{7B[2]}, C_{7B[3]}, and six (n+3=6) switches SW_{7B[0]}, SW_{7B[1]}, SW_{7B[2]}, SW_{7B[3]}, SW_{7B[4]}, and SW_{7B[5]}, with a common node 785(1) between the switches SW_{7B[0]}, SW_{7B[1]}; a common node 785(2) between the capacitors C_{7B[1]}, C_{7B[2]} and the switch SW_{7B[2]}; a common node 785(3) between the capacitors C_{7B[2]}, C_{7B[3]} and the switch SW_{7B[3]}; and a common node 785(4) between the switches SW_{7B[4]}, SW_{7B[5]}. The capacitive element 790 has one terminal 792 to which switches SW_{7B[1]}, SW_{7B[2]}, SW_{7B[3]}, and SW_{7B[4]} may be connected, and another terminal 798 that may be electrically connected to the negative terminal 788 of the voltage source 787.

The connection of the capacitive element 790 to the driver 780 does not change methodology 88. In concept a capacitor is a symmetrical device (meaning terminals 792, 798 are indistinguishable), therefore there are two possible connections of the capacitive element 790 to the driver 780. The first option is to electrically connect the terminal 792 to a positive terminal 786 of a voltage source 787 and electrically connect the terminal 798 to the driver output terminal 704B of the driver 780). The second option is shown in FIG. 7B, in which the terminal 792 is electrically connected to the driver output terminal 704B of the driver 780 and the terminal 798 is electrically connected to the negative terminal 788 of the voltage source 787.

The capacitive element driver 780 has or is electrically connected to a controller 781 via a path system 783 for electrically connecting the controller 781 to the switches to allow the controller 781 to selectively connect the storage capacitors and the positive terminal 786 and negative terminal 788 of a voltage source 787 in a sequence of switching stages within one complete V_{O7B} driving cycle such that average value of the voltage V_{7B[1]}, V_{7B[2]}, V_{7B[3]}, of the storage capacitors not change with time.

The capacitive element driver 780 has been illustrated in FIG. 7B to conform to its generalized capacitive element driver 700A of FIG. 7A, including its components and nomenclature, and so will not be described in detail here. FIG. 8C shows a chart 880 that illustrates the methodology 88 defining the stages that may be used to control the n+3=6 switches throughout a V_{O7B} driving cycle, including the phase of the switching methodology associated with the selected stage, the switches that are activated during the selected state, the voltage to which V_{O7B} at the capacitive element 790 is driven during the selected stage.

During the operation of the capacitive element driver 780 through a complete V_{O7B} driving cycle, the embodiment of capacitive element driver 780 undergoes the same stages and switching sequence phases and sub-phases disclosed with reference to capacitive element driver 700A. For example, referring to FIG. 8C, the capacitive element driver 780 is switched in fourteen stages, which corresponds to the 2(2n+1) stages of the switching sequence phase outlined for capacitive element driver 700A and are provided with the same reference numerals for ease of presentation. Further, the phases that the capacitive element driver 780 undergoes while switching correspond to the switching sequence phases outlined for capacitive element driver 700A, and so the reference numerals for the stages and switching sequence phases and sub-phases for capacitive element driver 700A are used herein for capacitive element driver 780. Given that n=3 for capacitive element driver 780:
The V_{O7B} driving cycle for capacitive element driver 780 starts with Stage 801(1) (phase 811).
The capacitive element driver 780 undergoes phase 812 in Stages 801(2)-801(4).
The capacitive element driver 780 undergoes phase 821 in Stages 801(5)-801(7).
The capacitive element driver 780 undergoes phase 822 in Stage 801(8).
The capacitive element driver 780 undergoes phase 823 in Stages 801(9)-801(11).
The capacitive element driver 780 undergoes phase 830 in Stages 801(12)-801(14).
The capacitive element driver 780 returns to Stage 801(1) in phases 840.

### Capacitive Element Drivers 700C-1, 700C-2

FIG. 7C-1 illustrates a generalized embodiment of a non-dissipative element-enabled capacitive element driver 700C-1, which differs from the capacitive element driver 700A by the driver's first and last switches (which would be switches SW_{7C[0]} and SW_{7C[n+2]}) being closed or replaced with hard-wired connections. The switches (SW_{7C[1]}, SW_{7C[2]}, . . . , SW_{7C[n+1]}) may be arranged to open and close one at a time, in sequence (SW_{7C[1]}, SW_{7C[2]}, . . . , SW_{7C[n+1]}) to raise the voltage of the capacitive element C_{07C} from ground (0V) to V_{DD7C}. The switches may be arranged to open and close one at time, in reverse sequence (SW_{7A[n+1]}, SW_{7C[n]}, . . . , SW_{7C[1]}) to lower the voltage of C_{07C} from V_{DD7C} to ground (0V).

As with the capacitive element driver 700A, the non-dissipative element-enabled capacitive element driver 700C−1 minimizes E_{LOSS} without using relatively expensive larger-sized conductors or other inductors employed in conventional resonant capacitive element driving. For a complete switching cycle, the energy loss per driving cycle (E_{LOSS[7C]})

$${E}_{l o s s [ 7 C ]} = {C}_{07 C} * {( {V}_{DD 7 C} )}^{2} / ( n ) .$$

The capacitive element driver 700C-1 has n non-dissipative elements (which in an illustrative but not necessarily preferred embodiment may be storage capacitors) (C_{7C[1]}, C_{7C[2]}, C_{7C[3]}, . . . , C_{7C[n-1]}, C_{7C[n]}); n+1 switches (SW_{7C[1]}, SW_{7C[2]}, . . . , SW_{7C[n]}, SW_{7C[n+1]}); a voltage source 720C for supplying a voltage V_{DD7C}, and a capacitive element 730C (also known as capacitive element C_{O7C}, element, or C_{O7C}) are included in a capacitive element driver 700C. The number n may be any positive integer. A capacitive element 730C may be a capacitor or any element capable of being positioned at the output terminal of a circuit and there function as a capacitor. For example, the capacitive element 730C may be one or more capacitive loading elements.

Thus in driver 700C-1, the one or more non-dissipative elements are connected in series between terminals of the voltage source, and the two or more switches are connected at one of their ends to an input of the capacitive element. A first switch SW_{7C[1]} may be electrically connected at its other end to a common node 705C(1) between the negative terminal 728C of the voltage source 720C and a first non-dissipative element C_{7C[1]}, and a last switch SW_{7C[n+1]}, may be electrically connected at its other end to a common node 705C(n+1) between a positive terminal 726C of the voltage source and a last non-dissipative element C_{7C[n]}.

The capacitive element driver 700C-1 may have the voltage source 720C (also known as the voltage source V_{DD7C}) for supplying a voltage of a value as a component of the capacitive element driver 700A, but in other embodiments, it may be a unit separate from and electronically attachable to the capacitive driving circuit of the capacitive element driver 700C-1. Also, the capacitive element 730C may be a unit separate from and electronically attachable to the capacitive driving circuit of the capacitive element driver 700C-1, but in other embodiments, it may be a component of the capacitive element driver 700C-1.

The switch SW_{7C[1]} is electrically connected to and disposed between a negative terminal 728C of the voltage source 720C (for supplying a voltage V_{DD7C}) and one terminal 732C of the capacitive element 730C, for holding a voltage V_{O7C} thereacross. The switch SW_{7C[n+1]} is electrically connected to and disposed between a positive terminal 726C of the voltage source 720C and the input 732C of the capacitive element 730C. The other terminal 738C of the capacitive element C_{O7C} may be electrically connected to ground or to the negative terminal 728C of the voltage source 720C.

The negative terminal 728C of the voltage source 720C may be electrically connected to a common node 705C(1) between the non-dissipative element C_{7C[1]} and the switch SW_{7C[1]}. The positive terminal 726C of the voltage source 720C may be electrically connected to a common node 705C(n+1) between the non-dissipative element C_{7C[n]} and the switch SW_{7C[n+1]}.

The n storage capacitors may be electrically connected in series and disposed between the common nodes 705C(1), 705C(n+1), with a storage capacitor C_{7C[x]}, where x is from 1 to n, disposed between and electrically connected to nodes 705C(x), 705C(x+1). Further, the switch SW_{7C[x]}, where x is between 1 to n+1, may be disposed between and electrically connected to nodes 705C(x) and the input 732C of capacitive element C_{O7C}. Further, the operation of the driver 700C-1 allows for driving the voltage of a capacitive element between two voltage levels such as ground and supply voltage by transferring the energy stored in the driver's non-dissipative elements to the capacitive element in step-wise transfers, by alternatingly turning on and off two or more of the driver's switches in sequential order to drive the voltage of the capacitive element between the two levels. Specifically,
one terminal of switch SW_{7C[1]} may be electrically connected to the input 732C of the capacitive element C_{O7C}, and the other terminal may be electrically to the common node 705C(1) of the non-dissipative element C_{7C[1]} and the negative terminal 728C of the voltage source 720C, with the closing of the switch SW_{7C[1]} when the other switches are open causing a “bypass” of the non-dissipative elements of the driver 700C-1, passing the grounded voltage at the negative terminal 728C to the input 732C of the capacitive element C_{O7C};
one terminal of switch SW_{7C[2]} may be electrically connected to the input 732C of the capacitive element C_{O7C}, and the other one terminal may be electrically connected to the common node 705C(2) of the non-dissipative elements C_{7C[1]} and C_{7C[2]}, with the closing of the switch SW_{7C[2]} when the other switches are open causing delivery of voltage equal to V_{7C[1]} to the input of the capacitive element C_{O7C};
one terminal of switch SW_{7C[3]} (not shown) may be electrically connected to the input 732C of capacitive element C_{O7C}, and the other terminal may be electrically connected to the common node 705C(3) of the non-dissipative elements C_{7C[2]}, C_{7C[3]} (not shown), with the closing of the switch SW_{7C[3]} when the other switches are open are open causing delivery of voltage equal to V_{S7C[1]}+V_{S7C[2]} to the input of the capacitive element C_{O7C};
one terminal of switch SW_{7C[n]} may be electrically connected to the input 732C of capacitive element Coe, and the other terminal may be electrically connected to the common node 705C(n) of the non-dissipative elements CS_{7C[n-1]} (not shown), CS_{7C[n]}, with the closing of the switch SW_{7C[n]} when the other switches are open causing delivery of voltage level equal to Σᵢ₌₁ⁿ⁻¹V_{7C[i]} from the non-dissipative elements to the input of the capacitive element C_{O7C};
one terminal of switch SW_{7C[n+1]} may be electrically connected to the input 732C of the non-dissipative element C_{O7C}, and the other terminal may be electrically connected to the common node 705C(n+1) of the non-dissipative element CS_{7C[n+1]} and the positive terminal 726C of the voltage source 720C, with the closing of the switch SW_{7C[n+1]} when the other switches are open causing a “bypass” of the non-dissipative elements of the driver 700C-1, passing the supply voltage at the positive terminal 726C to the input 732C of the capacitive element C_{O7C}; and
After achieving peak voltage with this sequence of switch activation, the switches SW_{7C[1]} to SW_{7C[n+1]} may be closed, one at a time, sequentially in reverse order (SW_{7C[n+1]} to SW_{7C[1]}) to drive V_{O7C} back to the grounded voltage level at the negative terminal 728C.

The capacitive element driver 700C-1 also has or is electrically connected via a path system, not shown, to a controller, not shown, which is arranged to provide control signals to signal the capacitive element driver 700C-1 to start or stop a switching sequence methodology. The path system electrically connects the controller to the switches to allow the controller to selectively connect the storage capacitors, voltage source 720C, and the capacitive element in stages within one complete V_{O7C} driving cycle in which switches are switched on and off in a sequence of stages within one complete V_{O7C} driving cycle. As with the driver 700A, the stages may be implemented in a sequencing methodology having a plurality of phases; the methodology is defined to ensure the average value of voltage of the storage capacitors remains unchanged over time.

In circuits having a single non-dissipative element and two switches, the first switch may be electrically connected at its other end to one end of the single non-dissipative element, and a last switch may be electrically connected at its other end to the other end of the single non-dissipative element. In circuits having n non-dissipative elements and n+1 switches, for the remaining switches SW_{[i]} (1≤i≤n), a switch SW_{[i]} may be electrically connected at one end to the input terminal of the capacitive element and at its other end to a common node between non-dissipative elements C_{[i-1]}, C_{[i]}.

The capacitive element driver 700C-2 is a 3-non-dissipative element (NDE) version of the generalized capacitive element driver 700C-1. Driver 700C-2 has been illustrated in FIG. 7C-2 to conform to the driver 700C-1 of FIG. 7C-1, including its components and nomenclature, and so will not be described in detail here. FIGS. 8B-2A, 8B-2B1, and 8B-2B2 show charts 860, 868, and 869, respectively, that illustrate the methodology 86 defining the stages that may be used to control the (n+1)=4 switches throughout a V_{O7C} driving cycle, including the phase of the switching methodology associated with the selected stage, the switches that are activated during the selected state, the voltage to which V_{O7C} at the capacitive element C_{O7C} is driven during the selected stage.

The methodology 86, which is a 3-NDE version of the generalized switching methodology for driver 700C-1 disclosed above, may be applied to the three NDEs in the driver 700C-2. The methodology 86 outlines the switching of the capacitive element driver 700C-2 during the stages of a complete V_{O7C} voltage driving cycle, with the switches SW_{7C[1]} to SW_{7C[4]} closed, one at a time, sequentially (SW_{7C[1]} to SW_{7C[4]}), and after achieving peak voltage with this sequence of switch activation, the switches SW_{7C[1]} to SW_{7C[3]} may be closed, one at a time, sequentially in reverse order (SW_{7C[3]} to SW_{7C[1]}), in stages 865, 866, respectively, with a return to stage 861 to drive V_{O7C} to the grounded voltage level at the negative terminal 728C:
At stages 861 the switch SW_{7C[1]} may be closed while the other switches are open to cause a “bypass” of the NDEs of the driver 700C-2, passing the grounded voltage at the negative terminal 728C to the output terminal 704C with V_{O7C}=0 at steady state;
At stages 862, 866 the switch SW_{7C[2]} may be closed while the other switches are open to cause delivery of voltage equal to V_{7C[1]} to the output terminal 704C with V_{O7C}=⅓ V_{DD7C} at steady state;
At stages 863, 865 the switch SW_{7C[3]} may be closed while the other switches are open to cause delivery of voltage equal to V_{7C[1]}+V_{7C[2]} to the output terminal 704C with V_{O7C}=(⅔)V_{DD7C} at steady state; and
At stage 864, the switch SW_{7C[4]} may be closed while the other switches are open to cause another “bypass” of the non-dissipative elements of the driver 700C-2, so that the voltage at the voltage source V_{DD7C} is passed to the output terminal 704C with V_{O7C}=V_{DD7C} at steady state.

FIG. 8B-2B2 shows that the NDE C_{7C[3]} does not contribute to changes in voltage VO7C in the methodology 86, in essence showing that NDE C_{7C[3]} is redundant in the driver 700C-2.

### Capacitive Element Driver 700F: Adding Switches to Circuits

A capacitive element driver 700F is similar to the driver 700C-2 of FIG. 7C-2. The driver 700F has been illustrated in FIG. 7F to conform to the driver 700C-2, including its components and nomenclature, with the reference numerals modified to refer to 700F rather than 700C-2, so much of the detail of the switch 700F will not be repeated. The similarities between the driver 700F and the driver 700C-2 include:
the removal in the driver 700C-2 of the positive interconnection between the node 705C(4) and the positive terminal 726C of the voltage source;
the addition in FIG. 700F of a positive interconnection 716F between the positive terminal 726F and the circuit output terminal 704F;
the addition in FIG. 700F of a node 754F disposed on the positive interconnection 716F at the output of the switch SW_{7F-4}; and
the addition in FIG. 700F of a fifth switch SW_{7F-5} disposed on the positive interconnection 716F between the positive terminal 726F and the node 754F.

A description of the methodology 700F that is associated with the circuit 700F, and a comparison of the methodologies 86, 2600, are presented in FIG. 26D and below in Section 9, CIRCUIT/SWITCHING SEQUENCE METHODOLOGY VARIANTS, of the Detailed Description.

### Capacitive Element Drivers 700D/700E

FIGS. 7D and 7E illustrate other embodiments of the capacitive element driver of the instant invention. In capacitive element drivers 700D and 700E, the storage capacitors (non-dissipative elements) are not limited to having their terminals connected together in series with one terminal of a first non-dissipative element in the series electronically and directly connected directly to one terminal of the voltage source and one terminal of a last non-dissipative element in the series electronically and directly connected to the other terminal of the voltage source. In the drivers 700D and 700E, the NDE terminals may be connected to other nodes. For instance, they may be electrically connected to the negative terminal of the voltage source (ground), or to the positive terminal of the voltage source, or to any number of other connections or combinations thereof. The terminals of a driver's non-dissipative elements may be electrically connected to ground, the voltage source, or any number of other nodes in the circuit, for example, low-impedance voltage nodes. Further, as would be recognized by a person of ordinary skill in the art of circuit design, the terminals of some of the non-dissipative elements may be connected in series and others connected to other common nodes. In general, the terminals of a driver's non-dissipative elements may be electrically connected directly or indirectly between the terminals of the voltage source.

In earlier-described embodiments of a driver having two or more non-dissipative elements and three or more switches, the switches may be electrically connected at one of their ends to the input terminal of the capacitive element, with the first and last switches electrically connected at their other ends to the negative terminal and positive terminals, respectively, of the voltage source. The n NDEs of the drivers 700D, 700E disclosed here may be electrically connected in parallel, and the drivers 700D, 700E differ from the earlier disclosed embodiments in that:
one or more non-dissipative elements are not arranged in series between terminals of the voltage source;
the first and last switches of the drivers both may be electrically connected at one of their ends directly to one of the terminals of the voltage source and at their other ends directly to the output terminal of the driver;
the remainder of the switches (n in number) may be associated with and electrically connected to the n NDEs to form a set of switch/NDE combinations, with one end of a selected switch/NDE combination electrically connected to the other switch/NDE combinations at an NDE common node and with the other end of the selected switch/NDE combination also electrically connected to the other switch/NDE combinations at a switch common node;
one of the first and last switches may be electrically connected between the NDE common mode and the input of the capacitive element being driven, while the other of the first and last switches may be electrically connected between the switch common mode and one of the terminals of the source voltage.

In addition, as described in further detail below in the detailed description of Variants E, F, G, H, the driver/methodology combination may be constructed to access a driver's NDEs in any desired order. As an example, the alternative methodology could have one of 5 other options for switching the switches in the switch/NDE combinations, in any of the combinations that are mathematically possible

In the driver 700D shown in FIG. 7D:
the first switch SW_{7D[1]} may be disposed on the negative interconnection of the driver 700D, connected at one end to the input 732D of the capacitive element C_{O7D} and at its other end to the NDE node 705D(0), which links the set of common nodes 705D(1), . . . , 705D(n); and
the last switch SW_{7D[n+2]} may be disposed on the positive interconnection of the driver 700D, connected at one end to the switch node 705D(n+1), which links the electrically connected switch ends of the switch/NDE combinations to the positive interconnection and at its other end to the positive terminal 726D of the voltage source.

In the driver 700D, the switches in the switch/NDE combinations are disposed between the positive terminals of the NDEs and the positive common node 705D(n+1), which itself is disposed between the last switch (connected to the positive terminal of the voltage supply) and the driver output terminal; the switches in the switch/NDE combinations are arranged to disconnect the connection between the positive common node 705D(n+1) and their associated NDEs. In other embodiments of the driver 700D, the switches in the switch/NDE combinations may be disposed between the negative terminals of the NDEs and the negative common node 705D(0), which itself is disposed between the first switch (connected to the negative terminal of the voltage supply) and the driver output terminal.

In practical terms, in FIG. 7D, disposing the switches in the switch/NDE combinations at the negative terminal of the NDEs allows for the construction of the FIG. 700D with N-type metal-oxide-semiconductor (NMOS) technology so that all control signals may be referenced to ground, thus simplifying the semiconductor design of the driver 700D.

The operation of the driver 700D allows for driving the voltage of a capacitive element between two voltage levels such as ground and supply voltage by transferring the energy stored in the non-dissipative elements to the capacitive element in step-wise transfers, by alternatingly turning on and off two or more switches in sequential order to drive the voltage of the capacitive element between the two levels. It may be necessary for the driver 700D to operate initially over multiple switching cycles/sequences for the n non-dissipative elements of the driver 700D to reach steady-state (equilibrium) values that approximate those achieved by the non-dissipative elements of the driver 700A from the start of driver operation. During the initial switching operation of the driver 700D, the charge will be re-distributed by the capacitive element to the n non-dissipative elements of the driver 700D until the n non-dissipative elements reach their steady-state (equilibrium) values. When the n non-dissipative elements of the driver 700D reach steady-state (equilibrium) values, the voltages that they may supply become integer fractions of the voltage V_{DD7D}, specifically V_{CS7D[i]}=V_{DD7D}*i/(n+1), where i is the i-th non-dissipative element in the set of n non-dissipative elements of the driver 700D.

After the initial operation of multiple switching cycles/sequences, the switching methodology for the driver 700D may yield the following results:
When the switch SW_{7D[1]} is closed and the other switches are open, a “bypass” of the non-dissipative elements of the driver 700D results, passing the grounded voltage at the negative terminal 728D to the input 732D of the capacitive element C_{O7D};
When the switch SW_{7D[2]} is closed and the other switches are open, voltage equal to V is V_{CS7D[1]} delivered to the input of the capacitive element C_{O7D};
When the switch SW_{7D[3]} (not shown) is closed and the other switches are open, voltage equal to V_{CS7D[2]} is delivered to the input of the capacitive element C_{O7D}; and
When the switch SW_{7D[n+1]} is closed and the other switches are open, voltage equal to V_{CS7D[n]} is delivered to the input of the capacitive element C_{O7D}; and
When the switch SW_{7D[n+2]} is closed and the other switches are open, a “bypass” of the non-dissipative elements of the driver 700D results, passing the supply voltage V_{DD7D} at the positive terminal 726D to the input 732D of the capacitive element C_{O7D}.

The switching methodology for the driver 700D may include reversing the switching process to drive the voltage of the capacitive element back to the initial level. Specifically:
When the switch SW_{7D[n+1]} is closed and the other switches are open are open, voltage equal to V_{CS7D[n]} is delivered to the input of the capacitive element C_{O7D};
When the switch SW_{7D[3]} (not shown) is closed and the other switches are open, voltage equal to V_{CS7D[2]} is delivered to the input of the capacitive element C_{O7D};
When the switch SW_{7D[2]} is closed and the other switches are open, voltage equal to V is V_{CS7D[1]} delivered to the input of the capacitive element C_{O7D}; and
When the switch SW_{7D[1]} is closed and the other switches are open, a “bypass” of the non-dissipative elements of the driver 700D results, passing the grounded voltage at the negative terminal 728D to the input 732D of the capacitive element C_{O7D}.

As noted above, in the driver 700D, an initial operation of repeated cycles of the switching sequence will re-distribute electrical charge between the non-dissipative elements until the steady state average voltage on the non-dissipative elements is given by:

$${V}_{CS 7 D [ i ]} = {V}_{DD 7 D} * i / ( n + 1 ) .$$

In the driver 700E of FIG. 7E:
the first switch SW_{7E[1]} may be disposed on the negative interconnection of the driver 700E, connected at one end to the negative terminal 728E of the voltage source 720E and at the other end to the switch common node 705E(n+1), which links the switches SW_{7E[2]}, SW_{7E[3]}, . . . , SW_{7E[n+1]} to the outlet of the driver 700E; and
the last switch SW_{7E[n+2]} may be disposed on the positive interconnection of the driver 700E, connected at one end to the input 732E of the capacitive element C_{O7E} and at its other end to the NDE common node that links the NDEs CS_{7E[1]}, CS_{7E[2]}, . . . , CS_{7E[n]} to the positive interconnection.

Similar to the driver 700D, in the driver 700E the switches in the switch/NDE combinations are disposed between the negative terminals of the NDEs and the negative common node 705E(n+1), which itself is disposed between the first switch (connected to the negative terminal of the voltage supply) and the driver output terminal; the switches in the switch/NDE combinations are arranged to disconnect the connection between the negative common node 705E(n+1) and their associated NDEs. In other embodiments of the driver 700E, the switches in the switch/NDE combinations may be disposed between the positive terminals of the NDEs and the positive common node 705E(0), which itself is disposed between the last switch (connected to the positive terminal of the voltage supply) and the driver output terminal.

In practical terms, in FIG. 7E, disposing the switches in the switch/NDE combinations at the positive terminal of the NDEs allows for the construction of the FIG. 700D with P-type metal-oxide-semiconductor (PMOS) technology so that all control signals may be referenced to V_{DD7E}, thus simplifying the semiconductor design of the driver 700E.

As with the operation of the driver 700D, the driver 700D allows for driving the voltage of a capacitive element between two voltage levels such as ground and supply voltage by transferring the energy stored in the non-dissipative elements to the capacitive element in step-wise transfers, by alternatingly turning on and off two or more switches in sequential order to drive the voltage of the capacitive element between the two levels. As with the driver 700D, it may be necessary for the driver 700E to operate initially over multiple switching cycles/sequences for the n non-dissipative elements of the driver 700E to reach steady-state (equilibrium) values that approximate those achieved by the non-dissipative elements of the driver 700A from the start of driver operation. During the initial switching operation of the driver 700E, the charge will be re-distributed by the capacitive element to the n non-dissipative elements of the driver 700E until the n non-dissipative elements reach their steady-state (equilibrium) values. When the n non-dissipative elements of the driver 700E reach steady-state (equilibrium) values, the voltages that they may supply become integer fractions of the voltage V_{DD7E}, specifically V_{CS7E[i]}=V_{DD7E}*(n+1−i)/(n+1), where i is the i-th non-dissipative element in the set of n non-dissipative elements of the driver 700E.

After the initial operation of multiple switching cycles/sequences, the switching methodology for the driver 700E may yield the following results:
When the switch SW_{7E[1]} is closed and the other switches are open, a “bypass” of the non-dissipative elements of the driver 700E results, passing the grounded voltage at the negative terminal 728E to the input 732E of the capacitive element C_{O7E};
When the switch SW_{7E[2]} is closed and the other switches are open, voltage equal to V_{DD7E} minus V_{CS7E[1]} is delivered to the input of the capacitive element C_{O7E};
When the switch SW_{7E[3]} (not shown) is closed and the other switches are open, voltage equal to V_{DD7E} minus V_{CS7E[2]} is delivered to the input of the capacitive element C_{O7E};
When the switch SW_{7E[n+1]} is closed and the other switches are open are open, voltage equal to V_{DD7E} minus V_{CS7E[n]} is delivered to the input of the capacitive element C_{O7E};
When the switch SW_{7E[n+2]} is closed and the other switches are open, a “bypass” of the non-dissipative elements of the driver 700E results, passing the supply voltage V_{DD7E} at the positive terminal 726E to the input 732E of the capacitive element C_{O7E}.

As in the switching methodology for the driver 700D, the switching methodology for the driver 700E may include reversing the switching process to drive the voltage of the capacitive element back to the initial level. Specifically:
When the switch SW_{7E[n+1]} is closed and the other switches are open, voltage equal to V_{DD7E} minus V_{CS7E[n]} is delivered to the input of the capacitive element C_{O7E};
When the switch SW_{7E[3]} (not shown) is closed and the other switches are open, voltage equal to V_{DD7E} minus V_{CS7E[2]} is delivered to the input of the capacitive element C_{O7E};
When the switch SW_{7E[2]} is closed and the other switches are open, voltage equal to V_{DD7E} minus V_{CS7E[1]} is delivered to the input of the capacitive element C_{O7E}; and
When the switch SW_{7E[1]} is closed and the other switches are open, a “bypass” of the non-dissipative elements of the driver 700E results, passing the grounded voltage at the negative terminal 728E to the input 732E of the capacitive element C_{O7E};

As with the driver 700D, an initial operation of repeated cycles of the switching sequence will re-distribute electrical charge between the non-dissipative elements until the steady state average voltage on the non-dissipative elements is given by:

$$\begin{matrix}{V}_{CS 7 E [ i ]} = {V}_{DD 7 E} * ( n + 1 - i ) / ( n + 1 ) \\ = {V}_{DD 7 E} - {V}_{DD 7 E} * ( i ) / ( n + 1 )\end{matrix}$$

During the operation of the capacitive element drivers 700D, 700E, through their complete driving cycles, the embodiments of capacitive element drivers 700D, 700E may undergo the same stages and switching sequence phases and sub-phases disclosed with reference to capacitive element driver 700A, with the average voltage level value of the non-dissipative element may be maintained unchanged over time while the first capacitive element driver is operated through the first sequence of stages.

For example, as with the driver 700A, the sequence of stages for driver 700D may have a pattern of switch activation with a bypass portion in which the capacitive element driver is bypassed during application thereof on the capacitive element driver; and an addition portion that may be applied to the capacitive element driver after application of the bypass portion on the capacitive element driver, and in which voltage is added to an input voltage of the capacitive element driver during application thereof on the capacitive element driver. Further, the pattern of switch activation may have a second addition portion to be applied to the capacitive element driver before application of the bypass portion on the capacitive element driver, and arranged to cause another addition of voltage to the input voltage of the capacitive element driver during application thereof on the capacitive element driver.

In addition, as with the driver 700A, the sequence of switching stages may have a switching pattern in a capacitive element driver, the switching pattern in which a subtraction portion may be applied to the driver to cause subtraction of voltage from an input voltage of the capacitive element driver during application thereof on the capacitive element driver; and a bypass portion arranged to be applied to the capacitive element driver after application of the subtraction portion on the capacitive element driver, and to cause bypassing of the capacitive element driver capacitive element during application thereof on the capacitive element driver. Further, the switching pattern may have a second subtraction portion arranged to be applied to the capacitive element driver after application of the bypass portion on the capacitive element driver, and arranged to cause another subtraction of voltage from the input voltage of the capacitive element driver during application thereof on the capacitive element driver.

When the drivers 700A, 700C-1, 700C-2 are matched with properly sized components (which would be readily achieved by a circuit designer of ordinary skill in the art), the “series” configuration of the non-dissipative elements in the drivers 700A, 700C allows the voltages on their respective storage capacitors (non-dissipative elements) immediately to set to their respective steady-state values whenever the supply voltage (V_{DD7A}, V_{DD7C}) changes. Alternatively, the independently connected or independently referenced (sometimes referred to as “nested” or “parallel”) configuration of the non-dissipative elements in the drivers 700D, 700E call for the drivers to operate to transfer charge between non-dissipative elements through multiple switching cycles before their non-dissipative elements are brought to their steady-state voltages.

### Capacitive Element Drivers 700G/700H

FIGS. 7G and 7H illustrate capacitive element drivers 700G, 700H, which are 3-non-dissipative element (NDE) versions of the generalized capacitive element drivers 700D, 700E, respectively. Drivers 700G, 700H have three (3) NDEs and five (5) switches. In capacitive element drivers 700G and 700H, as in capacitive element drivers 700D, 700E, the terminals of the non-dissipative elements may be arranged in parallel between common nodes.

As indicated below, while the NDEs may be arranged in parallel, topologically speaking, the NDEs will not be accessed together in any single stage; otherwise, the charge sharing between the NDE and the capacitive element that the circuit is driving them may cause the NDE average voltage change with time. An NDE may be either isolated (no connection for charge sharing), or connected alone to the output terminal of the driver, which itself is connected to the capacitive element. Alternatively, the NDE may be connected in series with other NDEs to the output terminal of the driver.

Drivers 700G, 700H have been illustrated in FIGS. 7G, 7H to conform to the drivers 700D of FIG. 7D, 700H of FIG. 7H, including their components and nomenclature, with the reference numerals of the components of drivers 700D, 700E, modified to refer to their counterpart components in drivers 700G, 700H and so will not be described in detail here.

### 4. Capacitive Element Driver Components

As the capacitive element drivers 400, 780 are embodiments of the capacitive element driver 700A, for the description herein of components for capacitive element drivers of the present invention, the components of the capacitive element driver 700A will be used herein as representative of the components in capacitive element drivers 400, 780 and any other capacitive element drivers encompassed by the present invention.

### Non-Dissipative Elements

The embodiment shown in capacitive element driver 700A has no requirements and/or constraints on the relationship between the value of one non-dissipative element and the value of another, different non-dissipative element. For example, the value of one non-dissipative element may be equal to the value of another, different non-dissipative element; or the value of one may be different from the value of another, different non-dissipative element, with the difference in value of a non-dissipative element close or not at all close to the value the other, different non-dissipative element.

Additionally, the embodiment shown in capacitive element driver 700A has no requirements and/or constraints on the type of one non-dissipative element and the type of another, different non-dissipative element. In illustrative but not necessarily preferred embodiments, the type of one non-dissipative element may be a storage capacitor. In such embodiments, the type of another non-dissipative element may also be a storage capacitor or another type of non-dissipative element, such as a rechargeable battery, a reverse-biased semiconductor PN-junction, or a capacitor with its capacitance modified by a transformer.

A storage capacitor in capacitive element driver 700A may be of any suitable type. For example, without limitation, a storage capacitor may be a transistor; it may be ceramic or electrolytic, or it may be created using any known method, including without being limiting Poly-Insulator-Poly (PIP), Metal-Insulator-Metal (MIM), Metal-Oxide-Metal (MOM), or Metal-Oxide-Semiconductor (MOS). The storage capacitors do not need to be of the same type; one storage capacitor may be identical to, similar to or of a different type than another storage capacitor.

### Switches

There are no requirements and/or constraints on the implementation of a switch and/or configurations of switches in the capacitive element driver 700A. Without limitation, examples of suitable switches for use in the capacitive element driver 700A are illustrated in FIGS. 9A-9G. While certain figures herein show and the disclosures herein describe certain transistors as n-channel or p-channel, it is to be understood that any suitable transistor may be used. For example, an n-channel or p-channel field effect transistor (FET) may be employed in lieu of n-channel or p-channel transistors. An NPN or PNP bipolar junction transistor (BJT) may be employed in lieu of n-channel or p-channel transistors, with the BJT having an emitter in lieu of a source and a collector in lieu of a drain.

FIG. 9A shows a configuration of a switch SW₉ₐ (910) with terminals a₉ₐ and b₉ₐ.

FIG. 9B shows two configurations of an n-channel transistor SW_{9b1} (920) with the terminal a_{9b1} at its source and the terminal b_{9b1} at its drain; and an n-channel transistor SW_{9b2} (925) with the terminal a_{9b2} at its drain and the terminal b_{9b2} at its source.

FIG. 9C shows two configurations of a p-channel transistor SW_{9c} (930) with terminal a_{9c1} at its source and terminal b_{9c1} at its drain; and p-channel transistor SW_{9c2} (935) with terminal a_{9c2} at its drain and terminal b_{9c2} at its source.

FIG. 9D shows two configurations of a switch formed by an n-channel and a p-channel transistor in parallel:
Switch SW_{9d1} (940) has the drain of an n-channel transistor SW_{9b2} (925) electrically connected to the source of a p-channel transistor SW_{9c1} (930) at their terminal a_{9d1}, and with the source of the n-channel transistor SW_{9b2} (925) electrically connected to the drain of the p-channel transistor SW_{9c1} (930) at their terminal b_{9d1}.
Switch SW_{9d2} (945) has the source of an n-channel transistor SW_{9b1} (920) electrically connected to the drain of a p-channel transistor SW_{9c2} (935) at their terminal a_{9d2}, and with the drain of the n-channel transistor SW_{9b1} (920) electrically connected to the source of the p-channel transistor SW_{9c2} (935) at their terminal b_{9d2}.

FIG. 9E shows two configurations of a switch formed by two n-channel transistors in series.
Switch SW₉ₑ₁ (950) has the n-channel transistor SW_{9b2} (925) with its drain electrically connected to the switch terminal a₉ₑ₁, and with its source electrically connected to the source of the n-channel transistor SW_{9b1} (920), which has its drain at the switch terminal b₉ₑ₁.
Switch SW₉ₑ₂ (955) has the n-channel transistor SW_{9b1} (920) with its source electrically connected to the switch terminal a₉ₑ₂, and with its drain electrically connected to the drain of the n-channel transistor SW_{9b2} (925), which has its source at the switch terminal b₉ₑ₂.

FIG. 9F shows configurations of a switch formed by two p-channel transistors in series.
Switch SW_{9f1} (960) has the p-channel transistor SW_{9c2} (935) with its drain electrically connected to the switch terminal a_{9f1}, and with its source electrically connected to the source of the p-channel transistor SW_{9c1} (930), which has its drain at the switch terminal b_{9f1}.
Switch SW_{9f2} (965) has the p-channel transistor SW_{9c1} (930) with its source electrically connected to the switch terminal a_{9f2}, and with its drain electrically connected to the drain of the p-channel transistor SW_{9c2} (935), which has its source at the switch terminal b_{9f2}.

FIG. 9G shows four configurations of a switch formed by two n-channel and two p-channel transistors.
Switch SW_{9g1} (970) and switch SW_{9g2} (975) show two configurations of a switch formed by two switches in parallel (with one switch having two n-channel transistors in series and another switch with two p-channel transistors in series).
Switch SW_{9g1} (970) has the switch SW₉ₑ₁ (950) with its switch terminal a₉ₑ₁ electrically connected to the switch terminal a_{9g1} of the switch SW_{9g1} (970) and the switch terminal a_{9f2} of the switch SW_{9f2} (965); and with its switch terminal b₉ₑ₁ electrically connected to the switch terminal b_{9g1} of the switch SW_{9g1} (970) and the switch terminal b_{9f2} of the switch SW_{9f2} (965).
Switch SW_{9g2} (975) has the switch SW₉ₑ₂ (955) with its switch terminal a₉ₑ₂ electrically connected to the switch terminal a_{9g2} of the switch SW_{9g2} (975) and the switch terminal a_{9f1} of the switch SW_{9f1} (960); and with its switch terminal b₉ₑ₂ electrically connected to the switch terminal b_{9g2} of the switch SW_{9g2} (975) and the switch terminal b_{9f1} of the switch SW_{9f1} (960).

Switch SW_{9g3} (980) and switch SW_{9g4} (985) show two configurations of a switch formed by two switches in series (with each switch having an n-channel and a p-channel transistor in parallel).
Switch SW_{9g3} (980) has the switch SW_{9d1} (940) with its switch terminal a_{9d1} electrically connected to the switch terminal a_{9g3} of the switch SW_{9g3} (980); and with its switch terminal b_{9d1} electrically connected to the switch terminal a_{9d2} of the switch SW_{9d2} (945), which has its switch terminal b_{9d2} electrically connected to the switch terminal b_{9g3} of the switch SW_{9g3} (980).
Switch SW_{9g4} (985) has the switch SW_{9d2} (945) with its switch terminal a_{9d2} electrically connected to the switch terminal a_{9g4} of the switch SW_{9g4} (985); and with its switch terminal b_{9d2} electrically connected to the switch terminal a_{9d1} of the switch SW_{9d1} (940), which has its switch terminal b_{9d1} electrically connected to the switch terminal b_{9g4} of the switch SW_{9g4} (985).

### Capacitive Elements

As noted above, a capacitive element may be a capacitor or any element capable of being positioned at the output terminal of a circuit and there function as a capacitor. For example, the capacitive element may be one or more capacitive loading elements. Also, as with the capacitive elements 430, 730A a capacitive element may be a unit separate from and electronically attachable to the capacitive driving circuit of the capacitive element driver, but in other embodiments, it may be a component of the capacitive element driver.

There are no constraints on the type of capacitive element to be driven in a capacitive element driver 700A. Whether an electrical device/network (such as those shown in FIGS. 10-18) is of a two-terminal or a multiple-terminal type, an impedance (Z) between any two of the terminals shows capacitive functionality in the electrical device/network, and the capacitive element driver 700A may be used to drive the electrical device/network with reduced total energy dissipation per complete V_{O7A} driving cycle.

In operation, an electrical device/network 1030 may be attached to the driver 1000 of FIG. 10 by electrically connecting its terminal 1034 of impedance Z₁₀ to a first node 1004 (also known as a V_{O10} node) of the driver 1000, the node 1004 being electrically connected to a common node 1014 of the switches SW_{10[1]} to SW_{10[n+1]} of the driving circuit 1010, and by electrically connecting its terminal 1036, which in this illustrative but not necessarily preferred embodiment, is of the same impedance Z₁₀, to a node 1006 that is electrically connected to the positive terminal 1026 of the voltage source 1020 (e.g. voltage source V_{DD10}) of the driver 1000.

Another embodiment of a capacitive element driver is shown in FIG. 11, in which an n-terminal device/network 1130 has an impedance (Z_{XY11}) existing between terminal X₁₁ and terminal Y₁₁, and shows capacitive functionality in the electrical device/network. The driver 1100 has a capacitive driving circuit 1110 that may be used to drive the electrical device/network 1130 with reduced total energy dissipation per complete V_{O11} driving cycle. As shown in FIG. 11, the terminal X₁₁ of the n-terminal electrical device/network 1130 may be connected to the V_{O11} node 1104 of the driver 1100, which is electrically connected to a common node 1114 of the switches SW_{11[1]} to SW_{II[n+1]} of the capacitive driving circuit 1110, and the terminal Y₁₁ of the n-terminal electrical device/network 1130 may be connected to a node 1108 that is electrically connected to the negative terminal 1128 of the voltage source V_{DD11} of the driver 1100.

Another embodiment of a capacitive element driver is shown in FIG. 12, in which an n-terminal device/network 1230 has an impedance (Z_{XY12}) existing between the terminal X₁₂ and terminal Y₁₂, and shows capacitive functionality in the electrical device/network. The driver 1200 has a capacitive driving circuit 1210 that may be used to drive the electrical device/network 1230 with reduced total energy dissipation per complete V_{O12} driving cycle. As shown in FIG. 12, the terminal X₁₂ of the n-terminal electrical device/network 1230 may be connected to the V_{O12} node 1204 of the driver 1200, which is electrically connected to a common node 1214 of the switches SW_{12[1]} to SW_{12[n+1]} of the capacitive driving circuit 1210, and the terminal Y₁₂ of the n-terminal electrical device/network 1230 may be connected to a node 1206 that is electrically connected to the positive terminal 1226 of the voltage source V_{DD12}.

An n-terminal device/network may be of any suitable type, including without limitation a transistor, which may have an impedance (Z) existing between its gate and source terminal, and may show capacitive functionality; therefore, a capacitive driving circuit such as those described here may be used to drive the transistor with reduced total energy dissipation per complete output voltage driving cycle. Such transistors may be of any suitable type, including MOSFET(s), GaN-FET(s), SiC-FET(s), JFET(s) or IGBT(s), and may be formed of a single transistor or a plurality of transistors.

Four such embodiments are shown in FIGS. 13-16, in which the gate terminal(s) of the transistors 1330, 1430, 1530, 1630 are electrically connected to the V_{O13} node 1314 of the capacitive driving circuit 1310, the V_{O14} node 1414 of the capacitive driving circuit 1410, the V_{O15} node 1514 of the capacitive driving circuit 1510, the V_{O16} node 1614 of the capacitive driving circuit 1610, respectively.
In FIG. 13, the source terminal(s) 1337 of the transistor(s) 1330 is(are) electrically connected to the negative terminal 1328 of the voltage source V_{DD13} electrically connected to the circuit 1310.
In FIG. 14, the source terminal(s) 1437 of the transistor(s) 1430 is(are) electrically connected to the positive terminal 1426 of the voltage source V_{DD14} electrically connected to the circuit 1410.
In FIG. 15, the drain terminal(s) 1539 of the transistor(s) 1530 is(are) electrically connected to the positive terminal 1526 of the voltage source V_{DD15} electrically connected to the circuit 1510.
In FIG. 16, the drain terminal(s) 1639 of the transistor(s) 1630 is(are) electrically connected to the negative terminal 1628 of the voltage source V_{DD16} electrically connected to the circuit 1610.
   In the circuits of FIGS. 13-16, the Source and Drain terminals are shown as unconnected for simplicity. It will be apparent to one of ordinary skill in the art of circuits that such terminals are electrically connectable to another component such as a power supply (for example, a voltage source).

Two other embodiments of a capacitive element driver are shown in FIGS. 17-18, in which an element such as a device/network 1740, 1840 may be driven by capacitive driving circuits 1710, 1810, respectively, through capacitive elements 1730, 1830 respectively. The capacitive element 1740, 1840 may be one or more transistors or a device/network formed of any combination of different passive elements (e.g. resistors, capacitors, inductors) and/or active elements (e.g. transistors). The device/networks 1740, 1840 may have two or more terminals and may have an impedance (Z) existing thereacross; so device/networks 1740, 1840 may show capacitive functionality and may be driven with a capacitive driving circuit, for example capacitive driving circuit 1710, 1810, respectively, so as to reduce total energy dissipation per complete output voltage driving cycle.

FIGS. 17 and 18 show the capacitive driving circuits 1710, 1810 electrically connected to the capacitive elements 1730, 1830, which are, in turn, electrically connected to the device/networks 1740, 1840 respectively. The device/networks 1740, 1840 are electrically connected to the capacitive driving circuits 1710, 1810 through the voltage sources 1720, 1820, with the terminals 1746, 1846 of the device/networks 1740, 1840 electrically connected to the positive terminals 1726, 1826 of the voltage sources 1720, 1820, respectively; and with the terminals 1748, 1848 electrically connected to the negative terminal 1728, 1828 of the voltage sources V_{DD17}, V_{DD18}, respectively.

In the illustrative but not necessarily preferred embodiments of FIGS. 17, 18, the capacitive elements 1730, 1830 are transistors, but it is to be understood that any suitable electrical device(s) or network(s) having capacitive functionality may be used as capacitive elements 1730, 1830. FIGS. 17, 18 show transistors 1730, 1830 electrically connected through gate terminal(s) to the V_{O17} node 1714 of the circuit 1710 and the V_{O18} node 1814 of the capacitive driving circuit 1810, respectively.

FIG. 17 shows the source terminal(s) 1737 of the transistor(s) 1730 connected to a node 1744 of the device/network 1740; and FIG. 18 shows the drain terminal(s) 1839 of the transistor(s) 1830 connected to a node 1844 of the device/network 1840. In other embodiments of FIG. 17, the drain terminal(s) 1739 of the transistor(s) 1730 may be connected to extra terminals of the device/network 1740; and in other embodiments of FIG. 18, the source terminal(s) 1837 of the transistor(s) 1830 may be connected to extra terminals of the device/network 1840,

In operation, the capacitive driving circuit 1710, 1810, drives the device/network 1740, 1840 though the capacitive element 1730, 1830, respectively, in stages within one complete V_{O17}, V_{O18} driving cycle in which the switches of the capacitive driving circuit 1710, 1810 are closed and opened in combinations in a sequence of switching stages within one complete V_{O17}, V_{O18} driving cycle from ground to V_{DD17}, V_{DD18}. The stages may be those described herein and implemented in a switching sequence methodology that that is defined to ensure the average value of voltage of the storage capacitors remains unchanged over time.

In FIGS. 17, 18, the device/networks 1740, 1840 are shown with three terminals. When the device/networks 1740, 1840 are two terminal systems, one of the network/device terminals is connected to either the drain or the source terminal of transistor 1730, 1830, and the other of the network/device terminals is electrically connected to either the positive or the negative terminal of the voltage source V_{DD17}, V_{DD18}. In other embodiments, the other of the network/device terminals may be electrically connected to either the positive or the negative terminal of the voltage source V_{DD17}, V_{DD18}, through any of multiple terminals of a “black box” electrically connected between the device/network 1740, 1840 and the voltage source V_{DD17}, V_{DD18}.

### 5. Applications of Switch Sequencing

Although the switching sequence methodology described herein contemplates being repeatable across a plurality of output voltage driving cycles to provide periodic charging of a capacitive element or a device/system that is functional as a capacitive element, it may be understood that the capacitive element drivers and the switching sequence methodology described herein may be used to provide a periodic driving for a selected number of output voltage driving cycles or a selected period, followed by inactivity.

It may also be understood that the switching sequence methodology described herein may be implemented in a discontinuous manner without constraints on in which stage the switching sequence methodology should be started. For example, as referred to FIG. 8A, the capacitive element driver may be started at any stage from Stage 801(1) to Stage 801(4n+2). The capacitive element driver may then be switched by following a switching sequence methodology such as the methodologies disclosed herein, and may be stopped at any stage followed by inactivity.

It may be understood that while the capacitive drivers and the switching sequence methodology described herein may be used in applications in which periodic switching is used to maintain the voltage of storage capacitors in the driver, the capacitive drivers and the switching sequence methodology may also be used to reduce energy loss in an application involving a one-time driving of a capacitive element. While periodic switching may be employed to maintain voltage of storage capacitors in the driver, it can be seen that, once the voltage of storage capacitors in the drivers is maintained, then a one-time driving of capacitive element may be performed with reduced energy loss.

### 6. High-Frequency Switching Capacitive Element Driving Circuit

The devices, methods, and systems for driving the voltage of a capacitive element between two voltage levels such as ground and supply voltage may be used to provide efficient high-frequency switching.

The capacitive element disclosed herein may be combined with a power switch to create a high efficiency switch. FIG. 19A is a circuit diagram showing a high-efficiency switch system 1900a in which a capacitive element driver 1910a may be electrically connected to the gate of a power switch 1930a, which may be a circuit but in this illustrative but not necessarily preferred embodiment is a transistor, and which may be switched at very high frequency. The drain and the source of the power switch 1930a may be accessed by the user through the terminals 1915a, 1914a, respectively, and may be connected according to the needs of the application. To control the gate of the power switch 1930a, the high-efficiency switch system 1900a may have a switching controller 1960a electrically connected to the capacitive element driver 1910a to provide control signals to signal the capacitive element driver 1910a to start or stop a switching sequence methodology such as one of them disclosed herein (e.g. FIG. 8A). Similarly, FIG. 19B is a circuit diagram showing a high-efficiency switch system 1900b in which a capacitive element driver 1910b may be electrically connected to the gate of a power switch 1930b; and the drain and the source of the power switch 1930b may be accessed through the terminals 1915b, 1914b. The high-efficiency switch system 1900b may have a switching controller 1960b electrically connected to the capacitive element driver 1910b through terminal 1912b.

The high-efficiency switch system 1900a may have dual voltage sources V_{DD19a} and V_{SS19a}. As shown in FIG. 19A, the positive terminal of the voltage source V_{DD19a} may be connected to the system 1900a through the terminal 1911a; the negative terminal of the voltage source V_{SS19a} may be connected to the system 1900a through the terminal 1913a; the negative terminal of voltage source V_{DD19a}, and the positive terminal of voltage source V_{SS19a} may both be connected to the system 1900a through the terminal 1916a. Similarly, as shown in FIG. 19B, the positive terminal of the voltage source V_{DD19b} may be connected to the system 1900b through the terminal 1911b; the negative terminal of the voltage source V_{SS19b} may be connected to the system 1900b through the terminal 1913b; the negative terminal of voltage source V_{DD19b}, and the positive terminal of voltage source V_{SS19b} may both be connected to the system 1900b through the terminal 1916b.

Although not shown in FIG. 19A, it can be seen with reference to the capacitive element driver 700A of FIG. 7A or the capacitive driving circuit 1610 shown in FIG. 16 that:
The positive terminal of voltage source V_{DD19a} may be electrically connected through the terminal 1911a to the last switch SW_{19[n+2]} (not shown) of the capacitive element driver 1910a (analogously to the manner in which the positive terminal of voltage source V_{DD7A} may be electrically connected to the last switch SW_{7[n+2]} of the capacitive element driver 700A and the positive terminal of voltage source V_{DD16} may be electrically connected to the last switch SW_{16[n+2]} of the capacitive driving circuit 1610), and
the negative terminal of voltage source V_{SS19a} electrically connected through the terminal 1913a to the first switch SW_{19[0]} (not shown) of the capacitive element driver 1910a (analogously to the manner in which the negative terminal of voltage source V_{DD7A} may be electrically connected to the first switch SW_{7[0]} of the capacitive element driver 700A and the negative terminal of voltage source V_{DD16} may be electrically connected to the first switch SW_{16[0]} of the capacitive driving circuit 1610).

A terminal V_{GREF} may electrically connect two terminals, specifically, the terminal 1916a and the source terminal 1914a of power switch 1930a. It can be seen that, were voltage source V_{SS19a} to be removed from the capacitive element driver 1910a and the terminal 1913a electrically connected to the terminal 1916a, the circuit design of the capacitive element driver 1910a would be almost identical to the circuit design of the capacitive driving circuit 1610 shown in FIG. 16, except for the order in which the sources and drains of the power switch 1930a and the power switch 1630 are connected to the drivers 1910a, 1610, respectively. FIG. 13 may also be referred to for the comparison because FIG. 19A illustrates a circuit that, after the voltage source V_{SS19a} of FIG. 19A is removed therefrom, is identical to the circuit shown in FIG. 13.

Under a switching sequence methodology 2200, which is a modification of the methodology 80 shown in FIG. 8A, 8B-1, with methodology 2200 reflecting the number of non-dissipative elements and switches in the system 1900a, the gate of power switch 1930a may be driven from V_{GREF}−V_{SS19a} to V_{GREF}+V_{DD19a} and then from V_{GREF}+V_{DD19a} to V_{GREF}−V_{SS19a} to respectively turn the switch on or off according to the signals from the controller 1960a, which may be electrically connected through the terminal 1917a to the switches SW_{19[0]}-SW_{19[n+2]} of the capacitive element driver 1910a. In an embodiment in which the capacitive element driver 1910a has more than one driver cell, as is disclosed below, such as the two-cell capacitive element driving circuit 2100, a switching sequence methodology such as those shown in FIG. 22K through FIG. 22M-5B or FIG. 24A-24B-3 may be implemented.

It may be noted that, in previously described embodiments, such as those shown in FIG. 4, the voltage source is part of the disclosed systems, and in the embodiment shown in FIGS. 19A, 19B, the voltage sources V_{DD19a}, V_{SS19a}, V_{DD19b}, V_{SS19b}, are positioned outside of the systems 1900a, 1900b. Either positioning is acceptable and the selection of position of the voltage source is at the option of the designer, regardless of whether one or multiple voltage sources are employed in or for the system.

Similarly, in certain embodiments, such as is shown in FIG. 19A, the switching controller 1960a is positioned outside of the system 1900a, electrically connected to the system 1900a through terminal 1917a, but in other embodiments, such as shown in FIG. 19B, the switching controller 1960b is a part of the system 1900b, and is connected to a control path system (not shown) through a terminal 1917b to receive instructions such as ENABLE to trigger the switching controller 1960b to signal the circuitry and components of system 1900b.

Additionally, in certain embodiments, the capacitive element, for example, an electrical device/network 1030 such as is shown in FIG. 10, is positioned outside of the system 1000, and has no direct connection with a switching controller. In other embodiments, a capacitive element, for example, a capacitive element 1930a and 1930b such as are shown in FIGS. 19A, 19B, respectively, is part of the system 1900a, 1900b, and may have a direct connection with a switching controller 1960a, 1960b.

Thus, it can be seen that the capacitive element drivers 1910a, 1910b and the capacitive elements 1930a, 1930b, one or both of which may be a transistor, may be packaged together to form a high efficiency switch system 1900a, 1900b.

### 7. Multi-Driver Cell Capacitive Element Driving Circuit

### Capacitive Element Driver Cell

FIG. 20 shows a capacitive element driver cell (also known as a “driver cell” or simply “cell”) 2000 that may be combined with other driver cells to construct a capacitive element driving circuit that may be used to further reduce the total energy dissipation of a capacitive element driver per one output voltage driving cycle. The driver cell 2000 may be constructed similarly to the capacitive element driver 700A in FIG. 7A, with n non-dissipative elements, which may be storage capacitors (C_{S20[1]}, C_{S20[2]}, C_{S20[3]}, . . . , C_{S20[n-1]}, C_{S20[n]}) that can store and release a voltage V_{CS20[1]}, V_{CS20[2]}, V_{CS20[3]}, . . . , V_{CS20[n-1]}, V_{CS20[n]}, respectively. The driver cell 2000 may also have n+3 switches (SW_{20[0]}, SW_{20[1]}, SW_{20[2]}, . . . , SW_{20[n+2]}) connected as the n storage capacitors and n+3 switches of driver 700A, with a common node 2005[1] between the switches SW_{20[0]}, SW_{20[1]} and a common node 2005(n+1) between the switches SW_{20[n+1]}, SW_{20[n+2]}, but with the following exceptions:
One terminal of switch SW_{20[0]} (analogous to the terminal of switch SW_{7A[0]} that is connected to the negative terminal 728A of the voltage source V_{DD7A}) operates as a terminal V_{DOWN20} for the driver cell 2000;
One terminal of switch SW_{20[n+2]} (analogous to the terminal of switch SW_{20[n+2]} that is connected to the positive terminal 726A of the voltage source V_{DD7A}) operates as a terminal V_{UP20} for the driver cell 2000; and
for each switch SW_{20[y]}, where y is from 1 to n+1, one terminal of the switch SW_{20[y]} (analogous to the terminal of switch SW_{7A[y]} that is connected to the terminal 732A of the capacitive element 730A (e.g. C_{O7A})) operates as a terminal V_{X20} 2004 of the driver cell 2000 that is electrically connected to a common node 2014 of the switches inclusively between switches SW_{20[1]} and SW_{20[n+1]}.

In an illustrative but not necessarily preferred embodiment, the non-dissipative elements may be storage capacitors. In other embodiments, the non-dissipative elements may all be another type of non-dissipative element, such as a rechargeable battery, a reverse-biased semiconductor PN-junction, or a capacitor with its capacitance modified by a transformer. Further in some embodiments, the non-dissipative elements may be all of the same type, and in other embodiments, the non-dissipative elements may all be a combination of types of non-dissipative elements.

### FIG. 21: A Basic Multi-Cell Driving Circuit

The driver cell 2000 may be connected in series with one or more driver cells 2000 to form a capacitive element multi-cell driving circuit 2100 that can further reduce the energy dissipation of capacitive element drivers with fewer numbers of non-dissipative elements.

FIG. 21 shows the basic embodiment in which a capacitive element driving circuit 2100 (also known as a “driving system” or “circuit”). In the K-cell driving circuit shown in FIG. 21, K equals 2, with the circuit 2100 having two driver cells 2101-1, 2101-2, each with a single non-dissipative element to further reduce the energy dissipation of capacitive element drivers. In an illustrative but not necessarily preferred embodiment, the non-dissipative elements both may be storage capacitors. In other embodiments, the non-dissipative elements may all be of a different type, or at least one of the non-dissipative elements may be of a different type.

Further, while the K-cell driving circuit 2100 illustrated in FIG. 21 is shown as formed from two driver cells 2000 (which, as noted above, may be constructed similarly to the capacitive element driver 700A), it is to be understood that any of the capacitive element drivers disclosed herein (including without limitations 780, 700C-1, 700C-2, 700D, 700E, 700G, 700H) disclosed above may be used as the first driver cell 2101-1 in the multi-driver circuit 2100 and in any other embodiment of the multi-driver circuit disclosed below.

FIGS. 22A-22J illustrate the circuit 2100 in operation.

Referring to FIGS. 21 and 22A-22J, driver cells 2101-1, 2101-2 are connected in series, with cell 2101-1 having:
a positive input terminal 2111 electrically connected to its switch SW[3],
a negative input terminal 2113 electrically connected to its switch SW[0], and
an output terminal 2104 electrically connected to the common node 2114 of its switches SW[1] and SW[2].

The voltage source V_{DD21} is connected to the cell 2101-1, with the positive terminal 2126 of voltage source V_{DD21} electrically connected to the positive input terminal 2111, and the negative terminal 2128 of the voltage source V_{DD21} electrically connected to the negative input terminal 2113. The output terminal 2104 is electrically connected to a common node 2115 between the positive input terminal 2121, negative input terminal 2123 of the driver cell 2101-2, in which:
a positive input terminal 2121 is electrically connected to the switch SW[3] of the cell 2101-2;
a negative input terminal 2123 is electrically connected to the switch SW[0] of the cell 2101-2;
an output terminal 2124 is electrically connected to a common node 2134 of the switches SW[1] and SW[2] of the cell 2101-2, and with the output terminal 2124 electrically connected to the input terminal 2132 of the capacitive element 2130 (e.g. C_{O21}).

In a K-cell driving circuit, with the terminal 2104 of one driver cell being electrically connected to the common node between the input terminals of another driver cell, hereinafter the one and other cell may be referred to as “adjacent” to each other. Further, when the one cell is electrically connected between the other cell and the circuit's voltage source, hereinafter the one cell may be referred to as “upstream” of the other cell; and with the other cell electrically connected between the one cell and the output terminal of the circuit, hereinafter the other cell may be referred to as “downstream” of the one cell in the circuit. Accordingly, the cell 2101-1 may be said to be upstream to its adjacent cell 2101-2, and the cell 2101-2 may be said to be downstream to its adjacent cell 2101-1. In addition, driver cells so connected may be referred to as “chained” or as “cascaded” driver cells, and the combination of the common node 2115, the positive input terminal 2121, and the negative input terminal 2123 of the downstream driver cell 2101-2 may be referred to as a single input terminal for the downstream driver cell 2101-2.

It was shown before in the discussion of circuit 400, which had a single storage capacitor and switched in accordance with switching sequence of Stages 501(1)-501(6), the average current, hence net charge, of a storage capacitor C_{S} is held at zero and the average value of V_{CS4}=V_{DD4}/3. Using the same reasoning, V_{CS21[1]}=V_{DD21}/3.

During the operation of cell 2101-1 and 2101-2, VCS21[1], the output of the cell 2101-1, operates as the input of the cell 2101-2. Therefore, using the same reasoning as above, the average value of V_{CS21[2]} is equal to V_{CS21[1]}/3=(V_{DD21}/3)/3=V_{DD21}/9. Therefore, V_{DD21}=3V_{CS21[1]}=9V_{CS21[2]}.

In the operation of the circuit 2100, 18 stages are associated with one complete V_{O21} driving cycle, and a change of V_{DD21}/9 per stage occurs over the 18 stages of one complete V_{O21} driving cycle.

As with the capacitive element driver 700A, the driving circuit 2100 has or is electrically connected via a path system to a controller 2160, which is arranged to provide control signals to signal the capacitive element driving circuit 2100 to start or stop a switching sequence methodology. The switching controller 2160 controls the activation and deactivation of the switches in driver cells 2101-1, 2101-2 to drive the circuit 2100 through the complete V_{O21} driving cycle, in which V_{O21} is driven from ground to V_{DD21}, and then back to ground, and using a set of stages as shown in FIGS. 22A-22J:
In FIG. 22A, at Stage 2201(1), switch sets (SW[0], SW[1]) of cell 2101-1 and (SW[0], SW[1]) of cell 2101-2 are closed, and V_{O21} is driven to the ground level (e.g. 0V);
In FIG. 22B, at Stage 2201(2), switch sets (SW[0], SW[1]) of cell 2101-1 and (SW[0], SW[2]) of cell 2101-2 are closed, and V_{O21} is driven to V_{CS21[2]}.
In FIG. 22C, at Stage 2201(3), switch sets (SW[0], SW[2]) of cell 2101-1 and (SW[1], SW[3]) of cell 2101-2 are closed, and V_{O21} is driven to (V_{CS21[1]}−V_{CS21[2]}=2V_{CS21[2]})
In FIG. 22D, at Stage 2201(4), switch sets (SW[0], SW[2]) of cell 2101-1 and (SW[2], SW[3]) of cell 2101-2 are closed, and V_{O21} is driven to (V_{CS21[1]}=3V_{CS21[2]}).
In FIG. 22E, at Stage 2201(5), switch sets (SW[0], SW[2]) of cell 2101-1 and (SW[0], SW[2]) of cell 2101-2 are closed, and V_{O21} is driven to (V_{CS21[1]}+V_{CS21[2]}=4V_{CS21[2]}).
In FIG. 22F, at Stage 2201(6), switch sets (SW[1], SW[3]) of cell 2101-1 and (SW[1], SW[3]) of cell 2101-2 are closed, and V_{O21} is driven to (V_{DD21}−V_{CS21[1]}−V_{CS21[2]}=5V_{CS21[2]}).
In FIG. 22G, at Stage 2201(7), switch sets (SW[1], SW[3]) of cell 2101-1 and (SW[2], SW[3]) of cell 2101-2 are closed, and V_{O21} is driven to (V_{DD21}−V_{CS21[1]}=6V_{CS21[2]})
In FIG. 22H, at Stage 2201(8), switch sets (SW[1], SW[3]) of cell 2101-1 and (SW[0], SW[2]) of cell 2101-2 are closed, and V_{O21} is driven to (V_{DD21}−V_{CS21[1]}+V_{CS21[2]}=7V_{CS21[2]}).
In FIG. 22I, at Stage 2201(9), switch sets (SW[2], SW[3]) of cell 2101-1 and (SW[1], SW[3]) of cell 2101-2 are closed, and V_{O21} is driven to (V_{DD21}−V_{CS21[2]}=8V_{CS21[2]})
In FIG. 22J, at Stage 2201(10), switch sets (SW[2], SW[3]) of cell 2101-1 and (SW[2], SW[3]) of cell 2101-2 are closed, and V_{O21} is driven to (9V_{CS21[2]}=V_{DD21}).
In FIG. 22I, at Stage 2201(11), the switches operate as in Stage 2201(9), and V_{O21} is driven to 8V_{CS21[2]}.
In FIG. 22H, at Stage 2201(12), the switches operate as in Stage 2201(8), and V_{O21} is driven to 7V_{CS21[2]}.
In FIG. 22G, at Stage 2201(13), the switches operate as in Stage 2201(7), and V_{O21} is driven to 6V_{CS21[2]}.
In FIG. 22F, at Stage 2201(14), the switches operate as in Stage 2201(6), and V_{O21} is driven to 5V_{CS21[2]}.
In FIG. 22E, at Stage 2201(15), the switches operate as in Stage 2201(5), and V_{O21} is driven to 4V_{CS21[2]}.
In FIG. 22D, at Stage 2201(16), the switches operate as in Stage 2201(4), and V_{O21} is driven to 3V_{CS21[2]}.
In FIG. 22C, at Stage 2201(17), the switches operate as in Stage 2201(3), and V_{O21} is driven to 2V_{CS21[2]}.
In FIG. 22B, at Stage 2201(18), the switches operate as in Stage 2201(2), and V_{O21} is driven to V_{CS21[2]}.

The controller 2160 may then return to Stage 2201(1) (In FIG. 22A) to drive the output voltage of the circuit 2100 to ground. Thus it can be seen that the incremental and selective closing and opening of switches in the cells of a multi-cell driving circuit may provide step-wise increases from ground to a peak voltage for the selected cell, with each switch set providing either a decrease in or increase to the output voltage of a selected amount of voltage, or no change to the output voltage. FIG. 22K is a chart showing the switching sequence and the resultant value of V_{O21} to which the voltage across the capacitive element 2130 is driven during one complete V_{O21} driving cycle. It can be seen that the stages and phases through which the driving circuit operates to drive voltage from ground to the supply voltage are mirrored in the stages and phases through which the driving circuit operates to drive the voltage from the supply voltage to ground. Therefore, the stages after Stage 2201(10), in which V_{O21} is driven to ground may be known by reference to the Stage 2201(1) to Stage 2201(10).

It can also be seen in FIG. 22K that the Stage 2201(18) constitutes the last stage of the output voltage driving cycle for circuit 2100. In the Stage 2201(18), the cell 2101-1 is bypassed to provide ground to the input of the cell 2101-2 and the cell 2101-2 is driven to provide V_{CS21[2]}. In order to bring the output voltage of the cell 2100 to ground after completion of the Stage 2201(18), the switching sequence methodology 2200 may apply the switching operations of the Stage 2201(1) (shown in FIG. 22A) to the circuit 2100 in order to bypass the cell 2101-1 in such a manner that the negative terminal 2128 of the voltage source for the circuit 2100, which provides ground, is electrically connected to the output of the cell 2101-1 so that the input of the cell 2101-2 is grounded, and to bypass the cell 2101-2 so that the output of the cell 2101-2, and hence the output of the circuit 2100, is grounded.

When the driving circuit 2100 is arranged to cease operation after one application of the output voltage driving cycle, the last stage of the switching sequence methodology 2200 may constitute repeating the Stage 2201(1) operation to bring the output of the circuit 2100 to ground. When the driving circuit is arranged to continue operation, the last stage of the switching sequence methodology 2200 may constitute the first stage of the next iteration of the output voltage driving cycle for the circuit 2100.

Going forward, it is to be understood that future references to completing an output voltage driving cycle for a capacitive element driving circuit includes bringing the output of the capacitive element driving circuit to ground by applying the first stage of a switching sequence methodology after the last stage of a switching sequence methodology; and future references to applying the first stage of a switching sequence methodology contemplates applying either of the above-described methods for bringing the output of a capacitive element driving circuit to ground.

### Voltage Assignment Functionalities

FIGS. 22L-1-22L-3 are charts specifying the voltage assignment functionality of sets of closed switches in embodiments of switching sequences of driver cells in selected driving circuits. In this embodiment, for convenience of calculation, the non-dissipative elements are assumed to have identical voltage storage capacities but it is to be understood that it will be the choice of designer to select the voltage storage capacities of any of the non-dissipative elements in any driver cell of driving circuit.

In certain embodiments in which a cell has more than one non-dissipative element and the voltage of any two such elements are not equal to each other, the switching may occur as is disclosed for FIGS. 22A-22J to produce a step-wise increase in voltage from ground to the supply voltage and then to ground, but the steps (change in voltage) may not be uniform.

### FIG. 22L-1: 1-Non-Dissipative Element Driver Cell

Specifically, FIG. 22L-1 shows the voltage assignment functionality 2001-1 of a driver cell x with one non-dissipative element and four switches. The driver cell x is operable as the cell 2101-2 in FIGS. 22A-J, which has a voltage output and a voltage input that is electrically connectable to the output of 2101-1 and to the voltage input for both switches SW[0] and SW[3] of cell 2101-2.

In FIGS. 22A-22J, it can be seen that, in cell 2101-1, when the switch sets (SW[0], SW[1]) or (SW[2], SW[3]) are closed, the non-dissipative element of cell 2101-1 is bypassed, with the switch set (SW[0], SW[1]) electrically connecting the negative terminal of the voltage source to the output of the cell 2101-1 and supplying a ground as an output for the cell 2101-1. The switch set (SW[2], SW[3]) of cell 2101-1 also operates to bypass the non-dissipative element, electrically connecting the positive terminal of the voltage source to the output of the cell 2101-1 and supplying the voltage output V_{DD} of the voltage source as the output of the cell 2101-1. In the cell 2101-2, because the cell's voltage input operates as the voltage input for both switches SW[0] and SW[3] of cell 2101-2, both of the switch sets (SW[0], SW[1]) and (SW[2], SW[3]) function to bypass the non-dissipative element of the cell 2101-2, electrically connecting the input of cell 2101-2 to the output of cell 2101-2.

Therefore, in cell x, which is operable as the cell 2101-2 and which has a voltage output V_{Out[x]} and a voltage input V_{In[x]} that is electrically connectable to the output of its upstream adjacent cell and to both switches SW[0] and SW[3] of cell x, both of the switch sets (SW[0], SW[1]) and (SW[2], SW[3]) function to bypass the non-dissipative element of the cell x. FIG. 22L-1 shows the functionality of the switch sets (SW[0], SW[1]), (SW[2], SW[3]) of the driver cell x to both electrically connect the input of the driver cell x to its output. FIG. 22L-1 also shows the functionality of the switch set (SW[0], SW[2]), releasing V[x] (the non-dissipative element's voltage storage capacity) to add to V_{In[x]}; and the functionality of the switch set (SW[1], SW[3]), subtracting V[x] from V_{In[x]}.

### FIG. 22L-2: 2-Non-Dissipative Element Driver Cell

FIG. 22L-2 shows the voltage assignment functionality 2001-2 for a driver cell y, which may also be operable as the cell 2101-2. The driver cell y has two non-dissipative elements and five switches, with the switch sets (SW[0], SW[1]) and (SW[3], SW[4]) operating to bypass the non-dissipative elements. The switch sets (SW[0], SW[2]), (SW[0], SW[3]) add a selected amount of voltage to the input voltage V_{In[y]}; and the switch sets (SW[1], SW[4]), (SW[2], SW[4]) subtract a selected amount of voltage from V_{In[y]}. When the non-dissipative elements have identical voltage storage capacities, for example the voltage V[y]:
the switch set (SW[0], SW[2]) adds V[y] to the input voltage V_{In[y]},
the switch set (SW[0], SW[3]) adds twice V[y] to V_{In[y]},
the switch set (SW[1], SW[4]) subtracts twice V[y] from V_{In[y]}, and
the switch set (SW[2], SW[4]) subtracts V[y] from V_{In[y]}.

### FIG. 22L-3: Generalized Driver Cell

FIG. 22L-3 shows the voltage assignment functionality 2001-q of sets of closed switches in a generalized driver cell k which may also be operable as the cell 2101-2. The driver cell k has q non-dissipative elements and q+3 switches. As with the embodiments of FIG. 22L-1 and FIG. 22L-2, the switch sets (SW[0], SW[1]) and (SW[q+1], SW[q+2]) operate to bypass the non-dissipative elements passing the input voltage V_{In[k]} to the output of cell k; the switch sets (SW[0], SW[2]) through (SW[0], SW[q+1]) add a selected amount of voltage to the input voltage V_{In[k]}; and the switch sets (SW[1], SW[q+2]) through (SW[q], SW[q+2]) subtract a selected amount of voltage from V_{In[k]}. When the non-dissipative elements have identical voltage storage capacities, for example the voltage V[k]:
the switch set (SW[0], SW[2]) adds V[k] to V_{In[k]};
the switch sets (SW[0], SW[3]) through (SW[0], SW[q+1]) add 2V[k] through qV[k], respectively, to V_{In[k]}; and
the switch sets (SW[1], SW[q+2]) through (SW[q−1], SW[q+2]) subtract qV[k] through 2V[k], respectively, from V_{In[k]}.

The switch set (SW[q], SW[q+2]) subtracts V[k] from V_{In[k]}. A comparison of the switch activation in the voltage assignment functionality 2001-q of FIG. 22L-3 and the voltage assignment functionalities 2001-1, 2001-2 in FIGS. 22L-1 and 22L-2 shows that increasing the number of non-dissipative elements in a driver cell allows for the number of steps in the step-wise process to increase and the difference between the amount of voltage delivered per step to reduce. Thus, the delivery of voltage to a driving circuit's output may be made smoother.

### 8. Switching Sequence Methodologies

FIGS. 22M-1A-22M-5B are charts illustrating switching sequence methodologies for selected driving circuits when the non-dissipative elements of the cells in the driving circuits have identical voltage storage capacities, adopting the notation for operation of sets of closed switches shown in the voltage assignment functionalities of FIGS. 22L-1-22L-3.
FIG. 22M-1A, 22M-1B show a more detailed specification of the voltage supplied at each stage of the switching sequence methodology 2200 of FIG. 22K, as described above, in which the switches in the first and second cells 2101-1, 2101-2 are opened and closed in a sequence to increase the supplied voltage in a step-wise manner to V_{DD21} and then are opened and closed in a sequence to decrease the supplied voltage in a step-wise manner to ground, the entire switching sequence defining one V_{O21} driving cycle.
FIG. 22M-2A 1(A1)-22M-2A2 show a methodology 2220 for switching a driving circuit [wxy], also herein known as driver or circuit 4000, with three driver cells [w], [x], [y], each with one non-dissipative element, in which:
   FIGS. 22M-2A 1(A1), 22M-2A1(A2) are switching charts 2222(a), 2222(b), respectively, and
   FIG. 22M-2A1(B) is a sequence pattern chart 2222c detailing the switch sets that are closed on the circuit [xyz] and the circuit's output voltages during application of the stages 2221(1)-2221(54); and

FIG. 22M-2B 1, 22M-2B2 show a switching sequence methodology 2240 for a driving circuit [vwxy] with four driver cells [v], [w], [x], [y], each with one non-dissipative element.

FIG. 22M-3A, 22M-3B show a switching sequence methodology 2260 for a driving circuit [ab] with two driver cells, with a first cell [2] with one non-dissipative element and four switches and a second cell [b] with two non-dissipative elements and five switches.

FIG. 22M-4A, 22M-4B show a switching methodology 2270 for a driving circuit [mn] with two driver cells, with a first cell [m] with two non-dissipative elements and five switches and a second cell [n] with one non-dissipative element and four switches.

FIG. 22M-5A1, 22M-5A2, 22M-5B show a switching sequence methodology 2280 for a driving circuit [mnp] with a first cell [m] and second cell [n] with two non-dissipative elements each and a third cell [p] with three non-dissipative elements.

As noted above, in the illustrative but not necessarily preferred embodiment described herein, a switch sequencing methodology may be defined to operate a multi-cell circuit to produce step-wise changes in the output voltage of the circuit. The circuit's switch sequencing methodology may be formed of a set of cell-switching methodologies, with a cell-switching methodology defining a sequence for activating switch sets in one of the cells in the circuit. The circuit may be operated according to the circuit's switch sequencing methodology by applying the cell switching methodologies on their associated cells concurrently and synchronously across the circuit. The cells in the multi-cell circuit are arranged in series, with the output voltage of one cell providing the input voltage of its downstream adjacent cell, so that an incremental change in an upstream cell impacts the voltage production of other cells downstream in the circuit.

The incremental changes in upstream and downstream cells may be seen in the selective closing and opening of switches in the cells of a multi-cell driving circuit. The switching may provide step-wise increases from ground to a peak voltage for a selected cell, with each switch set providing either a decrease in or increase to the output voltage of a selected amount of voltage, or no change to the output voltage. The increases may be seen in FIGS. 22M-1A and 22M-1B from Stages 2201(1) to 2201(10), and the decreases may be seen in FIGS. 22M-1A and 22M-1B from Stages 2201(10) to 2201(1), the first stage of applying the switching sequence methodology 2200 on the circuit 2100.

FIGS. 22M-1A to 22M-5B illustrates several examples of switch sequencing methodologies for operating a multi-cell circuit. The methodologies described below may be seen to be defined by an ordered set of phases, with phase defined by an ordered set of patterns of cell activation, and with a pattern of cell activation defined by an ordered set of stages which are applied in chronological order to activate a switch set in the cell to produce a series of desired output voltage results. When the methodologies are operated concurrently and synchronously, the desired result of incremental change in the cell's output voltage may be achieved.

The illustrated methodologies may be seen to have common phases of operation, with the phases activating switch sets according to common switching patterns, to produce the step-wise increases in the output voltage of the multi-cell circuit 2100 up to its peak voltage and, if desired, to provide for operation of the phases and switching patterns in reverse order to produce step-wise decreases in the output voltage of the multi-cell circuit 2100 from its peak voltage to approaching ground.

Going forward, operation of a methodology in reverse order shall mean operation of its constituent phases in reverse order, with a phase operated in reverse order meaning operation of its constituent switching patterns in reverse order, and with operation of a switching pattern in reverse order meaning operation of its defined constituent stages in reverse chronological order as well. Further, going forward, a phase operated in reverse order shall be known as a “reverse phase,” and a switching pattern operated in reverse order shall be known as a “reverse switching pattern.”

Except for the cell electrically connected to the voltage source (here called the “first cell”), the methodologies for step-wise driving of the cells in the multi-cell driving circuit have the following phases which apply the following step-wise cell-switching patterns to a cell [i], where 2≤i≤K:
The initiating cell [i] phase applies an initiating cell [i] switching pattern on a selected cell [i] that is arranged:
   to provide the input voltage of the cell [i] as its output voltage (effecting a “bypass” of the cell [i]) by closing one of the sets of switches, either the switch set (SW[0], SW[1]) or the switch set (SW[n[i]+2], SW[n[i]+1]), that effects bypass, and
   then to increase incrementally the cell [i]'s output voltage by the voltage V_{CS[i]} provided by a non-dissipative element of the cell [i], by selectively activating the set(s) of switches of the cell [i] that increase the output voltage V_{O[i]}, with the switch activations, where there is more than one such set, performed in an order to produce increasing amounts of output voltage increases.
The executing cell [i] phase may proceed after the completion of the initiating cell [i] phase. The executing cell [i] phase may implement a series of executing cell [i] switching patterns on the cell [i], with an application of the executing cell-switching pattern arranged:
   first to reduce incrementally the cell [i]'s output voltage by selectively activating the set(s) of switches in the cell [i] that subtract a voltage storage capacity of non-dissipative element(s) from the input voltage of the cell [i], with the switch activations, where there is more than one such set, performed in an order to produce decreasing amounts of output voltage reduction(s), and with the reduction in the input voltage being VCS[i] when cell [i] contains a single non-dissipative element, or V_{[i]} or a multiple thereof when cell [i] contains more than one non-dissipative element.
      It should be noted here that the subtraction of V_{[i]} or multiples thereof from the input voltage of the cell [i] during the first stage of an executing cell [i] switching pattern does not result in a reduction of the output voltage of the cell [i]. At the same time that voltage is being subtracted from the cell [i] input voltage during a cell [i] switching pattern, a switching pattern operating on one or more cells upstream to the cell [i] increases the input voltage of the cell [i] by a selected amount of voltage for at least the duration of the cell [i] switching pattern on the cell [i]. Therefore, while the subtraction operation reduces the amount of input voltage for the cell [i], the increase in cell [i]'s input voltage is greater than the amount of voltage subtracted from the input voltage, resulting in a net increase in the amount of voltage available at the cell [i] output.
   then to bypass the cell [i] by selectively activating a set of switches of the cell [i] that provides the input voltage of cell [i] as its output voltage; and
   then to increase incrementally the cell [i]'s output voltage by selectively activating the sets of switches in the cell [i] that increase the output voltage, with the switch activations ordered to produce increasing amounts of output voltage.
The peaking cell [i] phase applies a peaking cell [i] switching pattern on the cell [i] that is arranged:
   first to reduce incrementally the cell [i]'s output voltage by selectively activating the set(s) of switches in the cell [i] that reduce the output voltage, with the switch activations, where there is more than one such set, ordered to produce decreasing amounts of output voltage reductions; and
   then to bypass the cell [i] by selectively activating a set of switches of the cell [i] that provides the input voltage of cell [i] as its output voltage.
      When the driving circuit is arranged to cease operation when its output voltage reaches its peak voltage, the peaking cell [i] phase may end, and, with it, the methodologies end.

Should the driving circuit be arranged to operate through a complete output voltage driving cycle from ground to peak to approaching ground again, the methodologies may continue on a cell [i] to reduce the cell's output voltage from the peak voltage in step-wise decreases back to ground using the following phases which apply the following step-wise switching patterns to the cell [i].
After the cell [i+1] reaches its peak output voltage, the peaking cell [i] phase applies the remainder of the peaking cell [i] switching pattern on the cell [i] that is arranged:
   to maintain the bypass of the cell [i] for the duration of one stage of the cell [i] methodology switching pattern when the cell [i] is the cell that has an output terminal that is or is electrically connected to the output terminal of the driving circuit (hereinafter known as the “last cell”), or otherwise until the completion of the remainder of the peaking cell [i+1] switching pattern on the cell [i+1], and
   to reduce incrementally the cell [i]'s output voltage by selectively activating the set(s) of switches in the cell [i] that reduce the output voltage, with the switch activations, where there is more than one such set, ordered to produce increasing amounts of output voltage reductions.
The reverse executing cell [i] phase, in which a series of reverse executing cell switching patterns may be implemented in reverse order, may begin at the completion of the peaking cell [i] phase. The reverse executing cell [i] phase may implement a series of reverse executing cell [i] switching patterns in which the stages of the executing cell [i] switching pattern are implemented in reverse order. An application of the reverse executing cell [i] switching pattern may be arranged:
   first to increase incrementally the cell [i]'s output voltage by selectively activating the set(s) of switches in the cell [i] that increase the output voltage, with the switch activations, where there is more than one such set, ordered to produce decreasing amounts of output voltage increases;
   then to bypass the cell [i] by selectively activating a set of switches of the cell [i] that provides the input voltage of cell [i] as its output voltage; and
   then to reduce incrementally the cell [i]'s output voltage by selectively activating set(s) of switches in the cell [i] that reduce the output voltage, with the switch activations, where there is more than one such set, ordered to produce increasing amounts of output voltage reductions. Similar to the voltage subtraction operation in the executing cell [i] switching pattern, the addition of V_{[i]} or multiples thereof to the input voltage of the cell [i] during the first stage of a reverse executing cell [i] switching pattern does not result in an increase in the output voltage of the cell [i]. At the same time that voltage is being added to the cell [i] input voltage during a reverse cell [i] switching pattern, a switching pattern operating on one or more cells upstream to the cell [i] decreases the input voltage of the cell [i] by a selected amount of voltage for at least the duration of the reverse cell [i] switching pattern on the cell [i]. Therefore, while the addition operation increases the amount of input voltage for the cell [i], the decrease in cell [i]'s input voltage is greater than the amount of voltage added to the input voltage, resulting in a net decrease in the amount of voltage available at the cell [i] output.
The reverse initiating cell [i] phase may be implemented at the completion of the reverse executing cell [i] phase. In the reverse initiating cell [i] phase, a reverse initiating cell [i] switching pattern, in which the stages of an initiating cell [i] switching pattern is implemented in reverse order, is then applied on the cell [i], to:
   first increase incrementally the cell [i]'s output voltage by selectively activating the set(s) of switches of the cell [i] that increase the output voltage V_{O[i]}, with the switch activations, where there is more than one such set, ordered to produce decreasing amounts of output voltage increases; and
   then bypass the cell [i] by selectively activating a set of switches of the cell [i] that provides the input voltage of cell [i] as its output voltage, with the bypass of the cell [i] maintained until the output voltage of the last cell (cell [K]) in the K-cell circuit is at V_{CS[K]}, which is one step away from being driven to ground.

In the last stage of the output voltage driving cycle, the cells [i] for 2≤i≤(K−1) are bypassed to provide ground to the input of the cell [K] to allow the cell [K] to be driven to provide V_{CS[K]}. In order to bring the output voltage of the cell [K] to ground, the switching sequence methodology may apply its first stage. As noted above, when the output voltage of the driving circuit reaches V_{CS[K]}, and the driving circuit is arranged to cease operation after one application of the output voltage driving cycle, the last stage of the reverse initiating cell [i] phase may call for subjecting the cell [i] to a single application of the first stage of the output voltage driving cycle to bypass the cell [i]. When the driving circuit is arranged to continue operation, the last stage of the reverse initiating cell [i] phase may call for subjecting the cell [i] to the first stage of the output voltage driving cycle to bypass the cell [i].

The first cell in the multi-cell driving circuit (cell [1]) may be seen to operate with the above-described initiating cell [i] phase, followed by the above-described peaking cell [i] phase, both with i=1, and with the initiating cell [1] phase's bypass operations achieved by selectively activating a set of switches of the cell [1] that provides the voltage of the negative terminal of the voltage source for the circuit 2100 (shown to be ground in the voltage source in FIG. 21) to the input of the cell [2]. Similarly, the cell's bypass operations in the peaking phase may be achieved by selectively activating a set of switches of the cell [1] that provides the supply voltage of the circuit's voltage source to the input of the cell [2].

Upon completion of the output voltage driving circle, the output voltage of driving circuit is at V_{CS[K]}, which is one step away from ground. When the driving circuit is arranged to cease operation after one application of the output voltage driving cycle, the cell [1] may be subjected to an application of the first stage of the output voltage driving cycle to bypass the cell [1] in such a manner that the negative terminal of the voltage source for the circuit, which provides ground, is electrically connected to the output of the cell [1] so that the input of the cell [2] is also grounded. Should the driving circuit be arranged to continue operation to drive the circuit through repeated output voltage driving cycles, the methodology may proceed after applying the last stage of the driving cycle to apply the first stage of the next iteration of the driving cycle. The first stage also bypasses the cell [1], resulting in a grounding of the output voltage of the cell [1] and returning the methodology to its initiating cell [1] phase to begin the step wise drive of the circuit's output from ground to peak to ground again.

In the embodiments disclosed herein, the number of stages in which a switched set activation is maintained on a selected cell (cell [i]) that is not a last cell (“cell [K]”) may be based on the number of non-dissipative elements in its adjacent downstream cell (hereinafter “cell [i+1]”) in the K-cell circuit. As described in more detail in the illustrious but not necessarily preferred embodiments disclosed above and below, a switched set activation may be maintained in the selected cell [i] for the duration of the methodology switching pattern that is concurrently being performed on the cell [i+1]. When the selected cell (cell [i]) is the last cell (cell [K]) of the K-cell circuit, there is no cell [i+1] and a switched set activation may be maintained in the cell [i] for the duration of one stage of the methodology switching pattern.

Further, as described in more detail below, the number of stages in which a cell switching pattern operates on a selected cell is also based on the number of non-dissipative elements in the selected cell. For example, a cell with one non-dissipative element has only one switch set that may be closed to increase its output voltage, while a cell with three non-dissipative elements has three switch sets that may be closed to increase its output voltage. The same holds for the number of sets of switches in the cell [i] that may be closed to reduce its output voltage. Accordingly, the number of step wise voltage changes in a selected cell's cell switching patterns will be based on the number of non-dissipative elements in the cell.

In order to understand how the cells of the multi-cell driving circuit concurrently and synchronously operate to close and open the switches provide incremental increase and then decrease of output voltages of the cells, which in turn drives incremental increase and then decrease of the overall output voltage of the driving circuit, attention will be now turned to FIGS. 22M-1A to 22M-5B, to describe examples of cell-switching methodologies for circuits having varying numbers of cells and for cells having varying numbers of non-dissipative elements.

Initiating cell phases and switching patterns, executing cell phases and switching patterns, and peaking cell phases and switching patterns will also be in the figures as “INITIATING” or “I,” “EXECUTING” or “E,” and “PEAKING” or “P,” respectively.

### 8.1. K-Cell Driving Circuits, Each Cell With One Non-Dissipative Element

### FIG. 22M-IA: 2-Cell Driving Circuit

FIGS. 22K, 22M-1A, and 22M-1B show the illustrative but not necessarily preferred embodiment of the methodology 2200 for opening and closing the switches in the driver cells so as to increment the voltage output in a step-wise manner from a driving circuit having two cells, each with one non-dissipative element. The methodology 2200 starts with a Stage 2201(1), in which the switches (SW[0], SW[1]) of both driver cells are activated to drive the driving circuit's output to ground. In a Stage 2201(2), the switches (SW[0], SW[1]) of the driver cell 2101-1 stay activated to drive the cell's output to ground (thus preventing the driver cell 2101-1 from contributing voltage to the driving circuit's output), while the switches (SW[0], SW[2]) of the driver cell 2101-2 (which is closest in the circuit to the output terminal) are activated to release V_{CS21[2]}, the voltage storage capacity from its one non-dissipative element, so that V_{CS21[2]} becomes the output of the driving circuit 2100.

Once the V_{CS21[2]} has been reached, in Stages 2201(3) through 2201(5), the switches (SW[0], SW[2]) of the driver cell 2101-1 may be activated to release V_{CS21[1]}, its voltage storage capacity, from its non-dissipative element so that V_{CS21[1]} is provided as the voltage output of the cell 2101-1.
In the Stage 2201(3), the switches (SW[1], SW[3]) of the driver cell 2101-2 are operated to reduce V_{CS21[1]} by V_{CS21[2]}
In a Stage 2201(4), the switches (SW[2], SW[3]) of the driver cell 2101-2 are operated to bypass the non-dissipative element of the driver cell 2101-2, raising the output voltage to V_{CS21[1]′}, which equals three times the output voltage V_{CS21[2]}. In other equally illustrative but not necessarily preferred embodiments, the bypass in the cell 2101-2 may be accomplished by operating the switches (SW[0], SW[1]) of cell 2101-2 rather than the switches (SW[2], SW[3]).
In a Stage 2201(5), the switches (SW[0], SW[2]) of the driver cell 2101-2 are operated so that both driver cells provide their available voltage storage capacity to increase the output voltage from V_{CS21[1]}. To V_{CS21[1]}+V_{CS21[2]}=4V_{CS21[2]}.

In Stages 2201(6) through 2201(8), the switch set (SW[1], SW[3]) of the driver cell 2101-1 is activated to raise the input of the cell 2101-1 to the driving circuit's supply voltage V_{DD21}, and then to reduce V_{DD21} by the cell 2101-1 voltage storage capacity V_{CS21[1]} so as to provide V_{DD21}−V_{CS21[1]} as the voltage output of the cell 2101-1.
In the Stage 2201(6), the switch set (SW[1], SW[3]) of the driver cell 2101-2 is activated to subtract the cell 2101-2 voltage storage capacity V_{CS21[2]} from the voltage output of the cell 2101-1, resulting in a voltage output 5V_{CS21[2]} for the driving circuit.
In a Stage 2201(7), the cell 2101-2 is bypassed by activating switch set (SW [2], SW[3]) or, as noted earlier, switch set (SW[0], SW[1]), to provide the voltage output of the cell 2101-1, namely V_{DD21}−V_{CS21[1]} or 6V_{CS21[2]}
In a Stage 2201(8), the switch set (SW[0], SW[2]) of cell 2101-2 is activated to add V_{CS21[2]} to the voltage output of the cell 2101-1, thus providing 7V_{CS21[2]} as the voltage output of the driving circuit.

In Stages 2201(9) and 2201(10), the switch set (SW[2], SW[3]), or switch set (SW[0], SW[1]), of the driver cell 2101-1 are activated to bypass the non-dissipative element of the cell 2101-1, thus delivering the driving circuit's supply voltage V_{DD21} as the voltage output of the cell 2101-1.
In Stages 2201(9), the switch set (SW[1], SW[3]) of cell 2101-2 is activated to subtract V_{CS21[2]} from V_{DD21} to provide a voltage output 8V_{CS21[2]} for the driving circuit; and
In Stages 2201(10), the switch set (SW[2], SW[3]) or, as noted earlier, switch set (SW[0], SW[1]) of cell 2101-2 are activated to bypass the non-dissipative elements of the cell 2101-2 to provide a voltage output V_{DD21}=9V_{CS21[2]} for the driving circuit.

Switch activation according to the methodology 2200 continues to provide a step-wise increase of the voltage output for the driving circuit from ground to the maximum voltage releasable by circuit 2100, namely to V_{DD21}. In Stages 2201(11) to 2201(18), switch activation according to the methodology 2200 may continue in reverse to reduce the voltage output in a step-wise manner from V_{DD21} to V_{CS21[2]}. The circuit's output voltage may be driven from V_{CS21[2]} to ground by applying a Stage 2201(1) as a stand-alone or as the first stage of the next operation of the output voltage driving cycle to drive the output voltage of the circlit in a step-wise increase back to V_{DD21}, and then to drive the output voltage in a step-wise decrease back to V_{CS21[2]}.

As noted above, in certain embodiments, in any selected cell that is not the first cell in the driving circuit (i.e. in cells that do not have input terminals electrically connected to the driving circuit's voltage source), the pass-through switch sets (SW[0], SW[1]) and (SW[2], SW[3]) may be interchangeable, as both sets of switches, when closed, electrically connect the selected cell's inputs to its output.

FIG. 22M-1A and FIG. 22M-1B show the phases of and patterns in switch sequencing that may be applied to cause the methodology 2200 to provide a step-wise increase and then decrease of output voltage during a complete driving cycle. Specifically:
In an initiating cell [2] phase 2212-1 for cell 2101-2, a two-stage initiating cell [2] switching pattern 2202-1 may be applied to the cell 2101-2 in Stages 2201-1 to 2201-2, so that the switches of the second cell 2101-2 are operated to bypass the cell 2101-2 for one stage and then supply V_{CS21[2]} to the output voltage of the driving circuit 2100 in another stage.
   An executing cell [2] phase 2213-1 for the cell 2101-2 may begin after the completion of the initiating cell [2] phase 2212-1. In the executing cell [2] phase 2213-1, a three-stage executing cell [2] switching pattern 2203-1 may be applied to the switches in the cell 2101-2 simultaneously with the initiating cell [1] phase 2215-1 (described below) operating on the cell 2101-1 to increase the input voltage of the cell 2101-2 by V_{CS21[1]} so that the application of the executing cell [2] switching pattern 2203-1 drives the output voltage of the circuit 2100 to 4V_{CS21[2]}. The switches in the cell 2101-2, which are operated to first subtract V_{CS21[2]} from the input voltage of the cell 2101-2, then bypass cell 2101-2, and then supply V_{CS21 [2]} to the output voltage of the cell 2101-2.
   As noted above in general terms, the subtraction of V_{CS21[2]} from the output voltage of the cell 2101-2 during the first stage of the switching pattern 2203-1 does not result in a reduction of the output voltage of the cell 2101-2 (which is also the output voltage of the circuit 2100). At the same time that the subtraction of the switching pattern 2203-1 occurs, an initiating cell [1] phase 2215-1 (described below) operates on the cell 2101-1 to increase the input voltage of the cell 2101-2 by V_{CS21[1]} for the duration of the executing cell [2] switching pattern 2203-1 on the cell 2101-2. Therefore, while the subtraction operation on the cell 2101-2 results in a reduction of the newly increased input voltage of the cell 2101-2, the output voltage of the cell 2101-2 is V_{CS21[1]}−V_{CS21[2]}=2V_{CS21[2]}.
   In the next stage of the executing cell [2] switching pattern 2203-1 on the cell 2101-2, the cell 2101-2 is bypassed allowing the output voltage of the cell 2101-2 to reach V_{CS21[1]}=3V_{CS21[2]}; and the next stage of the executing cell [2] switching pattern 2203-1 supplies 21 [2] to the output voltage of the cell 2101-2, resulting in an output voltage of V_{CS21[1]}+V_{CS21[2]}=4V_{CS21[2]}.
   In the phase 2213-1, the executing cell [2] switching pattern 2203-1 may be repeated on the cell 2101-2 simultaneously with the peaking cell [1] phase 2217 (described below) operating on the cell 2101-1 to increase the input voltage of the cell 2101-2 by V_{DD21}−V_{CS21[1]} so that the repetition of the the executing cell [2] switching pattern 2203-1 drives the output voltage of the circuit 2100 to 5V_{CS21[2]}, then to 6V_{CS21[2]}, and then to 7V_{CS21[2]}.
A peaking cell [2] phase 2214 may begin after the completion of the executing cell [2] phase 2213-1. In the peaking cell [2] phase 2214, two stages of the peaking cell [2] switching pattern 2204 may be applied to the second cell 2101-2 to reach a peak output voltage of 9V_{CS21[2]}, by first subtracting V_{CS21[2]} from the input voltage of the cell 2101-2 in a Stage 2201(9), and then by bypassing the cell 2101-2 in a Stage 2201(10).

Simultaneously, the switches of the cell 2101-1 may be activated as follows:
In an initiating cell [1] phase 2215-1, a five-stage initiating cell [1] switching pattern 2205-1 may be applied on the cell 2101-1. The initiating cell [1] switching pattern 2205-1 may begin by operating the switches of the cell 2101-1 first to ground the input of cell 2101-2 during the application of the two-stage initiating cell [2] switching pattern 2202-1 on cell 2101-2 in the Stages 2201-1 to 2201-2, and then to provide V_{CS21[1]} to cell 2101-2 as its input voltage during the first application of the three-stage executing cell [2] switching pattern 2203-1 on the cell 2101-2. Throughout the initiating cell [1] phase 2215-1, in the cell 2101-1, the switch SW[0] (electrically connected to the negative terminal of the voltage source) is maintained closed, and the switch SW[3] of the cell 2101-1 (electrically connected to the positive terminal of the voltage source) remains open.
A peaking cell [1] phase 2217, in which the switch SW[0] is maintained open and the switch SW[3] (electrically connected to the positive terminal of the voltage source) is maintained closed, may begin after the completion of the initiating cell [1] phase 2215-1. In the peaking cell [1] phase 2217, a five-stage peaking cell [1] switching pattern 2207 may be applied on the cell 2101-1 during the Stages 2201(6)-2201(10) to drive the cell 2101-1 to its peak output voltage, first by activating the switches in the cell 2101-1 in the Stages 2201(6)-2201(8) during the second application of the executing cell [2] switching pattern 2203-1 on the cell 2101-2 to provide V_{DD21} less to the cell 2101-2 as its input voltage, and then in the Stages 2201(9)-2201(10) during the application of the peaking cell [2] switching pattern 2204 on the cell 2101-2 to provide the supply voltage V_{DD21} to the input of cell 2101-2 (in effect, bypassing cell 2101-1). Throughout the peaking cell [1] phase 2217 of the cell 2101-1, the switch SW[0] is maintained open, and the switch SW[3] remains closed.

The switching methodology 2200, having thus achieved a peak output of V_{DD21} for the driving circuit 2100 at the completion of the Stage 2201(10), may then be applied to the circuit 2100 in reverse order to operate a complete driving cycle in which the output voltage of the cell 2100, having been increased in a step-wise manner to an output voltage of V_{DD21}, may be returned in step-wise decreases back to ground. The cell switching will include switch activation through Stages 2201(11)-2201(18) to effect the step-wise decrease of the circuit's output voltage to V_{CS21[2]}.

The driving cycle being completed at Stage 2201(18), the next operation of the driving cycle may drive the output voltage to ground in its first stage. The cycle may repeat to drive the output voltage in a step-wise manner to V_{DD21} then back to V_{CS21[2]}.

The changes to the cell switching patterns for driving the cell 2101-2 in reverse order through Stages 2201(11)-2201(18) follow:
After the peaking cell [2] switching phase 2214 increases the output voltage of the circuit 2100 to V_{DD21}=9V_{CS21[2]} at the completion of the second stage of the peaking cell [2] phase 2214 at the Stage 2201(10), the phase 2214 may continue at Stage 2201(11) to activate the switch set that had been activated in Stage 2201(9), thus subtracting V_{CS21[2]} from V_{DD21} the input voltage of the cell 2101-2.
A reverse executing cell [2] phase 2213-2 may begin after the completion of the peaking cell [2] phase 2214 on the cell 2101-2. The reverse executing cell [2] phase 2213-2 may constitute an executing cell [2] phase 2213-1 operated on the cell 2101-2 in reverse order. In the reverse executing cell [2] phase 2213-2, a three-stage reverse executing cell [2] switching pattern 2203-2 may be applied twice to the switches in the cell 2101-2. The reverse executing cell [2] switching pattern 2203-2, in which the stages of the executing cell [2] switching pattern 2203-1 may be implemented in reverse order, may be applied to activate the switch set in cell 2101-2 to supply V_{CS21[2]} to the output voltage of the cell 2101-2, then to bypass cell 2101-2, and then to subtract V_{CS21[2]} from the cell 2101-2 input voltage V_{DD21}. The second application of the reverse executing cell [2] switching pattern 2203-2 brings the output voltage of the circuit 2100 to V_{CS21[1]} less V_{CS21[2]}, or 2V_{CS21[2]} at the completion of the Stage 2201(17).
A reverse initiating cell [2] phase 2212-2 may begin on the cell 2101-2 after the completion of the reverse executing cell [2] phase 2213-2 at Stage 2201(17). The reverse initiating cell [2] phase 2212-2, which may constitute the initiating cell [2] phase 2212-1 operated in reverse order, has a two-stage reverse initiating cell [2] switching pattern 2202-2, in which the stages of the initiating cell [2] switching pattern 2202-1 may be operated in reverse order. The reverse initiating cell [2] switching pattern 2202-2 may be applied on the switches in the cell 2101-2, first to supply 21 [2] to the output voltage in a Stage 2201(18), then in a repeat of Stage 2201(1), to bypass the cell 2101-2 to bring the output voltage of the circuit 2100 back to ground.

The changes to the phases and switching patterns for the methodology 2200 to drive the cell 2101-1 in reverse order follow:
A peaking cell [1] phase 2217 may proceed at the completion at the Stage 2201(10) of the first two stages of the peaking cell [2] phase 2214. The peaking cell [1] switching pattern 2207 of the phase 2217:
   continues to maintain the supply voltage V_{DD21} on the input of the cell 2101-2 while cell 2101-2 is still undergoing the peaking cell [2] switching pattern 2204, and
   then operates during the Stages 2201(12)-2201(14) to again provide V_{DD21} less V_{CS21[1]} to the input of the cell 2101-2 while the cell 2101-2 is undergoing the first application of the reverse executing cell [2] switching pattern 2203-2.
A reverse initiating cell [1] phase 2215-2 begins after the completion of the peaking cell [1] phase 2217 for the cell 2101-1. The reverse initiating cell [1] phase 2215-2, which may constitute the initiating cell [1] phase 2215-1 operated in reverse order, may be applied to the cell 2101-1. The reverse initiating cell [1] phase 2215-2 has a five-stage reverse initiating cell [1] switching pattern 2205-2, in which the stages of the initiating cell [1] switching pattern 2205-1 may be operated in reverse order. The reverse initiating cell [1] switching pattern 2205-2 may be applied on the switches in the cell 2101-1:
   first to operate during the Stages 2201(15)-2201(17) to supply V_{CS21[1]} to the input of the cell 2101-2 while the cell 2101-2 is undergoing the second application of the reverse executing cell [2] switching pattern 2203-2, and
   then, during the Stages 2201(18)-2201(1), with Stage 2201(1) constituting the first stage of the next operation of the driving cycle for the circuit 2100, to provide ground to the input of the cell 2101-2 while the cell 2101-2 is undergoing the application of the reverse initiating cell [2] switching pattern 2202-2 to bring the output voltage of the circuit 2100 back to ground in the manner described above.

### FIGS. 22M-2A1(A1)-22M-2A2: 3-Cell Driving Circuit

The switching methodology switching charts 2222a, 2222b (FIGS. 22M-2A1(A1), 22M-2A1(A2), respectively) and switching patterns chart 2225 [FIG. 22M-2A1(B)] detail a methodology 2220 and identifies switch activation for operating a driving circuit [wxy] with three driver cells [w], [x], [y], each with one non-dissipative element and four switches.

Comparing the methodology 2200 switching sequence chart (FIG. 22M-1A) to the methodology 2220 switching sequence chart 2225 [FIG. 22M-2A 1(B)], and comparing the methodology 2200 phases chart (FIG. 22M-1B) to the methodology 2220 phases chart (FIG. 22M-2A2), it can be seen that the switching patterns that may be used to control the output voltage of a two-cell driving circuit may be modified to control a three-cell driving circuit. As in the switching methodology 2200, a cell in a driving circuit having three driver cells may be electrically bypassed by closing the first pair of switches (SW[0], SW[1]) in the series of switches in the cell and by closing the last pair of switches in the series of switches in the cell. Other switch sets may be operated to release the voltage storage capacity (and multiples thereof) of non-dissipative element(s), or to reduce the voltage output by the voltage storage capacity (and multiples thereof) of the non-dissipative element(s), to provide a step wise change in the voltage output for the driving circuit. In further stages, the non-dissipative element of another cell may be bypassed and the previously bypassed cell may then be activated with or without other cells in the driving circuit to extend the step-wise switching pattern to release and discharge different amounts of voltage.

Going forward, it is to be understood that references to the first switch set (SW[0], SW[1]) and last switch set (in a one-non-dissipative element cell, set (SW[2], SW[3])), both identify a cell bypass operation and, when used in descriptions of switching methodologies for all but the first cell in a multi-cell driving circuit, may be used interchangeably despite which of the bypassing switch sets is described herein, shown in the figures, or selected for implementation in a system according to this invention.

Turning now to a more detailed look at FIG. 22M-2A 1(B), a switching sequence methodology 2220 is shown for a driving circuit having three driver cells, cell [w], cell [x], cell [y], each with one non-dissipative element and four switches. The pattern of selective and sequential switch opening and closing that was disclosed in FIGS. 22K and 22M-1A may also be seen in FIGS. 22M-2A1(B) and 22M-2A2, in which voltage output increments in a step-wise manner by opening and closing selected switches to release voltage from selected cells while preventing other cells from contributing voltage to the driving circuit output, and, once the voltage is being output from the circuit is equal to the supply voltage for the circuit [wxy], (V_{DD[wxy]}), the stages of the process may be performed in reverse order to reduce the voltage output, again in a step-wise manner, back to an output voltage of V[y] at the Stage 2221(54). As with the exemplary driving cycle for the circuit 2100, the output voltage of the circuit [wxy] may be driven to ground with an application of the first stage, Stage 2221(1), of the V_{O[wxy]} driving cycle.

Many of the patterns of switch closing and resultant voltage outputs of Stages 2201(1) to 2201(18) of the methodology 2200 in FIGS. 22M-1A, 22M-1B may be seen in the patterns of switch closing and resultant voltage outputs of the Stages 2221(1) to 2221(54) in the methodology 2220 in FIGS. 22M-2A1(B), 22M-2A2.

Further, as in the embodiments disclosed above, the number of stages in which a switched set activation is maintained on a selected cell of a multi-cell circuit may be based on its position in in the circuit. For the cell [w] or [x] in the circuit [wxy], the number of stages in which a switched set activation is maintained may be based on the number of non-dissipative elements in its adjacent, downstream cell in the circuit [wxy]. A switched set activation may be maintained on the selected cell for the duration of the methodology switching pattern that is concurrently being performed on its adjacent, downstream cell. When the selected cell is the cell [y], (the last cell), the switched set activation may be maintained in the selected cell for the duration of one stage of the methodology switching pattern.

For the last cell of the circuit [wxy] (cell [y]):
In an initiating cell [y] phase 2232-1, in Stages 2221(1) to 2221(2), the two-stage initiating cell [y] switching pattern 2202-1 (which is the same switching pattern as the initiating cell [2] switching pattern 2202-1 in the methodology 2200 disclosed above) may operate on the cell [y] (the last cell defined earlier as the one electrically connected to the output terminal of the driving circuit [wxy]) to bypass it and then to add V[y] to the input voltage of cell [y].
Then, in an executing phase 2233-1, the three-stage executing cell [y] switching pattern 2203-1 may be applied to first subtract V[y] from the input voltage of the cell [y], then to bypass cell [y], and then to add V[y] to the input voltage of the cell [y]. The executing cell [y] switching pattern 2203-1 (which is the same switching pattern as the executing cell [2] switching pattern 2203-1 in the methodology 2200 disclosed above) may be applied on cell [y] for seven more applications (for a total of eight applications of switching pattern 2203-1) to bring the output voltage of the cell [y] to

$${V}_{D D [ w x y ]} - V [ x ] + V [ y ] = 25 V [ y ] .$$

The peaking cell [y] phase 2234 may begin after the completion of the executing cell [y] phase 2233-1. The peaking cell [y] phase 2234 may have a peaking cell [y] switching pattern 2204, (which is the same switching pattern as the peaking cell [2] switching pattern 2204 in the methodology 2200 disclosed above). The peaking cell [y] switching pattern 2204 may operate on cell [y] to bring the cell [wxy] to a peak output voltage, first by subtracting V[y] from the input voltage of the cell [y] in Stage 2221(27) and then by bypassing cell [y] in a Stage 2221(28). When the driving circuit [wxy] is operated to stop after achieving V_{DD[wxy]} as its output voltage, the peaking cell [y] phase 2234 may end at Stage 2221(28).

Simultaneously and synchronously, cell [x] may be activated as follows:
An initiating cell [x] phase 2235-1 may have an initiating cell [x] switching pattern 2205-1 (which is the same switching pattern as the initiating cell [1] switching pattern 2205-1 in the methodology 2200 disclosed above). The switching pattern 2205-1 operates for five stages on the cell [x], first to bypass cell [x] during the application of the two-stage initiating cell [y] switching pattern 2202-1 on the cell [y], and then to provide V[x] to the input of the cell [y] during the first application on the cell [y] of the three-stage executing cell [y] switching pattern 2203-1.
An executing cell [x] phase 2236-1 may begin after the completion of the initiating cell [x] phase 2235-1. In the executing cell [x] phase 2236-1, a nine-stage executing cell [x] switching pattern 2226-1 may operate repeatedly on the cell [x] across three applications of the executing cell [y] switching pattern 2203-1 on the cell [y],
   to first subtract V[x] from the voltage being input to the cell [x] (which is the output voltage of the cell [w]) during an entire application of the switching pattern 2203-1 on the cell [y],
   then to bypass cell [x] during another entire application of the switching pattern 2203-1 on the cell [y], and
   then to add V[x] to the output voltage of cell [x] during another entire application of the switching pattern 2203-1 on the cell [y].

The nine-stage executing cell [x] switching pattern 2226-1 then may be repeated on the cell [x] across three more applications of the executing cell [y] switching pattern 2203-1 on cell [y].
A peaking cell [x] phase 2237 may begin after the completion of the executing cell [x] phase 2236-1. The peaking cell [x] phase 2237 may have a peaking cell [x] switching pattern 2207 (which is the same switching pattern as the peaking cell [1] switching pattern 2207 in the methodology 2200 disclosed above) The switching pattern 2207 may operate on the cell [x] for its first three stages to subtract V[x] from the input of cell [x] during the final application of the three stage executing cell [y] switching pattern 2203-1 on the cell [y], and then to bypass cell [x] during the application of the first two stages of the peaking cell [y] switching pattern 2204 on the cell [y] until the peaking voltage of V_{DD[wxy]} of the circuit [wxy] is achieved at the output terminal of the cell [y]. When the driving circuit [wxy] is operated to stop after achieving V_{DD[wxy]} as its output voltage, the peaking cell [x] phase 2237 may end at Stage 2221(28).

Simultaneously and synchronously, cell [w] may be activated as follows:
In an initiating cell [w] phase 2238-1, a fourteen-stage initiating cell [w] switching pattern 2228-1 may begin by operating on the cell [w] to bypass the cell [w], thus applying ground to the input of cell [x] during the application of the initiating cell [x] phase 2235-1 on cell [x], and then to provide V[w] to the input of the cell [x] during the first application of the executing cell [x] switching pattern 2226-1 on the cell [x]. Throughout the initiating cell [w] phase 2238-1 on the circuit [wxy], the switch SW[0] in cell [w] remains closed and the switch SW[3] in cell [w] remains opened.
A peaking cell [w] phase 2239 may begin after the completion of the initiating cell [w] phase 2238-1. Throughout the phase 2239, the switch SW[0] in cell [w] remains open and switch SW[3] in cell [w] remains closed. In the peaking cell [w] phase 2239, a peaking cell [w] switching pattern 2229 operates on the cell [w] for its first nine stages to subtract V[w] from the input voltage of the cell [w] (which is the supply voltage V_{DD[wxy]} of the voltage source that is electrically connected to the circuit [wxy]) during the second application of the executing cell [x] switching pattern 2226-1 on the cell [x], and then to provide V_{DD[wxy]} to the input of the cell [x] during the five-stage peaking cell [x] switching pattern 2207, from Stages 2221(24) to 2221(28), until the output of the cell [x] also reaches the supply voltage V_{DD[wxy]}. When the driving circuit [wxy] is operated to stop after achieving V_{DD[wxy]} as its output voltage, the peaking cell [w] phase 2239 may end at Stage 2221(28).

The switching methodology 2220, having thus achieved an output of V_{DD[wxy]} for the driving circuit [wxy], may continue with the switch activation according to the already-describe phases and switching patterns for the methodology 2220 operating in reverse order to reduce the voltage output in a step-wise manner from V_{DD[wxy]} in Stage 2221(28) to ground in an application of a Stage 2221(1).

For cell [y]:
As in the switching methodology 2200, the peaking cell [y] phase 2234 may continue with the third stage of the peaking cell [y] switching pattern 2204 to subtract V[y] from the output voltage V_{DD[wxy]}
A reverse executing cell [y] phase 2233-2 may begin on the cell [y] after the completion of the peaking cell [y] phase 2234. The reverse executing cell [y] phase 2233-2 calls for repeated applications of a reverse executing cell [y] switching pattern 2203-2 on the cell [y]. In the embodiment of FIGS. 22M-2A 1(B), 22M-2A2, the reverse executing cell [y] switching pattern 2203-2 may be applied eight times to the switches in the cell [y]. The reverse executing cell [y] pattern 2203-2, in which the stages of the executing cell [y] switching pattern 2203-1 may be applied on the cell [y] in reverse order, is arranged to first add V[y] to the output voltage of the cell [y], then to bypass cell [y], and then to subtract V[y] from the input voltage of the cell [y], to bring the output voltage of the circuit [wxy] to V[x] less V[y] after the eight application of the reverse executing cell [y] switching pattern 2203-2 at the completion of the Stage 2221(53).
A reverse initiating cell [y] phase 2232-2 may begin after the completion of the reverse executing cell [y] phase 2233-2. In the reverse initiating cell [y] phase 2232-2, a two-stage reverse initiating cell [y] switching pattern 2202-2 is performed on the cell [y]. The reverse initiating cell [y] switching pattern 2202-2, in which the stages of the initiating cell [y] switching pattern 2202-1 may be implemented in reverse, may operate on the cell [y], first adding V[y] to the input voltage of the cell [y] in a Stage 2221(54), then bypassing cell [y] to bring the output voltage of the cell [y] back to ground in an application of a Stage 2221(1).

For cell [x]:
The peaking cell [x] phase 2237 may continue with the Stage 2221(29) of the peaking cell [x] switching pattern 2207 to bypass the cell [x] to ensure that V_{DD[wxy]} is provided to the input of the cell [y] for the duration of the peaking cell [y] switching pattern 2204 on the cell [y]; and then to reduce the voltage being input to the cell [y] by V_{[x]} during the first application of the reverse executing cell [y] switching pattern 2203-2 on the cell [y].
A reverse executing cell [x] phase 2236-2 may begin after the completion of the peaking cell [x] phase 2237. The reverse executing cell [x] phase 2236-2 calls for two applications on the cell [x] of the reverse executing cell [x] switching pattern 2226-2, in which the stages of the executing cell [x] pattern 2226-1 are implemented in reverse order. Each application of the reverse executing cell [x] switching pattern 2226-2 in the phase 2236-2 operates on the cell [x] during three applications of the reverse executing cell [y] switching pattern 2203-2 on the cell [y]:
   first adding V[x] to the input voltage of the cell [x] during an application of the reverse executing cell [y] switching pattern 2203-2 on the cell [y], which in the current embodiment is the second application of the reverse executing cell [y] switching pattern 2203-2 (the first application having operated on the cell [y] during the last stages of the peaking cell [x] switching pattern 2207);
   then bypassing the cell [x] during another application of the reverse executing cell [y] switching pattern 2203-2 on the cell [y], which in the current embodiment is the third application of pattern 2203-2 on the cell [y]; and
   then subtracting V[x] from the input voltage for the cell [y] during another application of the reverse executing pattern 2203-2 on the cell [y] which in the current embodiment is the fourth application of pattern 2203-2 on the cell [y].
In the current embodiment, the second application of the reverse executing cell [x] switching pattern 2226-2 is performed during the fifth, sixth, and seventh applications of the switching pattern 2203-2 on the cell [y]. The two applications of the reverse executing cell [x] switching pattern 2226-2 brings the output voltage for the circuit [wxy] to V[w], less V[x], and less V[y], or 5V[y] at the completion of the reverse cell [x] phase 2236-2.
A reverse initiating cell [x] phase 2235-2 may begin after the completion of the reverse executing cell [x] pattern 2236-2. In the phase 2235-2, a five-stage reverse initiating cell [x] pattern 2205-2, in which the stages of the initiating cell [x] pattern 2205-1 may be implemented in reverse order, first supplies V[x] to the voltage input for the cell [y] during the eighth application of the reverse executing cell [y] pattern 2203-2 on the cell [y], and then bypasses the cell [x] during the application of the reverse initiating cell [y] switching pattern 2202-2 on the cell [y], so that the switching pattern 2202-2 may bring the output voltage of the circuit [wxy] back to ground with an application of a Stage 2221(1).

For cell [w]:
The peaking cell [w] phase 2239 may continue with the Stage 2221(29) of the peaking cell [w] switching pattern 2229 to supply the circuit [wxy] 's supply voltage to the input of the cell [x] with a continuation of the supply voltage-bypass of the cell [w] for the duration of the peaking cell [x] switching pattern 2207 on the cell [x]; and then to reduce the voltage input to the cell [x] by V[w] during the first application of the reverse executing cell [x] switching pattern 2226-2.
A reverse initiating cell [w] phase 2238-2 may begin after the completion of the peaking cell [w] phase 2239 at the completion of Stage 2221(41). In the phase 2238-2, a 14-stage reverse initiating cell [w] switching pattern 2228-2, in which the stages of the initiating cell [w] switching pattern 2228-1 are implemented in reverse order, may be applied on the cell [w], first to add V[w] to the input voltage of the cell [w] during the second application of the reverse executing cell [x] switching pattern 2226-2 on the cell [x], and then to bring the input voltage for cell [x] back to ground by ground-bypassing cell [w] during the application of the reverse initiating cell [x] switching pattern 2205-2 on the cell [x]. As with cells [x], [y], the cell [w] may be brought to bypass after the completion of the output voltage driving cycle with an application of a Stage 2221(1).

### FIG. 22M-2B1: 4-Cell Driving Circuit

Generalizing the methodology 2200 even further, FIG. 22M-2B 1, 22M-2B2 presents an exemplary switching methodology 2240 for operating a driving circuit [vwxy] with four driver cells [v], [w], [x], [y], each with one non-dissipative element and four switches. The fourth driver cell in the driving circuit [vwxy] is presented here to illustrate how the same switch activation patterns that caused the activation of the switches in cells in the driving circuit [wxy] may be applied to activate the switches in cells in a driving circuit [vwxy] and in driving circuits with any number of driver cells.

FIG. 22M-2B 1 employs the functional representation of switching activations presented in FIGS. 22L-1 through 22L-3, which map the activated switch sets in a stage of a methodology to the functional result of the switching. For example, in a cell with one non-dissipative element:
Activating the switch set (SW[0], SW[1]) (also known as the first and second switches) in the first cell of a multi-cell circuit, specifically the cell that is directly connected to the voltage source for the driving circuit, operates to bypass the non-dissipative element of the first cell and apply the voltage at the negative terminal of the voltage source, here ground, to the output terminal of that first cell, referred to in FIG. 22M-2B 1 and in later switching charts as “b (ground)” or simply “b(g).”
Activating the last and second last switches in the first cell of a multi-cell circuit (the switch set (SW[2], SW[3]) in a one-non-dissipative element driving cell) also operates to bypass the cell; it applies the voltage at the positive terminal of the voltage source, here V_{DD[vwxy]}, to the output terminal of that first cell, referred to in FIG. 22M-2B1 and in later switching charts as “b (V_{DD[*]})”, where * is an identifier for the subject circuit.
As noted above, in any other cell other than the first cell in the described multi-cell circuit activating the first and second switches or the last and second last switches (the switch sets (SW[0], SW[1]) or (SW[2], SW[3]) in a one-non-dissipative element driving cell) also operates to bypass the cell, applying the voltage at the input terminal of the cell to the output terminal of the cell, referred to as “b.”
Activating the first and third switch in any cell of the described multi-cell circuit (switch (SW [0], SW[2]) in a one-non-dissipative element driving cell) operates to activate the non-dissipative element of the cell to add the voltage storage capacity of the cell's non-dissipative element to the input voltage of the cell, referred to as “+.”
Activating the last and third last switch in any cell of the described multi-cell circuit (switch (SW[1], SW[3]) in a one-non-dissipative element driving cell) operates to activate the non-dissipative element of the cell to subtract the amount of the voltage storage capacity of the cell's non-dissipative element from the input voltage of the cell, referred to as “−.”

The notation change allows a switching pattern to be illustrated in a single line of a chart, allowing fewer lines to be used in charts illustrating switch sequence methodologies, and allows the charts to show the repetition of switching patterns more easily. The change also allows for direct comparison of the switch sequence methodology 2220 of FIG. 22M-2A1(B) to the switch sequence methodology 2240 of FIG. 22M-2B 1, which demonstrates that, despite FIG. 22M-2A1(B) showing a single stage per row and FIG. 22M-2B 1 showing a switching pattern in each row, and despite driving circuits [wxy], [vwxy] differing in the number of cells in the circuit, the methodologies 2220, 2240 (and methodology 2200) have essentially the same phases and switching patterns of switch activation. FIGS. 22M-1A through FIG. 22M-2B2 illustrate that, as the number of cells in a driver circuit increases, the phases and switching patterns of switching in one switch sequence methodology for operating the most basic multi-cell diving circuit may be applied to driver circuits with larger number of cells to achieve step-wise changes in the voltage being delivered to outputs of driving circuits.

For simplicity of example, in FIG. 22M-2B 1, the cells in the driving circuit [vwxy] each contain one non-dissipative element, and all of the non-dissipative elements of the cell will have the same capacitance. The relaxation of those limitations will be discussed below. In the meantime, it can be seen that the switching sequencing of driving circuit [vwxy] continue to constitute switching patterns with functionality of (subtracting a selected voltage from a cell's output voltage “−,” bypassing the circuit “b,” and adding the selected amount of voltage to the cell's output voltage “+”) hereinafter referred to as “(−,b,+)”; and the applications of switching patterns in forward order or reverse order on a cell while analogous switching patterns are applied on upstream cell(s) in the circuit, result in step-wise changes in the output voltage of the circuit.

The last cell in the driving circuit [vwxy] (which is directly connected to the output of the driving circuit, and which in the driving circuit [vwxy] is cell [y]) may operate with the following phases and activation patterns:
In an initiating cell [y] phase 2252-1, the two-stage initiating last cell switching pattern 2202-1 (which is the same switching pattern as the initiating cell [2] switching pattern 2202-1 in the methodology 2200 and the initiating cell [y] switching pattern 2202-1 in the methodology 2220) is shown with the switch activation functionality notation (b,+) for bypassing the last cell, and then for adding the voltage storage capacity of the last cell's non-dissipative element (constituting a voltage step V[y]) to the input voltage of the cell [y]. As noted above, in the last cell of a driving circuit, the bypass is achieved by activating the switches (SW[0], SW[1]) or the switches (SW[2], SW[3]) in the cell [y].
The executing cell [y] phase 2253-1 begins after the completion of the initiating cell [y] phase 2252-1. The phase 2253-1 calls for repeated applications of the three-stage executing cell [y] switching pattern 2203-1 (which is the same switching pattern as the executing cell [2] switching pattern 2203-1 in the methodology 2200 and the executing cell [y] switching pattern 2203-1 in the methodology 2220). The executing cell [y] switching pattern 2203-1, with the functionality (−,b,+) operates to first subtract a voltage step V[y] from the input voltage of the last cell, then to bypass the last cell, and then to add v[y] to the input voltage of the last cell. In the methodology 2240, the pattern 2203-1 may be applied twenty-six times, until the output voltage of the circuit [vwxy] is two voltage steps away from equaling the supply voltage from the voltage source.
A peaking cell [y] phase 2254 begins after the completion of the executing cell [y] phase 2253-1. The peaking cell [y] phase 2254 employs a peaking cell [y] switching pattern 2204 with functionality of (−,b,−) (which is the same switching pattern as the peaking cell [2] switching pattern 2204 in the methodology 2200 and the peaking cell [y] switching pattern 2204 in the methodology 2220). The first two stages (−, b) of the peaking cell [y] switching pattern 2204 subtract V[y] from the last cell's input voltage, and then bypass the last cell to achieve the supply voltage as the output voltage of the circuit [vwxy].

When operation of the driving circuit continues after an output voltage for cell [y] that is equal to the supply voltage is achieved, the peaking cell [y] phase 2254 may allow the peaking cell [y] switching pattern 2204 to apply its complete (−,b,−) functionality, by operating the last stage of the peaking cell [y] switching pattern 2204 to again subtract V[y] from the cell [y] input voltage.
A reverse executing cell [y] phase 2253-2 may begin after the completion of the peaking cell [y] phase 2254. The phase 2253-2 may have a reverse executing cell [y] switching pattern 2203-2, in which the stages of the executing cell [y] switching pattern 2203-1 with (−,b,+) functionality are applied to the cell [y] in reverse order, with the switching pattern applying (+,b,−) functionality on the cell [y]. The reverse executing cell [y] switching pattern 2203-2 may be repeated until the output voltage of the circuit [vwxy] is two voltage steps away from ground.
A reverse initiating phase 2252-2 may begin after the completion of the reverse executing cell [y] phase 2253-2. The reverse initiating phase 2252-2 has a reverse initiating cell [y] switching pattern 2202-2, in which the stages of the initiating cell [y] switching pattern 2202-1 with functionality (b,+) are applied to the cell [y] in reverse order, employs a two-stage reverse initiating pattern 2202-2 with (+,b) functionality that may be operated to drive the output voltage of the circuit [vwxy] to ground, with the b functionality provided after the completion of the output voltage driving cycle by an application of a Stage 2241(1).

The first cell in the driving circuit (which is directly connected to the voltage source for the driving circuit, and which in the driving circuit [vwxy] is cell [v], is upstream and adjacent to the second cell of the driving circuit. The second cell also is referred to herein as cell [2] and in the driving circuit [vwxy] as cell [w]. The first cell may operate with the following phases and activation patterns:
In an initiating cell [v] phase 2218-1, an initiating cell [v] switching pattern 2208-1 may operate on the first cell in the circuit, with a switch activation functionality notation b(ground) repeated for 14 stages for the duration of the application of an initiating cell [w] switching pattern 2228-1 on the cell [w], and another activation functionality notation+repeated 27 stages for the duration of the first application on the second cell [w] of an executing cell [w] switching pattern 2241-1;
A peaking cell [v] phase 2219 may follow the completion of the initiating cell [v] phase 2218-1. The peaking cell [v] phase 2219 may have a peaking cell [v] switching pattern 2209 that first reduces the supply voltage of the voltage source by V[v] during a second application of the executing cell [w] switching pattern 2241-1 on the downstream adjacent cell [w]; and then bypasses the cell [v] to ensure that the cell [v] provides the supply voltage of the voltage source (V_{DD[vwxy]}) as the output of the cell [v] during the application of the peaking cell [w] switching pattern 2229 (described below) until the cell [w] achieves V_{DD[vwxy]} as its output.

When the methodology 2240 of the driving circuit [vwxy] continues after Stage 2241(82):
The peaking cell [v] switching pattern 2209 may continue its bypass (V_{DD[vwxy]}) of cell [v] until completion of the peaking cell [w] switching pattern 2229 on the downstream adjacent cell [w]; and then subtract V[y] from V_{DD[vwxy]} during the first application on the second cell [w] of a reverse executing cell [w] switching pattern 2241-2.
A reverse cell [v] switching initiating phase 2218-2 may begin after completion of the peaking cell [v] switching phase 2219 upon completion of the first application of the reverse executing cell [w] switching pattern 2241-2. The phase 2218-2 may have a reverse initiating cell [v] switching pattern 2208-2 in which the stages of the initiating cell [v] switching pattern 2208-1 are implemented in reverse order to provide the functionality of (+ for the duration on the cell [w] of the second application of the reverse executing cell [w] switching pattern 2241-2, b (ground) for the duration of the reverse initiating cell [w] switching pattern 2228-2), thus driving the output of the cell [w] to ground after the completion of the output voltage driving cycle by an application of a Stage 2241(1).

It can be seen in reference to FIGS. 22M-2B 1, 22M-2B2 that the methodology 2240 has the following phases and cell switching patterns:
The methodology for cell [w] has:
   an initiating cell [w] phase 2258-1 with an initiating cell [w] switching pattern 2228-1 (which is the same switching pattern as the initiating cell [w] switching pattern 2228-1 in the methodology 2220);
   an executing cell [w] phase 2251-1 which repeatedly applies an executing cell [w] switching pattern 2241-1;
   a peaking cell [w] phase 2259 with a peaking cell [w] switching pattern 2229 (which is the same switching pattern as the peaking cell [w] switching pattern 2229 in the methodology 2220);
   a reverse executing cell [w] phase 2251-2 which repeatedly applies a reverse executing cell [w] switching pattern 2241-2; and
   a reverse initiating cell [w] phase 2258-2 with a reverse initiating cell [w] switching pattern 2228-2.
The methodology for cell [x] has:
   an initiating cell [x] phase 2255-1 with initiating cell [x] switching pattern 2205-1 (which is the same switching pattern as the initiating cell [1] switching pattern 2205-1 in the methodology 2200 and the initiating cell [x] switching pattern 2205-1 in the methodology 2220);
   an executing cell [x] phase 2256-1 with an executing cell [x] switching pattern 2226-1 (which is the same switching pattern as the executing cell [x] switching pattern 2206-1 in the methodology 2220);
   a peaking cell [x] phase 2257 with a peaking cell [x] switching pattern 2207 (which is the same switching pattern as the peaking cell [1] switching pattern 2207 in the methodology 2200 and the initiating cell [x] switching pattern 2207 in the methodology 2220);
   a reverse executing reverse cell [x] phase 2256-2 with a reverse cell [x] switching executing pattern 2226-2; and
   a reverse initiating cell [x] phase 2255-2 with a reverse initiating cell [x] switching pattern 2205-2.

It may be seen that the driving circuit [vwxy] is one instantiation of a K-cell driving circuit in which the circuit has four cells, each cell in the driving circuit having a single non-dissipative element and four switches, and having the cell [v] and cell [y] of the circuit [vwxy] operate as cell [1] and cell [K], respectively, in a multi-cell driving circuit. Therefore, the above-described methodologies for controlling cells [v], [y] may serve as exemplary embodiments of methodologies for driving the cells [1], [K] of a generalized multi-cell circuit in which cells have a single non-dissipative element and four switches.

It may also be seen that the cells [w] and [x] are instantiations of a cell [i] in the so-defined generalized multi-cell driving circuit, where (2≤i≤K−1), and with i=2 for cell [w] and i=3 for cell [x] of the circuit [vwxy]. The methodologies for controlling cells [w], [x] may be understood in the methodology described below for controlling cell [i] of the multi-cell driving circuit in which each cell in the driving circuit has one non-dissipative element and four switches. The cell [i] may operate in accordance with a cell switching methodology having phases and switch activation patterns as follows:
An initiating cell [i] phase has an initiating cell [i] switching pattern with a functionality (of b for the duration of the application of an initiating cell [i+1] switching pattern on the cell [i+1], + for the duration of the first application in the driving cycle of an executing cell [i+1] switching pattern on the cell [i+1]).
An executing cell [i] phase may proceed after the completion of the initiating cell [i] phase. The executing cell [i] phase may operate multiple applications of an executing cell [i] switching pattern on the cell [i]. When the cell [i] has one non-dissipative element, the executing cell [i] phase may end upon completion of the second last application in the driving cycle of the executing cell [i+1] switching pattern on the cell [i+1]. When the cell [i] has n non-dissipative elements, the executing cell [i] phase may end upon completion of the (n+1)^{th} last application in the driving cycle of the executing cell [i+1] switching pattern on the cell [i+1].
   The executing cell [i] switching pattern on the cell [i] may have the functionality of:
      − during an application of the executing cell [i+1] switching pattern on the cell [i+1],
      b during another application of the executing cell [i+1] switching pattern on the cell [i+1], and
      + during yet another application of the executing cell [i+1] switching pattern on the cell [i+1].
A peaking cell [i] phase may follow the completion of the executing cell [i] switching phase. The peaking cell [i] phase may have a peaking cell [i] switching pattern with the functionality of:
   − for the duration of a final application in the driving cycle of the executing cell [i+1] switching pattern on the cell [i+1], and
   b during the application of a peaking cell [i+1] switching pattern on the cell [i+1] until the cell [i+1] achieves its peak voltage.

When operation of the driving circuit continues after the driving circuit achieves the supply voltage as its output voltage:
The peaking cell [i] switching pattern may continue: (b until completion of the peaking cell [i+1] switching pattern on the cell [i+1], − for the duration of the first application in the driving cycle of a reverse executing cell [i+1] switching pattern on the cell (i+1).
The reverse executing cell [i] phase may begin after completion of the peaking cell [i] phase. The reverse executing cell [i] phase may repeat a reverse executing cell [i] switching pattern. When the cell [i] has one non-dissipative element, the reverse executing cell [i] phase may end upon completion of the second last application in the driving cycle of the reverse executing cell [i+1] switching pattern on the cell [i+1]. When the cell [i] has n non-dissipative elements, the reverse executing cell [i] phase may end upon completion of the (n+1)^{th} last application in the driving cycle of the executing cell [i+1] switching pattern on the cell [i+1].
   A reverse executing cell [i] phase may the functionality of:
      + during an application of the reverse executing cell [i+1] switching pattern on the cell [i+1],
      b during another application of the reverse executing cell [i+1] switching pattern on the cell [i+1], and
      − during yet another application of the reverse executing cell [i+1] switching pattern on the cell [i+1].
A reverse initiating cell [i] phase may begin after completion of the reverse executing cell [i] phase. The reverse initiating cell [i] phase may have a reverse initiating cell [i] switching pattern having the functionality of:
   + during the last application of the reverse executing cell [i+1] switching pattern on the cell [i+1], and
   b during the application of the reverse initiating cell [i+1] switching pattern on the cell [i+1], with the b functionality provided after the completion of the output voltage driving cycle by an application of a Stage 2241(1).
      8.2. K-Cell Driving Circuits Having Cell(s) with More than One Non-Dissipative Element
      FIG. 22M-3A, 22M-4A: 2-Cell Driving Circuits Having a Cell with One Non-Dissipative Element and a Cell with Two Non-Dissipative Elements

Similar switching patterns may also be seen in the switching sequence methodologies 2260, 2270 in FIGS. 22M-3A, 22M-3B and 22M-4A, 22M-4B, for a driving circuit having a cell with one non-dissipative element and another cell with two non-dissipative elements. For purposes of simplification, the capacitances of non-dissipative elements are assumed to be equivalent, but it is to be understood that driving circuits and switching sequence methodologies may be developed for step-wise increase and decrease in voltage output of a driving circuit having non-dissipative elements of non equivalent capacitance.

It can be seen in the switching sequence methodologies 2260, 2270 that the phases of and the switching patterns for multi-cell driving circuits having non-dissipative elements distributed differently across the cells of the driving circuits are similar to switching patterns seen in methodologies 2200, 2220, and 2240, with the differences driven by the number of non-dissipative elements in the cells in the driving circuit, causing the switches in switch activation sets to be different due to the number of non-dissipative elements in the cells.

For example, a cell with a single non-dissipative element has one switch set (SW[0], SW[2]) that, when activated, causes an increase in the output voltage of the driving cell; while a cell with two non-dissipative elements has two switch sets (SW[0], SW[2]), (SW[0], SW[3]) that, when activated, cause an increase of the output voltage of the driving cell. Activation of the switch set (SW[0], SW[2]) supplies the voltage storage capacity of one non-dissipative element to the output voltage, while activation of the switch set (SW[0], SW[3]) supplies the voltage storage capacity of both non-dissipative elements to the output voltage.

Further, the cell with a single non-dissipative element has one switch set (SW[1], SW[3]) that, when activated, causes a reduction in the output voltage of the driving cell by the voltage storage capacity of its one non-dissipative element; while the cell with two non-dissipative elements has two switch sets (SW[1], SW[4]), (SW[2], SW[4]) that, when activated, cause a reduction in the output voltage of the driving cell. Activation of the switch set (SW[2], SW[4]) reduces the output voltage by the voltage storage capacity of one non-dissipative element, while activation of the switch set (SW[1], SW[4]) reduces the output voltage by the voltage storage capacity of both non-dissipative elements.

FIG. 22M-3A: Driving Circuit [Ab], Having Cell [b] with Two Non-Dissipative Elements

The switching sequence methodology 2260 of a driving circuit [ab] having a one-non-dissipative element cell [2] electrically connected to the voltage source of the driving circuit and a two-non-dissipative element cell [b] electrically connected to the output terminal of the driving circuit is shown in FIGS. 22M-3A, 22M-3B.

For the cell [b] of the circuit [ab], the methodology 2260 mirrors the methodology 2200 in having:
an initiating cell [b] phase 2262-1 similar to the initiating cell [2] phase 2212-1 of the methodology 2200 and having an initiating cell [b] switching pattern 2242-1 that is similar to the initiating cell [2] switching pattern 2202-1 for the initiating cell [2] phase 2212-1 in that the switching patterns 2242-1, 2202-1 both apply switch activations that increase the output voltage of their respective cells from bypass;
an executing cell [b] phase 2263-1 similar to the executing cell [2] phase 2213-1 of the methodology 2200 and having an executing cell [b] switching pattern 2243-1 that is similar to the executing cell [2] switching pattern 2203-1 for the executing cell [2] phase 2213-1 in that the switching patterns 2243-1, 2203-1 both apply switch activations that increase the output voltage of their respective cells from a minimum cell voltage to a peak cell voltage;
a peaking cell [b] phase 2264 similar to the peaking cell [2] phase 2214 of the methodology 2200 and having a peaking cell [b] switching pattern 2244 that is similar to the peaking cell [2] switching pattern 2204 for the peaking cell [2] phase 2214 in that the switching patterns 2244, 2204 both apply switch activations that increase the output voltage of their respective cells from a minimum cell voltage to a peak cell voltage and back to a minimum cell voltage;
a reverse executing cell [b] phase 2263-2 similar to the reverse executing cell [2] phase 2213-2 of the methodology 2200 and having a reverse executing cell [b] switching pattern 2243-2 that is similar to the reverse executing cell [2] switching pattern 2203-2, with the stages of the reverse switching patterns 2243-2, 2203-2 applied to their respective cells in reverse order from the switching patterns 2243-1, 2203-1, respectively; and
a reverse initiating cell [b] phase 2262-2 similar to the reverse initiating cell [2] phase 2212-2 of the methodology 2200 and having a reverse initiating cell [b] switching pattern 2242-2 that is similar to the reverse initiating cell [2] switching pattern 2202-2, with the stages of the reverse switching patterns 2242-2, 2202-2 applied to their respective cells in reverse order from the switching patterns 2242-1, 2202-1, respectively, with the b functionality provided after the completion of the output voltage driving cycle by an application of a Stage 2261(1).

Further, the switch closing and resultant output voltages of the initial Stages 2261(1), 2261(2) of the methodology 2260 mirror the switch closing and resultant voltage outputs of Stages 2201(1), 2201(2), respectively, of the methodology 2200, with Stage 2261(3) added after Stage 2261(2) to allow activation of the switch set (SW[0], SW[3]) in cell [b] so that the voltage storage capacity of both of the non-dissipative elements in the cell [b] may supply voltage to the output of the driving circuit [ab]. When both non-dissipative elements have equivalent voltage capacities, the driving circuit output is 2V[b].

The two-stage initiating cell [2] switching pattern 2202-1 of (b,+) functionality for the cell 2101-2 may be modified to provide a three-stage initiating cell [b] switching pattern 2242-1 of (b, +, 2+) functionality for the two-non-dissipative element driver cell. By extension, the two-stage combination of a reverse initiating cell [2] switching pattern 2202-2 and a first stage of an initiating cell [2] switching pattern 2202-1 of (+,b) functionality for the cell 2101-2 may be modified to provide a three-stage combination of a reverse initiating cell [b] switching pattern 2242-2 and a first stage of an initiating cell [b] switching pattern 2242-1 of (2+,+,b) functionality for the two-non-dissipative element driver cell [b].

The switch closing and resultant voltage outputs of Stages 2261(5), 2261(6), 2261(7) of the methodology 2260 mirror the switch closing and resultant voltage outputs of Stages 2201(3), 2201(4), 2201(5), respectively of the methodology 2200, with the following stages added:
The Stage 2261(4) is added before the Stage 2261(5) to allow activation of the switch set (SW[1], SW[4]) in cell [b] so that voltage storage capacity of both of the non-dissipative elements in the cell [b] may contribute to reducing the input voltage of the cell [b], which is V[2]. When both non-dissipative elements have equivalent voltage capacities, the driving circuit output voltage is V[2]-2V[b]=3V[b].
The Stage 2261(8) is added after the Stage 2261(7) to allow activation of the switch set (SW[0], SW[3]) in cell [b] so that voltage storage capacity of both of the non-dissipative elements in the cell [b] may contribute to increasing V[2]. When both non-dissipative elements have equivalent voltage capacities, the driving circuit output voltage is

V[a]+2V[b]=7V[b].

The switch closing and resultant voltage outputs of Stages 2261(10), 2261(11), 2261(12) of the methodology 2260 mirror the switch closing and resultant voltage outputs of Stages 2201(6), 2201(7), 2201(8), respectively, of the methodology 2200, with the following stages added:
The Stage 2261(9) is added before the Stage 2261(10) to allow activation of the switch set (SW[1], SW[4]) in cell [b] so that voltage storage capacities of both of the non-dissipative elements in the cell [b] contribute to reducing the input voltage of the cell [b], which is (V_{DD[ab]}−V[2]), resulting, when both non-dissipative elements have equivalent voltage capacities, in the driving circuit output voltage being (V_{DD[ab]}−V[2])−2V[b]=8V[b].
The Stage 2261(13) is added after the Stage 2261(12) to allow activation of the switch set (SW[0], SW[3]) in cell [b] so that voltage storage capacity of both of the non-dissipative elements in the cell [b] contributes to increasing the input voltage of the cell [b], resulting, when both non-dissipative elements have equivalent voltage capacities, in the driving circuit output being (V_{DD[ab]}−V[2])+2V[b]=12V[b].

The three-stage executing cell [2] switching pattern 2203-1 of (−,b,+) functionality for the cell 2101-2 of FIG. 22M-1A may be modified to provide a five-stage executing cell [b] switching pattern 2243-1 of (2−,−,b,+,2+) functionality for the two-non-dissipative element driver cell [b]. By extension, the three-stage reverse executing cell [2] switching pattern 2203-2 of (+,b,−) functionality for the cell 2101-2 may be modified to provide a five-stage reverse executing cell [b] pattern 2243-2 with functionality of (2+,+,b,−,2−) for the two-non-dissipative element driver cell [b].

The switch closing and resultant output voltages of Stages 2261(15), 2261(16), of the methodology 2260 mirror the switch closing and resultant output voltages of Stages 2201(9), 2201(10), respectively, of the methodology 2200, with the Stage 2261(14) added before the Stage 2261(15) to allow activation of the switch set (SW[1], SW[4]) in cell [b] so that the voltage storage capacity of both of the non-dissipative elements in the cell [b] may contribute to reducing the input voltage of the cell [b], which is V_{DD[ab]}, resulting, when both non-dissipative elements have equivalent voltage capacities, in the driving circuit output being V_{DD[ab]}−2V[b]=13V[b].

The three-stage peaking cell [2] switching pattern 2204 of (−, b, −) functionality for the cell 2101-2 may be modified to provide a five-stage peaking cell [b] switching pattern 2244 with functionality of (2−,−,b,−,2−) for the 2-non-dissipative element driver cell [b].

For the cell [2] of the circuit [ab], the methodology 2260 mirrors the methodology 2200 in having:
an initiating cell [2] phase 2265-1 similar to the initiating cell [1] phase 2215-1 of the methodology 2200 and having an initiating cell [2] switching pattern 2245-1 that is similar to the initiating cell [1] switching pattern 2205-1 for the initiating cell [1] phase 2215-1 in that the switching patterns 2245-1, 2205-1 both apply switch activations that increase the output voltage of their respective cells from ground to a peak cell voltage and in that patterns 2245-1, 2205-1 both maintain their sets of switch activations for the duration of the cell switching patterns being applied to the adjacent, downstream cell in their respective circuits;
a peaking cell [2] phase 2267 similar to the peaking cell [1] phase 2217 of the methodology 2200 and having a peaking cell [2] switching pattern 2247 that is similar to the peaking cell [1] switching pattern 2207 for the peaking cell [1] phase 2217 in that patterns 2247, 2207 both maintain their sets of switch activations for the duration of the cell switching pattern being applied to the adjacent, downstream cell in their respective circuits; and
a reverse initiating cell [2] phase 2265-2 similar to the reverse initiating cell [1] phase 2215-2 of the methodology 2200 and having a reverse initiating cell [2] switching pattern 2245-2 that is similar to the reverse initiating cell [1] switching pattern 2205-2 for the reverse initiating cell [1] phase 2215-2, with the stages of both switching patterns 2245-2, 2205-2 applied to their respective cells in reverse order from the switching patterns 2245-1, 2205-1, respectively.

Further, to accommodate the additional non-dissipative element in cell [b], the five-stage initiating cell [1] switching pattern 2205-1 for the cell 2101-1 may be modified to provide an eight-stage initiating cell [2] switching pattern 2245-1 for cell [2] with a functionality of (b,b,b,+,+,+,+,+). By extension, the five-stage combination of a reverse initiating cell [1] switching pattern 2205-2 and a first stage of an initiating cell [1] switching pattern 2205-1 for the cell 2101-1 may be modified to provide an eight-stage combination of a reverse initiating cell [2] switching pattern 2245-2 and a first stage of an initiating cell [2] switching pattern 2245-1 for cell [2] with functionality of (+,+,+,+,+,b,b,b).

The nine-stage peaking cell [1] switching pattern 2207 for the cell 2101-1 with functionality of (−, −, −,b,b,b, −, −,−) may be modified to provide a fifteen-stage peaking cell [2] switching pattern 2247 for cell [2] of (5 applications of −, 3 applications of b (until the cell [b] achieves its peak voltage)) followed by (2 more applications of b, 5 applications of −).

FIG. 22M-4A: Circuit [Mn], Having Cell [m] with 2 Non-Dissipative Elements

The switching sequence methodology 2270 of a driving circuit [mn] having a two-non-dissipative element cell [m] electrically connected to the voltage source of the driving circuit and a one-non-dissipative element cell [n] electrically connected to the output terminal of the driving circuit is shown in FIGS. 22M-4A, 22M-4B.

For the cell [n], the methodology 2270 mirrors the methodology 2200 in having:
an initiating cell [n] phase 2272-1 identical to the initiating cell [2] phase 2212-1 of the methodology 2200 and having an initiating cell [n] switching pattern 2202-1 that is identical to the initiating cell [2] switching pattern 2202-1 for the initiating cell [2] phase 2212-1;
an executing cell [n] phase 2273-1 similar to the executing cell [2] phase 2213-1 of the methodology 2200 and having an executing cell [n] switching pattern 2203-1 that is identical to the executing cell [2] switching pattern 2203-1 for the executing cell [2] phase 2213-1;
a peaking cell [n] phase 2274 identical to the peaking cell [2] phase 2214 of the methodology 2200 and having the peaking cell [n] switching pattern 2204 that is identical to the peaking cell [2] switching pattern 2204 for the peaking cell [2] phase 2214,
a reverse executing cell [n] phase 2273-2 similar to the reverse executing cell [2] phase 2213-2 of the methodology 2200 and having a reverse executing cell [n] switching pattern 2203-2 that is identical to the reverse executing cell [2] switching pattern 2203-2 for the executing cell [2] phase 2213-2; and
a reverse initiating cell [n] phase 2272-2 identical to the reverse initiating cell [2] phase 2212-2 of the methodology 2200 and having a reverse initiating cell [n] switching pattern 2202-2 that is identical to the reverse initiating cell [2] switching pattern 2202-2 for the reverse initiating cell [2] phase 2212-2; for the cell [n]; and

For the cell [m], the methodology 2270 mirrors the methodology 2200 in having:
an initiating cell [m] phase 2275-1 similar to the initiating cell [1] phase 2215-1 of the methodology 2200 and having an initiating cell [m] switching pattern 2248-1 that is similar to the initiating cell [1] switching pattern 2205-1 for the initiating cell [1] phase 2215-1 in that the switching patterns 2248-1, 2205-1 both apply switch activations that increase the output voltage of their respective cells from bypass and in that the patterns 2248-1, 2205-1 both maintain their sets of switch activations for the duration of the cell switching pattern being applied to the adjacent, downstream cell in their respective circuits;
a peaking cell [m] phase 2277 similar to the peaking cell [1] phase 2217 of the methodology 2200 and having the peaking cell [m] switching pattern 2249 that is similar to the peaking cell [1] switching pattern 2207 for the peaking cell [1] phase 2217 in that the switching patterns 2249, 2207 both apply switch activations that increase the output voltage of their respective cells from a minimum cell voltage to a peak cell voltage and back to a minimum voltage and in that patterns 2249, 2207 both maintain their sets of switch activations for the duration of the cell switching pattern being applied to the adjacent, downstream cell in their respective circuits; and
a reverse initiating cell [m] phase 2275-2 similar to the reverse initiating cell [1] phase 2215-2 of the methodology 2200 and having a reverse initiating cell [m] switching pattern 2248-2 that is similar to the reverse initiating cell [1] switching pattern 2205-2 for the reverse initiating cell [1] phase 2215-2 in that the stages of both switching patterns 2248-2, 2205-2 are applied to their respective cells in reverse order from the switching patterns 2248-1, 2205-1, respectively.

Further, the switch closing and resultant output voltages of Stages 2271(1) through 2271(5) and 2271(12) through 2271(16) of the methodology 2270 mirror the switch closing and resultant voltage outputs of Stages 2201(1) through 2201(5) and 2201(6) through 2201(10), respectively, of the methodology 2200.

The Stages 2271(6) through 2271(11) have been added to the methodology 2270 to allow activation of the switch sets (SW[0], SW[3]) and (SW[1], SW[4]) in cell [m] so that the voltage storage capacity of both of the non-dissipative elements in the cell [m] may contribute to the operation of the driving circuit [mn].

To accommodate both of the non-dissipative elements of the cell [m], the five-stage initiating cell [1] switching pattern 2205-1 for the cell 2101-1 may be modified to provide an eight-stage initiating cell [m] switching pattern 2248-1 with functionality of (b,b,+,+,+,2+,2+,2+) for the two-non-dissipative element driver cell [m]. The activation of the switch set (SW[0], SW[3]) of cell [m] in switching pattern 2248-1 provides the voltage storage capacity of both of its non-dissipative elements, thus increasing the output voltage of the cell [m], when the voltage storage capacity of both cells are V[m], to 2V[m]. By extension, the five-stage combination of a reverse initiating cell [1] switching pattern 2205-2 and a first stage of an initiating cell [1] switching pattern 2205-1 for the cell 2101-1 may be modified to provide an eight-stage combination of a reverse initiating cell [m] switching pattern 2248-2 and a first stage of an initiating cell [m] switching pattern 2248-1 for cell [m] with functionality of (2+,2+,2+,+,+,+,b,b) for the two-non-dissipative element driver cell [m].

The nine-stage peaking cell [1] switching pattern 2207 with (−, −, −,b,b,b, −, −, −) functionality may be modified to provide a fifteen-stage peaking cell [m] switching pattern 2249 with functionality of (2−,2−,2−,−,−,−,b,b,b,−,−,−,2−,2−,2−) for the 2-non-dissipative element driver cell [m]. The activation of the switch set (SW[1], SW[4]) of cell [m] reduces the input voltage of cell [m] by the voltage storage capacity of both non-dissipative elements of the cell [m], thus reducing the output voltage of the cell [m], when the voltage storage capacity of both cells are V[m], to V_{DD[mn]}−2V[m].

FIGS. 22M-5A1, 22M-5A2: Driving Circuit [mnp], Cell [m], [n] with Two Non-Dissipative Elements, Cell [p] with Three Non-Dissipative Elements

FIGS. 22M-5A1, 22M-5A2 shows the switching sequence methodology 2280 of a driving circuit [mnp] having a two-non-dissipative element cell [m] electrically connected to the voltage source of the driving circuit, a three-non-dissipative element cell [p] electrically connected to the output terminal of the driving circuit, and a two-non-dissipative element cell [n] electrically connected between cell [m] and cell [p]. FIGS. 22M-5A1, 22M-5A2 show the Stages 2281(z), where 1≤z≤350.

The methodology 2280 mirrors the methodology 2220, shown in FIGS. 22M-2A1(A1)-22M-2A2, which is also arranged to control a three-cell driving circuit [wxy]. For the cell [p], the methodology 2280 has:
an initiating cell [p] phase 2292-1, an executing [p] phase 2293-1, a peaking cell [p] phase 2294, a reverse executing cell [p] phase 2293-2, and a reverse initiating cell [p] phase 2292-2 that are identical in their order and, except for the number of stages therein, switching patterns to the initiating cell [y] phase 2232-1, executing [y] phase 2233-1, peaking cell [y] phase 2234, reverse executing cell [y] phase 2233-2, and reverse initiating cell [y] phase 2232-2, respectively, of the methodology 2220;
for the cell [n], an initiating cell [n] phase 2295-1, an executing cell [n] phase 2296-1, a peaking cell [n] phase 2297, a reverse executing cell [n] phase 2296-2, and a reverse initiating cell [n] phase 2295-2 that are identical in their order and, except for the number of stages therein, switching patterns to the initiating cell [x] phase 2235-1, executing cell [x] phase 2236-1, peaking cell [x] phase 2237, reverse executing cell [x] phase 2236-2, and reverse initiating cell [x] phase 2235-2, respectively, of the methodology 2220.
for the cell [m], an initiating cell [m] phase 2298-1, a peaking cell [m] phase 2299, and a reverse initiating cell [m] phase 2298-2 that are identical in their order and, except for the number of stages therein, switching patterns to the initiating cell [w] phase 2238-1, a peaking cell [w] phase 2239, and a reverse initiating cell [w] phase 2238-2, respectively, of the methodology 2220.

In addition, the switching patterns for cells [m], [n] in the methodology 2280 are similar to their counterpart switching patterns in their respective phases for cells [w], [x] in the methodology 2220 in that the switching patterns maintain their sets of switch activations for the duration of the cell switching patterns being applied to the adjacent, downstream cell in their respective circuits.

The switching sequence methodology 2280 is presented here to illustrate how the switching patterns disclosed herein may be modified to accommodate driving circuits created with any number of driver cells, each of which may be created with any number of non-dissipative elements.

Turning first to cell [p], which is a last cell in the multi-cell circuit and has three non-dissipative elements:
The two-stage initiating cell [y] switching pattern 2202-1 of (b,+) functionality for the initiating cell [y] phase 2232-1 in the methodology 2220 for the cell [y] may be modified to provide a four-stage initiating cell [p] switching pattern 2282-1 with a functionality of (b,+,2+,3+) in the methodology 2280 for the cell [p]. By extension, the two-stage combination of a reverse initiating cell [y] switching pattern 2202-2 and a first stage of an initiating cell [y] switching pattern 2202-1 of (+,b) functionality for the reverse initiating cell [y] phase 2232-2 in the methodology 2220 may be modified to provide the four-stage combination of a reverse initiating cell [p] switching pattern 2282-2 and a first stage of an initiating cell [p] switching pattern 2282-1 of (3+,2+,+,b) functionality in the methodology 2280 for the cell [p].
The three-stage executing cell [y] switching pattern 2203-1 of (“−,b,+) functionality for the executing cell [y] phase 2233-1 in the methodology 2220 for the cell [y] may be modified to provide a seven-stage executing cell [p] switching pattern 2283-1 of (3−,2−,−,b,+,2+,3+) functionality for the methodology 2280 for the cell [p]. By extension, the three-stage reverse executing switching pattern 2203-2 of (+,b,−) functionality for the reverse executing cell [y] phase 2233-2 in the methodology 2220 may be modified to provide the seven-stage reverse executing cell [p] switching pattern 2283-2 of (3+,2+,+,b,−,2−,3−) functionality for the methodology 2280 for the cell [p].
The three stage peaking cell [y] switching pattern 2204 of (−,b,−) functionality for the peaking cell [y] phase 2234 in the methodology 2220 for the cell [y] may be modified to provide a seven-stage peaking cell [p] switching pattern 2284 of (3−,2−,−,b,−,2−,3−) functionality for the methodology 2280 for the cell [p].

Turning to cell [n], which is a two non-dissipative element driver cell upstream and adjacent to a last cell with three non-dissipative elements:
The five-stage initiating cell [x] switching pattern 2205-1 of (b,b,+,+,+) functionality for the initiating cell [x] phase 2235-1 in the methodology 2220 for the cell [x] may be modified to provide an eighteen-stage initiating cell [n] switching pattern 2285-1 with the functionality of (4 stages of b, 7 stages of +, and 7 stages of 2+) for the cell [n]. By extension, the five-stage combination of a reverse initiating cell [x] switching pattern 2205-2 and a first stage of an initiating cell [x] switching pattern 2205-1 with functionality of (+,+,+,b,b) for the reverse initiating cell [x] phase 2235-2 of the methodology 2220 may be modified to provide the eighteen-stage combination of a reverse initiating cell [n] switching pattern 2285-2 and a first stage of an initiating cell [n] switching pattern 2285-1 with functionality of (7 stages of 2+, 7 stages of +, 4 stages of b) in the methodology 2280 for the cell [n].
The nine-stage executing cell [x] switching pattern 2226-1 with a functionality of (3 stages of −, 3 stages of b, and 3 stages of +) for the cell [x] in the methodology 2220 may be modified to provide a 35-stage executing cell [n] switching pattern 2286-1 with a functionality of (7 stages of 2−, 7 stages of −, 7 stages of bypass, 7 stages of +, and 7 stages of 2+) for a cell [n]. By extension, the nine-stage reverse executing cell [x] switching pattern 2226-2 with a functionality of (+,+,+,b,b,b,−,−,−) of the methodology 2220 may be modified to provide the 35-stage reverse executing cell [n] switching pattern 2286-2 with functionality of (7 stages of 2+, 7 stages of +, 7 stages of b, 7 stages of −, and 7 stages of 2−) in the methodology 2280 for the cell [n].
The nine-stage peaking cell [x] switching pattern 2207 with a functionality of (−, −, −,b,b,b, −, −,−) for the peaking cell [x] phase 2237 in the methodology 2220 for the cell [x] may be modified to provide a 35-stage peaking cell [n] switching pattern 2287 with a functionality of (7 stages of 2−, 7 stages of −, 7 stages of bypass, 7 stages of −, and 7 stages of 2−) in the methodology 2280 for the cell [n].

Turning to cell [m], which is a two non-dissipative element first cell in a three-driver cell driving circuit with the second cell having two non-dissipative elements and the third and last cell having three non-dissipative elements:
The 14-stage initiating cell [w] switching pattern 2228-1 with a functionality of (5 stages of b, 9 stages of +) for the initiating cell [w] phase 2238-1 in the methodology 2220 for the cell [w] may be modified to provide an 88-stage initiating cell [m] switching pattern 2288-1 with functionality of (18 stages of b, 35 stages of +, and 35 stages of 2+) for the methodology 2280 for the cell [m]. By extension, the 14-stage combination of a reverse initiating cell [w] switching pattern 2228-2 and a first stage of an initiating cell [w] switching pattern 2228-1 with a functionality of (9 stages of +, 5 stages of b) for the reverse initiating cell [w] phase 2238-2 in the methodology 2220 may be modified to provide the 88-stage combination of a reverse initiating cell [m] switching pattern 2288-2 and a first stage of an initiating cell [m] switching pattern 2288-1 with functionality of (35 stages of 2+, 35 stages of +, and 18 stages of b) for the methodology 2280 for the cell [m]; and
The 27-stage peaking cell [w] switching pattern 2229 with a functionality of (9 stages of −, 9 stages of b, 9 stages of −) of the peaking cell [w] phase 2239 in the methodology 2220 for the cell [w] may be modified to provide a 175-stage peaking cell [m] switching pattern 2289 with functionality of (35 stages of 2−, 35 stages of −, 35 stages of b, 35 stages of −, 35 stages of 2−) for the methodology 2280 for the cell [m].

A comparison of the methodologies presented herein shows, for the i-th cell of a K-cell driving circuit, that:
the initiating cell [i] switching pattern and the peaking cell [i] switching pattern have the same number of stages when the circuit is operated repeatedly:
   when the i-th cell is the last cell and the driving circuit is arranged to operate repeatedly through multiple driving cycles, with the number of stages in the initiating and peaking cell [i] switching patterns being twice the number of non-dissipative elements in the i^{th} cell plus 1 (when the driving circuit is arranged to cease operation after only one driving cycle, the number of stages in the initiating and peaking pattern for the i^{th} cell is the number of non-dissipative elements in the i^{th} cell+1); and
   when the i-th cell is not the last cell and the i-th cell has n non-dissipative elements, the number of stages in the initiating and peaking cell [i] switching patterns is equal to the number of stages in one application of the initiating or peaking cell [i+1] switching pattern plus the number of stages in n applications of the executing cell [i+1] switching pattern; and
when the i-th cell has an executing cell [i] switching pattern (i.e., is not the first cell), the executing cell [i] switching pattern has the same number of stages as twice the number of non-dissipative elements in the i-th cell plus one, multiplied by twice the number of non-dissipative elements in the (i+1)-th cell plus one.

In the circuit [mnp] shown in FIG. 22M-5A1, 22M-5A2, in which the cell [n] has 2 non-dissipative elements and the cell [p] has 3 non-dissipative elements, the executing cell [n] switching pattern 2286-1 has (2n[i]+1)(2n[i+1]+1) stages, with n[i]=2, and n[i+1]=3; and the executing cell [p] switching pattern 2283-1, has (2n[i]+1) stages, with nᵢ=3.

In the general embodiment of a K-cell driving circuit, for a cell [i], 2≤i≤K, the cell [i] has an executing switching pattern and nᵢ non-dissipative elements and the cell [i+1] has n[i+1] non-dissipative elements, and the executing cell [i] switching pattern has f(i−1) stages, with:

$$\begin{matrix}f ( i ) = N ( K ) / h ( i ) \\ = ( 2 n [ i + 1 ] + 1 ) ( 2 n [ i + 2 ] + 1 ) \text{…} ( 2 n [ K ] + 1 ) \\ f ( i - 1 ) = ( 2 n [ i ] + 1 ) ( 2 n [ i + 1 ] + 1 ) ( 2 n [ i + 2 ] + 1 ) … ( 2 n [ K ] + 1 ) \\ = ( 2 \cdot n [ i ] + 1 ) \cdot f ( i ) ; in which i ranges from 2 to K\end{matrix} .$$

It may be seen that f(i) is the number of combinations of activation of switches of the remaining cells (e.g. cell [i+1], cell [i+2], . . . , cell [K−1], and cell [K] in an output voltage driving cycle for a K-cell driving circuit).

### 8.3. FIGS. 23A-23B: Driving Circuit Generalized as to Number of Cells and Non-Dissipative Elements

While FIG. 21 shows an exemplary embodiment of a two-cell non-dissipative element-enabled capacitive element driving circuit 2100 in which the two driver cells, each having one non-dissipative element, are connected in series, FIGS. 23A, 23B illustrate a generalized embodiment of a non-dissipative element-enabled capacitive element driving circuit 2300 in which K driver cells are connected in series,
with each driver cell 2301-i (i being a positive integer and 1≤i≤K) having a selected number n[i] of non-dissipative elements;
with N being the largest number of non-dissipative elements in a cell in the driving circuit 2300 and with n[i] being a positive integer and 1≤n[i]≤N, and
with j identifying the j-th non-dissipative element in driver cell 2301-i, and with j being a positive integer and 1≤j≤n[i]).

Accordingly, the circuit 2100 is an instantiation of the circuit 2300, with K=2; and the cell 2000 is an instantiation of the cell 2301-i, with n[i]=n. As with the capacitive element driving circuit 2100, the capacitive element driving circuit 2300 may have the voltage source 2320 (also known as the voltage source V_{DD23}) for supplying a voltage of a selected value as a component of the capacitive element driving circuit 2300, but in other embodiments, the voltage source may be a unit separate from and electronically attachable to the capacitive driving circuit of the capacitive element driving circuit 2300. Also, as with the capacitive element 2130, the capacitive element 2330 may be a unit separate from and electronically attachable to the capacitive driving circuit of the capacitive element driving circuit 2300; in other embodiments, it may be a component of the driving circuit 2300.

Referring to FIG. 23A, the driver cells from 2301-1 to 2301-K may be similar in design to the driver cell 2000 of FIG. 20, with its n non-dissipative elements. In certain embodiments, all of the cells may have the same number of non-dissipative elements, and in other embodiments, at least one of the cells may have a different number of non-dissipative elements. Additionally, in an illustrative but not necessarily preferred embodiment, the non-dissipative elements in one or more cells may be of the same type, such as storage capacitors. In other embodiments, the non-dissipative elements in one or more driver cells may be of different types. Further, in this embodiment of FIG. 23A, for convenience of calculation, the non-dissipative elements are assumed to have identical capacitances, but it is to be understood that it will be the choice of designer to select the voltage storage capacities of any of the non-dissipative elements in any driver cell of driving circuit.

As shown in FIGS. 23A and 23B, and with reference to FIGS. 20 and 21, the driver cells 2301-1, 2301-2, . . . , 2301-K are electrically connected to the voltage source V_{DD23} and the capacitive element 2330, respectively, in the manner disclosed for the cells 2101-1, 2101-2:
with the positive terminal 2326 of the voltage source V_{DD23} electrically connected to the input terminal 2311-1 of the cell 2301-1;
with the negative terminal 2328 of the voltage source V_{DD23} electrically connected to the input terminal 2313-1 of the cell 2301-1;
with an output terminal 2304-1 of the cell 2301-1 electrically connected between a common node (shown in FIG. 22A as common node 2114) of the switches inclusively between SW[1] and SW[n[1]+1] of the cell 2301-1 and a common node 2315-2 of the input terminals 2311-2, 2313-2 of the cell 2301-2;
with the input terminals 2311-K, 2313-K of the cell 2301-K electrically connected through a common node 2315-K to the output terminal 2304-(K−1) (shown as terminal 2304-i in FIG. 23B) of a cell 2301-(K−1) (shown as cell 2301-i in FIG. 23B);
with the input terminals 2311-K, 2313-K of the cell 2301-K also electrically connected to the switches SW[n[K]+2], SW[0] (shown in FIG. 23B as SW_{23[n[i]+2]}, SW_{23[0]}), respectively, of the cell 2301-K; and
with the input terminal 2332 of the capacitive element 2330 (e.g. C_{O23}) electrically connected to the output terminal 2304-K of the cell 2301-K.

As shown in FIG. 23B, the cell 2301-i (for 2≤i≤(K−1), and for 1≤j≤n[i]) has:
input terminals 2311-i, 2313-i electrically connected to the switches SW_{23[n[,]+2]}, SW_{23[0]}, respectively, of the cell 2301-i;
the input terminals 2311-i, 2313-i connected through a common node 2315-i to a terminal 2304-(i−1) of a driver cell 2301-(i−1), and
an output terminal 2304-i electrically connected between a common node 2314-i of the switches inclusively between switches SW_{23[1]} and SW_{23[n[i]+1]} of the cell 2301-i and a common node 2315-(i+1) of the input terminals 2311-(i+1), 2313-(i+1) (not shown) of the cell 2301-(i+1) downstream and adjacent to the cell 2301-i.

The driving circuit 2300 has or is electrically connected via a path system to a controller 2360, which is arranged to provide control signals to signal the capacitive element driving circuit 2300 to start, operate the phases of and switching patterns in, and stop a switching sequence methodology. The switching controller 2360 controls the activation and deactivation of the switches in the K driver cells to drive the circuit 2300 through a V_{O23} driving cycle, using a set of stages that may be implemented in a sequencing methodology having a plurality of phases, with the methodology defined to ensure the average value of voltage of the storage capacitors remains unchanged over time.

### 8.3.1. Switching Sequence Stages in a Complete Voltage Driving Cycle

The driving circuit 2300 may be operated as the driving circuit 2100, with phases and switching patterns of opening and closing switches in which driving circuit voltage output is incremented (or decremented) in a selected step-wise manner intended to release voltage from the non-dissipative elements of one or more selected cells (non-dissipative element by non-dissipative element) while selectively preventing other cells from contributing voltage to the driving circuit output or allowing other cells access to the driving circuit's supply voltage to increase the driving circuit output. The methodology defines a circuit control process for producing step-wise changes provided by a multi-cell driving circuit by allowing an activated driver cell [i] to provide a selected amount of voltage to a cell [i+1], to maintain the provided voltage while a cell [i+1] produces a step-wise change in its voltage production; and, once the output voltage of the activated driver cell [i+1] reaches a maximum level (or minimum level, when the incremental change is a voltage decrease) available from its non-dissipative element(s), to change the selected amount of voltage to be provided to the cell [i+1], in order to continue the step-wise change of voltage releasable from the driving circuit.

In the following discussion of the cell methodologies for driving a K-cell circuit through a complete diving cycle, reference will be made to a “first cell” and a “last cell,” which will be defined in the rest of the described embodiments with the cell in the circuit having one input terminal electrically connected to the positive terminal of a voltage source for the circuit and another input terminal electrically connected to the negative terminal of the voltage source for the circuit known as the first cell (or cell [1]), and the cell in the circuit having its output terminal constitute or electrically connected to the output terminal of the circuit known as the last cell (or cell [K]).

For a cell [i] of a K-cell driving circuit with n[i] non-dissipative elements, the methodology 2400 may begin with an initiating cell [i] phase having an initiating cell [i] switching pattern that
(1) bypasses the cell [i] to allow the input voltage of the cell [i] reach its output voltage, and then
(2) incrementally increases the output voltage of the cell [i] by multiples of v[i], starting with an increase of V(i) to the cell [i] output voltage at the beginning of the initiating cell [i] phase and, by the end of the incremental increases in the initiating cell [i] phase, achieving an overall increase of n[i]V(i) to the cell [i] output voltage since the start of the initiating cell [i] phase.
The bypassing of the cell [i] may be accomplished by selectively activating a set of switches of the cell [i] that provides the input voltage of cell [i] as its output voltage, with the bypass maintained for the duration of one stage in the methodology when the cell [i] is the last cell in the circuit, or otherwise for the duration of an application of the initiating cell [i+1] switching pattern on the cell [i+1].

When the cell [i] is the first cell of the K-cell circuit, the bypass operation in the initiating cell [i] switching pattern constitutes a grounding of the output of the first cell, and may be achieved by activating the first and second switches of the cell [i] (switch set (SW[0], SW[1])) to electrically connect the negative terminal of the voltage source to the output terminal of the cell[i]. The grounding occurs because switch SW[0] connects the negative terminal of the voltage source to the output terminal of the cell[i], and the switch SW[1] is the one switch in the set of the n[i] switches in the cell 2301-1 electrically connectable to the common node to the terminal 2314-1 that is also electrically connectable to the switch SW[0] without a non-dissipative element intervening therebetween. Accordingly, closing the switch set (SW[0], SW[1]) electrically connects the negative terminal of the voltage source to the output terminal of the cell[i].

When cell [i] is any other cell in the K-cell circuit, the bypass operation in the initiating cell [i] switching pattern may be achieved by activating either the switch set (SW[0], SW[1]) or the switch set (SW[n[i]+2], SW [n[i]+1]), which is the set of the last and second last switches of the cell [i]. Both of the switches SW[0], SW[n[i]+2] are electrically connectable to the output of the cell 2301-(i−1), and the switches SW[1], SW[n[i]+1] are the two switches in the set of the n[i] switches in the cell 2301-i electrically connectable to the common node to the terminal 2314-i that is also electrically connectable, through one of the switch sets (SW[0], SW[1]) or (SW[n[i]+2], SW[n[i]+1]), to the cell [i] input without a non-dissipative element intervening therebetween. Accordingly, closing the switch set (SW[0], SW[1]) or (SW[n[i]+2], SW[n[i]+1]), electrically connects the input of the cell to the output of cell [i].
The incremental increase in the cell [1]'s output voltage may be achieved by selectively activating the sets of switches of the cell [i] that increase the output voltage of the cell [i],
   with the switch set activations performed in an order to produce increasing amounts of output voltage increase,
   with the initiating cell [i] switching pattern ending when the switch set activation resulting in the highest amount of cell [i] output voltage increase has been completed, and
   with a switch set activation to implement an increase in the cell [i] input voltage by one multiple of V(i) maintained on the cell [i] for the duration of one stage in the methodology when the cell [i] is the last cell in the circuit, or otherwise for the duration of one application of an executing cell [i+1] switching pattern on the cell [i+1].

The methodology 2400 for the cell [i] may proceed to an executing cell [i] phase upon completion of the initiating cell [i] phase except when the cell [i] is the first cell in a multi-cell circuit. The executing cell [i] phase repeats an executing cell [i] switching pattern that
(1) incrementally reduces the output voltage of the cell [i] by multiples of V(i) (starting with a reduction by n[i]V(i) in the cell [i] output voltage at the beginning of the executing cell [i] switching pattern and, by the end of the incremental reductions, achieving an overall reduction of V(i) in the cell [i] output voltage since the start of the executing cell [i] switching pattern); then
(2) bypasses the cell [i] to allow the input voltage of the cell [i] reach its output voltage, and then
(3) incrementally increases the output voltage of the cell [i] by multiples of V[i], starting with an increase of V(i) to the cell [i] output voltage at the beginning of the incremental increases and, by the end of the executing cell [i] phase switching pattern, achieving an overall increase of n[i]V(i) to the cell [i] output voltage since the start of the incremental increases.
The incremental reductions in the cell [1]'s output voltage may be achieved by selectively activating the sets of switches of the cell [i] that reduce the output voltage of the cell [i],
   with the switch set activations performed in an order to produce decreasing amounts of output voltage reductions,
   with the incremental reductions ending upon the completion of the switch set activation resulting in V[i] (the lowest amount of cell [i] output voltage reduction), and
   with a switch set activation to implement a reduction in the cell [i] input voltage by one multiple of V(i) maintained on the cell [i] for the duration of one stage in the methodology when the cell [i] is the last cell in the circuit, or otherwise for the duration of one application of an executing cell [i+1] pattern on the cell [i+1].
The bypassing of the cell [i] in an executing cell [i] switching pattern may be accomplished using the method described above in the initiating cell [i] switching pattern for bypassing operations on cells that are not the first cell in the cell [i], except that the bypass in the executing cell [i] switching pattern may be maintained for the duration of one stage in the methodology when the cell [i] is the last cell in the circuit, or otherwise for the duration of one application of the executing cell [i+1] switching pattern on the cell [i+1].
The incremental increases of the cell [i]'s output voltage in an executing cell [i] switching pattern, including the order of cell activations and the duration of an incremental increase operation, may be achieved using the methods described above in the initiating cell [i] switching pattern for incrementally increasing the cell [i]'s output voltage.

When the cell [i] is the last cell and n is the number of non-dissipative element of last cell, the executing cell [i] switching pattern is applied repeatedly until the (n+2)th last stage. When the cell [i] is not the last cell and n is the number of non-dissipative element of cell [i], the executing cell [i] switching pattern is applied repeatedly to the cell [i] until the completion of the (n+1)th last application of the executing cell [i+1] switching pattern on the cell [i+1]. The methodology 2400 for the cell [i] may proceed to a peaking cell [i] phase after the completion of the initiating cell [i] phase when the cell [i] is the first cell in the multi-cell circuit, or after the completion of the executing cell [i] phase when the cell [i] is any other cell in the multi-cell circuit. The peaking cell [i] phase may have a peaking cell [i] switching pattern that:
(1) incrementally reduces the cell [i] input voltage by multiples of V(i) (starting with a reduction by nV(i) at the beginning of the peaking cell [i] phase and, by the end of the incremental reductions, ending with an overall reduction of V(i) in the cell [i] output voltage since the start of the peaking cell [i] switching pattern);
(2) bypasses the cell [i] to allow the output voltage of the cell [i] to reach its input voltage; and
(3) performs a second set of incremental reductions to the cell [i] output voltage by multiples of V(i) (starting with a reduction by V(i) at the beginning of the second set of incremental reductions in the peaking cell [i] phase and, by the end of the incremental reductions, ending with an overall reduction of n[i]V(i) in the cell [i] output voltage since the start of the incremental reductions):
The first set of incremental reductions in the cell [i]'s output voltage in a peaking cell [i] switching pattern, including the order of cell activations and the duration of an incremental reduction operation, may be achieved using the methods described above in the executing cell [i] switching pattern for incrementally reducing the cell [i]'s output voltage.
The bypassing of the cell [i] in a peaking cell [i] switching pattern when the cell [i] is not the first cell in the circuit may be accomplished using the method described above in the initiating cell [i] switching pattern for bypassing operations on cells that are not the first cell in the cell [i], except that the bypass in the peaking cell [i] switching pattern may be maintained for the duration of one stage in the methodology when the cell [i] is the last cell in the circuit, or otherwise for the duration of one application of the peaking cell [i+1] switching pattern on the cell [i+1].
When the cell [i] is the first cell of a K-cell circuit, the bypass operation in the peaking cell [i] switching pattern may be achieved by activating the switch set (SW[n[i]+2], SW[n[i]+1]) to electrically connect the positive terminal of the voltage source to the output terminal of the cell[i], thus providing the supply voltage of the circuit's voltage source to the input of the cell [i+1]. The supply voltage bypass operation in the peaking cell [i] switching pattern may be achieved because switch SW[n[i]+2] is electrically connected to the positive terminal of the voltage source of the circuit 2300, and switch SW[n[i]+1] is the one switch in the set of the n[i] switches in the cell 2301-1 electrically connected to the common node to the terminal 2314-1 that is also electrically connected to the switch SW[n[i]+2] without a non-dissipative element intervening therebetween. Accordingly, closing the switch set (SW[n[i]+2], SW[n[i]+1]) electrically connects the positive terminal of the voltage source to the output terminal of the cell[i].
The second set of incremental reductions may be achieved by selectively activating the sets of switches of the cell [i] that reduce the output voltage of the cell [i],
   with the switch activations being performed in an order to produce increasing amounts of output voltage reductions,
   with the incremental reductions ending upon the completion of the switch set activation resulting in n[i]V[i] (the highest amount of cell [i] output voltage reduction), and
   with a switch set activation to implement a reduction in the cell [i] input voltage by one multiple of V(i) maintained on the cell [i] for the duration of one stage in the methodology when the cell [i] is the last cell in the circuit, or otherwise for the duration of one application of a reverse executing cell [i+1] switching pattern on the cell [i+1].

The methodology 2400 for a cell [i] may proceed to a reverse executing cell [i] phase upon completion of the peaking cell [i] phase except for when the cell [i] is the first cell in a multi-cell circuit. The reverse executing cell [i] phase may repeat a reverse executing cell [i] switching pattern that
(1) incrementally increases the output voltage of the cell [i] by multiples of V(i) (starting with an increase of n[i]V(i) in the cell [i] output voltage at the beginning of the reverse executing cell [i] switching pattern and, by the end of the incremental increases, ending with an overall increase of V(i) in the cell [i] output voltage since the start of the reverse executing cell [i] switching pattern;
(2) then bypasses the cell [i] to allow the output voltage of the cell [i] to reach its output voltage; and then
(3) incrementally reduces the output voltage of the cell [i] by V(i), starting with a reduction by V(i) in the cell [i] output voltage at the beginning of the incremental reductions and, by the end of the incremental reductions, ending with a reduction of n[i]V(i) in the output voltage at the completion of the reverse executing cell [i] switching pattern.
The incremental increases in the cell [i]'s output voltage may be achieved by selectively activating the sets of switches of the cell [i] that increase the output voltage of the cell [i],
   with the switch set activations performed in an order to produce decreasing amounts of output voltage increases,
   with the incremental increase ending when the switch set activation resulting in the lowest amount of cell [i] output voltage increase has been completed, and
   with a switch set activation maintained on the cell [i] for the duration of one stage in the methodology when cell [i] is the last cell in the circuit, or otherwise for the duration of one application of a reverse executing cell [i+1] pattern on the cell [i+1].
The bypassing of the cell [i] in a reverse executing cell [i] switching pattern, including the duration of a bypass operation, may be accomplished using the method described above in the executing cell [i] switching pattern for bypassing cell [i].
The incremental reduction of the cell [i]'s output voltage in a reverse executing cell [i] switching pattern, including the order of cell activations and the duration of the incremental reduction operations, may be accomplished using the methods described above to achieve the second set of incremental reductions in the peaking cell [i] switching pattern for incrementally reducing the cell [i]'s output voltage.
When the cell [i] is the last cell and n is the number of non-dissipative element of last cell, the reverse executing cell [i] switching pattern is applied repeatedly until the (n+2)th last stage. When the cell [i] is not the last cell and n is the number of non-dissipative element of cell [i], the reverse executing cell [i] switching pattern is applied repeatedly to the cell [i] until the completion of the (n+1)^{th} last application of the executing cell [i+1] switching pattern on the cell [i+1].

A reverse initiating cell [i] phase may begin after the completion of the peaking cell [i] phase when the cell [i] is the first cell in the multi-cell circuit, or after the completion of the reverse executing cell [i] phase when the cell [i] is any other cell in the multi-cell circuit. A reverse initiating cell [i] phase has a reverse initiating cell [i] switching pattern that
(1) incrementally increases the output voltage of the cell [i] by multiples of V[i] (starting with an increase of n[i]V(i) in the cell [i] output voltage at the beginning of the reverse initiating cell [i] phase and, by the end of the incremental increases, ending with an overall increase of V(i) in the cell [i] output voltage since the start of the reverse initiating cell [i] phase; and
(2) then bypasses the cell [i], ending with the input voltage of the cell [i] being applied to the output terminal of the cell [i] at the completion of the reverse initiating cell [i] switching pattern.
The incremental increase in the cell [i]'s output voltage of the cell [i] in the reverse initiating cell [i] phase, including the order of cell activations and the duration of the incremental increase operations, may be achieved using the method described above to achieve the incremental increases in the executing cell [i] switching pattern.
The bypassing of the cell [i] in the reverse initiating cell [i] phase, including the duration of the bypassing, may be accomplished using the method described above to achieve the bypassing in the initiating cell [i] switching phase. As noted previously, in the first cell, the bypass operation electrically connects the negative terminal of the voltage source to the output terminal of the first cell, thus grounding the cell [i+1].

As with the operation of the driving circuit 2300, the incremental change in the voltage output is achieved by releasing the voltage capacity of a cell upon which a switch activation has been performed and increasing the overall voltage output through selective and sequential operation of non-dissipative elements in upstream cells, using selective opening and closing of switches at the terminals of the non-dissipative elements. It can be seen that the patterns of switch opening/closing and cell activation/bypassing that may be employed for simpler driving circuits to accomplish step-wise delivery of voltage outputs may be adapted to accomplish the step-wise delivery of voltage outputs for more complex driving circuits, with larger numbers of cells and non-dissipative elements.

The generalized driving circuit 2300 is arranged to allow each of the K driver cells in a driving circuit 2300 to have a number n[i] of non-dissipative elements (the number n not necessarily being equivalent in each cell). In total, in this illustrative but not necessarily preferred embodiment, one complete V_{O23} driving cycle may be accomplished in

$$2 \cdot {\prod }_{i = 1}^{K} [ 2 \cdot n [ i ] + 1 ] stages ,$$

where:
n[i] is the number of non-dissipative elements in the i-th driver cell in the driving circuit 2300; and
K is the number of driver cells in the driving circuit, with 1≤i≤K.

Using the earlier described embodiment of the basic two-cell driving circuit 2100 shown in FIGS. 21 and 22A-22J, with each cell having one non-dissipative element (K=2 and n[i]=1 for both driver cells), the number of stages in the switching sequence methodology 2200 may be calculated as:

$$\begin{matrix}2 \cdot {\prod }_{i = 1}^{K} [ 2 \cdot n [ i ] + 1 ] = 2 * \{ [ ( 2 * 1 ) + 1 ] * [ ( 2 * 1 ) + 1 ] \} \\ = 2 * ( 3 * 3 ) \\ = 18\end{matrix} .$$

Therefore, one complete V_{O21} driving cycle for the basic driving circuit 2100 is accomplished in 18 stages.

FIG. 22M-3A illustrates a switching sequence methodology 2260 for a two-cell driving circuit with a first driver cell having one non-dissipative element and a second cell having two non-dissipative elements. As illustrated in the chart in FIG. 22M-3A, K=2; n[1]=1; and n[2]=2, and the number of stages in the switching sequence methodology 2260 may be calculated as:

$$\begin{matrix}2 \cdot {\prod }_{i = 1}^{K} [ 2 \cdot n [ i ] + 1 ] = 2 * \{ [ ( 2 * 1 ) + 1 ] * [ ( 2 * 2 ) + 1 ] \} \\ = 2 * [ 3 * 5 ] \\ = 30\end{matrix} .$$

Therefore, one complete voltage driving cycle for driving circuit so defined is accomplished in 30 stages.

FIG. 22M-4A illustrates a switching sequence methodology 2270 for another two-cell driving circuit, with a first driver cell having two non-dissipative elements and a second cell having one non-dissipative element. As illustrated in the chart in FIG. 22M-4A, K=2; n[1]=2; and n[2] =1, and the number of stages in the switching sequence methodology 2270 may be calculated as:

$$\begin{matrix}2 \cdot {\prod }_{i = 1}^{K} [ 2 \cdot n [ i ] + 1 ] = 2 * \{ [ ( 2 * 2 ) + 1 ] * [ ( 2 * 1 ) + 1 ] \} \\ = 2 * [ 5 * 3 ] \\ = 30\end{matrix} .$$

Therefore, one complete voltage driving cycle for a 2-cell driving circuit having one driving cell with one non-dissipative storage element and another driving cell with two non-dissipative storage elements would encompass 30 stages, irrespective of the position of the driver cells relative to each other in the driving circuit.

FIGS. 22M-3A, 22M-4A show that certain multi-cell driving circuits having the same number of non-dissipative elements but in which the non-dissipative elements are distributed differently across the cells of the driving circuits (with the number of non-dissipative elements varying from cell to cell), may have the same overall number of stages despite the location of the cells in the driving circuit (whether or not a cell with more non-dissipative elements is positioned first, second, or last in the driving circuit), driving circuits having varying numbers of cells may still have the same number of stages, as long as the driving circuits share the same number of non-dissipative elements.

As an example, the multi-cell driving circuits [ab], [mn] of FIGS. 22M-3A, 22M-4A, respectively, each have two cells and three non-dissipative elements overall. The driving circuit [ab] has a first cell [2] with one non-dissipative element and four switches and a second cell [b] with two non-dissipative elements and five switches. The driving circuit [mn] has a first cell [m] with two non-dissipative elements and five switches and a second cell [n] with one non-dissipative element and four switches. The switching sequence methodologies for operation of circuits [ab], [mn] both have 30 stages:

On the other hand, other driving circuits having an identical number of non-dissipative elements overall may not have an identical number of stages in their switching sequence methodologies. As an example, the two-cell driving circuits [cd], [ef], [gh] each may have four non-dissipative elements overall, with:
A circuit [cd] having a first cell [c] with one non-dissipative element and a second cell [d] with three non-dissipative elements (with K=2; n[c]=1; and n[d]=3);
a circuit [ef] having a first cell [e] with three non-dissipative elements and a second cell [f] with one non-dissipative element (with K=2; n[e]=3; and n[f]=1);
a circuit [gh] having a first cell [g] and a second cell [h] each with two non-dissipative elements (with K=2; n[g]=2; and n[h]=2).

While the switching sequence methodologies for operation of circuits [cd], [ef] both have 42 stages for step-wise operation, with:

$$\begin{matrix}2 \cdot {\prod }_{i = 1}^{K} [ 2 \cdot n [ i ] + 1 ] = 2 * \{ [ ( 2 * 1 ) + 1 ] * [ ( 2 * 3 ) + 1 ] \} = 2 * \{ [ ( 2 * 3 ) + 1 ] * [ ( 2 * 1 ) + 1 ] \} = \\ = 2 * [ 3 * 7 ] = 2 * [ 7 * 3 ] = 42\end{matrix} ;$$

the switching sequence methodologies for operation of circuit [gh] has:

$$\begin{matrix}2 \cdot {\prod }_{i = 1}^{K} [ 2 \cdot n [ i ] + 1 ] = 2 * \{ [ ( 2 * 2 ) + 1 ] * [ ( 2 * 2 ) + 1 ] \} \\ = 2 * [ 5 * 5 ] = 50 stages for step - wise operation\end{matrix} .$$

Further, the switching sequence methodology for operation of a circuit [pqr], [stuv], both also having four non-dissipative elements. The switching sequence methodology for operation of the three-cell circuit [pqr], (with K=3; n[p]=1, n[q]=2; n[r]=1), has:

$$\begin{matrix}2 \cdot {\prod }_{i = 1}^{K} [ 2 \cdot n [ i ] + 1 ] = 2 * \{ [ ( 2 * 1 ) + 1 ] * [ ( 2 * 2 ) + 1 ] * [ ( 2 * 1 ) + 1 ] \} \\ = 2 * [ 3 * 5 * 3 ] = 90 stages for step - wise operation\end{matrix} ;$$

while the switching sequence methodology for operation of the four-cell circuit [stuv], with (K=4; n[s]=n[t]=n[u]=n[v]=1), has:

$$\begin{matrix}2 \cdot {\prod }_{i = 1}^{K} [ 2 \cdot n [ i ] + 1 ] = 2 * \{ [ ( 2 * 1 ) + 1 ] * [ ( 2 * 1 ) + 1 ] * [ ( 2 * 1 ) + 1 ] ] * [ ( 2 * 1 ) + 1 ] \} \\ = 2 * [ 3 * 3 * 3 * 3 ] = 162 stages for step - wise operation\end{matrix} .$$

Selection of the number of cells and non-dissipative elements in a driving circuit is at the choice of the driving circuit designer, depending on the desired operational and functional specifications.

To generalize, when all K driver cells of a driving circuit have the same number n of non-dissipative elements, n[1]=n[2]=n, and the number of stages in the switching sequence methodology 2400 may be calculated as:

$$\begin{matrix}2 \cdot {\prod }_{i = 1}^{K} [ 2 \cdot n [ i ] + 1 ] = 2 \cdot {\prod }_{i = 1}^{K} [ 2 n + 1 ] \\ = 2 * [ {( 2 n + 1 )}^{K} ]\end{matrix} .$$

Therefore, one complete voltage driving cycle for a K-cell driving circuit, each cell with the same number n of non-dissipative elements, would encompass 2*[(2n+1)^{K}] stages. When K=1 (as in the embodiment of circuit 700A in FIG. 7a),

$$\begin{matrix}2 \cdot {\prod }_{i = 1}^{K} [ 2 \cdot n [ i ] + 1 ] = 2 \cdot {\prod }_{i = 1}^{1} [ 2 n + 1 ] \\ = 2 ( 2 n + 1 ) \\ = 4 n + 2\end{matrix} .$$

Therefore, as confirmed in FIGS. 8A-8C, one complete voltage driving cycle for a driving circuit having one driver cell with n non-dissipative storage elements would encompass (4n+2) stages.

### 8.3.2. Voltage Levels During a Complete Voltage Driving Cycle

Returning to the driving circuit 2300, in one illustrative and not necessarily preferred embodiment, and for convenience, within each driver cell 2301-i, V_{CS23[x]}=V_{CS23[y]} for x≠y where both x and y are any integer from 1 to n[i]. When V_{CS23[i]}=V_{CS23[x]}, where x is any integer from 1 to n[i], V_{CS23[i]}, which is the voltage level at the driver cell 2301-i, may be expressed by equation (7), where i is any integer ranged from 1 to K:

$${V}_{CS 23 [ i ]} = {V}_{DD 23} / {\prod }_{j = 1}^{i} [ 2 \cdot n [ j ] + 1 ] \qquad ( 7 )$$

By setting i=K, the voltage of the storage capacitor at the K-th driver cell (e.g. V_{CS23[K]}) may be expressed by equation (8):

$${V}_{CS 23 [ K ]} = {V}_{DD 23} / {\prod }_{j = 1}^{K} [ 2 \cdot n [ i ] + 1 ] \qquad ( 8 )$$

Thus, V_{CS23[K]} represents a change of V_{O23} per stage over the 2·Πⱼ₌₁^{K}[2·n[j]+1] stages of one complete V_{O23} driving cycle of the driving circuit 2300. Therefore,
At a Stage 2401(1), V_{O23} is driven to the ground level (e.g. 0V).
At a Stage 2401(2), V_{O23} is driven to V_{CS23[K]}.
At a Stage 2401(3), V_{O23} is driven to (2·V_{CS23[K]}).
At a Stage 2401(4), V_{O23} is driven to (3·V_{CS23[K]}).

. . .
At a Stage 2401(r), where r=Πⱼ₌₁^{K}[2·n[j]+1], V_{O23} is driven to (V_{DD23}−V_{CS23[K]}).
At a Stage 2401(r), where r=Πⱼ₌₁^{K}[2·n[j]+1]+1, V_{O23} is driven to V_{DD23}.
At a Stage 2401(r), where r=Πⱼ₌₁^{K}[2·n[j]+1]+2, V_{O23} is driven to (V_{DD23}−V_{CS23[K]}).

. . .
At a Stage 2401(r), where r=2·Πⱼ₌₁^{K}[2·n[j]+1]−2, V_{O23} is driven to (3·V_{CS23[K]}).
At a Stage 2401(r), where r=2·Πⱼ₌₁^{K}[2·n[j]+1]−1, V_{O23} is driven to (2·V_{CS23[K]}).
At a Stage 2401(r), where r=2·Πⱼ₌₁^{K}[2·n[j]+1], V_{O23} is driven to V_{CS23[K]}, after which another V_{O23} driving cycle may be started by returning to the Stage 2401(1) described above.

It may be seen that:
From Stage 2401(2) to Stage 2401(r), where r=Πⱼ₌₁^{K}[2·n[j]+1], V_{O23} is driven from V_{CS23[K]} to V_{DD23}−V_{CS23[K]} with V_{CS23[K]} as the V_{O23} voltage change per stage.
From Stage 2401(r), where r=Πⱼ₌₁^{K}[2·n[j]+1]+2 to Stage 2401(r), where r=2·Πⱼ₌₁^{K}[2·n[j]+1], V_{O23} is driven from (V_{DD23}−V_{CS23[K]}) to V_{CS23[K]} with V_{CS23[K]} as the V_{O23} voltage change per stage.
Stage 2401(p) is identical in operation and result to Stage 2401(q) when

$$p + q = 2 \cdot {\prod }_{j = 1}^{K} [ 2 \cdot n [ j ] + 1 ] + 2 ,$$

p is any integer from 2 to Πⱼ₌₁^{K}[2·n[j]+1], and
g is any integer from Πⱼ₌₁^{K}[2·n[j]+1]+2 to 2·Πⱼ₌₁^{K}[2·n[j]+1].
For example,
   Stage 2401(2) is identical in operation and result to 2401(r), where r=2 f₁[2·n[j]+1]; and
   Stage 2401(r), where r=Πⱼ₌₁^{K}[2·n[j]+1], is identical in operation and result to Stage 2401(r), where Πⱼ₌₁^{K}[2·n[j]+1]+2.

It is to be understood that in this embodiment, V_{CS23[x]}=V_{CS23[y]}, but it is not necessary that the voltage capacities of each of the non-dissipative elements be identical. It will be the choice of the designer to select the voltage storage capacities of the non-dissipative elements in any driver cell of driving circuit and to define the switching sequence methodology to accomplish the desired driving cycle, in which voltage available at the driving circuit output is built and then reduced by step wise stages. As noted above, the number of stages (and so the number of steps) in the switching sequence methodology depends on the number of driver cells and the number of non-dissipative elements in the driving circuit. However, when the voltage capacities of each of the non-dissipative elements in the circuit are not identical, the amount of voltages released or stored in each of the stages (and the amount time spent at each stage) are not necessarily identical.

The energy dissipated on switches per stage may be calculated according to equation (9):

$$\frac{1}{2} {{C}_{O 23} ( \frac{{V}_{DD 23}}{{\prod }_{j = 1}^{K} [ 2 \cdot n [ j ] + 1 ]} )}^{2} = \frac{1}{{2 [ {\prod }_{j = 1}^{K} [ 2 \cdot n [ j ] + 1 ] ]}^{2}} {C}_{O 23} {{V}_{DD 23}}^{2} \qquad ( 9 )$$

As noted above, there are 2·Πⱼ₌₁^{K}[2·n[j]+1] stages per one complete voltage driving cycle, so the total energy dissipation from the circuit 2300 over the complete V_{O23} driving cycle, may be calculated according to equation (10):

$${E}_{t \_ circuit \_ 2300} = 2 \cdot {\prod }_{j = 1}^{K} [ 2 \cdot n [ j ] + 1 ] \times \frac{1}{{2 [ {\prod }_{j = 1}^{K} [ 2 \cdot n [ j ] + 1 ] ]}^{2}} {C}_{O 23} {{V}_{DD 23}}^{2} \qquad ( 10 )$$

$${E}_{t \_ circuit \_ 2300} = \frac{1}{{\prod }_{j = 1}^{K} [ 2 \cdot n [ j ] + 1 ]} {C}_{O 23} {{V}_{DD 23}}^{2} \qquad ( 11 )$$

In the classical driving scheme total energy dissipation of one complete V_{O} driving cycle E_{t_classic}=C_{O}V_{DD}². Thus, it can be seen that the circuit 2300, constructed with K capacitive element driver cells 2000, each driver cell with n storage capacitors, can reduce total energy dissipation per one V_{O23} driving cycle by Πⱼ₌₁^{K}[2·n[j]+1] times.

As an example, when a capacitive element driving circuit is constructed with K=3 capacitive element driver cells, each with n=1 storage capacitors (n[i]=1 for all i ranged from 1 to 3), total energy dissipation may be seen to be reduced per one V_{O} driving cycle by 27 times.

### 8.3.3. FIGS. 24A-24B3: Switching Sequence Methodology 2400

A switching controller 2360 controls the activation and deactivation of the switches in driver cells 2301-1, 2301-2, . . . , 2301-K to drive the circuit 2300 through the complete V_{O23} driving cycle using the above-identified stages, which results in a step-wise increase of the voltage V_{O23} to a peak voltage V_{DD23} (the voltage supplied by the voltage source 2320), and then a step-wise decrease of the voltage V_{O23} to ground.

The switching sequence methodology 2400 is one embodiment of the sequencing followed by the switching controller 2360, in which switches are activated in combinations within one complete V_{O23} driving cycle. In order to simplify the description of the stages and phases of the methodology 2400, the following parameters may be defined:

$$N ( K ) = {\prod }_{j = 1}^{K} [ 2 \cdot n [ j ] + 1 ] ] ;$$

$$h ( i ) = {\prod }_{l = 1}^{i} [ 2 \cdot n [ l ] + 1 ] ; and$$

$$f ( i ) = \frac{N ( K )}{h ( i )} ;$$

where i is any integer between 1 and K;
where K is the number of cells in the driving circuit;
where n[j], n[l] are the number of non-dissipative elements in a driver cell 2301-j, 2301-l, respectively;
where N(K) is half the number of stages of one complete V_{O23} driving cycle, with N(K)+1 being the stage in which the circuit and its constituent cells reach their peak voltages;
where h(i) is the number of combinations of switch activations that the first i cells in the multi-cell circuit 2300 (e.g., cell 2301-1, cell 2301-2, . . . , cell 2301-(i−1), and cell 2301-i) have contributed to one complete V_{O23} driving cycle;
where f(i) is the number of combinations of switch activations that the remaining cells, e.g. cell 2301-(i+1), cell 2301-(i+2), . . . , cell 2301-(K−1), and cell 2301-K, have contributed to one complete V_{O23} driving cycle.
   It may be seen that there are h(z−1)−1 executing cell [z] switching patterns in one executing cell [z] phase.

In addition, the following equalities may be used to simplify the description of the stages and phases of the methodology 2400:

$$g ( i ) = \frac{f ( i ) + 1}{2} ;$$

$$f ( i - 1 ) = ( 2 \cdot n [ i ] + 1 ) \cdot f ( i ) ; and$$

$$g ( i - 1 ) = n [ i ] \cdot f ( i ) + g ( i ) .$$

Assuming continuous operation of the driving circuit 2300 and including the number of switching sets in a reverse initiating switching pattern in the count of the number of switching sets, it can be seen that:
f(i) is the number of stages that a selected switch in cell [i] (other than the first and last switch in cell [i]) is closed in any cell [i] switching pattern;
f(i−1) is the number of stages in an executing cell [i] switching pattern;
g(i) is the number of stages in the portion of a reverse initiating cell [i+1] switching pattern that brings the multi-cell circuit output to ground; and
g(i) is also the number of stages in the portion of a peaking cell [i+1] pattern that brings the multi-cell circuit voltage output to its supply voltage, so that g(i−1) is the number of stages in the portion of a peaking cell [i] switching pattern that brings the multi-cell circuit voltage output to its supply voltage.

The charts shown in FIG. 24A to 24B-3 illustrate the switching sequence methodology 2400 in which switches are activated in combinations within one complete V_{O23} driving cycle.

### FIG. 24A: Switching Sequence Methodology 2400 for Cell 2301-1

FIG. 24A, showing the initiating cell [1] phase 2412[1]-1 and the peaking cell [1] phase 2414[1] for the first driver cell 2301-1 in the driving circuit 2300, illustrates the stages, phases, and switching patterns described below that control the (n[1]+3) switches in the first driver cell. FIGS. 24B-1, 24B-2, 24B-3 show the initiating cell [z] phase 2412[z]−1, the executing cell [z] phase 2413[z]−1, and the peaking cell [z] phase 2414[z], respectively, for one of the remainder of the driver cells in the driving circuit 2300 (generally, the cell 2301-z, where 2≤z≤K). FIG. 24B-1-24B-3 illustrate the stages, phases, and switching patterns that may be used to control the (n[z]+3) switches in the remainder of the K−1 driver cells (e.g. cell 2301-2, cell 2301-3, . . . , cell 2301-(K−1), and cell 2301-K) to drive the circuit to its peak voltage in a step-wise manner. The voltage to which V_{O23} at the capacitive element 2330 is driven during the selected stage are identified below.

The driving circuits associated described above and illustrated in FIGS. 22M-1A through 22M-5B may be viewed as instantiations of the generalized driving circuit 2300 in which the number K of cells in the driving circuit range from 1 to 4 and in which the number n of non-dissipative elements in a cell range from 1 to 3. The methodologies associated with the driving circuits illustrate how to drive the multi-cell driving circuits from ground to a peak voltage to ground in step-wise increments.

it may be understood that the phases, switching patterns, stages, and switch activations for the methodology 2400 may be understood with reference to those in described in detail earlier for the methodologies 2200, 2220, 2240, 2260, 2270, 2280, and will not be completely repeated here. Further, it will be understood that, as with the other switching methodologies disclosed herein, the switching sequence methodology 2400 may be operated in reverse order to drive the output of the generalized driving circuit 2300 in a step-wise manner back to ground. The modifications presented for the above-described methodologies to allow operation of their associated driving circuits to reduce their voltage outputs in a step-wise manner from peak voltage to ground may be applied to the methodology 2400 to allow operation of the driving circuit 2300 in reverse order. To simplify the description further, the stages controlling the switches shown in FIGS. 24A-24B-3 are illustrated in Stage 2401(1) to Stage 2401(r), where r=Πⱼ₌₁^{K}[2·n[j]+1]+1, which constitutes the stage at which the voltage V_{O23} is driven from ground level to V_{DD23}. As shown in the figures, the stages, phases, and switching patterns through which the driving circuit may drive voltage from ground to the supply voltage illustrate the stages and phases through which the driving circuit may operate to drive the voltage from the supply voltage to ground. Therefore, the stages after Stage 2401(r), where r=Πⱼ₌₁^{K}[2·n[j]+1]+1 may be known by reference to the Stages 2401(1) to Stage 2401(r), where r=Πⱼ₌₁^{K}[2·n[j]+1]+1.

Finally, unless specified in the following description of the stages and phases, the switches are open.

### Initiating Cell [1] Phase 2412[1]-1:

In the initiating cell [1] phase 2412[1]-1 of the switching sequence methodology 2400 for the cell 2301-1, the switch SW[0] (the switch electrically connected to the negative terminal 2328 of voltage source V_{DD23}) of cell 2301-1 is closed and remains closed until the end of the initiating cell [1] phase 2412[1]-1, which closes at Stage 2401(r), where r=(n[1]f(1)+g(1)), after which the switch SW[0] is opened.

The initiating cell [1] phase 2412[1]-1 may have an initiating cell [1] switching pattern 2402[1]-1 which begins by grounding the cell 2301-1 from Stage 2401(1) to Stage 2401(r), where r=g(1). The grounding may be achieved by closing the switch SW[1] of the cell 2301-1 (the one switch in the set of the n[1] switches in the cell 2301-1 electrically connected to the common node to the terminal 2314-1 that is also electrically connected to the switch SW[0] without a non-dissipative element intervening therebetween), thus bypassing the cell 2301-1 so that the input voltage of the cell 2301-1 (specifically, ground) is applied to the output of the cell 2301-1 and therefore to the input of cell 2301-2. The bypass is maintained for the duration of an application of an initiating cell [2] switching pattern 2402[2]-1 on the cell 2301-2, which ends upon the completion of the Stage 2401(r), where r=g(1).

The initiating cell [1] switching pattern 2402[1]-1 may continue closing the remainder of the switches in cell 2301-1, specifically switch SW[2] to SW[n[1]+1], in a sequential manner, with the closing of the switch maintained for the duration of an application of an executing cell [2] switching pattern 2403[2]-1 on the cell 2301-2:
For example,
   the switch SW[2] is closed from the Stage 2401(r), where r=(g(1)+1), to the Stage 2401(r), where r=(f(1)+g(1)), and then opened; and
   the switch SW[3] of the cell 2301-1 is closed from Stage 2401(r), where r=(f(1)+g(1)+1) to Stage 2401(r), where r=(g(1)+2·f(1)), and then opened.
      The described operation of switches continues until switch SW[n[1]+1] of the cell 2301-1 is closed from Stage 2401(r), where r={g(1)+[(n[1]−1)·f(1)]+1} to Stage 2401(r), where r=(n[1]f(1)+g(1)), after which the initiating cell [1] switching pattern 2402[1]-1 has been completed and the switch set (SW[0], SW[n[1]+1]) of the cell 2301-1 are opened.

### Peaking Cell [1] Phase 2414[1]:

The peaking cell [1] phase 2414[1] drives the cell 2301-1 to reach a peak voltage. In the peaking cell [1] phase 2414[1], a peaking cell [1] switching pattern 2404[1] opens the switch SW[0] and closes the switch SW[n[1]+2] (the switch electrically connected to the positive terminal 2326 of voltage source V_{DD23}). The switch SW[n[1]+2] remains closed for the duration of the peaking cell [1] phase, which will be in effect until the end of the Stage 2401(r), where r=(2g(1)+2n[1]f(1)) when the driving circuit 2300 ceases operation when the multi-cell circuit output voltage reaches its supply voltage, or which will be in effect until the end of the peaking cell [1] phase at Stage 2401(r), where r=(3g(1)+3n[1]f(1)−1) when the driving circuit 2300 continues operation after the multi-cell circuit output voltage reaches its supply voltage, after which it is opened.

Throughout the application of the peaking cell [1] switching pattern 2404[1], the switches SW[1] to SW[n[1]+1] are closed incrementally. The sequence of switching for switches SW[1] to SW[n[1]+1] in the peaking cell [1] switching pattern 2404[1] tracks the above-disclosed sequence of switching for the initiating cell [1] switching pattern 2402[1]-1. Specifically:
each switch closure incrementally subtracts V_{CS23[1]} from the output voltage of the cell 2301-1, starting with adding −n[1]V_{CS23[1]} and ending with adding −V_{CS23[1]}, and
the closure is maintained for the f(1) stages of an application of the executing cell [2] switching pattern 2403[2]-1 for the cell 2301-2. For example,
   the switch SW[1] is closed from the Stage 2401(r), where r={(n[1]·f(1))+g(1)+1}, to the Stage 2401(r), where r={[(n[1]+1)·f(1))+g(1)}, and then opened; and
   the switch SW[2] is closed from Stage 2401(r), where r={[(n[1]+1)·f(1)]+g(1)+1}, to Stage 2401(r), where r={[(n[1]+2)·f(1)]+g(1)}, and then opened.
      The above described switching pattern continues until SW[n[1]] of the cell 2301-1 is closed. The SW[n[1]] is maintained closed for the duration of one application of an executing cell [2] switching pattern 2403[2]-1 on the cell 2301-2 and ends at Stage 2401(r), where r={[2·n[1]·f(1)]+g(1)}, after which the peaking switching pattern 2404[1] closes the switch SW[n[1]+1] of the cell 2301-1, thus bypassing the cell 2301-1 so that the supply voltage of the voltage source for the circuit 2300 (V_{DD23}) is delivered to the input of the cell 2301-2. The bypass, which coincides with the start of the peaking cell [2] switching pattern 2404[2] of the peaking cell [2] phase 2414[2] for the cell 2301-2, continues until the output of the cell 2301-2 reaches its peak voltage at Stage 2401(r), where r={[2·n[1]·f(1)]+2·g(1)}.

FIGS. 24B-1-24B-3 show the stages and the switching sequence methodology 2400 for the sequential switching in the remainder of the (K−1) driver cells (e.g. cell 2301-2, cell 2301-3, . . . , cell 2301-(K−1), and cell 2301-K) in the driving circuit 2300 throughout a V_{O23} driving cycle.

In the cell 2301-z, the switch SW[0] and the switch SW[n[z]+2] are electrically connected through a common node to the output terminal of the cell 2301-(z−1). Accordingly, bypassing of the cell 2301-z may be achieved through closing either the switch set (SW[0], SW[1]) or (SW[n[z]+1], SW[n[z]+2]), with SW(n[z]+1) being the one switch in the set of the n[z] switches in the cell 2301-z electrically connected to the common node to the terminal 2314-z that is also electrically connected to the switch SW[n[z]+2] without a non-dissipative element intervening therebetween). As noted above, the representation in FIGS. 24B-1 through 24B-3 of the bypassing functionality with one of the bypassing switch sets does not preclude the application of bypassing with the other bypassing switch set.

### FIGS. 24B-1-24B-3: Switching Sequence Methodology 2400 for Cell 2301-z

The following methodology may be applied to the remainder of the cells of the circuit 2300:

Initiating Cell [z] Phase 2412[z]-1:

The initiating cell [z] phase 2412[z]-1, which is implemented in a cell 2301-z, where 2≤z≤K, shown in FIG. 24B-1, is similar to the initiating cell [1] phase 2412[1]-1 for the cell 2301-1. As in phase 2412[1]-1, the switch SW[0] in the cell 2301-z may be closed and remain closed for the duration of the phase 2412[z]-1 until the phase ends upon the completion of the Stage 2401(r), where r=(n[z]f(z)+g(z)), after which the switch SW[0] in the cell 2301-z is opened.

The initiating cell [z] phase 2412[z]-1 has an initiating cell [z] switching pattern 2402[z]-1 that starts by closing the Switch SW[1] of cell 2301-z, thus bypassing the cell 2301-z for the duration of one stage in the methodology when the cell 2301-z is the last cell in the circuit, or otherwise for the duration of the initiating cell [z+1] switching pattern 2402 [z+1]-1 of the initiating cell [z+1] phase 2412[z+1]-1 for the cell 2301-(z+1).

The initiating cell [z] switching pattern 2402[z]-1 then proceeds to incrementally close and then open the remainder of the switches in the cell 2301-z in a sequential manner in which the switch closures incrementally adds V_{CS23[z]} to the output voltage of the cell 2301-z, starting with an increase of V_{CS23[z]} to the cell 2301-z output voltage at the beginning of the initiating cell [z] phase and ending with an increase of n[z]V_{CS23[Z]} to the output voltage by the end of the initiating cell [z] phase 2412[z]-1. The incremental switching of SW[2] to SW[n[z]+1] while the switch SW[0] is closed selectively activates the sets of switches of the cell 2301-z that increase the output voltage of the cell 2301-z in an order to produce increasing amounts of output voltage increase.

The closures may be maintained for the duration of one stage in the methodology when the cell 2301-z is the last cell in the circuit 2300, or otherwise for the f(z) stages of the duration of an application of the executing cell [z+1] switching pattern 2403[z+1]-1 on the cell 2301-(z+1).

The described switching continues until switch SW[n[z]+1] of the cell 2301-z is closed from Stage 2401(r), where r={g(z)+[(n[z]−1)·f(1)]+1} to Stage 2401(r), where r=n[z]f(z)+g(z)=g(z−1), after which the initiating cell 2301-z phase 2412[z]-1 has been completed and the switches SW[0], SW[n[z]+1] of the cell 2301-z are opened.

Executing Cell [z] Phase 2413[z]-1:

The executing cell [z] phase 2413[z]-1 may proceed after the initiating cell [z] phase 2412[z]-1 is completed. As shown in FIG. 24B-2, the executing cell [z] phase 2413[z]-1 may begin with the switch SW[0] in the cell 2301-z open and the switch SW[n[z]+2] in the cell 2301-z closed. The executing cell [z] phase 2413 [z]-1 may have an executing cell [z] switching pattern 2403[z]-1 that is applied h(z−1)−1 times.

The executing cell [z] switching pattern 2403[z]-1 may start by incrementally closing and opening the switches SW[1] through SW[n[z]] in the cell 2301-z in a sequential manner while the switch SW[n[z]+2] in the cell 2301-z is closed, causing an incremental reduction in the output voltage of the cell 2301-z by V_{CS23[z]} (starting with a subtraction of n[z]V_{CS23[z]} from output voltage of the cell 2301-(z−1) at the beginning of the executing cell [z] phase 2413[z]-1 and ending with a subtraction of V_{CS23[z]} in the cell 2301-(z−1) output voltage by the end of the incremental reductions).

The incremental switching of SW[1] to SW[n[z]] while the switch SW[n[z]+2] is closed selectively activates the sets of switches of the cell 2301-z that decrease the output voltage of the cell 2301-z in an order to produce decreasing amounts of output voltage reductions. The closures may be maintained for the duration of one stage in the methodology when the cell 2301-z is the last cell in the circuit 2300, or otherwise for the f(z) stages of the duration of an application of an executing [z+1] switching pattern 2403[z+1]-1 on the cell 2301-(z+1).

At the completion of the closure of switch SW[n[z]], which occurs at the end of the Stage 2401(r), where r=g(z−1)+(n[z])·f(z), the incremental reduction of V_{CS23[z]} in the output voltage of the cell 2301-z has been completed, and switch SW[n[z]] of cell 2301-z may be opened and the switch SW[n[z]+1] may be closed to bypass the cell 2301 [z]-1 for the duration of one stage in the methodology when the cell 2301-z is the last cell in the circuit 2300, or otherwise for the duration of an application of an executing [z+1] switching pattern 2403 [z+1]-1 on the cell 2301-(z+1).

At the completion of the bypassing of the cell 2301-z at Stage 2401(r), where r=g(z−1)+(n[z]+1)·f(z), is completed, the switch SW[n[z]+2] of cell 2301-z may be opened and the switch SW[0] may be closed and the executing cell [z] switching pattern 2403 [z]-1 may proceed to incrementally close and then open the switches SW[2] through SW[n[z]+1] in the cell 2301-z in a sequential manner to incrementally add V_{CS23[z]} to the output voltage of the cell 2301-z. The incremental switching of SW[2] to SW[n[z]+1] while the switch SW[0] is closed may be achieved using the methods described above in the initiating cell [z] switching pattern 2402 [z]-1 to incrementally increasing the cell [i]'s output voltage starting with an increase of V_{CS23[z]} to the cell 2301-z output voltage and ending with an increase of n[z]V_{CS23[z]} to the output voltage. When the executing cell switching pattern has been applied h(z−1)−1 times, and the output voltage of the cell [i] at the start of the executing cell [z] phase 2413[z]-1 has been increased by n[z]V_{CS23[z]}, the executing cell [z] phase 2413[z]-1 has been completed.

Peaking Cell [z] Phase 2414[z]:

The peaking cell [z] phase 2414[z] may proceed after the executing cell [z] phase 2413[z]-1 is completed. As shown in FIG. 24B-3, the switch SW[0], which had been closed during the last stages of the executing cell [z] phase 2413[z]-1, has been opened and the switch SW[n[z]+2] has been closed and remains closed during the entirety of the peaking cell [z] phase 2414[z].

The peaking cell [z] phase 2414[z] has a peaking cell [z] switching pattern 2404[z] that starts as does the executing cell [z] switching pattern 2403[z]-1 by incrementally closing and opening the switches SW[1] through SW[n[z]] in the cell 2301-z in a sequential manner while the switch SW[n[z]+2] in the cell 2301-z is closed, causing an incremental reduction in the output voltage of the cell 2301-z by V_{CS23[z]} (starting with a subtraction of n[z]V_{CS23[z]} from the input voltage of the cell 2301-z at the beginning of the peaking cell [z] phase 2414[z] and ending with a subtraction of V_{CS23[z]} from the cell 2301-z input voltage by the end of the incremental reductions.)

The incremental switching of SW[1] to SW[n[z]] while the switch SW[n[z]+2] is closed may be achieved using the methods described above in the executing cell [z] switching pattern 2403[z]-1 for incrementally decreasing the cell [z]'s output voltage.

At the completion of the closure of switch SW[n[z]], which occurs at the end of the Stage 2401(r), where r=N(K)+1−g(z−1)+n[z]·f(z), the switch SW[n[z]] may be opened and the switch SW[n[z]+1] of cell 2301-z may be closed to bypass the cell 2301-z for the duration of one stage in the methodology when the cell 2301-z is the last cell in the circuit 2300, or otherwise until the operation of the peaking [z+1] switching pattern 2404[z+1] on the cell 2301-(z+1) achieves as output voltage of the cell 2301-(z+1)'s peak voltage at Stage 2401(r), where r=N(K)+1−g(z−1)+g(z)+n[z]f(z)=N(K)+1.

### 9. Circuit/Switching Sequence Methodology Variants

### 9.1. The Variants

FIGS. 25A-39C-3 illustrate embodiments of certain of the methods, circuits, devices, and systems for sequenced operation of switching non-dissipative elements in capacitive element driving systems. FIGS. 25A, 25B, 25C contains the tables 2550a 2550b, 2550c that summarizes certain circuit/circuit switching methodology systems that are detailed above and are thus the subject of the above-cited U.S. Pat. No. 11,575,376 and U.S. patent application Ser. No. 18/090,469 (both naming as inventors the co-inventors herein), or that summarize additional embodiments of variants comprising certain circuits, switching methodology systems, or combinations thereof that are related variants of circuits and circuit switching methodologies described above and in the above-cited U.S. Pat. No. 11,575,376. In certain of those figures, the switches are presented shown in cells having double wavy borders when the negative rail is referenced and in cells having dash dot (stroked) borders when the positive rail is referenced.

The circuit/methodology systems 2500a, 2500b, 2500c include circuits (specifically without limitation circuits 780, 700C-2, 700F, 700G, 700H, 2900, 3400, 3700, and 4000) having one or more non-dissipative element and multiple switches (also referred to herein as SW), and that are operated according to one or more defined patterns (denoted in the circuit's associated switching sequence methodologies) in order to generate output voltage in defined amounts to drive capacitive elements according to defined objectives. The capacitor element-driving circuits may access the non-dissipative elements in the defined patterns due to the operation (opening/closing) of the multiple switches.

| Circuit | | | | Associated Switching Methodology | | |
|---|---|---|---|---|---|---|
| Driver No. | FIG. | 3 NDEs | #SW | No. | FIG(S). | Variant |
| 700C-2 | 7C-2 | series | 4 | 86 | 8B-2B1 | A1 |
| 700F | 7F | series | 5 | 2600 | 26B-1 | A2 |
| 700G | 7G | parallel | 5 | 8600 | 8D-B1 | B1 |
| 700H | 7H | parallel | 5 | 8700 | 8E-B1 | B2 |
| 780 | 7B | series | 6 | 2700 | 27-B1 | C |
| | | | | 2800 | 28-B1 | D |
| 2900 | 29 | parallel | 7 | 3000 | 30B-1 | E |
| | | | | 3100 | 31B-1 | F |
| | | | | 3200 | 32B-1 | G |
| | | | | 3300 | 33B-1 | H |
| 3400 | 34 | series | 9 | 3500 | 35B-1 | I |
| | | | | 3600 | 36B-1 | J |
| 3700 | 37 | series | 13 | 3800 | 38B-1, 38B-2 | K |
| | | | | 3900 | 39B-1, 39B-2 | L |
| System [wxy]: | System: | 1 per cell | 12:4 per | System: 3-NDE | System: 3-NDE | M |
| a 3-NDE | 3-NDE | | cell | version of 2220 | version of | |
| version of 2100 | version | | | | 22M-2A1(A1) | |
| | of FIG. 21 | | | | −22M-2A1(A2) | |
| System 4000: a | System: | | | 4100 | 41B-1A, | N |
| 3 cascaded | 40 | | | | 41B-1B | |
| cells 400 | | | | | | |
| Cells 400, | Cells: | 1 | 4 | Cells: 2220, 500 | 22A-22J, 5G | M |
| 2101-1,2; | 22J, 4 | | | | | |
| Cells 400, | Cells: | 1 | 4 | | | N |
| W, x, y | 40, 4 | | | | | |

The operation of the drivers allows for driving the voltage of a capacitive element between two voltage levels by transferring the energy stored in a driver's non-dissipative elements to the capacitive element in step-wise transfers, by alternatingly turning on and off two or more of the driver's switches in sequential order to drive the voltage of the capacitive element between the two levels. Also, the methodologies drive the driver's voltage up to a peak voltage in a set of stages, and then reverses the same set of stages to drive the voltage of the capacitive element back to the initial level (ground).

### 9.2. The Variant Tables (FIGS. 25A-25C)

FIGS. 25A-25C shows the tables 2550a, 2500b, 2550c, respectively, that disclose illustrative but not necessarily preferred embodiments 2500 of methods, circuits, devices, and systems for sequenced switching of non-dissipative elements in capacitive element driving systems, including certain variant circuits that are newly disclosed or disclosed in one of the parent applications and certain new variant methodologies that are newly disclosed or disclosed in one of the parent applications. Variants may be defined in differences in circuit design or in methodology definition and are exemplary and not dispositive of the sorts of variants contemplated by this disclosure or any claims already issued, herein presented. Or presented subsequently.

The tables 2550a, 2550b, 2550c identify the driver and associated methodology combinations by reference numerals for the circuit/methodology systems 2500 disclosed herein, and the Variant Type that will be serve as a reference numeral for each disclosed combination. The tables also detail certain characteristics of each variant, with rows for the following characteristics.

Table 2550a: Variants A1, A2, B1, B2, C, D. In FIG. 25A, the table 2550a details specifications for the earlier-disclosed circuit/methodology systems. Variant A1, A2 relate to circuits 700C-2 (FIG. 7C-2), 700F (FIG. 7F), respectively, with switching methodologies 86 (FIGS. 8B-2A-8B-2B2), 2600 (FIGS. 26A-26B-2), respectively, associated with the drivers 700C-2, 700F, respectively.

Variants B1, B2, relating to circuits 700G (FIG. 7G), 700H (FIG. 7H), respectively, with switching methodologies 2700 (FIGS. 27-A-27-B2), 2800 (FIGS. 28-A-28-B2), respectively, associated with the drivers 700G, 700H, respectively.

Variants C, D both related to circuit 780 (FIG. 7B), with: Variant C including the switching methodology 88 (FIG. 8C) associated with the driver 780 and re-presented herein as methodology 2700 (FIGS. 27A-27B-2), to emphasize the similarities and differences between Variant D and the comparisons thereto; and Variant D including the switching methodology 2800 (FIGS. 28A 28B-2) associated with the driver 780.

Table 2550b: Variants E, F, G, H. In FIG. 25B, the table 2550b details specifications for Variants E, F, G, H related to a single circuit 2900 (FIG. 29) and four switching methodologies: methodology 3000 (FIGS. 30A-30B-2), methodology 3100 (FIGS. 31A-31B-2), methodology 3200 (FIGS. 32A-32B-2), and methodology 3300 (FIGS. 33A-33B-2), respectively, associated with the driver 2900. The driver 2900, to which several methodologies may be applied is the same circuit in use by the several methodologies, a single circuit. The different Vi's detailed by the methodologies in each Variant are not due to a different choice of component values. They result from applications of different switching methodologies.

Table 2550c: Variants I, J, K, L, M, N. In FIG. 25C, the table 2550b continues, detailing specifications for the variant circuit/methodology systems and disclosing: Variants I, J with a single circuit 3400 (FIG. 34) and two switching methodologies 3500 (FIGS. 35A-35B-2), 3600 (FIGS. 36A-36B-2), respectively, associated with the driver 3400; and Variant K, L with a single circuit 3700 (FIG. 37) and two switching methodologies 3800 (FIGS. 38A-1-38B-2), 3900 (FIGS. 39A-1-39B-2), respectively, associated with the driver 3700.

Variant M/N relate to a driving system 4000 (FIG. 40), which is a 3-cell driving circuit [wxy] formed of three single NDE driver cells [w], [x], [y], also shown as single driving circuit 400 (FIG. 4) and cells 2101-1, 2101-2, which together form a 2-cell NDE driving circuit 2100 (FIG. 21) (the operation of circuit 2100 are shown in FIGS. 22A-22J), with each cell having one NDE and four switches, and two switching methodologies with methodology 2220 (FIG. 22M-2A1(A1)-22M-2A2) and methodology 4100 (FIGS. 41A-1, 41B-2), associated with the driver 4000.

In table 2550c, Variants M, N are identified as separate variants. However, as is discussed below, Variant M is functionally identical to Variant N. Each methodology (methodology 2220 for Variant M and methodology 4100 for Variant N) has an identical number of stages producing identical output voltages, but a few stages, particularly those related to the bypass of the NDEs to supply a cell's output terminal with ground or the supply voltage V_{DD} (also shown herein as V_{DD}), call for different switch closures. The different closures do not change the output voltages of those stages, but they are included here to highlight that methodologies may contain substantive and non-substantive differences. In certain places herein, “Variants M, N” is occasionally referred to as “Variant M/N.”

CAPACITOR REFERENCE RAIL: Typically in circuit topology, the interconnection that distributes a voltage to several parts of a circuit is referred to as a reference rail (or rail), with an interconnection between the positive terminal of the voltage source (V_{DD}) referred to as a positive reference rail, and an interconnection between ground (GND) referred to as a negative reference rail. The term “Capacitor Reference Rail” identifies a circuit's voltage interconnection (either V_{DD} or ground) to the input terminal of its NDE (or stack of NDEs) in the non-grounding and non-peaking stages of a methodology associated with a driver operating to swing the voltages from either the highest voltage level (V_{DD}) or the lowest ground voltage level. The non-grounding and non-peaking stages of a methodology also referred to herein as the executing or reverse executing stages of a methodology. The term “Capacitor Reference Rail” thus refers to the rail which is referenced in each executing or reverse executing stage of the circuit's switching methodology.

The grounding and peaking stages of the circuit's switching methodology are not included in the definition of “Capacitor Reference Rail” because no NDEs are activated in the transfer of GND or V_{DD} in those stages, in which the specific reference rail provides the voltage level GND or V_{DD} irrespective of the reference rail utilized in the methodology's previous or subsequent stages. Capacitor reference rails may be of “fixed,” “switched,” and “hybrid” types.

A “fixed” capacitor reference rail signifies that, in all of the executing or reverse executing stages of a methodology associated with a selected driver, the interconnection from a selected driver's input terminal to its output terminal is to a single rail (be it positive or negative). In other words, the selected driver's NDEs achieve their desired capacitor voltages in a methodology by referencing only one of the selected driver's reference rails (with the capacitor reference rail constituting either a V_{DD} or Ground rail) in all stags of its methodology. The voltage between its terminals across an NDE in the circuit capacitor (also referred to herein as the “capacitor voltage” or the “terminal voltage”) is discussed in more detail below

The circuit topology alone does not control what is a driver's type of capacitor reference rail; the circuit's associated methodology, which defines the Variant's switching sequence, also defines a Variant's capacitor reference rail type. As an example, Variant B1, with its driver 700G and associated methodology 8600, has a switching sequence in which the reference rail is always grounded (see FIG. 8D-A), while Variant B2, with its driver 700H and associated methodology 8700, has a switching sequence in which the reference rail is always the driver's input voltage V_{DD7H} (see FIG. 8E-A). The reference rail for Variant B1 always provides GND, while the reference rail for Variant B2 always provides V_{DD7H}. However, in both Variants, the reference rail does not change between the driver's input voltage and GND during the respective Variants' switching sequences.

A “switched” capacitor reference rail signifies that the capacitor voltages for the selected driver are referenced to one reference rail (e.g. GND) for some stages of its associated methodology and to the other reference rail (e.g. V_{DD}) at other stages of the switching methodology. A switched capacitor reference rail type may be “batch” or “alternate.”

“batch” switching. In “batch” switching, the reference rail continues to operate as the rail for one reference level for several consecutive stages, then switches to operate as the rail for the other reference level for several consecutive stages, and then repeats, with the term “batch 1” referring to a batch type in which the batch pattern starts with ground first, and the term “batch 2” referring to a batch type in which the batch pattern starts with V_{DD} first.

“alternate” switching. In “alternate” switching, the reference rail alternates between the two rails (V_{DD} and ground) at every stage of the methodology, with the term “alternate 1” referring to a pattern that starts with GND first, and the term “alternate 2” referring to a pattern that starts with V_{DD} first.

The terms “batch” and “alternate” encompass the capacitor reference rail type of many circuit/switching methodologies, but not all of them. For example, the switching methodology 3000 (FIG. 30A) associated with the driver circuit 2900 (Variant E), which may be seen to have a “batch” capacitor reference rail type, has a switching pattern of GGGVVV-VVVGGG, with G representing a negative reference rail, and V representing a positive reference rail. In comparison, the switching methodology 3200 (FIG. 32A) associated with the driver circuit 2900 (Variant G), which may be seen to have an “alternate” Capacitor Reference Rail type, has a switching pattern of GVGVGV-VGVGVG, with G again representing a negative reference rail, and V again representing a positive reference rail.

In other embodiments, a driver/methodology variant could have a switching methodology with a Capacitor Reference Rail type that is neither batch nor alternate, for example, a variant's switching sequence could be GGVGVV-VVGVGG, where V=V_{DD}, G=Ground.

CAPACITOR CONFIGURATION: The term “Capacitor Configuration” identifies the manner in which a selected driver's NDEs are activated and thus connected to the driver's output terminal during the application of the executing or reverse executing stages in the methodology associated with the selected driver. As in the Capacitor Reference Rail type description above, the grounding and peaking stages of the circuit's switching methodology are not included in the definition of the Capacitor Configuration type due to the non-activation of NDEs during those stages. A Capacitor Configuration type may be “stacked” or “non-stacked”.

“non-stacked” Capacitor Configuration. The term “non-stacked” describes a feature of a NDE configuration in which the driver of a selected driver/methodology combination, at each and every executing or reverse executing stage of its associated switching methodology, has only a single NDE activated in the driver between the driver output V_{O} and the “Capacitor Reference Rail” (V_{DD} or Ground). In a “non-stacked” capacitor configuration, a driver's output voltage is connected to a single NDE in all non-grounding and non-peaking stages of an associated methodology.

Examples of variants with a non-stacked capacitor configuration include Variants B1, B2, E, F, G, H, in which their driver's output voltages are connected to a single NDE in all non-grounding and non-peaking stages of their associated methodology. Having a non-stacked capacitor configuration does not mean that the NDEs in a selected driver are arranged to operate in “parallel” in the driver. For example, the driver 2900 has three NDEs (C₂₉₋₁, C₂₉₋₂ and C₂₉₋₃) associated with the methodologies in the Variants E, F, G, H. Each NDE is connected between a negative reference rail (between the driver output V_{O29} and GND) and a positive reference rail (between the driver output V_{O29} and V_{DD29}), so that, topologically speaking, the NDEs are arranged in “parallel.” However, none of the NDEs are arranged to operate in “parallel” in the driver 2900.

A “non-stacked” capacitor configuration may be seen in the switching methodology 3000 (FIG. 30A) associated with the driver circuit 2900 (Variant E), in which, except for the grounding/peaking stages of the methodology 3000, only a single NDE in the driver circuit 2900 is activated in each stage of the methodology. To repeat, while NDEs C₂₉₋₁, C₂₉₋₂ and C₂₉₋₃ are arranged topologically in parallel in circuit 2900, a “non-stacked” capacitor configuration does not mean that its NDEs are electrically connected in “parallel” because in methodology 3000, no two NDEs are accessed in parallel in methodology 3000 nor in any methodology described herein.

For example, every stage of the methodologies associated with Variants E, F, G, H, with the exceptions of the grounding and peaking stages (for the reasons discussed above), activates only one single NDE between the driver output V_{O29} and GND (or V_{DD29}). It does not mean “parallel”. Take Variant E as an example, at any one stage there is only one single NDE between output V_{O} and GND (or VDD), so while the NDEs C_{29_1}, C₂₉₋₂, and C₂₉₋₃ are arranged in the driver 2900 in parallel in a topological sense, they do not operate in parallel at any stage of the methodologies 3000, 3100, 3200, 3300. Two capacitors operating in parallel would mean their respective terminals are shorted together, which is not the case here.

Variant E: For example, with Variant E, stages 3002, 3014 activate only NDE C₂₉₋₁ between GND and V_{O29}, stages 3003, 3013 activate only NDE C₂₉₋₂ between GND and V_{O29}, stages 3004, 3012 activate only NDE C₂₉₋₃ between GND and V_{O29}, stages 3005, 3011 activate only NDE C₂₉₋₃ between V_{DD29} and V_{O29}, stages 3006, 3010 activate only NDE C₂₉₋₂ between V_{DD29} and V_{O29}, and stages 3007, 3009 activate only NDE C₂₉₋₁ between V_{DD29} and V_{O29}. Thus, NDEs C_{29_1}, C₂₉₋₂ and C₂₉₋₃ are NOT connected in parallel at any stage.

Variants B1, B2, F, G, H: A review of FIGS. 8D-B1, 8E-B1, 31-B1, 32-B1, 33-B1 will show similar non-stacked capacitor configurations (in which a driver's NDE output voltages are connected to a single NDE in all executing and reverse executing stages) in the methodologies for Variants B1, B2, F, G, H.

“stacked” Capacitor Configurations: Variants C, I. In a “stacked” Capacitor Configuration, a selected driver's output voltage is not necessarily connected to only one NDE at all stages in an associated methodology. In other words, in a “stacked” capacitor configuration, a driver output voltage is connected to more than one NDE in one or more non-grounding and non-peaking stages of an associated methodology.

Variant C: “stacked” Capacitor Configuration. In Variant C, having the driver 780 and its associated switching methodology 2700, the number of NDEs connected to the output voltage driver's output voltage V_{O7B} (again excepting out grounding/peaking stages) varies from stage to stage in the associated switching methodology 2700.

In the stages just after grounding, the Variant NDEs are stacked up, one NDE at a time, and in the stages just before grounding, the NDE stacks are reduced, one NDE at a time, with only NDE C_{7B[1]} activated between GND and V_{O7B} in stages 2702, 2714, then two NDEs C_{7B[1]}, C_{7B[2]} activated between GND and V_{O7B} in stages 2703, 2713, and then three NDEs C_{7B[1]}, C_{7B[2]}, C_{7B[3]} activated between GND and V_{O7B} in stages 2704, 2712.

In the stages just before peaking, the Variant C NDE stacks are reduced, one NDE at a time, and in the stages just after peaking, the NDEs are stacked up, one NDE at a time, with three NDEs C_{7B[1]}, C_{7B[2]}, C_{7B[3]} activated between V_{DD7B} and V_{O7B} in stages 2705, 2711, then two NDEs C_{7B[2]}, C_{7B[3]} activated between V_{DD7B} and V_{O7B} in stages 2706, 2710, and then only NDE C_{7B[3]} activated between V_{DD7B} and V_{O7B} in stages 2707, 2709.

Variant C could be considered to be a hybrid of the “stacked” and “non-stacked” capacitor configurations in that certain stages of its methodology could fulfill certain of the definitional requirements of “stacked” and “non-stacked” capacitor configurations, with the output voltage of its driver 780 connecting to a stack of NDEs at some stages in its associated methodology 2700, and to a single NDE at other stages in the methodology 2700. Stages of Variant C that activate only one NDE in its driver 780 during application of the methodology 2700 include stages 2702/2714, 2707/2709; and stages of Variant C that activate more than one NDE in its driver 780 during application of methodology 2700 include stages 2703/2713-2706/2710).

It can be seen that Variant C does not technically fulfill the definitional requirement for “non-stacked” capacitor configuration because its methodology 2700 does not connect the output voltage of its driver 780 to a single NDE in all non-grounding and non-peaking stages of the methodology 2700. However, Variant C does fulfill the definitional requirement for “stacked” capacitor configuration because application of the methodology 2700 on the driver 780 does connects the output voltage of driver 780 to more than one NDE in one or more non-grounding and non-peaking stages of the methodology 2700. Therefore, Variant C is properly designated as having a “stacked” capacitor configuration.

Variant I: “stacked” Capacitor Configuration. Similarly, Variant I, with its driver 3400 and its associated switching methodology 3500, is properly designated as having a “stacked” capacitor configuration, even though certain stages of its methodology 3500 could be considered to fulfill certain of the definitional requirements of “stacked” and “non-stacked” capacitor configurations.

In the stages just after grounding, the NDEs of the driver 3400 are activated one at a time, with only NDE C₃₄₋₁ is activated between GND and V_{O34} in stages 3402, 3414, then only NDE C₃₄₋₂ is activated between GND and V_{O34} in stages 3403, 3413, and then only one NDE C₃₄₋₃ is activated between GND and V_{O34} in stages 3404, 3412;

In the stages just before peaking, the NDEs are increased over three stages, and in the stages just after peaking, the NDEs are reduced over three stages, with two NDEs C_{7B[1]}, C_{7B[3]} activated between GND and V_{O7B} in stages 3405, 3411, then two NDEs C_{7B[2]}, C_{7B[3]} activated between GND and V_{O7B} in stages 3406, 3410, and then three NDEs C_{7B[1]}, C_{7B[2] ]}, C_{7B[3]} activated between GND and V_{O7B} in stage 3407, 3409.

In Variant I, the output voltage of its driver 3400 connects to a stack of NDEs at some stages in its associated methodology 3500, and to a single NDE at other stages in the methodology 3500. Stages of Variant I that activate only one NDE in its driver 3400 during application of the methodology 3400 include stages 3502/3514, 3503/3513, 3504/3512. Stages of Variant I that activate more than one NDE in its driver 3400 during application of methodology 3400 include stages 3505/3511, 3506/3510, 3507/3509.

As with Variant C, the Variant I does not technically fulfill the definitional requirement for “non-stacked” capacitor configuration because its methodology 3500 does not connect the output voltage of its driver 3400 to a single NDE in all non-grounding and non-peaking stages of the methodology 3400. And, while the methodology stages 3505/3511, 3506/3510, 3507/3509 display a different pattern of NDE activation than its related stages in Variant C (in activating non-consecutive NDEs, it still fulfills the definitional requirement for the “stacked” capacitor configuration of connecting the output voltage of driver 3400 to more than one NDE in one or more non-grounding and non-peaking stages of the methodology 3500. Therefore, Variant I is properly designated as having a “stacked” capacitor configuration.

STACKED CAPACITOR VOLTAGE OPERATION: The term “Stacked Capacitor Voltage Operation” identifies a characteristic of the mathematical operation that is applied to a circuit due to the manner of connection of stacked NDEs in the circuit and other components of the circuit during application of an associated methodology. In a “+” Stacked Capacitor Voltage Operation, NDEs of a selected circuit are connected and activated in the circuit to yield the sum of NDE capacitor voltages (e.g. v₁+v₂). In a “−” Stacked Capacitor Voltage Operation, the NDEs are connected and activated to yield a difference of capacitor voltages (e.g. v₁−v₂).

The “Stacked Capacitor Voltage Operation” is independent of the “Capacitor Reference Rail.” For example, it can be a “+” operation whether the Capacitor Reference Rail is V_{DD} or GND. Similarly, it can be a “−” operation whether the Capacitor Reference Rail is V_{DD} or GND.”

Variant N: Stacked Capacitor Voltage Operation. Variant N, with its driver 4000 and associated methodology 4100, is an example of a methodology in which the “Stacked Capacitor Voltage Operation” may be “+” or a “−” whether the Capacitor Reference Rail is V_{DD} or GND. In stages 4105/4151 and 4103/4153, in which the capacitor reference rail is GND, stages 4105/4151 perform a “+” operation on the driver 4000 to yield V_{O[wxy]}=(Vx+Vy)+0V; and stages 4103/4153 perform a “−” operation on the driver 4000 to yield V_{O[wxy]}=(Vx−Vy)+0V. In stages 4118/4138 and 4120/4136, in which where “capacitor reference rail” is V_{DD[wxy]}, stages 4118/4438 perform a “+” operation on the driver 4000 to yield V_{O}=V_{DD[wxy]}−(Vx+Vy); and stages 4120/4136 perform a “−” operation on the driver 4000 to yield V_{O}=V_{DD[wxy]}−(Vx−Vy).

nstep: nstep is the number of steps as a function of number of capacitors (n), specifically the number of steps that driver output traverses as it goes from ground to V_{DD} or vice versa. For example, in a one-capacitor driver (such as circuit 400) has nstep=3 (see FIG. 5G), with stage 501(1) yielding ground, stage 501(2) yielding V_{CS4}, stage 501(3) yielding V_{DD}−V_{CS4}; and stage 501(4) yielding peak (V_{DD}), it takes three steps (from ground to V_{CS4}, from V_{CS4} to V_{DD}−V_{CS4}, and from V_{DD}−V_{CS4}, to V_{DD}) to peak voltage. As another example, in the 3 non-dissipative element methodologies 2800, 3000, 3100, 3200, 3300, and 3500, nstep=7, making the complete voltage driving cycle 15 stages.

A count of the number of steps that driver output traverses as it goes from ground to V_{DD} or vice versa in a methodology associated with a 3-NDE driver of a selected one of the exemplary Variants A1-M disclosed herein yields an nstep for the 3-NDE driver of the selected variant, and a count of the number of steps in a 2-NDE version of the 3-NDE methodology that excludes the methodology stages in which a selected one of the NDEs does not contribute to the driver's output voltage would yield an nstep for a 2-NDE embodiment of the selected variant.

Similarly, a count of the number of the steps in a single-NDE version of the 3-NDE methodology that includes only the methodology stages in which a single one of the NDEs contributes to the driver's output voltage methodology would yield an nstep for a 1-NDE embodiment of the selected variant. Extrapolation of the nsteps for a set of drivers sharing the same generalized circuit topology but having different counts of NDEs yields an nstep for the generalized circuit, with n being the number of NDEs in the generalized circuit.

Thus, an nstep may be derived for each of the 3-NDE variants presented here, for 1- and 2-NDE versions of the 3-NDE variants, and (by extrapolation) for an NDE-generalized version of each of the variants.

Variant A1: nstep=n. The methodology 86 (FIGS. 8B-2B1, 8B-2B2) that, when applied to 3-NDE driver 700C-2, yields nstep=3. The methodology 86, when modified to ignore stage 863 its nstep count in order to generate a 2-NDE methodology, yields nstep=2 for a 2-NDE embodiment of Variant A1, and a 1-NDE embodiment of methodology 86 that ignores stages 862, 863 in its nstep count yields nstep=1. By extrapolation, an n-NDE embodiment of Variant A1 yields nstep°=°n.

Variants A2, B1, B2: nstep=n+1. The methodologies 2600, 8600, 8700, when applied to driver 700F of Variant A2, driver 700G of Variant B1, and driver 700H of Variant B2, respectively, yield nstep=4, with 2-NDE embodiments yielding nstep=3, and 1-NDE embodiments yielding nstep=2. By extrapolation, n-NDE embodiments of Variants A2, B1, B2 yield nstep=n+1.

Variants C, D: nstep=2n+1. The methodologies 2700, 2800 of Variants C, D, respectively, when each are applied to the same 3-NDE driver 780, yield nstep=7, with 2-NDE embodiments yielding nstep=5 and 1-NDE embodiments yielding nstep=3. By extrapolation, n-NDE embodiments of Variants C, D yield nstep=2n+1.

Variants E, F, G, H: nstep=2n+1. The methodologies 3000, 3100, 3200, 3300 of Variants E, F, G, H, respectively, when each are applied to the same 3-NDE driver 2900, yield nstep=7, with 2-NDE embodiments yielding nstep=5, and 1-NDE embodiments yielding nstep=3. By extrapolation, n-NDE embodiments of Variants E, F, G, H yield nstep=2n+1.

Variant I: nstep=[n(n+1)/2]+1, Variant J: nstep=2ⁿ. The methodologies 3500, 3600 of Variants I, J, respectively, when applied to the same 3-NDE driver 3400, yield nstep=7 for Variant I and nstep=8 for Variant J, while the 2-NDE embodiments for both yield nstep=4, and the 1-NDE embodiments for both yield nstep=2. By extrapolation, an n-NDE embodiment of Variant I yields nstep=[n(n+1)/2]+1, and an n-NDE embodiment of Variant J yields nstep=2.

Variant K: nstep=n(n+1)+1, Variant L: nstep=2⁽ⁿ⁺¹⁾−1 The methodologies 3800, 3900, respectively, when applied to the same 3-NDE driver 3700, yield nstep=13 for Variant K and nstep=15 for Variant L, while the 2-NDE embodiments for both yield nstep=7, and both 1-NDE embodiments yields nstep=3. By extrapolation, an n-NDE embodiment of Variant K yields nstep=[n(n+1)]+1, and an n-NDE embodiment of Variant L yields nstep=(2⁽ⁿ⁺¹⁾−1).

Variants M, N: System nstepₘₐₓ°=3ⁿ. The driving systems of Variants M, N are characterized by having one or more NDEs spread over one or more driver cells arranged in a series, with one driver cell's input terminal being connected to the output terminal of the driver cell immediately preceding it in the series. Herein, the driver cells so connected may be referred to as “chained” or as “cascaded” driver cells. Embodiments of Variants M, N show that there is more than one way to spread a plurality of NDEs across one or more driver cells in a driver system. Topology options differ in the number of driver cells in the system, in the number of NDEs in each of the driver cells, and in the arrangement of the NDEs in each driver cell. For example, possible cell/NDE combinations may include a single cell system containing all of the NDEs, or numerous kinds of multi-cell systems in which its cells may contain different numbers of NDEs.

It is the circuit designer's choice as to which circuit design to use in designing a suitable system, with the desired characteristics of a driver system in mind. For purposes of convenience, in the examples herein, the Variants M, N cell designs will be modeled on the capacitive element driver 700A, which constitutes a more generalized embodiment of the driver 400, with more than one non-dissipative element (NDE) electrically connected in series between a positive reference rail and a negative reference rail of the cell. Note also that driver 780, which is the foundation driver for Variants C, D, is the 3-NDE embodiment of the driver 700A.

Referring to FIG. 7A, each NDE in driver 700a has a first end and a second end, a first NDE in the series electronically connected by its first end to a first node on the negative rail and a last NDE in the series electronically connected by its second end to a last node on the positive rail. It also has an NDE switch associated with each NDE in the series, with the NDE switch associated with the last NDE, whether in a single-NDE cell or in a multi-NDE cell, being disposed between the last node on the positive rail and the cell's output terminal, and with any other NDE in the cell having the NDE switch associated therewith disposed between the cell's output terminal and a node between the second end of the NDE and a first end of an adjacent NDE.

The driver 700a has a negative rail input switch disposed between the first node and the cell's input terminal; a negative rail output switch disposed between the first node and the cell's output terminal; and a positive rail switch disposed between the last node and the cell's input terminal.

Each topology option for constructing a desired driver system having one or more NDEs spread over one or more driver cells may yield a different value of nstep for the Variants M, N systems. Further, in such a driver system, nstep is derivable for each potential cell/NDE combination, and a maximum value of nstep in the set may be deemed nstepₘₐₓ.

While the discussion of Variants M, N cell designs will be limited to comparing embodiments of the driver 700A, the fundamentals of designing multi-cell drivers are applicable in analyzing the suitability of other foundation topologies will still apply. For example, the characteristics of a design may be determined by analyzing embodiments having fewer constituent elements of a subject design and extrapolating to determine characteristics of generalizations of the subject design. The comparisons of cell design through a review of their nstep, nstepₘₐₓ, and Vᵢ will provide insights as to a driver's performance or energy requirements.

1-NDE embodiments of Variant M/N nstepₘₐₓ=3. A single-NDE embodiment of a Variant M/N driver system may be constructed of a single cell with the topology of the single-NDE driver 400 of FIGS. 4-5F, and the methodology 2220, 4100 associated with the single-NDE embodiment of a Variant M/N driver system is the methodology 500 of FIG. 5G. The driver 400/methodology 500 may also be found in the single-NDE embodiment of Variant C, with its driver 780/methodology 2700 modified into a single-NDE driver and a methodology that excludes two of driver 780's two NDEs), and in the single-NDE embodiment of the generalized driver 700a (FIG. 7A)/methodology 80 (FIG. 8B-1). In any of the combinations, application of the methodology 500) on the driver 400 yields nstep=3. As the driver 400 has only one NDE, the topologies in which the single NDE may be arranged in the driver 400 are limited to the single circuit topology shown in FIG. 7A, and so the 1-NDE embodiment nstep=nstepₘₐₓ=3.

2-NDE embodiment of Variant M/N: nstepₘₐₓ=9. A 2-NDE embodiment of a Variants M, N driver system based on driver 700a/methodology 80 may be constructed using one of the two following driver system topologies. In the first option, the 2-NDE system may be constructed from a single cell having the circuit topology of a 2-NDE version of the 3-NDE driver 780 (FIG.°7B), yielding nstep=2. In the second option, the 2-NDE system may be constructed from a 2-cell system having the circuit topology of a driving circuit 2100 (FIGS. °21-22J) with two single NDE cells in a driver system having the circuit topology of the 2-cell driver 2100, with application of its associated methodology 2200 (FIG. 22M-1A) yielding nstep°=9. The second option (a 2-cell Variant M/N driver system) yields a higher value of nstep than the first option (yielding nstep°=2), so a 2-cell Variant M/N driver system constructed with two single-NDE cells yields the higher nstep, with the 2-NDE embodiment nstep≤9 and nstepₘₐₓ=9.

3-NDE embodiment of Variants M, N nstepₘₐₓ=27. A three NDE embodiment of a Variants M, N driver system based on driver 700a/methodology 80 may be constructed using one of the following driver system topologies:

In the first option, the 3-NDE system may be constructed from a single cell having the circuit topology of the 3-NDE driver 780 (FIG. 7B-1), with its associated methodology 88 (FIG. 8C) rewritten as the 3-NDE methodology 2700 of FIG. 27B-1), the application of which to driver 780 yielding nstep°=°3.

In the second option, the 2-NDE system may be constructed from three 1-NDE cells and having the circuit topology of the 3-cell driver 4000 (FIG. 40), also known as driver [wxy] [referred to herein in FIG. 22M-2A1(A1) and above in the Section 8.1: “K-Cell Driving Circuits, Each Cell With One Non-Dissipative Element,” sub-section “FIGS. 22M-2A1 (A1)-22M-2A2: 3-Cell Driving Circuit” ], with application of their associated methodologies 2220 [FIG. 22M-2A1(A1)], 4100 (FIGS. 41A-1-41B-2) yielding nstep=27.

In the third option, the 3-NDE driving system may be constructed from two driver cells, one cell having a single NDE and the other cell having two NDEs. Available topologies for constructing such driver systems may be found in the driver [ab] of FIG. 22M-3A having a single NDE cell [2] followed by a 2-NDE cell [b], with its associated methodology 2260; and in the driver [mn] of FIG. 22M-4A having a 2-NDE cell [m] followed by a single NDE cell [n] and its associated methodology 2270.

Driver [ab] is described herein in the Section 8.2: “K-Cell Driving Circuits Having Cell(s) With More than One Non-Dissipative Element,” sub-section “FIG. 22M-3A: Driving Circuit [ab], Having Cell [b] with Two Non-Dissipative Elements”; and driver [mn] is described herein in the Section 8.2 noted above, in sub-section “FIG. 22M-4A: Circuit [mn], Having Cell [m] with 2 Non-Dissipative Elements,” Application of methodologies 2260, 2270 on drivers [ab], [mn], respectively, both yield nstep=15.

It can be seen that the second option, constructing the driver system from three cascaded 1-NDE cells based on driver 700a/methodology 80 again yields a higher value of nstep for the Variants M, N driver system, with the 3-NDE embodiment nstep≤27 or nstepₘₐₓ=27.

n-NDE embodiment of Variants M, N nstepₘₐₓ=3ⁿ. As defined above, a Variants M, N driver system based on driver 700a/methodology 80 has one or more NDEs disposed in one or more cascaded driver cells. As noted above, the n-NDE driver 700A may constitute the model for the cells in the Variants M, N driver system V_{DD}, with the circuit topology available for creating a 1-NDE Variants M, N driver system limited to the circuit topology of driver 400 (FIG. 4). As has been seen from analyzing the 2- and 3-NDE Variants M, N driver systems, when one or more NDEs are disposed in one or more driver cells, the highest yield of nstep will arise from a circuit topology having n single-NDE cascaded driver cells.

Already shown is the 1-NDE embodiment yielding nstep=nstepₘₐₓ=3, the 2-NDE embodiment yielding nstepₘₐₓ=9, and the 3-NDE embodiment yielding nstepₘₐₓ=27, nsteps, with the 2-NDE and the 3-NDE embodiments (and by default the 1-NDE embodiment) constructed of at least one cascaded 1-NDE driver cells.

By extrapolation, an n-NDE multi-celled driver system will achieve the highest yield nstep by constructing the driver system of n cascaded 1-NDE cells, with the cells having the circuit topology based on driver 400/methodology 500 (distributing the n NDEs in another other way will reduce the driver's nstep. Therefore, by extrapolation, with a single NDE driver system yielding nstep=3, the 2-NDE driver system yielding nstepₘₐₓ=9, and the 3-NDE driver system yielding nstepₘₐₓ=9, the n-NDE Variants M, N driver system will yield nstep≤27 or nstepₘₐₓ=3ⁿ.

Generally, when the cells of a driving system are modeled on the driver 700a, a driving system constructed with n cascaded NDE driver cells, each with a single NDE, requires less energy to operate than either a driving system constructed with a single driver cell having n NDEs or a driving system constructed with n NDEs spread out over fewer than n cascaded NDE driver cells. Accordingly, with respect to energy consumption, the operational performance of the driving system with n cascaded single-NDE driver cells is more efficient than the operational performance of a driving system constructed from the two other topological options.

Vₛₜₑₚ: The driver output step size Vₛₜₑₚ, also known as and referred to herein as Vstep, where Vₛₜₑₚ°=°V_{DD}/nstep°→°V_{DD}=(nstep)(Vstep), with V_{DD} (the amount of voltage that a circuit may generate) transmitted across the driver's given supply rail. As noted above, nstep is the number of steps that driver output traverses as it goes from ground to V_{DD} or vice versa, so with Vₛₜₑₚ being the driver's output step size, when nstep is maximized is maximized while V_{DD} remains constant, Vstep is reduced.

While other characteristics (such as manufacturing/component cost, power loss overhead, and timing) may contribute to improving operational efficiency of a capacitive element driver, energy consumption is a major factor. In theory, for a given supply voltage, V_{DD}, with V_{DD}=(nstep)(Vstep), associating a circuit with a methodology with a larger nstep renders Vstep commensurately smaller, thus results in increased energy efficiency. However, in practice, a larger nstep requires the circuit to have more switches and capacitors which imply (1) higher cost (2) more associated supporting circuitries and parasitics, hence higher power losses which, if excessive, can exceed the potential savings (hence defeating original purpose of energy saving).

Also, a typical application may require that the circuit transition from ground (0 Volts) to V_{DD} (or vice versa) within a given time, or as quickly as possible. When the switching methodology associated with the circuit calls for a higher nstep (for increased energy savings), the circuit will be subjected to a large number of stages to complete the transition from 0 to V_{DD} (or vice versa), hence operating the circuit through a more challenging driving cycle to meet the timing requirements, necessitating bigger switches to achieve smaller time constants for faster settling, increasing cost and power overhead.

Thus, while in theory, methodologies may be developed to provide an nstep that is as high as possible, in practice increasing nstep beyond some value would yield diminishing returns, leading to unacceptable cost or power overhead, and unachievable timing requirements.

CAPACITOR VOLTAGE (V₁): The terminal voltage of the i-th capacitor in the circuit is known as Vᵢ, and is expressed in terms of driver output step size Vₛₜₑₚ.

“Constant” Capacitor Voltage (Vᵢ) refers to the value of a defined voltage that remains constant during application of a selected methodology (e.g., V₁=V₂=V₃=Vᵢ, or generally Vᵢ=Vₛₜₑₚ; in general, when Vᵢ is constant, Vᵢ=[(k)(Vₛₜₑₚ)], where k is a proportionality constant. Note that the term “constant” used herein does not refer to capacitor voltage being unchanged with time. A constant capacitor voltage herein means that a driver's capacitor voltage does not change from one capacitor to the next during an application of a methodology on the driver (hence, an NDE's voltage in a driver is “constant” relative to the voltages of other NDEs in the driver), with a proportionality factor that is the same for all of the capacitors in the driver. Note that k may differ from driver to driver as a function of the topology of a driver and the stages of its associated methodology. Examples of driver/methodology variants herein having “constant” capacitor voltage include Variants A1, A2, C, D, which produce the following capacitor voltages.

Variant A1: constant with Vᵢ=Vₛₜₑₚ. Associated with the Variant A1 is the 3-NDE methodology 86 (FIG. 8B-2B1), in which nstep=3, and in which (from stage 862) V_{7C[1]}=(1/3)V_{DD7C}, (from stage 863) V_{7C[2]}=(1/3)V_{DD7C}, and (from stage 863) V_{7C[3]}=(1/3)V_{DD7C}, with the stages incrementing and decrementing V_{O7C} by (1/3)V_{DD7C}, In all, in each stage that activates an NDE, + or − (1/3)V_{DD7C} is contributed to V_{O7C}, depending upon whether the positive or negative rail is referenced during that stage. Therefore, Variant A1 has a constant capacitor voltage of Vᵢ°=°V_{7C[1]}°=°V_{7C[2]}°=°(1/3)V_{DD7C}, with V_{7C[3]} being irrelevant). Because Vₛₜₑₚ°=°V_{DD}/nstep and Vᵢ°=°(1/3)V_{DD7C}°→°Variant A1's Vᵢ°=°Vₛₜₑₚ. In general terms, for Variant A1,°Vᵢ°=°(k₁)(Vₛₜₑₚ), with k₁ being a proportionality constant equal to 1.

Variant A2: constant with Vᵢ=k₂*Vₛₜₑₚ. Associated with the Variant A2 is the 3-NDE methodology 2600 (FIG. 26B-1), in which nstep°=°4, and in which (from stage 2602) V_{7F-1}°=°(1/4)V_{DD7F}, (from stage 2603) V_{7F-2}°=°(1/4)V_{DD7F}, and (from stage 2603) V_{7F-3}=(1/4)(V_{DD7F}), with the stages incrementing and decrementing V_{O7F} by (1/4)V_{DD7F}, In all, an NDE contributes + or − (1/4)V_{DD7F} to V_{O7F} in any stage in which it is activated. Therefore, Variant A2 has a constant capacitor voltage of Vᵢ=V_{7F-1}=V_{7F-2}=V_{7F-3}=(1/4)V_{DD7F}. Because Vₛₜₑₚ°=°V_{DD}/nstep, Variant A2's Vᵢ°=°Vₛₜₑₚ. In general terms, for Variant A2, Vᵢ°=°(k₂)(Vₛₜₑₚ), with k₂ being proportionality constant equal to 1.

Variant C: constant with V₁=Vₛₜₑₚ. Associated with the Variant C is the 3-NDE methodology 2700 (FIG. 27B-1), in which nstep°=°7, and in which (from stage 2702) V_{7B[1]}=(1/7)V_{DD7B}, (from stage 2703) V_{7B[2]}°=°(1/7)V_{DD7B}, and (from stage 2704) V_{7B[3]}=(1/7) V_{DD7B} with the stages incrementing and decrementing V_{O7B} by (1/7)V_{DD7B}. In all, an NDE contributes + or − (1/7)V_{DD7B} to V_{O7B} in any stage in which it is activated. Therefore, Variant C has a constant capacitor voltage of Vᵢ°=°V_{7B[1]}°=°V_{7B[2]}°=°V_{7B[3]}°=°(1/7)V_{DD7B}. Because Vₛₜₑₚ°=°V_{DD}/nstep, °Variant C's Vᵢ°=°Vₛₜₑₚ. In general terms, for Variant C, °Vᵢ°=°k_{C}*Vₛₜₑₚ, with k_{C}°=°1.

Variant D: constant with Vᵢ=2*Vₛₜₑₚ. Associated with the Variant D is the 3-NDE methodology 2800 (FIG. 28B-1), in which nstep°=°7, and, due to its alternate2 capacitor reference rail pattern, in which (from stage 2803) V_{7B[1]}°=°(2/7)V_{DD7B}, (from stage 2805) V_{7B[2]}°=°(2/7)V_{DD7B}, and (from stage 2807) V_{7B[3]}°=°(2/7)V_{DD7B} with the stages incrementing and decrementing V_{O7B} by (1/7)V_{DD7B}. In all, an NDE contributes + or − (1/7)V_{DD7B} to V_{O7B} in any stage in which it is activated. Therefore, Variant D has a constant capacitor voltage of Vᵢ=2V_{7C[1]}=2V_{7C[2]}=2V_{7C[3]}=(2/7)V_{DD7C}. Because Vₛₜₑₚ°=°V_{DD}/nstep,°Variant D's Vᵢ°=°2Vₛₜₑₚ. In general terms, for Variant D,°Vᵢ°=°k_{D}*Vₛₜₑₚ, where k_{D}°=°2.

“Linear” Capacitor Voltage refers to the value of a voltage contributed by a selected NDE increasing linearly over the application of a selected methodology (e.g. V₁°=°1°V, V₂°=°2°V, V₃°=°3°V, or generally Vᵢ=[i(Vₛₜₑₚ)]. Linearity in this context does not mean that the voltage of any NDE increases linearly over time during any stage. Examples of driver/methodology variants having “linear” capacitor voltage include Variants B1, B2, E, F, G, H, I, K, which produce the following capacitor voltages, with n being the number of NDEs in their associated drivers and, as noted above, Vₛₜₑₚ=V_{DD}/nstep.

It may be noted that, at steady state, while Variants B1, B2, E, I, K all yield the same capacitor voltages Vᵢ=[i(Vₛₜₑₚ)] and Variants F, G, H each yield its own capacitor voltages which are multiples of i(Vₛₜₑₚ), all of the Variants B1, B2, E, I, K are classified as having a “linear” capacitor voltage because all of their V; are linearly related with i. In other words, none of the voltages of any NDEs associated with these variants increasing linear over time during a stage; the capacitor voltages of the NDEs in these drivers differ successively by Vₛₜₑₚ. Generally, for Variants B1, B2, E, F, G, H, I, K, Vᵢ={k[i(Vₛₜₑₚ)]}, where k is a proportionality constant.

Variant B1: linear with V₁=[i(Vₛₜₑₚ)] Associated with the Variant B1 is the 3-NDE methodology 8600 (FIG. 8D-B1), in which nstep°=°4, and, due to its fixed capacitor reference rail and non-stacked capacitor configuration, (from stage 8602) V_{7G[1]}°=°(1/4)V_{DD7G}, (from stage 8603) V_{7G[2]}°=°(1/2)V_{DD7G}, and (from stage 8604) V_{7G[3]}°=°(3/4)V_{DD7G}, with the stages changing the amount of V_{O7G} that had already been contributed by (1/4)V_{DD7G} and with a selected stage incrementing the amount of V_{O7G} by (1/4)V_{DD7G} or decrementing the amount of V_{O7G} by (1/4)V_{DD7G}, depending on whether the selected stage is in an executing switching pattern phase or in a reverse executing switching pattern phase.

Because only one NDE is activated in the methodology 8600 in any stage in its executing or reverse executing phase, an activated NDE contributes all of the fraction of V_{O7G} that the stage produces. Therefore, the amount of capacitor voltage that an activated NDE produced in a selected stage necessarily increases or reduces (depending on whether the selected stage executes or reverse executes) to supply the portion of V_{O7G} for the selected stage.

In the case of Variant B1, the amount of change in V_{O7G} from stage to stage is constant, resulting in a linear change in the amount of V_{O7G} produced from stage to stage. Also, because Vₛₜₑₚ°=°V_{DD}/nstep and °V_{7G[1]}°=°(1/4)V_{DD7G}, V_{7G[2]}°=°(2/4)V_{DD7G}, V_{7G[3]}°=°(3/4)V_{DD7G}, →° V_{7G[1]}°=°Vₛₜₑₚ, V_{7G[2]}°=°2Vₛₜₑₚ, V_{7G[3]}°=°3Vₛₜₑₚ°+°Vᵢ°=°(i)Vₛₜₑₚ. In general terms, for Variant B1, V_{V}°=°k_{B1}*i)(Vstep), where k_{B1}°=°1.

Variant B2: linear with V₁=[2i(Vₛₜₑₚ)] Associated with the Variant B2 is the 3-NDE methodology 8700 (FIG. 8E-B1), in which nstep°=°4. Variant B2 is similar to Variant Blin also having a fixed capacitor reference rail and non-stacked capacitor configuration but which differs from Variant B1 in Variant B2's 3-NDE methodology 8700 referencing the positive capacitor reference rail instead of the negative positive capacitor reference rail. It can be seen from stage 8702 that V_{7H[1]}°=°(1/4)V_{DD7H}, from stage 8703 that V_{7H[2]}°=°(1/2)V_{DD7H}, and from stage 8704 that V_{7H[3]}°=°(3/4)V_{DD7H}. As with the Variant B1, the Variant B2 stages also change the amount of V_{O7G} that had already been contributed by (1/4) V_{DD7H}, with a selected stage incrementing the amount of V_{O7H} by (1/4)V_{DD7H} or decrementing the amount of V_{O7H} by (1/4)V_{DD7H}, depending on whether the selected stage is in an executing switching pattern phase or in a reverse executing switching pattern phase.

As with the Variant B1, only one NDE is activated in the methodology 8700 in any stage in its executing or reverse executing phase, and the activated NDE contributes all of the fraction of V_{O7H} that the stage produces. Therefore, the amount of capacitor voltage that an activated NDE produced in a selected stage necessarily increases or reduces (depending on whether the selected stage executes or reverse executes) to supply the portion of V_{O7H} for the selected stage.

And analogous to Variant B1, the amount of change in V_{O7H} from stage to stage is constant, resulting in a linear change in the amount of V_{O7H} produced from stage to stage. In addition, analogously to Variant B1, because Vₛₜₑₚ°=°V_{DD}/nstep and V_{7H[1]}°=°(1/4)V_{DD7H}, V_{7H[2]}°=°(2/4)V_{DD7H}, V_{7H[3]}°=°(3/4)V_{DD7H},→°V_{7H[1]}°=°Vₛₜₑₚ, V_{7H[2]}°=°2Vₛₜₑₚ, V_{7H[3]}°=°3Vₛₜₑₚ°→°for Variant B2, Vᵢ°=°(i)Vₛₜₑₚ. In general terms, for Variant B2, Vᵢ°=°k_{B2}*i)(Vstep), where k_{B2}°=°1.

Variant E: linear with Vᵢ=[i(Vₛₜₑₚ)] Associated with the Variant E is the 3-NDE methodology 3000 (FIG. 30B-1), in which nstep°=°7 and (from stage 3002) V_{29-1°=°(}1/7)V_{DD29}, (from stage 3003) V₂₉₋₂°=°(2/7)V_{DD29}, and (from stage 3004) V₂₉₋₃°=°(3/7)V_{DD29}. Variant E, which has a batch 1 switched capacitor reference rail and non-stacked capacitor configuration, has stages that change the amount of V_{O29} that had already been contributed by (1/7)V_{DD29}, with a selected stage incrementing the amount of V_{O29} by (1/7)V_{DD29} or decrementing the amount of V_{O29} by (1/7)V_{DD29}, depending on whether the selected stage is referencing the negative reference rail or the positive reference rail, respectively.

As with the Variants B1, B2, only one NDE is activated in the methodology 3000 in any stage in its executing or reverse executing phase, and the activated NDE contributes all of the fraction of V_{O29} that the stage produces. Therefore, the amount of capacitor voltage that an activated NDE produced in a selected stage necessarily increases or reduces (depending on whether the selected stage executes or reverse executes) to supply the portion of V_{O29} for the selected stage.

And analogous to Variants B1, B2, the amount of change in V_{O29} from stage to stage is constant, resulting in a linear change in the amount of V_{O29} produced from stage to stage. In addition, because Vₛₜₑₚ°=°V_{DD}/nstep and°V₂₉₋₁°=°(1/7)V_{DD29}, V₂₉₋₂°=°(2/7)V_{DD29}, V₂₉₋₃°=°(3/7)V_{DD29}, →°V₂₉₋₁°=°Vₛₜₑₚ, V₂₉₋₂°=°2Vₛₜₑₚ, V₂₉₋₃°=°3Vₛₜₑₚ°→°Vᵢ°=°(i)Vₛₜₑₚ. In general terms, for Variant E, Vᵢ°=°(k_{E}*i)(Vstep), where k_{E}°=°1.

Variant F: linear with V₁=[(2n+1−i)(Vₛₜₑₚ)] Variant F is similar to Variant E, differing by Variant F referencing the positive rail first, then switching to referencing the negative rail until it achieves peaking voltage (Variant E references the negative rail first, then switches to referencing the positive rail until it achieves peaking voltage). The switching of the order of referencing rails causes the Variant F NDE output voltage values to differ from their counterparts in Variant E, so that, in the 3-NDE methodology 3100 (FIG. 31B-1) of Variant F with its nstep°=°7, shows that (from stage 3107) V₂₉₋₁°=°(6/7) V_{DD29}, (from stage 3106) V₂₉₋₂°=°(5/7) V_{DD29}, and (from stage 3105) V₂₉₋₃ °=°(4/7) V_{DD29}. As with Variant E, the Variant F stages also change the amount of V_{O29} that had already been contributed by (1/7)V_{DD29}, with a selected stage incrementing the amount of V_{O29} by (1/7)V_{DD29} or decrementing the amount of V_{O29} by (1/7)V_{DD29}, depending on whether the selected stage is referencing the negative capacitor reference rail or the positive capacitor reference rail, respectively.

As with the Variants B1, B2, E, an activated NDE produces in a selected stage the entire amount of capacitor voltage that driver output is necessarily increased or reduced (depending on whether the selected stage executes or reverse executes). And analogous to Variants B1, B2, E, the amount of change in V_{O29} from stage to stage is constant, resulting in a linear change in the amount of V_{O29} produced from stage to stage. Also, because Vₛₜₑₚ°=°V_{DD}/nstep and V₂₉₋₁°=°(3/7) V_{DD29}, V₂₉₋₂°=°(5/7)V_{DD29}, and V₂₉₋₃°=°(4/7)V_{DD29}→°V₂₉₋₁°=°6Vₛₜₑₚ, V₂₉₋₂°=°5Vₛₜₑₚ, and V₂₉₋₃°=°4Vₛₜₑₚ°→°Vᵢ°=°(2n+1−i)(Vₛₜₑₚ). In general terms, for Variant F, Vᵢ°=°(k_{F})(2n+1−i)(Vₛₜₑₚ), where where k_{F}°=°1.

Variant G: linear with Vᵢ=[(2i−1)(Vₛₜₑₚ)] Variant G is similar to Variants E, F differing by Variant G utilizing an alternate 1 capacitor switching pattern. In Variant G, the 3-NDE methodology 3200 (FIG. 32B-1), nstep°=°7 and (from stage 3202) V₂₉₋₁°=°(1/7)V_{DD29}, (from stage 3204) V₂₉₋₂°=°(3/7)V_{DD29}, and (from stage 3206) that V₂₉₋₃°=°(5/7)V_{DD29}. The Variant G stages also change the amount of V_{O29} that had already been contributed by (1/7)V_{DD29}, with a selected stage incrementing the amount of V_{O29} by (1/7)V_{DD29} or decrementing the amount of V_{O29} by (1/7) V_{DD29}, depending on whether the selected stage is referencing the negative capacitor reference rail or the positive capacitor reference rail, respectively.

As with the other Variants (B1, B2, E, F), the amount of capacitor voltage that an activated NDE produced in a selected stage necessarily increases or reduces (depending on whether the selected stage executes or reverse executes) to supply the portion of V_{O29} for the selected stage. Additionally, the amount of change in V_{O29} from stage to stage is constant, resulting in a linear change in the amount of V_{O29} produced from stage to stage. Also, because Vₛₜₑₚ°=°V_{DD}/nstep and V₂₉₋₁=(1/7) V_{DD29}, V₂₉₋₂=(3/7) V_{DD29}, V₂₉₋₃=(5/7) V_{DD29}→°V₂₉₋₁=Vₛₜₑₚ, V₂₉₋₂=3Vₛₜₑₚ, and V₂₉₋₃=5Vₛₜₑₚ→°Vᵢ°=°(2i−1)(Vₛₜₑₚ)]. Therefore, Variant G's Vᵢ°=°[(2i−1)(Vₛₜₑₚ)]. (k_{G})(2i−1)(Vₛₜₑₚ), where k_{G}°=°1.

Variant H: linear with Vᵢ=[(2i)(Vₛₜₑₚ)] Variant H is similar to the other linear Variants differing by Variant H utilizing an alternate2 capacitor switching pattern. In Variant H, the 3-NDE methodology 3300 (FIG. 33B-1), nstep°=°7 and (from stage 3303) V₂₉₋₁°=°(2/7)V_{DD29}, (from stage 3305) V₂₉₋₂°=°(4/7)V_{DD29}, and (from stage 3307) V₂₉₋₃°=°(3/7)V_{DD29}. The Variant H stages also change the amount of V_{O29} that had already been contributed by (1/7)V_{DD29}, with a selected stage incrementing the amount of V_{O29} by (1/7)V_{DD29} or decrementing the amount of V_{O29} by (1/7) V_{DD29}, depending on whether the selected stage is referencing the negative capacitor reference rail or the positive capacitor reference rail, respectively.

As with the other linear Variants, the amount of capacitor voltage that an activated NDE produced in a selected stage necessarily increases or reduces (depending on whether the selected stage executes or reverse executes) to supply the portion of V_{O29} for the selected stage. Additionally, the amount of change in V_{O29} from stage to stage is constant, resulting in a linear change in the amount of V_{O29} produced from stage to stage. Also, because Vₛₜₑₚ°=°V_{DD}/nstep and V₂₉₋₁°=°(2/7) V_{DD29}, V₂₉₋₂°=°(4/7)V_{DD29}, and V₂₉₋₃°=°(3/7)V_{DD29}°→°V₂₉₋₁°=°2Vₛₜₑₚ, V₂₉₋₂°=°4Vₛₜₑₚ, V₂₉₋₃°=°6Vₛₜₑₚ→°Variant H's Vᵢ=(2i)(Vₛₜₑₚ)]. Therefore, Variant H's Vᵢ°=°(2i)(Vₛₜₑₚ). Analogously to the other linear Variants, Variant H's Vᵢ°=°(k_{H}i)(Vₛₜₑₚ), where k_{H}°=°2.

Variant I: linear with Vᵢ=[i(Vₛₜₑₚ)] Variant I is similar to the other linear variants, especially Variants B1, B2, E in having the same output voltage, with Variant I differing by utilizing a fixed capacitor switching pattern and activating more than one NDE in certain stages. In Variant I, the 3-NDE methodology 3500 (FIG. 35B-1), nstep°=°7 and (from stage 3501) V₃₄₋₁°=°(1/7) V_{DD34}, (from stage 3502) V₃₄₋₂°=°(2/7) V_{DD34}, and (from stage 3503) V₃₄₋₃°=°(3/7) V_{DD34}. The Variant I stages also change the amount of V_{O34} that had already been contributed by (1/7)V_{DD34}, with a selected stage incrementing the amount of V_{O34} by (1/7) V_{DD34} or decrementing the amount of V_{O34} by (1/7)V_{DD34}, depending on whether the selected stage is referencing the negative capacitor reference rail or the positive capacitor reference rail, respectively.

As with the other linear variants, the amount of capacitor voltage that an activated NDE produced in a selected stage necessarily increases or reduces (depending on whether the selected stage executes or reverse executes) to supply the portion of V_{O34} for the selected stage. Additionally, the amount of change in V_{O29} from stage to stage is constant, resulting in a linear change in the amount of V_{O29} produced from stage to stage. Also, because Vₛₜₑₚ°=°V_{DD}/nstep°and V₃₄₋₁°=°(1/7)V_{DD34}, V₃₄₋₂°=°(2/7)V_{DD34}, V₃₄₋₃°=°(3/7)V_{DD34}→*°V₃₄₋₁°=°(1) Vₛₜₑₚ, V₃₄₋₂°=°2Vₛₜₑₚ, V₃₄₋₃°=°3Vₛₜₑₚ°→°Vi°=°(i)(Vₛₜₑₚ)]. Therefore, Variant I's Vᵢ°=°[(kₜi)(Vₛₜₑₚ)]. where kₜ°=°1.

Variant K: linear with Vᵢ=[i(Vₛₜₑₚ)]. Variant K is similar to the other linear Variants, particularly B1, B2, E, I in having the same output voltage, with Variant K utilizing a batch 1 capacitor switching pattern and activating more than one NDE in certain stages. In Variant K, the 3-NDE methodology 3800 (FIG. 38B-1), nstep°=°13 and (from stage 3801) V₃₇₋₁°=°(1/13)V_{DD37}, (from stage 3802) V₃₇₋₂°=°(2/13)V_{DD37}, and (from stage 3803) V₃₇₋₃°=°(3/13)V_{DD37}. The Variant K stages also change the amount of V_{O37} that had already been contributed by (1/13)V_{DD37}, with a selected stage incrementing the amount of V_{O37} by (1/13) V_{DD37} or decrementing the amount of V_{O37} by (1/13)V_{DD37}, depending on whether the selected stage is referencing the negative capacitor reference rail or the positive capacitor reference rail, respectively.

As with the other linear variants, the amount of capacitor voltage that an activated NDE produced in a selected stage necessarily increases or reduces (depending on whether the selected stage executes or reverse executes) to supply the portion of V_{O37} for the selected stage. Additionally, the amount of change in V_{O37} from stage to stage is constant, resulting in a linear change in the amount of V_{O29} produced from stage to stage. Also, because Vₛₜₑₚ°=°V_{DD}/nstep and V₃₇₋₁=(1/13)V_{DD37}, V₃₇₋₂=°(2/13)V_{DD37}, V₃₇₋₃°=°(3/13)V_{DD37}→°V₃₇₋₁=(1)Vₛₜₑₚ, V₃₇₋₂=2Vₛₜₑₚ, V₃₄₋₃°=°3Vₛₜₑₚ→° Vi°=°(i)(Vₛₜₑₚ)]. Therefore, Variant I's Vᵢ°=°[(k_{K}i)(Vₛₜₑₚ)]. where k_{K}°=°1.

It may be noted that, while at steady state Variants E, I, K all yield the same capacitor voltages and Variants F, G, H yield their own capacitor voltages, they are all classified as having a “linear” capacitor voltage because all of their V; are linearly related with i. In other words, their capacitor voltages in these drivers differ successively by constant Vₛₜₑₚ, not that the voltage of any capacitor is increasing linearly over time during a stage). Generally, for the linear Variants, Vᵢ=[f(i)](Vₛₜₑₚ), where f(i) is a function of i.

“Binary” Capacitor Voltage (Vᵢ) refers to the value of a defined voltage increasing by an order of 2 during a selected methodology. The reference to binary is due to the circuit characteristic that, at steady state, its capacitor voltages are not equal, but related in binary fashion (e.g. V=1V, V₂=2V, V₃=4V). In particular, as with the other variants already discussed, the driver's capacitor voltage is not increasing over time during a methodology stage.

Variant J: binary with Vᵢ=[2⁽ⁱ⁻¹⁾(Vₛₜₑₚ)]. Variant J is similar to Variant I in also utilizing a fixed stacked capacitor switching pattern and activating more than one NDE in certain stages, referencing only one of the reference rails. Variant J differs from Variant I in its 3-NDE methodology 3600 (FIG. 36B-1), in which a stage activating NDE₃₄₋₁ and NDE₃₄₋₂ is added between the stage activating NDE₃₄₋₂ and the stage activating NDE₃₄₋₃, causing nstep°=°8 (as opposed to the nstep°=°7 of Variant I),

From FIG. 36B-1, the output voltages of Variant J's NDEs show that (from stage 3602) V₃₄₋₁°=°(1/8) V_{DD34}, (from stage 3603) V₃₄₋₂°=°(2/8) V_{DD34}, and (from stage 3605) V₃₄₋₃°=°(4/8)V_{DD34}. Because V_{DD})/(nstep)=Vₛₜₑₚ, V₃₄₋₁=(1)(Vₛₜₑₚ), V₃₄₋₂=(2)(Vₛₜₑₚ), and V₃₄₋₃=(4)(Vₛₜₑₚ). Therefore, Variant J's generalized Vᵢ°=°[(2ⁱ⁻¹)(Vₛₜₑₚ)].

Variant L: binary with Cell Vᵢ=[2⁽ⁱ⁻¹⁾(Vₛₜₑₚ)]; System nstep_{max°=°}3⁽ⁱ⁻¹⁾, Vₛₜₑₚ. Variant L provides the same binary progression in the values of its NDEs as Variant J. As with Variant J, Variant L differs from Variant K in its 3-NDE methodology 3900 (FIG. 39B-1B), in which a stage activating NDE₃₇₋₁, NDE₃₇₋₂ is added between the stage activating NDE₃₇₋₂ and the stage activating NDE₃₇₋₃, causing nstep°=°15 (as opposed to the nstep°=°13 of Variant K), and the output voltages of its NDEs to change, with (from stage 3902) V₃₇₋₁°=°(1/15) V_{DD37}, (from stage 3903) V₃₇₋₂°=°(2/15) V_{DD37}, and (from stage 3905) V₃₇₋₃°=°(4/15)V_{DD37}. Because (V_{DD})/(nstep)=Vₛₜₑₚ, V₃₇₋₁=(1)(Vₛₜₑₚ), V₃₇₋₂=(2)(Vₛₜₑₚ), and V₃₇₋₃=(4)(Vₛₜₑₚ). Therefore, Variant L's generalized Vᵢ°=°[(2ⁱ⁻¹)(Vₛₜₑₚ)]. And, as with Variant J, generally, the capacitor output voltage of the Variant L is binary, with Vᵢ=[2⁽ⁱ⁻¹⁾(Vₛₜₑₚ)].

“Ternary” Capacitor Voltage (Vᵢ) refers to the value of a defined voltage increasing by an order of 3 during a selected methodology. The reference to ternary is due to the circuit characteristic that, at steady state, its capacitor voltages are not equal, but related in ternary fashion (e.g. V₁=1V, V₂=3V, V₃=9V). In particular, as with the other variants already discussed, the driver's capacitor voltage is not increasing over time during a methodology.

Variant M/N: Cells' Single NDE nstepₘₐₓ=3; System Cells' nstepₘₐₓ°=°3ⁿ. Variant M/N, which in which a driver system has at least one NDE disposed over one or more cascaded driver cells based on driver 700a/methodology 80, is different from the other Variants presented here due to the presence of more than one driver connected to form a driving system. However, the nsteps of the driver systems in the Variant M/N driver system may be derived in the same manner as the nsteps of the individual drivers from which the driving system is developed.

As noted above, embodiments of Variants M, N can be modeled on more than one driver system topology, because there is more than one way to spread a plurality of NDEs across one or more driver cells in a driver system. Therefore, the nstep for Variants M, N driver/methodologies (the number of steps that driver output traverses as it goes from ground to V_{DD} or vice versa) may be determined for each potential cell/NDE combination, and the maximum value of nstep in the set of combinations, also termed nstepₘₐₓ,

Also as noted above, a 1-cell Variants M, N driver system may be constructed with the circuit topology of the 1-NDE driver 400 to yield a nstep=3 (which by default is the nstepₘₐₓ for a 1-NDE driver cell, there being only one nstep possible from a single NDE cell [w], [x], [y]). Further, as noted above, a 2-cell Variant M/N driver system may be constructed with either a single cell having the circuit topology of a 2-NDE version of the 3-NDE driver 780 (with an nstep=2), or two single NDE cells in a driver system having the circuit topology of the 2-cell driver 2100 (nstep=9)). As noted above, the 2-cell Variant M, N driver system nstep is found to be the greater nstep (which is 9) of the two topology options, so a 2-cell Variant M/N driver system is derived to have an nstep≤9, which makes nstepₘₐₓ=9.

Finally, a 3-cascaded cells Variant M/N driver system may be constructed as a 1-cell driver system, a driver system with three single-NDE cells (nstep=27), or a 2-cell driver system with one single-NDE cell and one 2-NDE cell, with the single cell either first or last in the cascade (in either case, nstep=9). As also discussed above, the 3-cell Variant M/N driver system nstep is found to be the largest value nstep of the three topology options, so the 3-cell, 3-NDE Variant M/N driver system has an nstep≤27, which makes nstepₘₐₓ=27. By extrapolation, then, for an n-cell, n-NDE Variant M/N driver system, nstep≤3ⁿ, which makes nstepₘₐₓ=3ⁿ.

Variant M/N: Cells' single NDE constant with Vᵢ=[3Vₛₜₑₚ]; System ternary with nstepₘₐₓ°=°[3⁽ⁱ⁻¹⁾](Vₛₜₑₚ). The output voltages of the driver systems in the Variant M/N driver system may also be derived in the same manner as the output voltages of the individual drivers from which the driving system is developed.

As noted above, the capacitor outlet voltage V; for a driver with n-NDEs may be determined by analyzing a switching methodology associated with a 3-NDE driver to determine the capacitor outlet voltages V₁, V₂, V₃ of the driver's three NDEs using V_{DD}°=°(nstep)(Vₛₜₑₚ)°→° Vₛₜₑₚ°=°(V_{DD})/(nstep), with Vₛₜₑₚ being the driver's output step size (or the fraction of peak voltage V_{DD} that is yielded at a selected stage or the and then extrapolating V₁, V₂, V₃ to identify Vᵢ, for a generalized driver with n NDEs.

It can be seen from the 1-NDE, 2-NDE, and 3-NDE cascaded-cell Variant M/N driver systems that the nstepₘₐₓ results from the driver system topology that cascades single-NDE cells. Therefore, Vᵢ for a Variant M/N driver system with n-NDEs may be extrapolated from the Vᵢ for the Variant M/N driver system having n single NDE cells and the associated methodologies 2220, 4100, with the 3-NDE driver system having 3 cascaded single-NDE driver cells, and the 1- and 2-NDE cell driver systems that may be modified therefrom.

With cells based on the driver 700a/methodology 80, the single-NDE cell Variant M/N driver system yields nstepₘₐₓ=3, the 2-cell Variant M/N driver system yields nstepₘₐₓ°=°9, and the 3-cell Variant M/N driver system yields nstep,°=°27; therefore, the highest nstep for the n-cell Variant M/N driver system yields nstepₘₐₓ°=°3ⁿ.

As shown above, with the cell of the system [xyz] is referred to as cell [y], the system's second cell referred to as cell [x], and the system's third cell referred to as cell [w] (with Vᵢ for the i^{th} cell in the driver system [wxy], 4000, and with nstep°=°27 and Vₛₜₑₚ=(1/27)V_{DD[wxy]}:
stages 4102, 4154 yield V_{O[wxy]}°=V[y]=°(1/27)V_{DD[wxy]}°=(1)Vₛₜₑₚ;
stages 4104, 4152 yield V_{O[wxy]}°=V[x]°=°(3/27)V_{DD[wxy]}=(3)Vₛₜₑₚ; and
stages 4110, 4146 yield V_{O[wxy]}°=V[w]°=°(9/27)V_{DD[wxy]}=(9)Vₛₜₑₚ.
   Because V[y]=(1)Vstep, V[x]=(3)Vstep, and V[x]=(9)Vstep, by extrapolation Variants M/N's Vᵢ°=°(3ⁱ)Vₛₜₑₚ, with i referring to the i-th cell in the driver 4000, [wxy]. Therefore, for Variants M, N, the driver cells' < > is constant with Vᵢ=[3Vₛₜₑₚ]; and the system Vᵢ° is ternary and equal to (3⁽ⁱ⁻¹⁾)Vₛₜₑₚ.

### 9.3. The Methodologies

The methodologies in the variants disclosed herein are disclosed in sequential snapshots of the active components of the circuits at issue at each stage of its associated methodology or methodologies, with differences in circuit configuration from one snapshot to the rest due to the circuits closed at the stage of the snapshot. The reference numerals and FIGS. of the functional snapshots for the enumerated variants are identified in the table below:

| | | | Associated Switching Methodology | | |
|---|---|---|---|---|---|
| | Circuit | | | Sequential Cycle | |
| Variant | No. | output | No. | Snapshot | Snapshot FIG. |
| A1 | V_{O7C} | 700C-2 | 86 | 860 | 8B-2A |
| A2 | V_{O7F} | 700F | 2600 | 2650 | 26A |
| B1 | V_{O7G} | 700G | 8600 | 8650 | 8D-A |
| B2 | V_{O7H} | 700H | 8700 | 8750 | 8E-A |
| C | V_{O7B} | 780 | 2700 | 2750 | 27A |
| D | | | 2800 | 2850 | 28A |
| E | V_{O29} | 2900 | 3000 | 3050 | 30A |
| F | | | 3100 | 3150 | 31A |
| G | | | 3200 | 3250 | 32A |
| H | | | 3300 | 3350 | 33A |
| I | V_{O34} | 3400 | 3500 | 3550 | 35A |
| J | | | 3600 | 3650 | 36A |
| K | V_{O37} | 3700 | 3800 | 3850a, 3850b | 38A-1, 38A-2 |
| L | | | 3900 | 3950a 3950b | 39A-1, 39A-2 |
| M | V_{O[wxy]} | 4000 | 2220 | 4155a-4155d | 41A-1-41A-4 |
| N | | | 4100 | | |

The table shows that a unique set of functional snapshots is presented for the identified methodologies, except for the methodologies 2220, 4100, which have a common functional snapshot set due to the methodologies 2220, 4100 being functionally equivalent. The NDE-bypass switch sets ([2],[3]), ([0],[1]) in Methodologies M, N both cause a bypass of the NDEs of the cell to which the switch closures are applied.

In the driving system 4000, the cells [w], [x], [y] are cascaded between the voltage source and the capacitive element that is driven by the driving system 4000. Therefore, in the cell [w], which is directly connected to the voltage source, the NDE-bypass switch set ([2],[3]) (also called herein the positive rail NDE-bypass switch set) causes the voltage at the positive terminal of the voltage source to be applied to the output terminal of the cell [w], and the NDE-bypass switch set ([0],[1]) (also called herein the negative rail NDE-bypass switch set) causes the grounded voltage at the negative terminal of the voltage source to be applied to the output terminal of the cell [w]. However, in the cells [x], [y], both of which are connected to the output terminal of the cell preceding it in the series, the closure of either closure sets ([2],[3]), ([0],[1]) causes the voltage at the output terminal of the preceding cell to be applied to the output terminal of the subject cell, resulting in the distinct NDE-bypass switch sets ([2],[3]), ([0],[1]) providing the same functionality in the subject cell. Therefore, even though the methodologies 2220, 4100 are different, they provide the driving system 4000 with identical output voltages. Therefore, the same Sequential Cycle Functional Snapshot Set 4155a-4155d may both be used to describe the functionality of both methodologies 2220, 4100.

The switch closures and output voltages of the variants' methodologies are illustrated in the following methodology tables, which detail the stages of the methodologies during their drivers' complete voltage driving cycles, and in the following switching patterns tables, which identify the sets of switches that are closed during each stage and the impact that the closures have on the operation and voltage outputs of the components of the associated circuits:

| | | Associated Switching Methodology | | | | |
|---|---|---|---|---|---|---|
| | | | Methodology | | Switching Patterns | |
| | | | Table | | Table | |
| Variant | Circuit | No. | No. | FIG. | No. | FIG. |
| A1 | 700C-2 | 86 | 868 | 8B-2B1 | 869 | 8B-2B2 |
| A2 | 700F | 2600 | 2660 | 26B-1 | 2665 | 26B-2 |
| B1 | 700G | 8600 | 8660 | 8D-B1 | 8665 | 8D-B2 |
| B2 | 700H | 8700 | 8760 | 8E-B1 | 8765 | 8E-B2 |
| C | 780 | 2700 | 2760 | 27B-1 | 2765 | 27B-2 |
| D | | 2800 | 2860 | 28B-1 | 2865 | 28B-2 |
| E | 2900 | 3000 | 3060 | 30B-1 | 3065 | 30B-2 |
| F | | 3100 | 3160 | 31B-1 | 3165 | 31B-2 |
| G | | 3200 | 3260 | 32B-1 | 3265 | 32B-2 |
| H | | 3300 | 3360 | 33B-1 | 3365 | 33B-2 |
| I | 3400 | 3500 | 3560 | 35B-1 | 3565 | 35B-2 |
| J | | 3600 | 3660 | 36B-1 | 3665 | 36B-2 |
| K | 3700 | 3800 | 3860a, | 38B-1A | 3865 | 38B-2 |
| | | | 3860b | 38B-1B | | |
| L | | 3900 | 3960a | 39B-1A | 3965 | 39B-2 |
| | | | 3960b | 39B-1B | | |
| M | System | 2220 | 2222a | 22M- | 2225 | 22M-2A1(B) |
| | [wxy]/ | | 2222b | 2A1(A1) | | |
| | 4000 | | | 22M- | | |
| | | | | 2A1(A2) | | |
| N | | 4100 | 4160a | 41B-1A | 4175 | 41B-2 |
| | | | 4160b | 41B-1B | | |

### 9.4 The Simulations

Screen shots of the results of simulations conducted on certain of the Variants 2500 are shown in the following figures:

| | Associated Switching | | | |
|---|---|---|---|---|
| Circuit | Methodology | | Simulations | |
| No. | No. | Variant | No. | FIG. |
| 780 | 2800 | D | 2870, 2880, 2890 | 28C-1, 28C-2, 28C-3 |
| 2900 | 3000 | E | 3070, 3080, 3090 | 30C-1, 30C-2, 30C-3 |
| | 3100 | F | 3170, 3180, 3190 | 31C-1, 31C-2, 31C-3 |
| | 3200 | G | 3270, 3280, 3290 | 32C-1, 32C-2, 32C-3 |
| | 3300 | H | 3370, 3380, 3390 | 33C-1, 33C-2, 33C-3 |
| 3400 | 3500 | I | 3570, 3580, 3590 | 35C-1, 35C-2, 35C-3 |
| | 3600 | J | 3670, 3680, 3690 | 36C-1, 36C-2, 36C-3 |
| 3700 | 3800 | K | 3870, 3880, 3890 | 38C-1, 38C-2, 38C-3 |
| | 3900 | L | 3970, 3980, 3990 | 39C-1, 39C-2, 39C-3 |

Simulations may be conducted to confirm that a variant performs as intended. For example, as disclosed above, Variant D may be expected to have capacitor voltage Vᵢ°=°(k_{D})(Vₛₜₑₚ), where k_{D} is a proportionality constant, with k_{D}=2 for Variant D. The simulation shown in screen shot 2870 (FIG. 28C-1) is of the capacitor voltages V_{7B[1]} (graph line 2871), V_{7B[2]} (graph line 3072), and V_{7B[3]} (graph line 2873), and shows that Variant D does perform as expected as its capacitor voltages converge (i.e. reach steady state) to the expected value of V_{7B[1]}°=°V_{7B[2]}°=°V_{7B[3]}°=°(2)(1)°=°2, with Vₛₜₑₚ assumed, for purposes of simplification and convenience of analysis in the simulations herein, to be 1 V after enough number of cycles have been executed.

Simulation does serve to show that it does take time for the NDE output voltages to converge to their final steady state values. For convenience and simplification in the simulations herein, initial capacitor voltages were assumed to be zero (0) (see Variant D screen shot 2870 and the other screen shots the entire simulations for Variants E-L, where the capacitor voltages started out at 0V, and took time to reach steady state). As a result, the driver output voltage (V_{O}) does not display a desired staircase waveform right from the start. For example, the screen shot 2880 shows that the Variant D driver output voltage V_{O} displayed a waveform that initially was somewhat chaotic and most certainly is not the intended staircase waveform shown in screen shot 2880.

If the circuit designer requires achieving steady state performance more quickly, rather than designing the system so that its operation with its starts with initial NDE output voltages V_{O}°=°0, a designer may choose to incorporate into its system an NDE pre-charger. It is the designer's option what to select as initial capacitor voltages. Values other than 0V may include V_{DD} or other appropriate values. System specifications may include Design considerations include selecting initial driver output waveform, as well as ease or cost of implementations, design, manufacturability, maintenance, or use, need for in-field adjustment, customizability, and flexibility.

The conducted simulations are based on an analytical model derived from charge conservation. For example, the simulation of Variant D shown in screen shot 2870 (FIG. 28C-1) constitutes operating the methodology 2800 on the driver 780 through four hundred (400) applications of a complete fourteen (14) stage V_{O7B} driving cycle (from stage 2801 to stage 2814 400 times). Four hundred applications of the methodology 2700 through the complete V_{O7B} driving cycle corresponds to 400 (14 stages)°=°5,600 timesteps of simulation. Therefore, the simulation shown in the screen shot 2870 (FIG. 28C-1) constitutes operating the circuit 780 through 5,600 timesteps, with graph line 2871 showing the simulation of NDE V_{7B[1]}, line 2872 showing the simulation of V_{7B[2]}, and line 2873 showing the simulation of V_{7B[3]}.

The screen shot 2880 (FIG. 28C-2) shows the simulation of the first three applications of the 400 applications of the methodology 2800 on driver 780, with graph line 2882 representing the output voltage V_{O7B} during those first cycles. The third chart, shown in screen shot 2890 (FIG. 28C-3), focuses on three applications of the methodology near the end of the 400 applications, with graph line 2892 representing the output voltage V_{O7B} during those last cycles. The number of timesteps in a simulation conducted on the other variants may be similarly calculated.

The screen shot 2870 shown in FIG. 28C-1 illustrates the evolution of capacitor voltages V_{7B[1]}, V_{7B[2]}, V_{7B[3]} during the simulation of the application of the methodology 2800 on the driver 780. Throughout this simulation, the driver output step size, Vₛₜₑₚ, for circuit 780 is assumed to be 1 V. Recalling that nstep is the count of stages of a voltage driving cycle that the driver output traverses as it goes from ground to peak (V_{DD}) or vice versa, for methodology 2800, nstep=7 (applying seven stages 2802-2808 to the circuit 780 to drive the output voltage to peak voltage V_{O7B}, and applying seven stages 2809-2801 to return the output voltage to ground). Since V_{DD7B}=nstep·Vₛₜₑₚ, for Variant D, V_{DD7B}=7 V.

In the graph 2870, the x-axis identifies counts of complete V_{O7B} driving cycles (“Cycle”) of the methodology 2800 that the simulation has applied to the circuit 780, and the Y-axis identifies simulated values, ranging from ground (0 V) to peak (7 V), of output voltages V_{7B[1]}, V_{7B[2]}, V_{7B[3]} of the three NDEs of the circuit 2800, and a data point plotted on the graph 2870 represents the simulated value of the output voltage of a selected NDE during a selected stage of a selected cycle (selected in this simulation to be the selected capacitor's output voltage in the last stage of the selected driving cycle, namely stage 2814). The function lines 2871, 2872, 2873 on the graph 2870 display the values of the output voltage of the NDEs C_{7B[1]}, C_{7B[2]}, C_{7B[3]}, respectively, at timestep counts during the simulation. The graph 2870 shows that, as time and the number of simulated cycles progress, the NDE's output voltages (V_{7B[1]}, V_{7B[2]}, V_{7B[3]}) converge to an expected steady state value of Vₛₜₑₚ=2 V.

The graph 2880 of FIG. 28C-2 and the graph 2890 of FIG. 28C-3 illustrate the evolution of the driver 2800 output voltage V_{O7B} during a selected number of timesteps of the simulation. In both graphs 2880, 2890, the simulated value of V_{O7B} is plotted against the timesteps that have been completed during the simulated application of cycles of the methodology 2800 conducted on the circuit 780, with the x-axis identifying the count of simulated timesteps (“TimeStep”), the y-axis identifying the simulated value of the V_{O7B} of the circuit 780 at a timestep of the simulation, and with data points plotted on the graphs 2880, 2890, with a selected data point representing a selected timestep and the circuit's output voltage during the duration of the stage associated with the selected timestep, the data points so plotted forming graph lines 2882, 2892 representing the output voltage V_{O7B}.

The graph line 2882 shows values of V_{O7B} for timesteps 1-43 of the 5,600-timestep simulation, which are values of V_{O7B} from the first driving cycles of the simulation, thus presenting V_{O7B} during operation of the circuit 2800 in its initial, transient state (referred to in FIG. 28C-2 as “driver output (initial)”). The graph line 2892 shows values of V_{O7B} for timesteps 5,406 to 5,448 of the simulation, which are values of V_{O7B} from the driving cycles 386-389 of the 400-cycle simulation, thus presenting V_{O7B} during operation of the circuit 2800 in its steady state (referred to in FIG. 28C-3 as “driver output (steady state)”).

It may be seen that over time and multiple applications of methodology 2800 on the circuit 780, the production of output voltage V_{O7B} takes on a staircase shape in which the driver's output voltage increases incrementally from a base voltage to a peak voltage and then decreases back again to the base voltage. A review of the other simulations on Variants E-L shows that over time and multiple applications of their associated methodologies on the circuits with which they are associated, the output voltages productions so simulated also take on a staircase shape in which the simulated driver's output voltage increases incrementally from a base voltage to a peak voltage and then decreases back again to the base voltage.

However, the driver's output voltage over a complete driving cycle does not necessarily assume a staircase shape from the onset of application of a methodology on a circuit. While the extent and duration of an initial turbulent state of operation of a circuit may depend on the characteristics and features of the specific circuit (including the initial capacitor voltages) and the specific methodology being applied to the circuit), as time progresses the circuit enters a steady state of operation, during which the driver output voltage may evolve into the staircase shape.

### 9.5. The Comparisons

The following charts illustrate comparisons of the methodologies in certain variant sets:

| Variant Sets | | | | |
|---|---|---|---|---|
| | | Switching | Comparisons | |
| Variant | Circuit | Methodology | Chart No. | FIG. |
| A1 | 700C-2 | 86 | 2669 | 26C |
| A2 | 700F | 2600 | | |
| B1 | 700G | 8600 | 8769 | 8F |
| B2 | 700H | 8700 | | |
| C | 780 | 2700 | 2869 | 28D |
| D | | 2800 | | |
| E | 2900 | 3000 | 3369a, 3369b | 33D-1, |
| F | | 3100 | | 33D-2 |
| G | | 3200 | | |
| H | | 3300 | | |
| I | 3400 | 3500 | 3669 | 36D |
| J | | 3600 | | |
| K | 3700 | 3800 | 3990 | 39D |
| L | | 3900 | | |
| M | 4000 | 2220 | 4169 | 41C |
| N | | 4100 | | |

Variants A1, A2: Adding Switches to Circuits and Applying Methodologies with Stacked Capacitors and Fixed Reference Rails)

As disclosed in detail above in the Section “Capacitive Element Drivers 700C-1, 700C-2”, the driver 700C-2 shown in FIG. 7C-2 illustrates a 3-NDE capacitive element driver with four switches, and the driver 700F shown in FIG. 7F illustrates a 3-NDE capacitive element driver with five switches. As described below, the additional switch in the driver 700F causes changes in their associated methodologies in the number of stages and in the output voltage produced.

Variant A1 (Circuit 700C-2/Methodology 86): Stacked Capacitors with Fixed Reference Rail

The combination of the driver 700C-2 of FIG. 7C-2 with its 6-stage methodology 86, known herein as “Variant A1,” with both driver 700C-2 and methodology 86 disclosed in the “Capacitive Element Drivers 700C-1, 700C-2” Section above, allows for the driver 700C-2 to operate its 4 switches through a complete V_{O7B} driving cycle to apply output voltage V_{O7B} from ground to peak voltage to ground again.

The methodology 86, which is a modified version of the generalized switching methodology for driver 700C-1, also disclosed above in the “Capacitive Element Drivers 700C-1, 700C 2” Section, may be applied to the three NDEs in the driver 700C-2, to achieve switching of the capacitive element driver 700C-2 during the stages of a complete V_{O7C} voltage driving cycle, with the switches SW_{7C[1]} to SW_{7C[4]} closed, one at a time, sequentially (SW_{7C[1]} to SW_{7C[4]}). After achieving peak voltage with this sequence of switch activation, the switches SW_{7C[1]} to SW_{7C[3]} may be closed, one at a time, sequentially in reverse order (SW_{7C[3]} to SW_{7C[1]}), in stages 865, 866, respectively, with a return to stage 861 to drive V_{O7C} to the grounded voltage level at the negative terminal 728C.

As noted above, FIG. 8B-2B2 shows that the NDE C_{7C[3]} in the driver 700C-2 does not contribute to the changes in voltage V_{O7C} in the methodology 86, in essence showing that the NDE C_{7C[3]} is redundant in the driver 700C-2. Therefore, the NDE C_{7C[3]} could be removed without affecting functionality. As an example, if the NDE C_{7C[3]} were removed from the driver 700C-2, with no electrical connection between nodes 705C(3), 705C(4), the resultant driver would operate with the same functionality as a 2-NDE version of the driver 700F. Therefore, the driver 700C-2 as shown in FIG. 8B-2B2 would have an additional capacitor with no added benefit, and therefore the driver would be more expensive to produce.

### Variant A2 (Circuit 700F/Methodology 2600): Adding Switches to Circuits

The combination of counterpart Driver 700F of FIG. 7F, with its 8-stage Methodology 2600, known herein as “Variant A2,” illustrated in FIGS. 26A-26C-3, and mentioned above in the “Capacitive Element Driver 700F” section, allows for the circuit 700F to be driven through a complete V_{O7F} driving cycle to apply output voltage V_{o7F} from ground to peak voltage to ground again. The methodology 2600, which is an expanded version of the switching methodology 86 for driver 700C-2 disclosed above, may be applied to the three NDEs in the driver 700F.

The methodology 2600 is shown in FIG. 26A to-FIG. 26C-3, which illustrate the operation of the circuit 700F at each stage of the methodology 2600 during a complete V_{O7F} driving cycle. FIG. 26A shows a chart 2650 of representations of sequential functional snapshots of the circuit 700F during application of the methodology 2600. FIGS. 26B-1, 26B-2 are tables 2660, 2665, detailing the stages 2601-2608 of the methodology 2600.

At a stage 2601 (as with stage 861), the switch SW_{7F-1} may be closed while the other switches are open to cause a “bypass” of the NDEs of the driver 700F, so that the grounded voltage at the negative terminal 728F is passed to the output terminal 704F with V_{O7F}=0 at steady state.

At stages 2602 (as with the stage 862), switch SW_{7F-2} may be closed while the other switches are open to cause delivery of voltage equal to V_{7F-1} to the output terminal 704F with V_{O7F}=(¼)V_{DD7F} at steady state. At a stage 2603 (as with the stage 863), the switch SW_{7F-3} may be closed while the other switches are open to cause delivery of voltage equal to V_{7F-1}+V_{7F-2} to the output terminal 704F with V_{O7F}=½V_{DD7F} at steady state.

At a stage 2604 (which has no counterpart stage in methodology 86), the switch SW_{7F-4} may be closed while the other switches are open to deliver V_{O7F}°=°V_{7F-1}°+°V_{7F-2}°+°V_{7F-3} to the output terminal 704F with V_{O7F}=(¾)V_{DD7F} at steady state.

At a stage 2605 (as with the stage 864 with the switch SW_{7C[4]}), the switch SW_{7F-5} may be closed while the other switches are open to cause another “bypass” of the non-dissipative elements of the driver 700F, so that the voltage at the voltage source V_{DD7F} is passed to the output terminal 704F with V_{O7F}=V_{DD7F} at steady state.

After achieving the peak voltage V_{DD7F} with this sequence of switch activation, in stage 2606 (which has no counterpart in the methodology 86), the switch SW_{7F-4} may be closed to deliver V_{O7F}°=°V_{7F-1}°+°V_{7F-2}°+°V_{7F-3} to the output terminal 704F with V_{O7F}=(¾)V_{DD7F} at steady state; in stage 2607 (as with stage 865) the switch SW_{7F-3} may be closed to deliver V_{O7F}°=°V_{7F-1}°+°V_{7F-2} to the output terminal 704F with V_{O7F}=(½)V_{DD7F} at steady state; in stage 2608 (as with the stage 866) the switch SW_{7F-2} may be closed to deliver voltage equal to V_{7F-1} to the output terminal 704F with V_{O7F}=(¼)V_{DD7F} at steady state; and, in another application of stage 2601 (stage 861) the switch SW_{7F-1} may be closed to deliver grounded voltage to the output terminal 704F with V_{O7F}=0 at steady state.

FIG. 26B-1 shows that the third NDE (C_{7F-3}) in the driver 700F now contributes to the changes in voltage V_{O7F} in the methodology 2600, in essence showing that the third NDE (C_{7F-3}) is no longer redundant in the driver 700F.

### Comparison of Variants A1, A2

The circuit topology of the circuit 700F of the Variant A2 is similar to that of the circuit 700C-2 of the Variant A1, except for the following: The positive terminal of the third capacitor of the circuit 700F, while still connected to the input of the circuit's fourth switch (SW_{7F-4}), is not connected to the positive terminal of the voltage source for the circuit 700F. Also, a fifth switch SW_{7F-5} is disposed between the positive terminal of the circuit's voltage source and a node between the output of the fourth switch (SW_{7F-4}) and the output terminal 704F of the circuit 700F.

The comparison chart 2669 in FIG. 26C shows the differences between the methodologies 86, 2600, with the stages of methodology 86 shown in regular font and the stages of methodology 2600 shown in italics, with the additional stages of methodology 2600 shown in rows with double lined (thick, thin) borders, and showing that the above-noted changes now allow the third NDE in the driver to contribute to the changes in voltage in the output of the driver, and in so doing, increase the driver's nstep from 3 to 4.

Capacitor Reference Rail/Capacitor Configuration: variants A1, A2 have fixed capacitor reference rails, and, because the circuits' NDEs are connected in series, they have a stacked capacitor configuration.

Stacked Capacitor Voltage Operation: variants A1, A2 demonstrate a “+” stacked capacitor voltage operation because all stages of their switching methodologies 86, 2600 yield summations of terminal voltages of circuit capacitors in their calculations of V_{O7C}, V_{O7F}, respectively.

nstep: The number of steps of a switching methodology that are traversed to bring a circuit's output voltage from ground to the circuit's peak is known as its nstep. nstep is based on the number of capacitors in a circuit. Variant A1's methodology nstep, based on the number of capacitors in the circuit 700F, equals 3 (applying three stages 862-864 to the circuit 700C-2 to drive the output voltage to peak, and applying three stages 865-861 to return the output voltage to ground), while nstep for Variant A2's switching methodology's 2600 equals 4 (applying four stages 2602-2605 to the circuit 700F to drive the output voltage to peak, and applying four stages 2606-2601 to return the output voltage to ground). Thus, the above-disclosed changes in the circuit topology and switch count in an n-NDE driver allow the n^{th} NDE in the driver to cease being redundant and to contribute to the changes in voltage in the output of the driver, and in so doing, allow the driver to achieve nstep=n+1.

An adapted version of the methodology 86 for a 2-NDE version of the circuit 700C-2, in which n=2, would generate nstep=2, a 1-NDE version, in which n=1, would generate nstep=1, and an n-NDE version of the circuit 700C-2 would generate nstep=n. An adapted version of the methodology 2600 for a 2-NDE version of the circuit 700F would generate nstep=3, a 1-NDE version of the circuit 700F would generate nstep=2, and an n-NDE version of the circuit 700F would generate nstep=n+1.

Vₛₜₑₚ: A driver's output step size Vₛₜₑₚ=V_{DD}/nstep, with V_{DD} being the output voltage of a given voltage supply. It follows that V_{DD}=(nstep)(Vstep). With Variant A2's nstep°=4, Variant A2's V_{DD7F}=(nstep)(Vstep)=(4)(Vstep), and Vstep=(1/4) V_{DD7F}.

Capacitor Voltage (Vᵢ): Vᵢ is the terminal voltage (the voltage across the NDE between its terminals) of the i-th capacitor, expressed in terms of driver output step size Vₛₜₑₚ where Vstep=V_{DD}/nstep.

Variant A1: constant with Vᵢ=k₁*Vₛₜₑₚ. Variant A1's V_{O7C} in its fixed switching methodology 86 increases by (1/3)V_{DD7C} in executing stages 862, 863, and decreases by (1/3)V_{DD7C} in reverse executing stage 865, 866. At each stage of the methodology 86, at least one or two of the three NDEs is accessed and activated to provide the additional (1/3)V_{DD7C} in stages 862, 863, and to reduce driver's output voltage by (1/3)V_{DD7C} in the stages 865, 866. At stage 863, due to the driver's three NDEs being connected in series, the closing of the switch SW_{7C[3]} accesses both NDEs C_{7C[1]}, C_{7C[2]}. Because the change in V_{O7C} is equal to (Vₛₜₑₚ), with i referring to the i-th capacitor in the driver 700C-2, the Variant A1 stages all reference the negative rail (except for stages 864, 861, which provide peak voltage and ground respectively).

When switch SW_{7C[4]} is closed at stage 864, it provides the peak V_{O7C} of V_{DD7C}, and when switch SW_{7C[1]} is closed at stage 864, it provides ground. Therefore, the driver 700C-2 achieves its peak voltage and ground without accessing its third and the topmost NDE C_{7C[3]}, rendering NDE C_{7C[3]} redundant; the driver output V_{O7C} would behave the same even if NDE C_{7C[3]} were removed from the driver 700C-2. Another way of viewing the performance of the driver 700C-2 is to consider that if closing the switch SW_{7C[4]} was intended to stack V_{7C[3]} on top of V_{7C[1]}°+°V_{7C[2]} to produce a voltage V_{O7C}°=°V_{7C[1]}°+°V_{7C[2]}°+°V_{7C[3]}, that voltage would simply be equal to V_{DD7C} because V_{O7C} is shorted to V_{DD7C} by lack of a switch to open between the voltage supply and the node 705C(4).

See FIG. 7F for the presence of a switch SW_{7F-5} in driver 700F of Variant A2, with switch SW_{7F-5} disposed between the voltage supply 720F and the node 754F, which would have removed the redundancy of its topmost NDE in driver 700C-2 had it been incorporated into the topology of driver 700C-2.

As noted above, Variant A1 has a constant capacitor voltage of Vᵢ°=°V_{7C[1]}°=°V_{7C[2]}°=°V_{7C[3]}=°(1/3)V_{DD7C}. Because Vₛₜₑₚ°=°V_{DD7C}/nstep and Vᵢ=(1/3)V_{DD7C}°→°Variant A1's Vᵢ°=°Vₛₜₑₚ°. In general terms, for Variant A1,°Vᵢ°=°k₁*Vₛₜₑₚ, with k₁ being a proportionality constant equal to 1.

Variant A2: constant with Vᵢ=(k₂)°Vₛₜₑₚ. Variant A2's Vᵢ is also constant because the increase in its output voltage V_{O7F} in each of its fixed methodology 2699 stages are also identical (they all have the same step size Vₛₜₑₚ=(¼)V_{DD7F}). As in Variant A1, only one NDE contributes to the change in the output terminal's voltage between each stage, so the output voltage of each NDE Vᵢ accordingly matches the increases in the driver's output voltage V_{O7F} in each of its stages. As noted above, Variant A2 has a constant capacitor voltage of Vᵢ°=°V_{7F-1}°=°V_{7F-2}°=°V_{7F-3}°=°(1/4)V_{DD7F}. Because Vₛₜₑₚ°=°V_{DD}/nstep and Vᵢ°=°(1/4)V_{DD7F}, Variant A2's Vᵢ°=°Vₛₜₑₚ°. In general terms, for Variant A2°Vᵢ°=°(k₂)(Vₛₜₑₚ), with k₂ being a proportionality constant equal to 1. Therefore, in methodology 2600, Vᵢ is also constant for each NDE in the driver 700F, and equal to Vstep, the change in V_{O7F} per stage.

Both circuits 86, 2600 yield step-wise voltage output, but driver 700C-2 has a shorter (6-stage) cycle and yields a lower peak voltage [V_{DD7C}=(3)(Vₛₜₑₚ) Volts], and driver 700C-2 has a longer (8-stage) cycle and yields a higher peak voltage [V_{DD7F}=(4)(Vₛₜₑₚ) Volts). In actual applications, typically V_{DD} is a given, with V_{step°}=°V_{DD}/nstep. For the same number of NDEs (n) in a driver, Variant A2 achieves finer Vₛₜₑₚ, with Variant A2's nstep°=°n+1 being higher than Variant A1's nstep°=°n. Hence, Variant A2 achieves more energy savings than Variant A1, making Variant A2 a more efficient design than Variant A1.

Note that the capacitance of all the 3 NDEs in Variants A1, A2 are equal, which is typical (although they are not restricted to be so), and the outputs are still linear stepwise. In addition, if each of their methodology stages have the same duration, the Variant A1 driving cycle (with an nstep=3) will conclude more quickly than the Variant A1 cycle (with an nstep=4.. While the Variant A1 has a speedier cycle time, it is not as energy efficient as Variant A2, with its higher nstep. A higher nstep allows a driver to obtain peak voltage in more stages, so each Vₛₜₑₚ is a little smaller in the amount of voltage that the driver needs to produce in each stage, or, returning to the staircase analogy, at each step of the stairs. Each step is a little shorter in Variant A2. Even though the energy required to make the step in Variant A2 is less than the energy required to make the step in Variant 1, with its lower nstep, the methodology of Variant A2 does require the driver to carry out more steps to transition the circuit from ground to V_{DD} or vice versa. The energy associated with each step of a driving cycle is (C)(Vstep)²°=°(C)(V_{DD}/nstep)², with C being the capacitance connected at terminal 704F and driven by the capacitive element driving system, while the energy associated with a complete driving cycle is (nstep)(C)(V_{DD}/nstep)², or (C)(V_{DD}²)/nstep. It can be seen, then, with nstep present in the denominator of the calculation of energy, as a methodology's nstep increases, the energy associated with the complete driving cycle decreases, resulting in an increase of energy savings per driving cycle. Therefore, with a higher nstep comes more energy savings, subject to the constraints cited above.

In addition, the NDE output voltage Vᵢ=Vₛₜₑₚ is smaller for Variant A2, versus V_{i°}=°Vₛₜₑₚ for Variant A1. Therefore, the driver 700F applying Variant A2's methodology 2600 is able to use NDEs with smaller voltage ratings, which are potentially smaller in size and/or less expensive.

When methodology 86 is applied to circuit 700C-2 (FIG. 7C-2), in its third stage switch SW_{7C[2]} is closed and circuit 700C yields V_{7C[1]}+V_{7C[2]}. However, in its fourth stage, which achieves peaking when switch SW_{7C[3]} is open and switch SW_{7C[4]} is closed, the circuit 700C-2 is provided with a direct path from the positive terminal of the voltage source to yield V_{DD7C}. It can be noted that, in the case of Variant A1, the value of V_{O7C}°=°V_{7C[1]}+°V_{7C[2]}+V_{7C[3]} is achieved during Variant A1's fourth stage (its peaking stage) not because methodology 86 allows all three NDEs to be accessed, but because the peaking stage of methodology 86 bypasses all three NDEs in order to supply Variant A1's V_{DD7C} to the driver's output terminal, and Variant A1's V_{DD7C} happens to equal V_{7C[1]}+V_{7C[2]}+V_{7C[3]}.

When methodology 2600 is applied to circuit 700F, because Circuit 700F has a fifth switch, Circuit 700F's fourth stage closes its switch SW_{7F-4}, all three NDEs are accessed, and circuit 700F yields V_{7F-1}+V_{7F-2}+V_{7F-3}. In its fifth stage, its fourth switch SW_{7F-4} is open and its fifth switch SW_{7F[5]} is closed, yielding V_{DD7F}. Adding an additional switch to the circuit design of driver 700F may increase the cost of production of the driver, while reducing the number of stages in a circuit's nstep could make the driver more efficient and less expensive to operate.

In summary, while the Variant A1, with its nstep°=°3, has a shorter (and hence speedier) cycle time, it is not as efficient as Variant A2, with its higher nstep that can generate the peak voltage with more but shorter steps Vₛₜₑₚ, resulting in energy savings and increased ability of the Variant A2 system to drive its voltage to a capacitive element and therefore support more kinds of capacitive elements, even those with higher capacitive input requirements.

Variants B1, B2: Circuits with Non-Stacked Capacitors

### Variant B1 (Circuit 700G/Methodology 8600): Switching on the Negative Capacitor Reference Rail

As noted above, the driver 700G shown in FIG. 7G has three NDEs that are connected in parallel, and 5 switches, with:
the first switch SW_{7G[1]} disposed on the negative interconnection 718G (also referred to herein as a “negative reference rail”) between the output terminal V_{o7G} and a common node 705G(0), and the fifth switch SW_{7G[5]} may be disposed on the positive interconnection 716G (also referred to herein as a “positive reference rail”) between a common node 705G(4) and the positive terminal 726G of the voltage source 720G;
the second, third, and fourth switches SW_{7G[2]}, SW_{7G[3]}, SW_{7G[4]} may be disposed between the positive terminals of the non-dissipative elements C_{7G[1]}, C_{7G[2]}, C_{7G[3]}, respectively, and the common node 705G(4); and
the negative terminals of the non-dissipative elements C_{7G[1]}, C_{7G[2]}, C_{7G[3]} may be directly connected to a negative interconnection 718G through common nodes 705G(1), 705G(2), 705G(3), respectively, which may be electronically directly connected together to form the common node 705G(0).

As discussed above in reference to drivers 700D, 700E, in other embodiments of driver 700G, the location of the switches SW_{7G[2]}, SW_{7G[3]}, SW_{7G[4]} may be disposed between the negative terminals of the non-dissipative elements C_{7H[1]}, C_{7H[2]}, C_{7H[3]}, respectively, and the common nodes 705G(1), 705G(2), 705G(3), respectively, with:
in FIG. 7G, disposing the switches in the switch/NDE combinations at the positive terminal of the NDEs;
in FIG. 7H, disposing the switches in the switch/NDE combinations at the negative terminal of the NDEs; and
in FIG. 7I, disposing the different switch/NDE combinations at different terminals of the NDEs.
   In any case, the switches may be constructed with N-channel or P-channel metal-oxide-semiconductor (NMOS or PMOS) transistors so that the switches can be optimized for semiconductor area depending on the steady-state voltage that the switches must connect. PMOS transistor switches may be preferred for connecting voltages that are closer to the positive reference rail (V_{DD7H}), while NMOS transistor switches may be preferred for connecting voltages that are closer to the negative reference rail (ground).

It is the circuit designers' option where to locate, for example, the switches SW_{7G[2]}, SW_{7G[3]}, SW_{7G[4]}, (they could even locate some at the positive terminals, and other at the negative terminals, of the non-dissipative elements, in this case C_{7G[1]}, C_{7G[2]}, C_{7G[3]}), with their decision involving application-specific and/or conventional transistor level implementation details. Additionally, the type of transistor (n-channel or p-channel) used for different switches may be selected based on common circuit design considerations to optimize performance and cost.

In addition, as described in further detail below in the detailed description of Variants E, F, G, H, the driver/methodology combination may be constructed along the same principles as Variant B1 in which the methodology could access a driver's NDEs in any desired order. As an example, the alternative methodology could have one of 5 other options for switching the switches in the SW_{7G[2]}, SW_{7G[3]}, SW_{7G[4]}, in the orders [SW_{7G[2]}, SW_{7G[4]}, SW_{7G[3]}]; [SW_{7G[3]}, SW_{7G[2]}, SW_{7G[4]}]; [SW_{7G[3]}, SW_{7G[4]}, SW_{7G[2]}], [SW_{7G[4]}, SW_{7G[2]} SW_{7G[3]}]; or [SW_{7G[4]}, SW_{7G[3]}, SW_{7G[2]}].

The methodology 8600 for opening and closing the switches of the driver 700G during the stages of a complete V_{O7G} driving cycle is shown in FIGS. 8D-A-8D-C3. FIG. 8D-A is a graphical representation 8650 of the methodology 8600; and FIG. 8D-B1 is a table 8660 detailing the switch closures and associated output voltages V_{O7G}, V_{O7G} (steady state) by stage of the complete V_{O7G} driving cycle. FIG. 8D-B2 is a table 2865 detailing the sets of switches that are closed and the resulting output voltages V_{O7G} during each stage of the methodology, and the switching pattern phase that the stages represent.

As noted above, the methodology 8600 drives the voltage V_{O7G} up to a peak voltage V_{DD7G} in a set of stages, and then reverses the same set of stages to drive the voltage of the capacitive element back to the initial level (ground). After the initial operation of multiple switching cycles/sequences on the driver 700G, the switching methodology for the driver 700G may yield the following results (recognizing that in each stage of the methodology 8600 if a switch is not identified as being closed, it is open).

In each stage 8601, the switch SW_{7G[1]} is closed to “bypass” the non-dissipative elements of the driver 700H so that grounded voltage at the negative terminal 728G is passed to the outlet terminal 704G, with V_{O7G}=0 at steady state. In stages 8602, 8608, the switch SW_{7G[2]} is closed and a voltage V_{7G[1]} is delivered to the outlet terminal 704G, with V_{O7G}=(1/4) V_{DD7G} at steady state. In stages 8603, 8607, the switch SW_{7G[3]} is closed and a voltage V is delivered to the outlet terminal 704G, with V_{O7G}=(2/4) V_{DD7G} at steady state. In stage 8604, 8606, the switch SW_{7G[4]} is closed and a voltage V_{7G[3]} is delivered to the outlet terminal 704G, with V_{O7G}=(3/4) V_{DD7G} at steady state; and, in a stage 8605, the switch SW_{7G[5]} is closed to “bypass” the non-dissipative elements of the driver 700G so that the source voltage V_{DD7G} is passed to the outlet terminal 704G, and at steady state V_{O7G}=V_{DD7G}.

The non-dissipative elements of the driver 700G are bypassed because the switches associated with the NDEs are kept open during the bypass operation so that the NDEs may not provide voltage to the output terminal.

### Variant B2 (Circuit 700H/Methodology 8700): Switching on the Positive Capacitor Reference Rail

As noted above, the driver 700H shown in FIG. 7H also has three NDEs that are connected in parallel, and 5 switches. In Driver 700H:
the first switch SW_{7H[1]} may be disposed on the negative interconnection 718H between the negative terminal 728H of the voltage source 720H and a common node 705H(0), and the fifth switch SW_{7H[5]} may be disposed on the positive interconnection 716H between a common node 705H(4) and the output terminal V_{O7H};
the second, third, and fourth switches SW_{7H[2]}, SW_{7H[3]}, SW_{7H[4]} may be disposed between the positive terminals of the non-dissipative elements C_{7H[1]}, C_{7H[2]}, C_{7H[3]}, respectively, and the common nodes 705H(1), 705H(2), 705H(3), respectively, which may be electronically directly connected together to form the common node 705H(4); and
the negative terminals of the non-dissipative elements C_{7H[1]}, C_{7H[2]}, C_{7H[3]} may be directly connected to a negative interconnection 718G through the common node 705H(0).

As with driver 700G, in other embodiments of driver 700H, the location of the switches SW_{7H[2]}, SW_{7H[3]}, SW_{7H[4]} may be disposed between the negative terminals of the non-dissipative elements C_{7H[1]}, C_{7H[2]}, C_{7H[3]}, respectively, and the common nodes 705H(1), 705H(2), 705H(3), respectively.

In addition, as with the driver 700G, a driver/methodology combination could be constructed that is an alternative embodiment of Variant B2 in which a driver's NDEs may be accessed in another desired order. As an example, the alternative methodology could use one of 5 other options for switching SW_{7H[2]}, SW_{7H[3]}, SW_{7H[4]}, in the orders [SW_{7H[2]}, SW_{7H[4]}, SW_{7H[3]}]; [SW_{7H[3]}, SW_{7H[2]}, SW_{7H[4]}]; [SW_{7H[3]}, SW_{7H[4]}, SW_{7H[2]}], [SW_{7H[4]}, SW_{7H[2]} SW_{7H[3]}]; and [SW_{7H[4]}, SW_{7H[3]}, SW_{7H[2]}].

Also, as noted above, the methodology 8700 for opening and closing the switches of the driver 700H during a complete V_{O7H} driving cycle is identical to the methodology 8600 in switch closures. In both methodologies, the five switches are closed sequentially, one at a time and in order, then closed sequentially, one at a time and in reverse order. Both methodologies are also identical in output voltages at steady state. But, because the layout of the driver 700G is different from the layout of Driver 700H, the voltages produced are different. After the initial operation of multiple switching cycles/sequences, the methodology 8700 for the driver 700H may yield the following results:
In each stage 8701, the outlet terminal 704H receives a voltage equal to V_{O7H}=0 (same as circuit 700G, where V_{O7G}=0);
In stages 8702, 8708, outlet terminal 704H receives V_{O7H}°=°V_{DD7H}−V_{7H[1]}°=°(1/4)V_{DD7H});
In stages 8703, 8707, outlet terminal 704H receives V_{O7H}°=°V_{DD7H}−V_{7H[2]} °=°(2/4)V_{DD7H});
In stages 8704, 8706, outlet terminal 704H receives V_{O7H}°=°V_{DD7H}−V_{7H[3]}°=°(3/4)V_{DD7H}); and
In a stage 8705, outlet terminal 704H receives the supply voltage V_{DD7H} (same as circuit 700G, where V_{O7G}=V_{DD7G}).

As discussed below, the difference in relative location of the first and fifth switches causes a significant difference in the manner that the voltage is drawn from the NDEs of each circuit during the stages in which the switches associated with the NDEs are closed.

### Comparison of Variants B1, B2

The comparison chart 8769 in FIG. 8F shows the differences between the methodologies 8600, 8700, with the stages of methodology 8600 shown in regular font and the stages of methodology 8700 shown in italics, and with the stages of methodologies 8600, 8700 that differ from each other (namely in Variants B1, B2 by the reference rail applied in a selected stage) presented
by the cell identifying the stage's V_{O7G} or V_{O7H} having a double wavy line border when the negative rail is referenced and
by the cell identifying the stage's V_{O7G} or V_{O7H} having a dash dot (stroked) border when the positive rail is referenced.

Capacitor Reference Rail/Capacitor Configuration: Variants B1, B2 have a fixed capacitor reference rail, and, because the circuit's NDEs are connected in parallel, a non-stacked capacitor configuration. Variants B1, B2 provide neither a + or − stacked capacitor voltage operation, because their NDEs are connected in parallel, not in stacked configurations, but it can be seen that, except for stage 86 the methodology 8600 causes the circuit 700G to operate from ground, and the methodology 8700 causes the circuit 700H to operate from V_{DD7H}.

nstep: The number of steps (nstep) of Variant B1, B2's switching methodologies that are traversed to bring the three-NDE circuits' output voltage from ground to the peak voltage equals 4 (applying four stages to the circuits 700G, 700H to drive the output voltage to peak, and applying four stages to return the output voltage to ground). By examination of the switching methodology for the circuits 700G, 700H, a 2-NDE version of the circuits would have a methodology nstep of 3 and a 1-NDE version of the circuit would have a methodology nstep of 2, leading to an n-NDE version of the circuits to have a methodology nstep of n+1.

Vstep: A driver's output step size, Vstep=V_{DD}/nstep, so for Variant B1, with nstep°=°4, Vstep°=°(1/4)V_{DD7G}.

Capacitor Voltage (V₁): V_{V} is the terminal voltage of the i-th capacitor in terms of Vstep. In switching methodologies 8600, 8700, V_{O7C}, V_{O7H} increase by (1/4)V_{DD7G}, (1/4)V_{DD7H}, respectively, at each stage, and then decrease by the same amount. Further, each methodology 8600, 8700, is defined to allow access to only one NDE at each of its stages, with each switch associated with the NDEs blocking access to the capacitor voltage of its NDE when open, and, providing access to its NDE when closed. At each methodology stage, only one NDE provides capacitor voltage during a selected stage, with no other NDEs providing capacitor voltages, so the capacitor voltage provided by the selected NDE will equal the capacitor voltage provided by the NDE accessed during the last previously applied stage plus the change in output voltage Vstep=(¼)V_{DD7G}.

Variant B1: linear with V₁=[i(Vₛₜₑₚ)]. For Variant B1, in its fixed switching methodology 8600 with i referring to the i-th capacitor in the driver 700G, the methodology 8600 stages, which all reference the negative rail one NDE at a time (except for stage 8605, which provides peak voltage), the output voltage of the NDE in the stage equals the numerator of the fractional fourths of V_{DD7G} that is output during that stage at steady state. In more quantitative terms, for Variant B1, nstep=4 and with Vstep°=°V_{DD}/nstep:
at stages 8602, 8608, V_{O7G}=V_{7G[1]}=°(1/4)V_{DD7G}=Vstep→V_{7G[1]}=(1)Vstep;
at stages 8603, 8607, V_{O7G}=V_{7G[2]}=°(2/4)V_{DD7G}=(2)[(1/4)V_{DD7G}]°=(2)Vstep→°V_{7G[2]}=(2)Vstep; and
at stages 8604, 8606, V_{O7G}=°V_{7G[3]}=(3/4)V_{DD7G}=°(3)[(1/4)V_{DD7G}]°=°(3)Vstep°→V_{7G[3]}=(3)Vstep.

Because V_{7G[1]}=(1)Vstep, V_{7G[2]}=(2)Vstep, and V_{7G[3]}=(3)Vstep, by extrapolation Variant B1's Vᵢ°=°(i)Vₛₜₑₚ, with i referring to the i-th NDE in the driver 700G. Therefore, for Variant B1, Vᵢ° is linear and equal to (i)Vstep.

Variant B2: linear with Vᵢ=[(n+1)−i]Vstep. For Variant B2, with i referring to the i-th capacitor in the driver 700H, the methodology 8700 stages, which all reference the positive rail one NDE at a time (except for stage 8601, which provides ground), the total amount of the reduction of the peak voltage V_{DD7H} by the output voltage of the accessed NDE in the selected stage equals the number of NDEs plus one, minus the numerator of the fractional fourths of V_{DD7H} that V_{O7H} equals during that stage at steady state. For example, for Variant B2, with nstep=4 and Vstep °=°V_{DD7H}/nstep°→°Vstep°=°(1/4)V_{DD7H}:
at stages 8702, 8708, V_{O7H}°=(1/4)V_{DD7H}=V_{DD7H}−V_{7H[1]}→V_{7H[1]}=V_{DD7H}−V_{O7H}→V_{7H[2]}=(4/4)V_{DD7H}−(1/4)V_{DD7H}=°(3/4)V_{DD7H}=(3)[(1/4)V_{DD7H}]°→°V_{7H[1]}=(3)Vₛₜₑₚ.
at stages 8703, 8707, V_{O7H}=°(2/4)V_{DD7H}°=V_{DD7H}−V_{7H[2]}→V_{7H-2}=V_{DD7H}−V_{O7H} →V_{7H[2]}=(4/4)V_{DD7H}−(2/4)V_{DD7H}=(2/4)V_{DD7H}°=(2)[(1/4)V_{DD7H}]°→°V_{7H[2]}=(2)Vₛₜₑₚ.
at stages 8704, 8706, V_{O7H}=(3/4)V_{DD7H}°=V_{DD7H}−V_{7H[3]}→V_{7H[3]}=V_{DD7H}−V_{O7H}→V_{7H[3]}=(4/4)V_{DD7H}−(3/4)V_{DD7H}=(1/4)V_{DD7H}°=(1)[1/4)V_{DD7H}]°→°V_{7H[3]}=(1)Vₛₜₑₚ.

Because Vₛₜₑₚ°=°V_{DD}/nstep, V_{7H[1]}=(3)Vstep, V_{7G[2]}=(2) Vstep, and V_{7G[3]}=(1)Vstep, by extrapolation, Variant B2's Vᵢ°=°[(n+1)−i] Vₛₜₑₚ, with i being the i-th NDE in the driver 700G and with n being the count of NDEs in the driver 700G. Therefore, for Variant B1, Vᵢ is linear and equal to [(n+1)−i]Vstep.

As noted above, the methodology 8600 used to operate driver 700G is identical in switch closures to the methodology 8700 used to operate driver 700H, with the difference being that in the methodology 8600 the negative rail is referenced for all stages except the fourth, when the output voltage is at peak, and in the methodology 8700 the positive rail is referenced for all stages except the first, when the output voltage is grounded. In addition, because of the reference rail change, V_{7G[1]}=V_{7H[3]}=Vₛₜₑₚ, V_{7G[2]}=V_{7H[2]}=(2)Vₛₜₑₚ; V_{7G[3]}=V_{7H[1]}=(3)Vₛₜₑₚ.

In both methodologies, the switches disposed on either the positive or negative reference rails rail are kept open during the stages in which the switches associated with the NDEs are closed, so that closing only one of the associated opens an electronic path to the outlet terminal 704G through the NDE with which the closed switch is associated. However, because the methodologies 8600, 8700 are operated on different circuits, the electronic paths differ in their directions that the voltage is connected through the capacitors. In essence, Variant B1 (Circuit 700G/Methodology 8600) switches on the negative capacitor reference rail, and Variant B2 (Circuit 700H/Methodology 8700) switches on the positive capacitor reference rail.

As noted above, the driver 700H differs in design from the driver 700G in the placement of the first and fifth switches:
in the driver 700G, the first switch SW_{7G[1]} is disposed between its common node 705G(0) and its outlet terminal 704G, and the fifth switch SW_{7G[5]} is disposed between its common node 705G(4) and its voltage source's positive terminal 726G; and
and in the driver 700H, the first switch SW_{7H[1]} is disposed between its common node 705H(0) and its voltage source's negative terminal 728H; and the fifth switch SW_{7H[5]} is disposed between its common node 705H(4) and the outlet terminal 704G.

In the driver 700G, because the positioning of the switches SW_{7G[1]}, SW_{7G[5]}, when the first and fifth switches are open, the driver's output terminal and the capacitors are shielded from the source voltage V_{DD7G}, imposing reference to the negative rail; so there is nothing to impede the voltage V_{7G[i]} of the NDE C_{7G[i]} from reaching the output terminal 704G when the switch SW_{7G[i+1]} is closed.

In addition, because of the positioning of the switches SW_{7H[1]}, SW_{7H[5]}, when the first and fifth switches are open, the driver's output terminal and the capacitors are shielded from ground, imposing reference to the positive rail; so there is nothing to impede the voltage V_{7H[i]} of the NDE C_{7H[i]} from reducing the amount of V_{DD7H} when the switch SW_{7H[i+1]} is closed.

Ground-referenced switches are easier to drive in general (as commonly known, exceptions exist, depending on specific circumstances). For example, in both Variants B1 (circuit 700G) and B2 (driver 700H), the three switches associated with the NDEs are referenced to V_{O} (instead of ground). In illustrative but not necessarily preferred alternative embodiments, the switches SW_{7G[4]}, SW_{7G[3]}, SW_{7G[2]}, in circuit 700G may be moved to between the negative terminals of the NDEs and the common node 705G(0), hence making them ground referenced.

Variants C, D: Batch Switching vs. Alternate Switching

FIG. 7B is a circuit diagram of a capacitive element driver 780 having three (n=3) non-dissipative elements arranged in series and six (6) switches; and FIGS. 27A-27C-3, 28A-28C-3 illustrate switching methodologies 2700, 2800, respectively, for operating the driver 780 during the stages of a complete V_{O7B} driving cycle. The driver 780/methodology 2700, known herein as Variant C, and the driver 780/methodology 2800, known herein as Variant D, operate to swap the closure states of the first and last switches, while the remaining switches are closed sequentially, one at a time and in order. As described below, Variants C, D differ by their patterns of closure swapping of the first and last switches and the sequential closing of the remaining switches.

### Variant C (Circuit 780/Methodology 2700): Batch 1 Switching

FIG. 27A to-FIG. 27C-3 illustrate the operation of the circuit 780 at each stage of the methodology 2700 during a complete V_{O7B} driving cycle, in which FIG. 27A shows a chart 2750 of representations of sequential functional snapshots of the circuit 780 during application of the methodology 2700. FIGS. 27B-1, 27B-2 are tables 2760, 2765, detailing the stages 2701-2714 of the methodology 2700.

The switching methodology 2700 operates to close one of the first or last switch while the remaining switches are closed sequentially in turn, one at a time, as follow. In stages 2701-2704, the switch SW_{7B[0]} is closed and the switch SW_{7B[5]} is open while the remaining switches (SW_{7B[1]}, SW_{7B[2]}, SW_{7B[3]}, SW_{7B[4]}) are closed sequentially in turn, one at a time, with stage 2701 providing a output voltage of ground and the output voltage increasing in each stage thereafter. In stages 2705-2708, the switch SW_{7B[0]} is open and the switch SW_{7B[5]} is closed while the remaining switches are again closed sequentially in turn, one at a time, until the peak voltage V_{DD7B} is reached when switches SW_{7B[4]}, SW_{7B[5]} are closed.

The stages of the methodology 2700 then repeat in reverse order to bring the output voltage back to ground. In stages 2708-2711, the switch SW_{7B[0]} is open and the switch SW_{7B[5]} is closed while the remaining switches are closed sequentially in turn, one at a time, but now in reverse order, with stage 2708, as noted above, providing a output voltage of peak and the output voltage decreasing in each stage thereafter. In stages 2712-2714 and in the return to stage 2701, the switch SW_{7B[5]} is open and the switch SW_{7B[0]} is closed while the remaining switches are closed sequentially, one at a time and in reverse order again, until the switches SW_{7B[0]}, SW_{7B[1]} are closed, until the output voltage is again grounded when switches SW_{7B[0]}, SW_{7B[1]} are closed.

After the initial operation of multiple switching cycles/sequences on the driver 780, the switching methodology 2700 may yield the following results from the driver 780. In each stage 2701, the outlet terminal 704B receives a voltage equal to V_{O7B}=0, at steady state. In stages 2702, 2714, the outlet terminal 704B receives a voltage equal to V_{7B[1]}, with V_{O7B}=1/7 V_{DD7B} at steady state. In stages 2703, 2713, the outlet terminal 704B receives a voltage equal to V_{7B[1]}+V_{7B[2]}, with V_{O7B}=2/7 V_{DD7B} at steady state. In stages 2704, 2712, the outlet terminal 704B receives a voltage equal to V_{7B[1]}+V_{7B[2]}+V_{7B[3]}, with V_{O7B}=3/7 V_{DD7B} at steady state. In stages 2705, 2711, where the first and last switches are swapped, the outlet terminal 704B receives a voltage equal to V_{DD7B}−(V_{7B[1]}+V_{7B[2]}+V_{7B[3]}), with V_{O7B}=4/7 V_{DD7B} at steady state. In stages 2706, 2710, the outlet terminal 704B receives a voltage equal to V_{DD7B}−(V_{7B[2]}+V_{7B[3]}), with V_{O7B}=5/7 V_{DD7B} at steady state. In stages 2707, 2709, the outlet terminal 704B receives a voltage equal to V_{DD7B}−V_{7B[3]}, with V_{O7B}=6/7 V_{DD7B} at steady state. In a stage 8708, the outlet terminal 704B receives the supply voltage V_{DD7B}.

### Variant D (Circuit 780/Methodology 2800): Alternate 2 Switching

FIG. 28A to-FIG. 28C-3 illustrate the operation of the circuit 780 at each stage of the methodology 2800 during a complete V_{O7B} driving cycle, in which FIG. 28A shows a chart 2850 of representations of sequential functional snapshots of the circuit 780 during application of the methodology 2800. FIGS. 28B-1-28B-2 are tables 2860, 2865, detailing the stages 2801-2814 of the methodology 2800; and FIGS. 28C-1-28C-3 graphically present the results of simulations of the operation of the methodology 2800 on the driver 780.

In methodology 2800, the switch SW_{7B[0]} is closed and the switch SW_{7B[5]} is open in every other stage, in the odd-numbered stages the switch SW_{7B[0]} open and the switch SW_{7B[5]} closed, and in even-numbered stages the switch SW_{7B[5]} open and the switch SW_{7B[0]} closed, with each remaining switch remaining closed for two stages. For example, in methodology 2800:
the switch SW_{7B[1]} is closed:
   for stage 2801 (the switch SW_{7B[0]} being closed, resulting in a grounded output with V_{O7B}=0 at steady state), and
   for stages 2802, 2804 (the switch SW_{7B[5]} being closed, resulting in an output voltage of V_{DD7B}−(V_{7B[1]}+V_{7B[2]}+V_{7B[3]}) with V_{O7B}=1/7 V_{DD7B} at steady state);
the switch SW_{7B[2]} is closed
   for stages 2803, 2813 (the switch SW_{7B[0]} being closed, resulting in an output voltage of V_{7B[1]}, with V_{O7B}=2/7 V_{DD7B} at steady state), and
   for stages 2804, 2812 (the switch SW_{7B[5]} being closed, resulting in an output voltage of V_{DD7B}−(V_{7B[2]}+V_{7B[3]}) with V_{O7B}=3/7 V_{DD7B} at steady state);
the switch SW_{7B[3]} is closed
   for stages 2805, 2811 (the switch SW_{7B[0]} being closed, resulting in an output voltage of V_{7B[1]}+V_{7B[1]})_{]} with V_{O7B}=4/7 V_{DD7B} at steady state), and
   for stages 2806, 2810 (the switch SW_{7B[5]} being closed, resulting in an output voltage of V_{DD7B}−V_{7B[3]} with V_{O7B}=5/7 V_{DD7B} at steady state) and
the switch SW_{7B[4]} is closed
   for stages 2807, 2809 (the switch SW_{7B[0]} being closed, resulting in an output voltage of V_{7B[1]}+V_{7B[2]}+V_{7B[3]}) with V_{O7B}=6/7 V_{DD7B} at steady state), and
   for stage 2808 (the switch SW_{7B[5]} being closed, resulting in an outlet terminal 704B receiving the supply voltage V_{DD7B}.

### Comparison of Variants C, D

The comparison chart 2869 in FIG. 28D shows the differences between the methodologies 2700, 2800, with:
the stages of methodology 2700 shown in non-italic font,
the stages of methodology 2800 shown in italics,
the stages of methodologies 2700, 2800 that differ from each other (namely in Variants C, D by the reference rail applied in a selected stage) presented
   by the cell identifying the stage's V_{O7B} having a double wavy line border when the negative rail is referenced and
   by the cell identifying the stage's V_{O7B} having a dash dot (stroked) border when the positive rail is referenced.

Capacitor Reference Rail: Variants C, D both demonstrate a switched capacitor reference rail because both systems change the reference connection for the NDEs at different stages of the driving cycle. Methodology 2700 illustrates a batched switched reference rail, because its capacitor voltages are referenced to the negative reference rail for multiple stages, then to the positive reference rail for multiple stages, then back to the negative reference rail for multiple stages until the cycle ends with a return to ground. Methodology 2800 illustrates an alternate switched reference rail, because its capacitor voltages alternate between the reference rails at each stage.

The methodology 2700 also illustrates batch 1 switching type, because its batch pattern starts with referencing the negative rail first; and the methodology 2700 illustrates batch°2 switching, because its batched switching pattern starts with V_{DD7B} first.

Capacitor Configuration: Variants C, D provide a stacked capacitor configuration, because the set of NDEs in the circuit 780 are connected in series at all stages in the methodologies 2700, 2800.

Stacked Capacitor Voltage Operation: Variants C, D provide “+” stacked capacitor voltage operations due to the NDEs connected to yield the sum of capacitor voltages. For example, when the switch SW_{7B[4]} is closed (as it is in stages 2704, 2705, 2711, 2712 in methodology 2700 and in stages 2804, 2805, 2811, 2812 in methodology 2800), NDEs C_{7B[1]}, C_{7B[2]}, C_{7B[3]} are accessed and their voltages are summed.

nstep: The number of steps (nstep) for Variants C, D both equal 7 (applying seven stages 02-08 to the circuit 780 to drive the output voltage to peak, and applying seven stages 09-14, 01 to return the output voltage to ground). An adapted version of the methodologies 2700, 2800 for a 2-NDE version of the circuit 780 would generate nstep=5, a 1-NDE version of the circuit 780 would generate nstep=3, and an n-NDE version of the circuit 780 would generate nstep=2n+1.

Vₛₜₑₚ: With its nstep°=7, V_{DD7B}=nstep*Vstep°=°(7)Vₛₜₑₚ.

Capacitor Voltage (Vᵢ): In Variants C, D, Vᵢ is also constant because the increase in the output voltage V_{O7F}, V_{O7H} in each of its stages are also identical (they all have the same step size Vₛₜₑₚ=(1/7)V_{DD7G}). As in Variant A1, only one NDE contributes to the change in the output terminal's voltage in the step between each stage, so the output voltage of each NDE accordingly matches the increases in the driver's output voltage V_{O7F} in each of its stages.

The stages of the batch 1 methodology 2700 that reference the negative rail are the first NDE-accessing switching set (stages 2702-2704) and the last NDE-accessing switching set (stages 2712-2714). Referring to FIG. 27B-1, with V_{7B[i]} being V₁ for the i^{th} NDE, with Vstep°=°V_{DD}/nstep, and, for Variant C, with nstep°=°7 and Vstep°=[(1/7)V_{DD7B}]:
at stages 2702, 2714, V_{O7B}=(1/7)V_{DD7B}=V_{7B[1]}→V_{7B[1]}=°[(1/7)Vstep]°→°V_{7B[1]}=(1)Vstep;
at stages 2703, 2713, V_{O7B}=(2/7)V_{DD7B} and°V_{O7B}=(V_{7B[1]}+V_{7B[2]})→°V_{7B[2]}=°V_{O7B}→°V_{7B[1]}°→°V_{7B[2]}=°[(2/7)V_{DD7B}]°−°[(1/7)V_{DD7B}]°=°(1/7)(V_{DD7B})°=Vstep°→V_{7B[2]}=(1)Vstep;
at stages 2704, 2712, V_{O7B}=(3/7)V_{DD7B} and°V_{O7B}=(V_{7B[1]}+V_{7B[2]}+V_{7B[3]})°→°V_{7B[3]}=°[(3/7)V_{DD7B}]°−°[(1/7)V_{DD7B}]°−°[(1/7)V_{DD7B}]°=°(1/7)(V_{DD7B})=Vstep°→V_{7B[3]}=(1)Vstep.

Because V_{7B[1]}=V_{7B[2]}=°V_{7B[3]}=°(1)Vstep, by extrapolation, Variant C's Vᵢ is constant with Vᵢ°=°(kc)Vₛₜₑₚ, with i referring to the i-th NDE in the driver 780 and k_{C}°=°1. Accordingly, for methodology 2700, Vᵢ, the terminal voltage of the i-th NDE is constant (equal to Vstep for each NDE in the driver), with Vᵢ=[(1/7)V_{DD7B}]. This can be confirmed in the stages that reference the positive rail, namely the second NDE-accessing switching set (stages 2705-2707) and the third NDE-accessing switching set (stages 2709-2711).

In the alternate 2 methodology 2800, the stages which reference the negative rail (namely the odd-numbered stages, except for the grounding stage), and referring to FIG. 28B-1 (with V_{7B[i]} being Vᵢ for the i^{th} NDE and with Vstep°=°V_{DD}/nstep, and, for Variant D, with nstep°=°7 and Vstep°=[(1/7)V_{DD7B}]:
at stages 2803, 2813, V_{O7B}=(2/7)V_{DD7B}=V_{7B[1]}=°(2)[(1/7))V_{DD7B}]→°V_{7B[1]}=(2)Vstep;
at stages 2805, 2811, V_{O7B}=(4/7)V_{DD7B}=V_{7B[2]} and°V_{O7B}=(V_{7B[1]}+V_{7B[2]}) °→°V_{7B[2]}=°V_{O7B}−°V_{7B[1]}=(4/7)V_{DD7B}−(2/7)V_{DD7B}=(2/7)V_{DD7B}→°V_{7B[2]}=°(2)[(1/7)(V_{DD7B})]°=(2)Vstep°→V_{7B[2]}=(2)Vstep; and
at stages 2807, 2809, V_{O7B}°=(3/7)V_{DD7B}=V_{7B[3]} and°V_{O7B}=(V_{7B[1]}+V_{7B[2]}+V_{7B[3]}).→°V_{7B[3]}=°V_{O7B}−V_{7B[1]}−V_{7B[2]}=(3/7)V_{DD7B}−°(2) [(2/7)V_{DD7B}] →°V_{7B[3]}=°(2)[(1/7)(V_{DD7B})]°=(2)Vstep°→V_{7B[3]}=(2)Vstep.

Accordingly, for methodology 2800, and for each NDE in the driver 780, Vᵢ, the terminal voltage of the i-th NDE is also constant (equal to (2)Vₛₜₑₚ) for each NDE in the driver 780 applying methodology 2800. In Variant D, Vᵢ is equal to two times the change in V_{O7B} per stage, with Vᵢ=(2)Vstep. Vstep=V_{DD7B}/nstep=V_{DD7B}/7; therefore, for Variant D, Vᵢ is equal to (2)Vₛₜₑₚ, and: Vᵢ=V_{7B[1]}=V_{7B[2]}=V_{7B[3]}=(2)Vstep=(2/7)V_{DD7B}; and

Because Variant C's Vᵢ°=°Vstep is smaller than Variant D's Vᵢ°=°(2)Vstep, Variant C can use NDEs with smaller voltage ratings, which are potentially smaller in size and/or less expensive.

### Variants E, F, G, H: Capacitor Reference Rails

FIG. 29 is a circuit diagram of a capacitive element driver 2900 having three (n=3) non-dissipative elements arranged in series and seven (7) switches, in which the first switch SW_{29-0A} and second-last switch SW_{29-4A} may be disposed and electrically connected at one of their ends directly to each other, with the other end of the switch SW_{29-0A} electrically connected directly to the negative terminal of the voltage source, and with the other end of the switch SW_{29-4A} electrically connected directly to the output terminal of the driver.

The second switch SW_{29-0B} and last switch SW_{29-4B} may be disposed and electrically connected at one of their ends directly to each other, with the other end of the switch SW_{29-0B} electrically connected directly to the positive terminal of the voltage source, and with the other end of the switch SW_{29-4B} electrically connected directly to the output terminal of the driver.

The remainder of the switches (3 in number) may be associated with and electrically connected to the 3 NDEs to form a set of three switch/NDE combinations, with one end of each switch/NDE combination electrically connected to a switch node between first switch SW_{29-0A} and second-last switch SW_{29-4A}, and with the other end of the switch/NDE combination electrically connected to an NDE node between the second switch SW_{29-0B} and last switch SW_{29-4B}.

FIG. 29 shows that all of its NDE/switch combinations are configured with the switches all below the NDEs, but in other embodiments, one or more of the switches may be disposed above or below an NDE, at the designer's election.

The Methodologies. FIGS. 30A-33C-3 illustrate switching methodologies 3000, 3100, 3200, 3300 for operating the driver 2900 during the 14 stages of a complete V_{O29} driving cycle. Each methodology illustrates a different style of switching, with driver 2900/methodology 3000 (Variant E) demonstrating batch 1 switching, driver 2900/methodology 3100 (Variant F) demonstrating batch 2 switching, driver 2900/methodology 3200 (Variant G) demonstrating alternate 1 switching, and driver 2900/methodology 3300 (Variant H) demonstrating alternate 2 switching.

### Variant E (Circuit 2900/Methodology 3000: Batch 1 Switching

FIGS. 30A-30C-3 illustrate the methodology 3000 for operating the driver 2900 during stages of a complete V_{O29} driving cycle, in which FIG. 30A shows a chart 3050 of representations of sequential functional snapshots of the circuit 2900 during application of the methodology 3000. FIGS. 30B-1, 30B-2 are tables 3060, 3065, detailing the stages 3001-3014 of the methodology 3000; and FIGS. 30C-1-30C-3 graphically present the results of simulations of the operation of the methodology 3000 on the driver 2900.

The switching methodology 3000 demonstrates batch switching, because its switching pattern references the NDE voltages to one rail for some stages (switch SW_{29-0A} for the negative reference rail in stages 3001-3004, 3012-3014) and to the other rail at other stages (switch SW_{29-0B} for the positive reference rail in stages 3005-3011). The batch switching of methodology 3000 is of the batch 1 type because it starts with referencing ground first (in this context, the switching pattern starts at the methodology's second stage, because the first stage, in which the output voltage is grounded, always references the negative rail, and the first stage of the second half of the methodology, in which output voltage is at peak, always references the positive rail.

In the first initial stage 3001, the switches SW_{29-0A}, SW_{29-4A} are closed while all the other switches are open to ground the circuit's output voltage, with V_{O29}=0 at steady state. Starting with the stage 3002, the methodology 3000 maintains the switch SW_{29-0A} closed to continue referencing the negative reference rail while the switches SW₂₉₋₁, SW₂₉₋₂, SW₂₉₋₁ are closed one at a time. Recognizing that the methodology 3000 operates its first half (which drives the circuit 2900 to peak output voltage) in reverse to drive the circuit 2900 back to ground output voltage, the switching methodology 3000 proceeds as follows.

At stages 3002-3004, 3012-3014, the switch set (SW_{29-0A}, SW_{29-4B}) is closed to reference the negative rail while the switches SW₂₉₋₁, SW₂₉₋₂, SW₂₉₋₃ are closed sequentially in turn, one at a time, with stages 3002-3004 closing the switches in order to increase the output voltage in each stage, and with the stages 3012-3014 closing the switches in reverse order to decrease the output voltage in each stage. Stages 3002, 3014 close SW₂₉₋₁ to deliver V₂₉₋₁ with V_{O29}=(1/7)V_{DD29} at steady state; stages 3003, 3013, close SW₂₉₋₂ to deliver V₂₉₋₂ with V_{O29}=(2/7)V_{DD29} at steady state; and stages 3004, 3012, closing SW₂₉₋₃ to deliver V₂₉₋₃ with V_{O29}=(3/7)V_{DD29} at steady state.

At stages 3005-3007, 3009-3011, the switch set (SW_{29-0B}, SW_{29-4A}) is closed to reference a positive rail while the switches SW₂₉₋₁, SW₂₉₋₂, SW₂₉₋₃ are closed sequentially in turn, one at a time. Stages 3005-3007 close the switches in reverse order to increase the output voltage by reducing the amount subtracted from V_{DD29} in each stage; stages 3009-3011 close the switches in order to decrease the output voltage by increasing the amount subtracted from V_{DD29} in each stage; stages 3005, 3011 close SW₂₉₋₃ to deliver (V_{DD29}−V₂₉₋₃) with V_{O29}=(4/7)V_{DD29} at steady state; stages 3006, 3010 closing SW₂₉₋₂ to deliver (V_{DD29}−V₂₉₋₂) with V_{O29}=(5/7)V_{DD29} at steady state; and stages 3007, 3009 closing SW₂₉₋₁ to deliver (V_{DD29}−V₂₉₋₁) with V_{O29}=(3/7)V_{DD29} at steady state.

In stage 3008, the switch set (SW_{29-0B}, SW_{29-4B}) is closed while all the other switches are open to provide a peak output voltage of V_{DD29}.

### Variant F (Circuit 2900/Methodology 3100: Batch 2 Switching

FIGS. 31A-31C-3 illustrate the methodology 3100 for operating the driver 2900 during stages of a complete V_{O29} driving cycle, in which FIG. 31A shows a chart 3150 of representations of sequential functional snapshots of the circuit 2900 during application of the methodology 3100. FIGS. 31B-1, 31B-2 are tables 3160, 3165, detailing the stages 3101-3114 of the methodology 3100; and FIGS. 31C-1-31C-3 graphically present the results of simulations of the operation of the methodology 3100 on the driver 2900.

As with the methodology 3000, the switching methodology 3100 also demonstrates batch switching, because switch SW_{29-0A} is closed to reference the negative reference rail for multiple stages, and switch SW_{29-0B} is closed to reference the positive reference rail for multiple stages. However, while methodology 3000 has a batch 1 switching type, methodology 3100 has a batch 2 switching type, with the positive rail of the circuit 2900 referenced in stages 3102-3104, 3112-3114 and the negative rail referenced in stages 3105-3107, 3109-3111.

In stage 3101, the switch set (SW_{29-0A}, SW_{29-4A}) is closed while all the other switches are open to provide an output voltage of ground, with V_{O29}=0 at steady state. After the first stage 3101, the switching methodology 3100 operates to close switches as follows.

At stages 3102-3104, 3112-3114, the switch set (SW_{29-0B}, SW_{29-4A}) is closed to reference a positive rail while the switches SW₂₉₋₁, SW₂₉₋₂, SW₂₉₋₃ are closed in turn, one at a time, with stages 3102-3104 closing the switches in order to increase the output voltage in each stage by reducing the amount subtracted from V_{DD29} in each stage, and with the stages 3112-3114 closing the switches in reverse order to decrease the output voltage in each stage by increasing the amount subtracted from V_{DD29} in each stage. Stages 3102, 3114 close SW₂₉₋₁ to deliver (V_{DD29}−V₂₉₋₁) with V_{O29}=(1/7)V_{DD29}, at steady state; stages 3103, 3113 close SW₂₉₋₂ to deliver (V_{DD29}−V₂₉₋₂) with V_{O29}=(2/7)V_{DD29} at steady state; and stages 3104, 3112 close SW₂₉₋₃ to deliver (V_{DD29}−V₂₉₋₃) with V_{O29}=(3/7)V_{DD29} at steady state.

At stages 3105-3107, 3109-3111, the switch set (SW_{29-0A}, SW_{29-4B}) is closed to reference the negative rail while the switches SW₂₉₋₁, SW₂₉₋₂, SW₂₉₋₃ are closed sequentially in turn, one at a time, with stages 3105-3107 closing the switches in reverse order to increase the output voltage in each stage by adding an amount to V_{O29} in each stage, and with the stages 3109-3111 closing the switches in order to decrease the output voltage in each stage.

Stages 3105, 3111 close SW₂₉₋₁ to deliver V₂₉₋₃ with V_{O29}=(4/7)V_{DD29} at steady state; stages 3106, 3110 close SW₂₉₋₂ to deliver V₂₉₋₂ with V_{O29}=(5/7)V_{DD29} at steady state, and stages 3107, 3109 close SW₂₉₋₁ to deliver V₂₉a with V_{O29}=(3/7)V_{DD29} at steady state.

In stage 3108, the switches SW_{29-0B}, SW_{29-4B} is closed while all the other switches are open to provide a peak output voltage of V_{DD29}.

### Variant G (Circuit 2900/Methodology 3200): Alternate 1 Switching

FIGS. 32A-32C-3 illustrate the methodology 3200 for operating the driver 2900 during stages of a complete V_{O29} driving cycle, in which FIG. 32A shows a chart 3250 of representations of sequential functional snapshots of the circuit 2900 during application of the methodology 3200. FIGS. 32B-1, 32B-2 are tables 3260, 3265, detailing the stages 3201-3214 of the methodology 3200; and FIGS. 32C-1-32C-3 graphically present the results of simulations of the operation of the methodology 3200 on the driver 2900.

The switching methodology 3200 also demonstrates alternate switching, because, under its control, the reference rail of the circuit 2900 alternates between V_{DD29} and ground at every stage. In the even stages of the methodology 3200, the switches SW_{29-0A}, SW_{29-4B} are closed to reference the negative rail, and in the odd stages the switches SW_{29-0B}, SW_{29-4A} are closed to reference the positive rail, rendering the alternate switching pattern of the methodology of type “1.”

In stage 3201, the switch set (SW_{29-0A}, SW_{29-4A}) is closed while all the other switches are open to provide an output voltage of ground, with V_{O29}=0 at steady state. As shown in FIG. 32B-1, starting with stage 3202, the remaining switches SW₂₉₋₁, SW₂₉₋₂, SW₂₉₋₃ are closed one at a time to drive the output voltage V_{O29} from ground to peak and to ground again in the following patterns.

The stages in which the negative rail is referenced include the even stages 3202, 3204, 3206, 3210, 3212, 3214. The even stages 3202, 3204, 3206 are applied in the drive of the circuit 2900 from ground to peak. In them, the switches SW₂₉₋₁, SW₂₉₋₂, SW₂₉₋₃ are closed sequentially in turn, in order and one at a time to increase the output voltage in each stage by adding an amount to V_{O29} in each even stage. The even stages 3210, 3212, 3214 are applied in the drive from peak to ground, and the switches SW₂₉₋₁, SW₂₉₋₂, SW₂₉₋₃ are closed sequentially in turn, in reverse order, one at a time to decrease the output voltage in each stage by reducing V_{DD29} by an amount in each even stage.

Stages 3202, 3214 close SW₂₉₋₁ to deliver V₂₉₋₁ with V_{O29}=(1/7)V_{DD29} at steady state; stages 3204, 3212 close SW₂₉₋₂ to deliver V₂₉₋₂ with V_{O29}=(3/7)V_{DD29} at steady state; and stages 3206, 3210 close SW₂₉₋₃ to deliver V₂₉₋₃ with V_{O29}=(5/7)V_{DD29} at steady state.

The stages in which the positive rail is referenced include the odd stages 3203, 3205, 3207, 3209, 3211, 3213. The odd stages 3203, 3205, 3207 are in the drive from peak to ground, and the switches SW₂₉₋₁, SW₂₉₋₂, SW₂₉₋₃ are closed sequentially in turn, in reverse order, one at a time to increase the output voltage in each odd stageby reducing the amount subtracted from V_{DD29}, and in the odd stages 3209, 3211, 3213, the switches SW₂₉₋₁, SW₂₉₋₂, SW₂₉₋₃ are closed sequentially in turn, in order, one at a time to reduce the output voltage in each odd stageby increasing the amount subtracted from V_{DD29}.

Stages 3203, 3213 close SW₂₉₋₁ to deliver (V_{DD29}−V₂₉₋₃) with V_{O29}=(2/7)V_{DD29} at steady state; stages 3205, 3211 close SW₂₉₋₂ to deliver (V_{DD29}−V₂₉₋₂) with V_{O29}=(4/7)V_{DD29} at steady state; and stages 3207, 3209 close SW₂₉₋₁ to deliver (V_{DD29}−V₂₉₋₁) with V_{O29}=(3/7)V_{DD29} at steady state.

In stage 3208, the switches SW_{29-0B}, SW_{29-4B} are closed while all the other switches are open to provide a peak output voltage of V_{DD29}.

### Variant H (Circuit 2900/Methodology 3300): Alternate 2 Switching

FIGS. 33A-33C-3 illustrate the methodology 3300 for operating the driver 2900 during stages of associated complete driving cycles, in which FIG. 33A shows a chart 3350 of representations of sequential functional snapshots of the circuit 2900 during application of the methodology 3300. FIGS. 33B-1, 33B-2 are tables 3360, 3365, detailing the stages 3301-3314 of the methodology 3300; and FIGS. 33C-1-33C-3 graphically present the results of simulations of the operation of the methodology 3300 on the driver 2900.

The switching methodology 3300 also demonstrates alternate switching because, under its control, the reference rail of the circuit 2900 alternates between V_{DD29} and ground at every stage. In the odd stages of the methodology 3300, the switches SW_{29-0A}, SW_{29-4B} are closed to reference the negative rail (grounded) and in the even stages the switches SW_{29-0B}, SW_{29-4A} are closed to reference the positive rail (with input voltage V_{DD29}), rendering the alternate switching pattern of the methodology of type “2.”

In stage 3301, the switch set (SW_{29-0A}, SW_{29-4A}) is closed while all the other switches are open to provide an output voltage of ground, with V_{O29}=0 at steady state. As shown in FIG. 33B-1, starting in stage 3302, the remaining switches SW₂₉₋₁, SW₂₉₋₂, SW₂₉₋₃ are closed one at a time to drive the output voltage V_{O29} from ground to peak and to ground again in the following patterns.

The stages in which the positive rail is referenced in the even stages 3302, 3304, 3306, 3310, 3312, 3314. The even stages 3302, 3304, 3306 are applied in the driver to the circuit 2900 from ground to peak. In them, the switches SW₂₉₋₁, SW₂₉₋₂, SW₂₉₋₃ are closed sequentially in turn, in reverse order one at a time to increase the output voltage in each even stage by reducing the amount subtracted from V_{DD29}. The even stages 3310, 3312, 3314 are applied in the drive from peak to ground, and the switches SW₂₉₋₁, SW₂₉₋₂, SW₂₉₋₃ are closed sequentially in turn, in order, one at a time to decrease the output voltage in each odd stageby increasing the amount subtracted from V_{DD29}.

Stages 3302, 3314 close SW₂₉₋₁ to deliver (V_{DD29}−V₂₉₋₃) with V_{O29}=(1/7)V_{DD29}, at steady state; stages 3304, 3312 close SW₂₉₋₂ to deliver (V_{DD29}−V₂₉₋₂) with V_{O29}=(3/7)V_{DD29} at steady state, and stages 3306, 3310 close SW₂₉₋₁ to deliver (V_{DD29}−V₂₉₁) with V_{O29}=(5/7)V_{DD29} at steady state.

The stages in which the negative rail is referenced in the odd stages 3303, 3305, 3307, 3309, 3311, 3313. The odd stages 3303, 3305, 3307 are applied in the drive of the circuit 2900 from ground to peak. In them, the switches SW₂₉₋₁, SW₂₉₋₂, SW₂₉₋₃ are closed sequentially in turn, in order, one at a time to increase the output voltage in each odd stage by adding an amount to V_{O29}. The odd stages 3309, 3311, 3313 are applied in the drive from peak to ground, and the switches SW₂₉₋₁, SW₂₉₋₂, SW₂₉₋₃ are closed sequentially in turn, in reverse order, one at a time to reduce V_{O29} by an amount in each odd stage.

Stages 3303, 3313 close SW₂₉₋₁ to deliver V₂₉a with V_{O29}=(1/7)V_{DD29} at steady state; stages 3305, 3311 close SW₂₉₋₂ to deliver V₂₉₋₂ with V_{O29}=(3/7)V_{DD29} at steady state; and stages 3307, 3309 close SW₂₉₋₃ to deliver V₂₉₋₃ with V_{O29}=(5/7)V_{DD29} at steady state.

In stage 3308, the switches SW_{29-0B}, SW_{29-4B} are closed while all the other switches are open to provide a peak output voltage of V_{DD29}.

Simulations. Four hundred simulations were conducted on the Variants E, F, G, H, with screen shot 3070 (FIG. 30C-1), screen shot 3170 (FIG. 31C-1), screen shot 3270 (FIG. 32C-1), and screen shot 3370 (FIG. 33C-1) showing simulations of Variants E, F, G, H constituting operating the methodologies 3000, 3100, 3200, 3300, respectively, on the driver 780 through four hundred (400) applications of a complete fourteen (14) stage V_{O7B} driving cycle (from stages 3001-3014, stages 3101-3114, stages 3201-3214, stages 3301-3314, respectively, 400 times). Four hundred applications of each methodology through the complete V_{O7B} driving cycle corresponds to 400 (14 stages)=5,600 timesteps of simulation for each Variant. Therefore, the simulations shown in the screen shots 3070, 3171, 3271, 3371 constitutes operating the circuit 780 through 5,600 timesteps.

The screen shots 3070, 3170, 3270, 3370 show simulations of the capacitor voltage V_{7B[1]} of the driver 780 in graph lines 3071, 3171, 3271, 3371, respectively, simulations of the capacitor voltage V_{7B[2]} in the graph lines 3072, 3172, 3272, 3372, respectively, and simulations of the capacitor voltage V_{7B[3]} in the graph lines 3073, 3173, 3273, 3373, respectively.

The screen shots 3080, 3180, 3280, 3380 show simulations of the first three applications of the 400 applications of the methodologies 3000, 3100, 3200, 3300, respectively, on driver 780, with the driver output voltage V_{O7B} during those first cycles represented in graph lines 3082, 3182, 3282, 3382, respectively. The screen shot 3090, 3190, 3290, 3390 focus on three applications of the methodology near the end of the 400 applications, with the driver output voltage V_{O7B} represented in graph lines 3092, 3192, 3292, 3392, respectively.

### Comparison of Variants E, F, G, H

The comparison charts 3369a, 3369b in FIG. 33D-1, 33D-2 shows the differences between the methodologies 3000, 3100, 3200, 3300, with the stages of methodology 3000 shown in regular non-italic font, the stages of methodology 3100 shown in bolded non-italic font, the stages of methodology 3200 shown in bolded regular font, and the stages of methodology 3300 shown in bolded italic font.

Capacitor Reference Rail: Variants E, F, G, H all demonstrate a switched capacitor reference rail because all systems swing their output voltages between highest and lowest ground voltage levels. Methodology 3000, 3100 illustrate batched switching because switch SW_{29-0A} is closed to reference the negative reference rail for multiple stages, and switch SW_{29-0B} is closed to reference the positive reference rail for multiple stages. Methodology 3000 illustrates batch 1 switching because it starts at its stage 3002 with referencing ground, and Methodology 3200 illustrates batch 2 switching because it starts at its stage 3102 with referencing V_{DD29} first.

Methodologies 3200, 3300 illustrate alternate switching because their capacitor voltages change between reference rails at each stage. Methodology 3000 illustrates alternate 1 switching because it starts is cycle at its stage 3202 with referencing ground, and Methodology 3200 illustrates alternate 2 switching because it starts its cycle at its stage 3302 with referencing V_{DD29} first.

Capacitor Configuration: Variants E, F, G, H provide a non-stacked capacitor configuration, because the NDEs in the circuit 2900, which is common to all of the Variants E, F, G, H, are all connected in parallel.

Stacked Capacitor Voltage Operation: Variants E, F, G, H provide neither a + or − stacked capacitor voltage operation, because their NDEs are not stacked, but it can be seen that each of the methodologies 3000, 3100, 3200, 3300 causes the circuit 2900 to operate from ground in certain stages and from V_{DD29} in other stages.

nstep: The number of steps (nstep) for each of the Variants E, F, G, H equals 7 (applying seven stages 02-08 to the circuit 2900 to drive the output voltage to peak, and applying seven stages 09-14, 01 to return the output voltage to ground). An adapted version of the methodologies 3000, 3100, 3200, 3300 for a 2-NDE version of the circuit 2900 would generate nstep=5, a 1-NDE version of the circuit 2900 would generate nstep=3, and an n-NDE version of the circuit 780 would generate nstep=2n+1.

Vstep: A noted above, the driver output step size Vₛₜₑₚ, where Vₛₜₑₚ°=°V_{DD}/nstep, is based on the subject driver's input voltage V_{DD} from the driver's given supply rail. With its nstep°=7, Vstep=(1/7)V_{DD29} and V_{DD29}=(7)Vstep.

Capacitor Voltage (Vᵢ): In switching methodologies 3000, 3100, 3200, 3300, as applied to the driver 2900, V_{O29} increases by (1/7)V_{DD29} at each stage, and then decreases by the same amount. Further, each of the four methodologies is defined to allow access to only one NDE at each of its stages, with each switch associated with the NDEs blocking access to the capacitor voltage of its NDE when open, and, providing access to its NDE when closed. At each methodology stage, only one NDE provides capacitor voltage during a selected stage, with no other NDEs providing capacitor voltages, so the capacitor voltage provided by the selected NDE will equal the capacitor voltage provided by the NDE accessed during the last previously applied stage plus the change in output voltage (Vstep=(1/7)V_{DD29}). Accordingly, in the four variants, the capacitor voltage Vᵢ is linear, with the Vᵢ for each NDE increased by Vstep=(1/7)V_{DD} from the Vᵢ for the NDE that it next follows in the driver.

Variant E: Vᵢ°=° (i)Vₛₜₑₚ. For Variant E, its batch 1 methodology 3000 stages reference the negative rail in the first NDE-accessing switching set (stages 3002-3004) and in the last NDE-accessing switching set (stages 3012-3014); and its stages reference the positive rail, namely the second NDE-accessing switching set (stages 3005-3007) and the third NDE-accessing switching set (stages 3009-3011). The methodology 3000 increases to peak voltage by referencing the negative rail while the NDEs are accessed one at a time in order, then referencing the positive rail while the NDEs are accessed one at a time in reverse order. The methodology 3000 then decreases from peak voltage to ground by referencing the positive rail while the NDEs are accessed one at a time in order, then referencing the negative rail while the NDEs are accessed one at a time in reverse order.

Referring to FIG. 30B-1 (with V₂₉₋ᵢ being Vᵢ for the i^{th} NDE in the driver 2900) and, as in the other embodiments disclosed herein, with nstep°=7 and Vstep=(1/7)V_{DD29},
at stages 3002, 3014, V_{O29}=°V₂₉₋₁°=(1/7)V_{DD29}°=°Vₛₜₑₚ°→°V₂₉₋₁°=(1)Vₛₜₑₚ.
at stages 3003, 3013, V_{O29}=V₂₉₋₂°=°(2/7)V_{DD29}°=°(2)[(1/7)V_{DD29}]°=(2)Vₛₜₑₚ°→°V₂₉₋₂=(2)Vₛₜₑₚ; and
at stages 3004, 3012, V_{O29}=V₂₉₋₃°=°(3/7)V_{DD29}°=°(3)[(1/7)V_{DD29}]°=(3)Vₛₜₑₚ°→°V₂₉₋₃=(3)Vₛₜₑₚ.

Accordingly, for methodology 3000, Vᵢ, the terminal voltage of the i-th NDE in the driver 2900 is linear (equal to (i)Vstep for each NDE in the driver). This can be confirmed by reviewing the stages in the methodology 3100 that reference the positive rail (stages 3005-3107 and 3109-31114).

The methodologies for Variants F, G, H have the same number of stages as methodology 3000, and their stages apply the same switch closures, and they all switch the reference rails of the driver 2900, but, referring to the comparison charts 3369a, 3369b, the methodologies apply the switch closures and reference rails in different manners.
In Variant F, the methodology 3100 increases to peak voltage by referencing the positive rail while the NDEs are accessed one at a time in reverse order, then referencing the negative rail while the NDEs are accessed one at a time in order.
The methodology 3100 then decreases from peak voltage to ground by referencing the negative rail while the NDEs are accessed one at a time in reverse order, then referencing the positive rail while the NDEs are accessed one at a time in order.

Therefore, while methodology 3000 is applied to the driver 2900:
at stages 3002-3004, output voltage is increased by closing the three switches SW₂₉₋₁, SW₂₉₋₂, SW₂₉₋₃ in order with a negative reference rail, and
at stages 3012-3014 output voltage is decreased by closing the three switches in reverse order with a negative reference rail.

Variant F: linear with°=°[(2n+1−i)Vstep]. While methodology 3100 is applied to the same driver 2900:
at stages 3105-3107, output voltage is increased by closing the three switches in reverse order with a negative reference rail, and
at stages 3109-3111 decreases output voltage by closing the three switches in order with a negative reference rail.
   Similar observations may be made with the switching that references the positive rails. Therefore, it can be seen that a driver's NDEs will have different Vᵢ based on the methodology applied to the driver.

For Variant F, its batch 2 methodology 3100 stages reference the positive rail in the first NDE-accessing switching set (stages 3102-3104) and the last NDE-accessing switching set (stages 3112-3114); and its stages reference the negative rail in the second NDE-accessing switching set (stages 3105-3107) and the penultimate NDE-accessing switching set (stages 3109-3111).

Referring to FIG. 31B-1, with V₂₉₋ᵢ being Vᵢ for the i^{th} NDE in the driver 2900 and, as in the other embodiments disclosed herein, with nstep=7, Vstep°=°V_{DD29}/nstep, and V_{DD29}=(Vstep)(nstep):
at stages 3107, 3109, V_{O29}=V₂₉₋₁=°(3/7)V_{DD29}=(6)[(1/7)V_{DD29}]=°(6)Vstep°→°V₂₉₋₁°=°(6)Vstep;
at stages 3106, 3110, V_{O29}°=V₂₉₋₂=(5/7)V_{DD29}=(5)[(1/7)V_{DD29}]=°(5)Vstep°→°V₂₉₋₂°=°(5)Vstep; and
at stages 3105, 3111, V_{O29}°=V₂₉₋₃=(4/7)V_{DD29}=(4)[(1/7)V_{DD29}]=(4)Vstep°→°V₂₉₋₃°=°(4)Vstep.

Because V₂₉₋₁=(6)Vstep, V₂₉₋₂=(5)Vstep, V₂₉₋₁=(4)Vstep, by extrapolation Variant F's Vᵢ°=°(2n+1−i)Vₛₜₑₚ, with i referring to the i-th NDE in the driver 700G. Therefore, for Variant F, Vᵢ° is linear and equal to [(2n+1−i)Vstep]. This can be confirmed by reviewing the stages in the methodology 3100 that reference the positive rail (stages 3102-3104 and 3112-3114).

Variant G: linear with °Vᵢ°=(2i−1)Vₛₜₑₚ. For Variant G, its alternate 1 methodology 3200 stages reference the negative rail in its even-numbered stages; and they reference the positive rail in its odd-numbered stages. In the methodology 3200, the stages which reference the negative rail (namely the even-numbered stages), and referring to FIG. 32B-1 (with V₂₉₋ᵢ being Vᵢ for the i^{th} NDE in the driver 2900) and with nstep°=7 and Vstep=(1/7)V_{DD29}:
at stages 3202, 3214, V_{O29}°=V₂₉₋₁=°(1/7)V_{DD29=}°Vₛₜₑₚ°→°V₂₉₋₁°=(1)Vₛₜₑₚ;
at stages 3204, 3212, V_{O29}°=V₂₉₋₂°=°(3/7)V_{DD29}=°(3)[(1/7)V_{DD29}]°=(3)Vₛₜₑₚ°→°V₂₉₋₂=(3)Vₛₜₑₚ; and
at stages 3206, 3210, V_{O29}°=V₂₉₋₃°=°(5/7)V_{DD29}=(5)[(1/7)V_{DD29}]°=(3)Vₛₜₑₚ°→°V₂₉₋₃=(5)Vₛₜₑₚ.

Because V₂₉₋₁=(1)Vstep, V₂₉₋₂=(3)Vstep, V₂₉₋₃=(5)Vstep, by extrapolation Variant G's Vᵢ°=°(2i−1)Vₛₜₑₚ, with i referring to the i-th NDE in the driver 700G. Therefore, for Variant G, Vᵢ° is linear and equal to [(2i−1)Vstep]. This can be confirmed by reviewing the stages in the methodology 3200 that reference the positive rail (stages 3103, 3105, 3507, 3509, 3511, 3513).

Variant H: linear with °Vᵢ°=(2i)Vₛₜₑₚ. In Variant H, the methodology 3300 applies alternate 2 switching, in which it references the negative rail in its odd-numbered stages; and it references the positive rail in its even-numbered stages. Referring to FIG. 33B-1, with V₂₉₋ᵢ being Vᵢ for the i^{th} NDE in the driver 2900 with nstep=7, V_{DD29}=(Vstep)(nstep)=, in its odd-numbered stages:
at stages 3303, 3313, V_{O29}°=V₂₉₋₁=(2/7)V_{DD29}=(2)[(1/7)V_{DD29}]°=(2)Vₛₜₑₚ°→°V₂₉₋₁=(2)Vₛₜₑₚ;
at stages 3305, 3311, V_{O29}°=V₂₉₋₂=(4/7)V_{DD29}=(4)[(1/7)V_{DD29}]°=(4)Vₛₜₑₚ°→°V₂₉₋₂=(4)Vₛₜₑₚ;
at stages 3307, 3309, V_{O29}°=V₂₉₋₃=(3/7)V_{DD29}=(6)[(1/7)V_{DD29}]°=(2)Vₛₜₑₚ°+°V₂₉₋₃=(6)Vₛₜₑₚ.

Because V₂₉₋₁=(2) Vstep, V₂₉₋₂=(4) Vstep, V₂₉₋₃=(6) Vstep, by extrapolation Variant H's Vᵢ°=°(2i)Vₛₜₑₚ, with i referring to the i-th NDE in the driver 700H. Therefore, for Variant H, V₁° is linear and equal to [(2i)Vstep]. This can be confirmed by reviewing the stages in the methodology 3200 that reference the positive rail (stages 3102, 3104, 3506, 3510, 3512, 3514).

Switching/NDE Reference Rail Types. As shown in the comparison charts 3369a, 3369b, in FIGS. 33D-1, 33D-2, each stage of their respective methodologies 3000, 3100, 3200, 3300 adds an amount to the driver's output voltage in its executing phase and subtracts an amount from the driver's output voltage in its reverse executing phase, no matter from which NDE capacitor output voltage is delivered. In addition, when referencing the positive rail, each stage adds to the output voltage by increasing the amount added to V_{DD}, and reduces the output voltage by increasing the amount subtracted from V_{DD}, no matter from which NDE the voltage is delivered.

Further, all their methodologies, which are associated with the driver 2900 in which NDEs are arranged in parallel, are internally consistent in their stages for increasing and decreasing the output voltage on the circuit 2900. Specifically, not only are the methodologies' switching patterns in their executing phases repeated in reverse order in the methodologies' reverse executing phases, their patterns in each phase of accessing NDEs of driver 2900 (in a selected order and with reference to one of its capacitor reference rail) are repeated in reverse order with reference to the other of its capacitor reference rails. Therefore, in order to achieve the staircase driver output, the switching sequence associated with referencing one reference rail is performed in reverse order of that associated with its other reference rail.

Variant E: Batch 1 Switching. For example, referring to FIGS. 30B-1, 30B-2, Variant E achieves the staircase driver output in its executing phase 3064 by using a batch1 switching pattern, first accessing its driver's NDEs in a selected order (C_{29_1}, C₂₉₋₂, C₂₉₋₃) using its negative reference rail, and then accessing them in reverse order (C₂₉₋₃, C₂₉₋₂, C_{29_1}) while using its positive reference rail. Then, in Variant E's reverse executing phase 3068, Variant E maintains the order of the NDEs as they were applied in its executing phase 3064 (C_{29_1}, C₂₉₋₂, C₂₉₋₃) then (C₂₉₋₃, C₂₉₋₂, C_{29_1}), but reverses the order in which its reference rail is used, with 3 stages accessing using its positive reference rail, and then 3 stages accessing its positive reference rail.

The switching pattern in which the order of access of a circuit's NDEs while referencing one reference rail is performed in reverse order while referencing the other reference rail continues with Variants F, G, H, K, L, irrespective of whether their associated methodologies access their driver's capacitor reference rails in batch or alternately.

Variant F: Batch 2 Switching. Referring to FIGS. 31B-1, 31B-2, Variant F uses a batch 2 switching pattern, swapping the order of accessing its reference rails while maintaining the order of NDE switching as is performed by Variant E throughout its entire switching cycle (for both executing and non-executing phases). Variant F achieves the staircase driver output in its executing phase 3164 by accessing its driver's NDEs in the same order as Variant E (C_{29_1}, C₂₉₋₂, C₂₉₋₃) then (C₂₉₋₃, C₂₉₋₂, C_{29_1}), but first accessing its positive reference rail for 3 stages and then its negative reference rail for 3 stages. Then, in Variant E's reverse executing phase 3168, Variant E maintains the order of the NDEs as they were applied in its executing phase 3164, but reverses the order of accessing its reference rail, first accessing its positive reference rail for 3 stages and then its negative reference rail for 3 stages in its executing stage, and then accessing its negative reference rail for 3 stages and then its positive reference rail for 3 stages in its reverse executing phase.

Variant G: Alternate 1 Switching. Referring to FIGS. 32B-1, 32B-2, Variant G uses an alternate1 switching in its methodology 3200. Variant G starts its executing phase 3264 referencing the same rail as does Variant E, with its first stage referencing the negative capacitor rail. Variant G then alternates between the positive and negative rails through the rest of its executing phase, ending with the positive rail. Then in its reverse executing phase 3268, Variant G references the rails in the reverse of its referencing in the executing phase, starting with the positive rail and ending with the negative rail.

Throughout its entire switching cycle (for both executing and non-executing phases), when Variant G reference one of the rails, it accesses its NDEs in those stages in the same order as Variant E accesses its NDEs when Variant E references that rail. Specifically Variant G accesses its NDEs C₂₉₋₁, C₂₉₋₂, C₂₉₋₃ in its negative rail stages in the same order as Variant E accesses its NDEs C_{29_1}, C₂₉₋₂, C₂₉₋₃ in its negative rail stages, and accessing its NDEs C₂₉₋₃, C₂₉₋₂, C₂₉₋₁ in its positive rail stages in the same order as Variant E accesses its NDEs C₂₉₋₃, C₂₉₋₂, C₂₉₋₁ in its negative rail stage.

Variant H: Alternate 2 Switching. Referring to FIGS. 33B-1, 33B-2, Variant H uses a batch 2 switching pattern, swapping the order of accessing its reference rails relative to the referencing in Variant G. Variant H achieves the staircase driver output in its executing phase 3364 by referencing the positive rail in its first executing phase stage, and then alternating between the negative and positive rails through the rest of its executing phase; and then, in its reverse executing phase 3368, referencing the rails in its stages in the reverse of its referencing order in the executing phase 3364, starting with the negative rail and ending with the positive rail.

Throughout its entire switching cycle, Variant G accesses its driver's NDEs associated with a selected reference rail in the same order as they are accessed in Variant G, with, when Variant H references one of the rails, it accesses its NDEs in those stages in the same order as Variant G accesses its NDEs when Variant G references that rail. Specifically Variant H accesses its NDEs C_{29_1}, C₂₉₋₂, C₂₉₋₃ in its negative rail stages in the same order as Variant E accesses its NDEs C_{29_1}, C₂₉₋₂, C₂₉₋₃ in its negative rail stages, and accesses its NDEs C₂₉₋₃, C₂₉₋₂, C₂₉₋₁ in its positive rail stages in the same order as Variant E accesses its NDEs C₂₉₋₃, C₂₉₋₂, C₂₉₋₁ in its negative rail stage.

In Variant E, F, G, H, the changes in reference rails and NDE accessing orders results in allowing the same driver 780 to yield different NDE voltages for a selected stage. Note though, that the methodology switch does not require a change of components, such as NDEs C_{29_1}, C₂₉₋₂, C₂₉₋₃ or V_{DD29} when driver 780 is associated with a different methodology. For example, in Variant E, V₂₉₋₁°=°(1)Vₛₜₑₚ, and in Variant F, V₂₉₋₁°=°(6)Vₛₜₑₚ. In both variants, only one NDE C_{29_1}, is activated, but in Variant E, it references the negative rail. and in Variant F, it references the positive rail. So, by application of a methodology that is appropriate for driving a selected capacitive element, NDE C₂₉₋₁ may have very different voltages for the same stage position. Therefore, a capacitive element driving system may obtain the feature of changing methodologies to be applied to the same driver 780 in order to accommodate different system use requirements. Thus, NDE voltages can be very different depending on the methodology used. In steady state, the output voltage of the capacitive element driver will be the same at each stage for all methodologies, but the NDE voltages are different.

Note that the described switching patterns for Variants E, F, G, H are not applicable for certain other variants described herein, for example, Variants A1, A2, B1, B2, I, J due to their having fixed capacitor reference rails (their methodologies access only a single reference rail).

It may be applicable in Variants C, D, with their stacked-capacitor configurations. In fact, two illustrative but not necessarily preferred embodiments are possible, in which two additional variants P, Q of stacked-capacitor configurations could use different methodologies with switching patterns of type Batch 2 and Alternate 1, similar to the switching patterns of the corresponding non-stacked variants F, G.

In short, while the staircase driver output is achievable by switching the NDEs in certain specific orders and patterns, the inter-relationship between methodology, Vᵢ, nstep, and reference rails, in general sense (which is not Variant specific), is that a Variant's methodology sequence of stages defines how the NDEs are accessed and activated, thereby controlling the driver's access to a given reference rail.

Not all methodologies will yield a staircase driver output, which is one voltage pattern having certain efficiencies. Only certain methodologies can yield a staircase driver output, and these methodologies differ in their achievable nsteps. Usually, V_{DD} for a driver is a given in a particular application for driving a capacitive element, and is determined by the selected voltage source. A higher nstep means a finer Vstep (=VDD/nstep), and more potential energy savings, in a very general sense, while a lower nstep means a speedier completion of a switching cycle, which may result in a quicker attainment of a steady state.

For example, a system controller such as the controller 460 may be electrically connected to the switches SW_{4[0]}, SW_{4[1]}, SW_{4[2]}, SW_{4[3]} of a driver 400 through paths 470, 471, 472, 473 respectively (shown in FIG. 4 in broken lines) to provide control signals to signal the capacitive element driver 400 to start or stop a switching sequence methodology, or to switch methodologies. The controller may apply to the switches of a driver a first methodology having a low nstep to bring the driver quickly to a selected level. This methodology can be applied for a certain number of cycles, a specific amount of time, or until a system's performance metric is met, such as attainment of steady state operation (or to near steady state operation). Then a second methodology can be applied, such as one with a higher nstep to operate the driver with greater efficiency in its steady state performance.

While, in the short time that the first methodology operates, the driver will not be achieving optimal energy conservation, the speedier attainment of steady state performance may outweigh the temporary loss of energy efficiency.

For example, Variant E has lower NDE capacitor voltages (with V₂₉₋₁°=°Vstep, V₂₉₋₂°=°(2)Vstep, V₂₉₋₃°=°(3)Vstep) compared with Variant F voltages (with V₂₉₋₁°=°(6)Vstep, V₂₉₋₂°=°(5)Vstep, V₂₉₋₁°=°(4) Vstep), Variant G voltages (with V₂₉₋₁°=°Vstep, V₂₉₋₂°=°(3)Vstep, V₂₉₋₃°=°(5)Vstep), and Variant H voltages (with V₂₉₋₁°=°(2) Vstep, V₂₉₋₂°=°(4)Vstep, V₂₉₋₁°=°(6) Vstep). As a result, the NDE capacitors that are usable in Variant E's driver 2900 may have lower voltage-rating, which can be smaller in size and/or less expensive generally. Generally, there are no drawbacks to NDEs being smaller in size.

Other things being equal, Variant E may have lower NDE voltages than Variants F/G/H, with Variant E's V₁=Vstep, V₂=(2)(Vstep), V₃°=°(3)(Vstep) compared with the NDE voltages of Variants F/G/H. As a result, Variant E could implement the NDEs with capacitors having lower voltage ratings, which can be smaller in size and/or less expensive generally. Similarly, Variants A2 and C have lower NDE voltages than their driver counterparts with different methodologies.

Many methodologies, such as methodologies in which NDEs are accessed one at a time, could access a driver's NDEs in any desired order. As an example, methodologies 2700, 2800, 3000-3300, each could have 6 different options for switching SW₁, SW₂, SW₃ on the positive and negative rails. Using methodology 3000 as an example, the following chart shows the options for batch switching variants of such methodologies to bring the driver's output voltage for from ground to V_{DD}:

| Switching | | possible reverse executing |
|---|---|---|
| SW₂₉₋₁-SW₂₉₋₃ | possible executing combinations | combinations |
| 3000-1 (like 3000) | in order (SW₂₉₋₁, SW₂₉₋₂, SW₂₉₋₃) | in reverse order (SW₂₉₋₃, SW₂₉₋₂, SW₂₉₋₁) |
| 3000-2 | in order (SW₂₉₋₁, SW₂₉₋₃, SW₂₉₋₂) | in reverse order (SW₂₉₋₂, SW₂₉₋₃, SW₂₉₋₁) |
| 3000-3 | in order (SW₂₉₋₂, SW₂₉₋₁, SW₂₉₋₃) | in reverse order (SW₂₉₋₃, SW₂₉₋₁, SW₂₉₋₂) |
| 3000-4 | in order (SW₂₉₋₂, SW₂₉₋₃, SW₂₉₋₁) | in reverse order (SW₂₉₋₁, SW₂₉₋₃, SW₂₉₋₂) |
| 3000-5 | in order (SW₂₉₋₃, SW₂₉₋₁, SW₂₉₋₂) | in reverse order (SW₂₉₋₂, SW₂₉₋₁, SW₂₉₋₃) |
| 3000-6 | in order (SW₂₉₋₃, SW₂₉₋₂, SW₂₉₋₁) | in reverse order (SW₂₉₋₁, SW₂₉₋₂, SW₂₉₋₃) |

| | |
|---|---|
| Possible positive/negative switching combinations | 6 |

Variant I/J with Circuit 3400: Adding Stages to Fixed Reference Rail System

The driver 3400 shown in FIG. 34C-2 illustrates a 3-NDE capacitive element driver with nine switches and may be operated in accordance with methodology 3500 (with its 14-stage driving cycle) and with methodology 3600 (with its 16-stage driving cycle.) As described below, the additional stages in methodology 3600 causes changes in the amount of time that is required to apply the methodology and in the output voltage produced per stage.

FIG. 34 is a circuit diagram of the capacitive element driver 3400 having three (n=3) NDEs C₃₄₋₁, C₃₄₋₂, C₃₄₋₃ and nine (9) switches, SW₃₄₋₀, SW_{34-1B}, SW_{34-1C}, SW_{34-2B}, SW_{34-2C}, SW_{34-3B}, SW_{34-3C}, SW_{34-4A}, and SW_{34-4B}, with:
a positive interconnection 3416 having a node 3455 disposed between a circuit output terminal 3404 and a positive terminal 3426 of the voltage source 3420, and a negative interconnection 3418 having node 3451a, 3451b disposed between the circuit output terminal 3404 and a negative terminal 3428 of the voltage source 3420;
node 3451a, NDE C₃₄₋₁, switch SW_{34-1B}, NDE C₃₄₋₂, switch SW_{34-2B}, NDE C₃₄₋₃, switch SW_{34-3B}, switch SW_{34-4B}, and node 3455 arranged in series;
nodes 3452a, 3453a, 3454 disposed between switch SW_{34-1B} and NDE C₃₄₋₂, switch SW_{34-2B} and NDE C₃₄₋₃, switch SW_{34-3B} and switch SW_{34-4B}; respectively;
a switch SW₃₄₋₀ disposed on the positive interconnection 3416 between the node 3455 and the positive terminal 3426 of the voltage source 3420, and a switch SW_{34-4A} disposed on the negative interconnection 3418 between the node 3451a and the circuit output terminal 3404;
switch SW_{34-1C}, node 3452b, switch SW_{34-2C}, node 3453b, switch SW_{34-3C}, connected in series between the node 3454 and a node 3451b; and
interconnections 3412, 3413 disposed between the nodes 3452a, 3452b and the nodes 3453a, 3453b, respectively.

### Variant I (Circuit 3400/Methodology 3500): Basic Fixed Reference Rail System

FIGS. 35A-35C-3 illustrate the methodology 3500 for operating the driver 3400 during stages of a complete driving V_{O34} cycle, in which FIG. 35A shows a chart 3550 of representations of sequential functional snapshots of the circuit 3400 during application of the methodology 3500. FIGS. 35B-1, 35B-2 are tables 3560, 3565, detailing the stages 3501-3514 of the methodology 3500; and FIGS. 35C-1-35C-3 graphically present the results of simulations of the operation of the methodology 3300 on the driver 3400.

The switching methodology 3500 demonstrates a fixed reference rail, because, except for stage 3508, which provides V_{DD34} as circuit's output voltage, its switching pattern references only the negative rail for all stages.

In the first initial stage 3501, SW_{34-4A} is closed to ground the circuit's output voltage with V_{O34}=0 at steady state. The switches SW_{34-1C}, SW_{34-2C}, SW_{34-3C} are also closed. Closing SW_{34-4A} alone would ground the driver's output voltage, but methodology 3500 optionally closes switches SW_{34-1C}, SW_{34-2C}, SW_{34-3C} to ground the nodes 3454, 3453a, 3452a so that their potentials are defined instead of being floating, which is generally a good practice. One potential disadvantage to closing the switches SW_{34-1C}, SW_{34-2C}, SW_{34-3C} to avoid floating circuit nodes is that this may charge and discharge parasitic (“stray”) capacitances in the circuit, causing some additional power loss. SW_{34-4B} may be closed too. It is optional.

A similar set of switch closings (closing switches SW_{34-1C}, SW_{34-2C}, SW_{34-3C} to ground the nodes 3454, 3453a, 3452a) may be used to avoid floating circuit nodes during transmission of the voltage V_{DD} (peak) across the power rail. It is the circuit designers' option whether or not to ground the nodes 3454, 3453a, 3452a when imparting ground or peak, with their decision involving application-specific and/or conventional transistor level implementation details.

Except for during the peaking stage 3508, the methodology 3500 maintains the switch SW_{34-4B} closed and the switches SW_{34-4A}, SW₃₄₋₀ open during stages 3502-3514 to cause the driver 3400 to reference the negative rail, and in so doing provide an electrical path between the NDEs accessed during those stages and the output terminal 3404 for the duration of the application of the rest of the cycle. During stages 3502-3507, the switches SW_{34-1B}, SW_{34-2B}, SW_{34-3B}, SW_{34-1C}, SW_{34-2C}, SW_{34-3C} are closed alone or in selected combinations to provide incremental increase in the output voltage in each stage, and at stages 3509-3514, those switches are closed alone or in selected combinations to provide incremental decrease in the output voltage in each stage.

Recognizing that the methodology 3500 operates its executing phase (which drives the circuit 3400 to peak output voltage) in reverse to drive the output voltage of the circuit 3400 back to ground, the switching methodology 3500 proceeds at steady state as follows:
stages 3502, 3514, deliver V_{O34}=V₃₄₋₁=(1/7)V_{DD34} by closing SW_{34-1B} to access C₃₄₋₁ and closing SW_{34-2C}, SW_{34-3C} to bypass C₃₄₋₂, C₃₄₋₃;
stages 3503, 3513 deliver V_{O34}=V₃₄₋₂=(2/7)V_{DD34} by closing SW_{34-2B} to access C₃₄₋₂ and closing SW_{34-1C}, SW_{34-3C} to bypass C₃₄₋₁, C₃₄₋₃;
stages 3504, 3512 deliver V_{O34}=V₃₄₋₃=(3/7)V_{DD34} by closing SW_{34-3B} to access C₃₄₋₃ and closing SW_{34-1C}, SW_{34-2C} to bypass C₃₄₋₁, C₃₄₋₂;
stages 3505, 3511 deliver V_{O34}=(V₃₄₋₁+V₃₄₋₃)°=(4/7)V_{DD34} by closing SW_{34-1B}, SW_{34-3B} to access C₃₄₋₁, C₃₄₋₃, and closing SW_{34-2C} to bypass C₃₄₋₂;
stages 3506, 3510 deliver V_{O34}=(V₃₄₋₂+V₃₄₋₃)°=°(5/7)V_{DD34} by closing SW_{34-2B}, SW_{34-3B} to access C₃₄₋₂, C₃₄₋₃, and closing SW_{34-1C} to bypass C₃₄₋₁; and
stages 3507, 3509 deliver V_{O34}=(V₃₄₋₁+V₃₄₋₂+V₃₄₋₃)=(3/7)V_{DD34} by closing SW_{34-1B}, SW_{34-2B}, SW_{34-3B} to access all three NDEs.

In stage 3508, the SW₃₄₋₀ and optional switches SW_{34-1C}, SW_{34-2C}, SW_{34-3C} are closed again to avoid floating circuit nodes at peak output voltage of V_{DD34} at steady state. Closing switches SW_{34-1C}, SW_{34-2C}, SW_{34-3C} are employed here at the circuit designer's option to avoid floating circuit nodes for peak without causing extra power loss at stage 3508.

### Variant J (Circuit 3400/Methodology 3600): Adding Stages to Variant I

FIGS. 36A-36C-3 illustrate the methodology 3600 for operating the driver 3400 during stages of associated complete driving cycles, in which FIG. 36A shows a chart 3650 of representations of sequential functional snapshots of the driver 3400 during application of the methodology 3600. FIGS. 36B-1, 36B-2 are tables 3660, 3665, detailing the stages 3601-3616 of the methodology 3600; and FIGS. 36C-1-33C-3 graphically present the results of simulations of the operation of the methodology 3600 on the driver 3400.

As with the switching methodology 3500, methodology 3600 also demonstrates a fixed reference rail, because, except for its peaking stage 3609, its switching pattern references only the negative rail for all stages. In the first stage 3601, SW _{34-4A} is closed to ground the circuit's output voltage with V_{O34}=0 at steady state. And, as in stage 3501, for the reasons described above, SW_{34-1C}, SW_{34-2C}, SW_{34-3C} are also closed at the circuit designer's option to ground the nodes 3454, 3453a, 3452a to avoid floating circuit nodes without causing extra power loss at stage 3601.

And, as in methodology 3500, except during the peaking stage 3609, methodology 3600 maintains the switch SW_{34-4B} closed during stages 3602-3614 to provide an electrical path between the NDEs accessed during those stages and the output terminal 3404 for the duration of the application of the rest of the cycle. During stages 3602-3607, the switches SW_{34-1B}, SW_{34-2B}, SW_{34-3B}, SW_{34-1C}, SW_{34-2C}, SW_{34-3C} are closed alone or in selected combinations to provide incremental increase in the output voltage in each stage, and at stages 3909-3614, they are closed alone or in selected combinations to provide incremental decrease in the output voltage in each stage.

At all stages of the methodology 3600 (except for the peaking stage 3609), SW_{34-0A}, SW_{37-4B} are closed to access the negative reference rail, and, at steady state:
stages 3602, 3616 (as with stages 3502, 3514), deliver V_{O34}=V₃₄₋₁=(1/8)V_{DD34} by closing SW_{34-1B} to access C₃₄₋₁ and closing SW_{34-2C}, SW_{34-3C} to bypass C₃₄₋₂, C₃₄₋₃;
stages 3603, 3615 (as with stages 3503, 3513) deliver V_{O34}=V₃₄₋₂=(2/8)V_{DD34} by closing SW_{34-2B} to access C₃₄₋₂ and closing SW_{34-1C}, SW_{34-3C} to bypass C₃₄₋₁, C₃₄₋₃;
stages 3604, 3614 (no counterparts in methodology 3500) deliver V_{O34}=(V₃₄₋₁+°V₃₄₋₂)°=(3/8)V_{DD34} by closing SW_{34-1B}, SW_{34-2B} to access C₃₄₋₁, C₃₄₋₂ and closing SW_{34-3C} to bypass C₃₄₋₃,
stages 3605, 3613 (as with stages 3504, 3512), deliver V_{O34}=V₃₄₋₃=(4/8)V_{DD34} by closing SW_{34-3B} to access C₃₄₋₃ and closing SW_{34-1C}, SW_{34-1C} to bypass C₃₄₋₁, C₃₄₋₂;
stages 3606, 3612 (as with stages 3505, 3511) deliver V_{O34}=(V₃₄₋₁+V₃₄₋₃)°=(5/8)V_{DD34} by closing SW_{34-1B}, SW_{34-3B} to access C₃₄₋₁, C₃₄₋₃, and closing SW_{34-2C} to bypass C₃₄₋₂;
at stages 3607, 3611 (as with the stage 3506, 3510) deliver V_{O34}=(V₃₄₋₂+V₃₄₋₃)°=°(6/8)V_{DD34} by closing SW_{34-2B}, SW_{34-3B} to access C₃₄₋₂, C₃₄₋₃, and closing SW_{34-1C} to bypass C₃₄₋₁, and
at stages 3608, 3510 (as with the stage 3507, 3509) deliver V_{O34}=(V₃₄₋₁+V₃₄₋₂+V₃₄₋₃)=(7/8)V_{DD34} by closing SW_{34-1B}, SW_{34-2B}, SW_{34-3B} to access all three NDEs.

In stage 3609 (as with stage 3508), the switch SW₃₄₋₀ is closed to provide a peak output voltage of V_{DD34} at steady state. For the reasons discussed above, the peaking methods of closing switches SW₃₄₋₀ and optionally closing switches SW_{34-1C}, SW_{34-2C}, SW_{34-3C} at the circuit designer's option avoid floating circuit nodes at peak without causing extra power loss at stage 3609.

### Comparison of Variants I, J

The comparison chart 3669 in FIG. 36D shows the differences between the methodologies 3500, 3600, with the stages of methodology 3500 shown in regular font and the stages of methodology 3600 shown in italics, with the additional stages of methodology 3600 shown in rows with double lined (thick, thin) borders.

Capacitor Reference Rail/Capacitor Configuration: variants I, J have fixed capacitor reference rails, and, because the circuit's NDEs are connected in series, they have a stacked capacitor configuration.

Stacked Capacitor Voltage Operation: Variants I, J demonstrate a + stacked capacitor voltage operation, because each of the methodologies 3500, 3600 both cause the circuit 3400 to operate from ground in all of its stages.

nstep: The nstep for Variant I equals 7 (applying seven stages 3502-3508 to circuit 3400 to drive the output voltage to peak, and applying seven stages 3509-3514, 3501 to return the output voltage to ground); and the nstep for Variant J equals 8 (applying eight stages 3602-3609 to the circuit 3400 to drive the output voltage to peak, and applying eight stages 3610-3616, 3601 to return the output voltage to ground).

Adapted versions of the methodologies 3500, 3600 for a 2-NDE version of the circuit 3400, in which n=2, would both generate nstep=4, a 1-NDE version, in which n=1, would both generate nstep=2, and, by extrapolation, an n-NDE version of the circuit 3400 would generate

$$nstep = \frac{n ( n + 1 )}{2} + 1$$

for the methodology 3500 and 2ⁿ for the methodology 3600.

Vₛₜₑₚ: As noted above, Vₛₜₑₚ is the driver output step size Vₛₜₑₚ°=°V_{DD}/nstep. For the methodology 3500, V_{O34} increases by (1/7)V_{DD34} at each stage and then decreases by the same amount. With nstep°=7 and V_{DD34}=nstep*Vstep, Vₛₜₑₚ=(1/7)V_{DD34}. For the methodology 3600, because of the two additional stages added to the methodology 3500 cycle to form the methodology 3600, nstep°=8 and Vₛₜₑₚ=(1/8)V_{DD34}.

Capacitor Voltage (Vᵢ): Variant I's fixed switching methodology 3500 as applied to the driver 3400 is defined to allow access to only one NDE at each of its stages, with each switch associated with the NDEs (SW_{34-1B} associated with NDE C₃₄₋₁, SW_{34-2B} associated with NDE C₃₄₋₂, and SW_{34-3B} associated with NDE C₃₄₋₃) blocking access to the capacitor voltage of its NDE when open, and providing access to its NDE when closed. At each methodology stage, only one NDE provides capacitor voltage during a selected stage, with no other NDEs providing capacitor voltages, so the capacitor voltage provided by the selected NDE will equal the capacitor voltage provided by the NDE accessed during the last previously applied stage plus the change in output voltage (Vstep=(1/7)V_{DD34}).

Variant I: Linear w/Vᵢ°=°(i)(Vₛₜₑₚ). In Variant I, the methodology 3500 has a fixed reference rail, with all of its stages referencing the negative rail (except for stage 3508, which provides peak voltage). Referring to FIG. 35B-1 (with V₃₄₋ᵢ being Vᵢ for the i^{th} NDE in the driver 3400) and with nstep°=7 and Vstep=(1/7)V_{DD34}:
at stages 3502, 3514, V_{O34}°=V₃₄₋₁=°(1/7)V_{DD34}=°Vₛₜₑₚ°→°V₃₄₋₁°=(1)Vₛₜₑₚ;
at stages 3503, 3513, V_{O34}°=V₃₄₋₂°=°(2/7)V_{DD34}=°(2)[(1/7)V_{DD34}]°=(2)Vₛₜₑₚ°→°V₃₄₋₂=(2)Vₛₜₑₚ;
at stages 3504, 3512, V_{O34}°=V₃₄₋₃°=°(3/7)V_{DD34}=(3)[(1/7)V_{DD34}]°=(3)Vₛₜₑₚ°→°V₃₄₋₃=(3)Vₛₜₑₚ.

Therefore, in methodology 3500, V_{V} is also V_{O34} (steady state), which is linear and equal to (i)Vstep for each NDE in the driver. This can be confirmed in the remainder of its stages 3505, 3506, 3507, 3509, 3510, 3511.

Therefore, in Variant I, Vᵢ is linear, and Vᵢ=(i)(Vₛₜₑₚ), with i referring to the i-th capacitor in the driver 3400.

Variant J: Binary w/Vᵢ°=°2⁽ⁱ⁻¹⁾(Vₛₜₑₚ). Variant J differs from Variant I by its methodology 3600 having two additional stages than the Variant I methodology 3500, with the stages of methodology 3600 tracking the stages of the methodology 3500 except for the addition of new stages 3604, 3614 and the renumbering of the stages due to their additions to the switching cycle. The methodology 3600 also has a fixed reference rail, with all of its stages referencing the negative rail (except for stage 3609, which provides peak voltage). Referring to FIGS. 36B-1, 36-B2, with V₃₄₋ᵢ being Vᵢ for the i^{th} NDE in the driver 3400) and with nstep°=8 and Vstep=(1/8)V_{DD34}:
at stages 3602, 3616, V_{O34}°=V₃₄₋₁=°(1/8)V_{DD34}=°Vₛₜₑₚ°→°V₃₄₋₁°=(1)Vₛₜₑₚ;
at stages 3603, 3615, V_{O34}°=V₃₄₋₂°=°(2/8)V_{DD34}=°(2)[(1/7)V_{DD34}]°=(2)Vₛₜₑₚ°→°V₃₄₋₂=(2)Vₛₜₑₚ;
at stages 3605, 3613, V_{O34}°=V₃₄₋₃°=°(4/8)V_{DD34}=(4)[(1/7)V_{DD34}]°=(4)Vₛₜₑₚ°→°V₃₄₋₃=(4)Vₛₜₑₚ.

Accordingly, for methodology 3600, Vᵢ, the terminal voltage of the i-th NDE of the driver 3400, Vᵢ is also V_{O34 (steady state)}, which increases, but not linearly.

In Variant J, Vᵢ is calculated to be V₃₄₋₁=1, V₃₄₋₂=2, V₃₄₋₃=4, rendering Vᵢ binary, with Vᵢ=[2⁽ⁱ⁻¹⁾](Vₛₜₑₚ)], with i referring to the i-th capacitor in the driver 3400. The amounts of Vᵢ can be confirmed in the remainder of its stages 3604, 3606, 3607, 3608, 3610, 3611, 3612, 3614.

The binary step sizes of Variant J make it potentially useful to designers of digital-to-analog converters (DACs) and analog-to-digital converters (ADCs), which typically make use of binary weighted reference voltages as part of their operation. In addition, the variants disclosed herein save power by performing stepwise driving, with power dissipation of (Cₒ)(V_{DD}²)/nstep, where nstep°>°1. The power dissipation associated with a conventional driver having supply voltage of V_{DD} and in which nstep=1 is (Cₒ)(V_{DD}²), with Cₒ being the capacitance of the capacitive element being driven by the circuit, is not capable of driving its circuit to increase its output voltage in a stepwise pattern by applying a multi-stage switching cycle to its driver, nor is it capable of increasing its driver's output voltage by inserting additional stages to its multi-stage switching cycle to increase the number of steps in its stepwise output voltage increase pattern.

Typically, as noted above, V_{DD} is a given dictated by the application of the driver to the capacitive element. Theoretically, more power saving may be achieved by having a larger nstep, or equivalently a finer step size Vₛₜₑₚ=V_{DD}/nstep. In practice, achieving a larger nstep requires more NDE's, more switches, hence a more complex circuit with the associated additional cost size, and power overhead commensurate with the level of complexity.

In addition, more power saving increases the number of stages of the circuit's switching cycle, which increases the time required to complete the voltage driving from 0 to V_{DD} (and vice versa). Typical system requirements would dictate constraints on the time to complete the circuit's switching cycle. These system requirements can be switching frequency (or period) requirements, or rise/fall time requirements. In general, the higher the nstep, the higher the number of switching stages in the circuit's switching cycle, and the less time will be allocated to execute each stage. Therefore, generally additional constraints, such as bigger switches, more power, etc), make it more difficult for the driving system to fulfill these timing requirements.

Because the need for power savings typically calls for having a larger nstep and increasing the number of stages of the circuit's switching cycle, and there is a practical limit of how high nstep can be, beyond which the drawback will outweigh the potential power savings, it is left to the circuit designer to choose the optimal value of nstep and the optimal number of number of stages of the circuit's switching cycle for the selected variant, with the choices based on the specifications of the system that the variant will drive.

Switching distinctions: Adding additional stages to a methodology increases the the nstep and reduces the Vₛₜₑₚ for a given V_{DD}, which can increase power savings. It may also increase the amount of time to operate a circuit through a complete voltage driving cycle and may increase the cost of production of the driver. Reducing the number of stages and a circuit's nstep could make the driver less expensive and speedier to operate. Based on above discussion and other things being equal, when n°≥°3, Variant J gives a significantly higher nstep than Variant I and can have greater power savings.

Variant K/L with Circuit 3700: Adding Stages to Switched Reference Rail System

The driver 3700 shown in FIG. 37C-2 illustrates a 3-NDE capacitive element driver with thirteen (13) switches and may be operated in accordance with methodology 3800 (with its 26-stage driving cycle) and methodology 3900 (with its 30-stage driving cycle). As described below, the additional stages in methodology 3900 causes changes in the amount of time that is required to apply the methodology and in the output voltage produced per stage.

FIG. 37 is a circuit diagram of a capacitive element driver 3700 having three (n=3) NDEs C₃₇₋₁, C₃₇₋₂, C₃₇₋₃ and thirteen (m=13) switches SW_{37-0A}, SW_{37-0B}, SW_{37-1A}, SW_{37-1B}, SW_{37-1C}, SW_{37-2A}, SW_{37-2B}, SW_{37-2C}, SW_{37-3A}, SW_{37-3B}, SW_{37-3C}, SW_{37-4A}, and SW_{37-4B}, with:
a positive interconnection 3716 having nodes 3754a, 3754b disposed between a circuit output terminal 3704 and a positive terminal 3726 of the voltage source 3720, and a negative interconnection 3718 having nodes 3751a, 3751b disposed between the circuit output terminal 3704 and a negative terminal 3728 of the voltage source 3720;
node 3751a, switch SW_{37-1A}, NDE C₃₇₋₁, switch SW_{37-1B}, switch SW_{37-2A}, NDE C₃₇₋₂, switch SW_{37-2B}, switch SW_{37-3A}, NDE C₃₇₋₃, switch SW_{33-3B}, and node 3754a arranged in series (on a component herein referred to as the “NDE interconnection 3717A”), and having nodes 3752a, 3753a disposed between switches SW_{37-1B}, SW_{37-2A}, and switches SW_{37-2B}, SW_{37-3A}, respectively;
node 3751b, switches SW_{37-1B}, SW_{37-2B}, SW_{37-3B}, and node 3754b disposed in series (on a component herein referred to as the “bypass interconnection 3717b”), with nodes 3752b, 3753b disposed between switches SW_{37-1B}, SW_{37-2B}, and switches SW_{37-2B}, SW_{37-3B}, respectively; and
switches SW_{37-0A}, SW_{37-4A} disposed on the negative interconnection 2718, and switches SW_{37-0B}, SW_{37-4B} disposed on the positive interconnection 2716, with:
   switch SW_{37-0A} disposed between the negative terminal 3728 of the voltage source 3720 and the nodes 3751a, 3751b, and switch SW_{37-4A} disposed between the circuit output terminal 3704 and the nodes 3751a, 3751b; and
   switch SW_{37-0B} disposed between the positive terminal 3726 of the voltage source 3720 and the nodes 3754a, 3754b, and switch SW_{37-4B} disposed between the circuit output terminal 3704 and the nodes 3754a, 3754b.

### Variant K (Circuit 3700/Methodology 3800): Basic Switched Reference Rail System

FIGS. 38A1-38C-3 illustrate the methodology 3800 for operating the driver 3700 during stages of a complete V_{O37} driving cycle, in which FIG. 38A-1, 38A-2 show charts 3850a, 3850b of representations of sequential functional snapshots of the circuit 3700 during application of the methodology 3800. FIGS. 38B-1A, 38B-1B, 38B-2 are tables 3860a, 3860b, 3865, respectively, detailing the stages 3801-3826 of the methodology 3800, with FIG. 38B-2 listing the switches that are open rather than closed (due to the larger number of closed switches than open switches in each stage); and FIGS. 38C-1-38C-3 graphically present the results of simulations of the operation of the methodology 3800 on the driver 3700.

The methodology 3800 demonstrates a batched 1 switching reference rail type, with its switching pattern's executing phase 3864 having 12 stages and its reverse executing phase 3868 having 12 stages that access rails and NDEs in reverse order of how they are accessed in the executing phase 3864. In addition, the methodology 3800 applies the above-described optional method for avoiding floating circuit nodes, not only in the grounding and peaking stages, but also in the stages of its executing and reverse executing phases.

The executing phase 3864 starts by referencing the negative rail in six stages (the first three of which access the three individual NDEs one at a time and the next three of which access the NDEs in combinations that increase the driver's V_{O37} by (1/13) V_{DD37} at each stage). The second part of the executing phase 3864 accesses the positive rail in its six stages, with the driver's NDEs accessed, alone and in combinations, in reverse order of how they were accessed in the first part of the executing phase 3864.

The reverse executing phase 3868 (of 12 stages) then accesses NDEs and rails of the driver 780 in reverse order of how they were accessed in the 12 stages of the executing phase 3864. Its 12 stages start by referencing the positive rail for six stages and then continues by referencing the negative rail in its final six stages to drive the output voltage to a grounded output voltage.

In the first initial stage 3801, the switches SW_{37-0A}, SW_{37-4A} are closed to ground the circuit's output voltage, with V_{O37}=0 at steady state. Also, for the reasons described above in the discussion of Variants I, J, the switch SW37-4B and switches SW_{37-1C}, SW_{37-2C}, SW_{37-3C} on the bypass interconnection 3717b and the switches (SW_{37-1A}, SW_{37-2A}, SW_{374-3A}) on the NDE interconnection 3717a (essentially, as shown in FIG. 38-B2, all the other switches except switches SW_{37-1B}, SW_{37-2B}, SW_{37-3B}, SW_{37-4BA}) is also closed (at the circuit designer's option) to avoid floating circuit nodes without causing additional power loss at stage 3801. As noted above, closing SW_{37-0A}, SW_{37-4A} is enough; closing the others is optional.

During the stages 3802-3813, the methodology 3800 provides incremental increase in the output voltage in each stage to drive the output voltage to peak:
during the stages 3802-3807, the switches SW_{37-0A}, SW_{37-4B} are closed to reference the negative rail 3718, adding voltage to the circuit's output voltage at each stage; and
during the stages 3808-3813, the switches SW_{37-0B}, SW_{37-4A} are closed to reference the positive rail 3718, reducing the amount of voltage that is subtracted from the voltage circuit's V_{DD37} input voltage at each stage.

At stage 3814, the circuit's output voltage achieves peak voltage V_{DD37}, and then during the stages 3815-3826, the methodology reverses the same stages to drive the output voltage back to ground:
during the stages 3815-3820, the switches SW_{37-0B}, SW_{37-4A} are closed to reference the positive rail 3718, increasing the amount of voltage that is subtracted from the voltage circuit's V_{DD37} input voltage at each stage; and
during the stages 3821-3826, the switches SW_{37-0A}, SW_{37-4B} are closed to reference the negative rail 3718, reducing voltage from the output voltage at each stage.

At stages 3802-3807, 3821-3826, SW_{37-0A}, SW_{37-4B} are closed to access the negative reference rail and, at steady state:
stages 3802, 3826 deliver V_{O37}=V₃₇₋₁=[(1/13)V_{DD37}] by closing SW_{37-1A}, SW_{37-1B} to access C₃₇₋₁ and closing SW_{37-2C}, SW_{37-3C} to bypass C₃₇₋₂, C₃₇₋₃, while optionally closing SW_{37-2A}, SW_{37-3A} to avoid floating circuit nodes;
stages 3803, 3825 deliver V_{O37}=V₃₇₋₂=[(2/13)V_{DD37}] by closing SW_{37-2A}, SW_{37-2B} to access C₃₇₋₂ and closing SW_{37-1C}, SW_{37-3C} to bypass C₃₇₋₁, C₃₇₋₃, while optionally closing SW_{37-1A}, SW_{37-3A} to avoid floating circuit nodes;
stages 3804, 3824 deliver V_{O37}=V₃₇₋₃=[(3/13)V_{DD37}] by closing SW_{37-3A}, SW_{37-3B} to access C₃₇₋₃ and closing SW_{37-1C}, SW_{37-2C} to bypass C₃₇₋₁, C₃₇₋₂, while optionally closing SW_{37-1A}, SW_{37-2A} to avoid floating circuit nodes;
stages 3805, 3523 deliver V_{O37}=(V₃₇₋₁+V₃₇₋₃)=[(4/13)V_{DD37}] by closing SW_{37-1A}, SW_{37-1B}, SW_{37-3A}, SW_{37-3B} to access C₃₇₋₁, C₃₇₋₃ and closing SW_{37-2C} to bypass C₃₇₋₂, while optionally closing SW_{37-2A} to avoid floating circuit nodes;
stages 3806, 3822 deliver V_{O37}=(V₃₇₋₂+V₃₇₋₃)=[(5/13)V_{DD37}] by closing SW_{37-2A}, SW_{37-2B}, SW_{37-3A}, SW_{37-3B} to access C₃₇₋₂, C₃₇₋₃ and closing SW_{37-1C} to bypass C₃₇₋₁, while optionally closing SW_{37-1A} to avoid floating circuit nodes; and
stages 3807, 3821 deliver V_{O37}=(V₃₇₋₁+V₃₇₋₂+V₃₇₋₃)=[(6/13)V_{DD37}] by closing SW_{37-1A}, SW_{37-1B}, SW_{37-2A}, SW_{37-2B}, SW_{37-3A}, SW_{37-3B} to access all three NDEs.

At stages 3808-3820, SW_{37-0B}, SW_{37-4A} are closed to access the positive reference rail and, at steady state:
stages 3808, 3820 deliver V_{O37}=[V_{DD37}°−°(V₃₇₋₁+V₃₇₋₂+V₃₇₋₃)]°=[(7/13)V_{DD37} by closing SW_{37-1A}, SW_{37-1B}, SW_{37-2A}, SW_{37-2B}, SW_{37-3A}, SW_{37-3B} to access all three NDEs;
stages 3809, 3819 deliver V_{O37}=[V_{DD37}°−°(V₃₇₋₂+V₃₇₋₃)]=[(8/13)V_{DD37}] by closing SW_{37-2A}, SW_{37-2B}, SW_{37-3A}, SW_{37-3B} to access C₃₇₋₂, C₃₇₋₃ and closing SW_{37-1C} to bypass C₃₇₋₁, while optionally closing SW_{37-1B} to avoid floating circuit nodes;
stages 3810, 3818 deliver V_{O37}=[V_{DD37}°−°(V₃₇₋₁+V₃₇₋₃)]°=°(9/13)V_{DD37} by closing SW_{37-1A}, SW_{37-1B}, SW_{37-3A}, SW_{37-3B} to access C₃₇₋₁, C₃₇₋₃ and closing SW_{37-2C} to bypass C₃₇₋₂, while optionally closing SW_{37-2B} to avoid floating circuit nodes;
stages 3811, 3817, SW_{37-3A}, SW_{37-3B} deliver V_{O37}=(V_{DD37}−°V₃₇₋₃)°=(10/13)V_{DD37} by closing SW_{37-3A}, SW_{37-3B} to access C₃₇₋₃ and closing SW_{37-1C}, SW_{37-2C} to bypass C₂₇₋₁, C₃₇₋₂, while optionally closing SW_{37-1B}, SW_{37-2B} to avoid floating circuit nodes;
stages 3812, 3816 deliver V_{O37}=(V_{DD37}−V₃₇₋₂)°=(11/13)V_{DD37} by closing SW_{37-2A}, SW_{37-2B} to access C₃₇₋₂ and closing SW_{37-1C}, SW_{37-3C} to bypass C₃₇₋₁, C₃₇₋₃, while optionally closing SW_{37-1B}, SW_{37-3B} to avoid floating circuit nodes; and
stages 3813, 3815 deliver V_{O37}=V₃₇₋₁₂=(V_{DD37}°−°V₃₇₋₁)°=(12/13)V_{DD37} by closing SW_{37-1A}, SW_{37-1B} to access C₃₇₋₁ and closing SW_{37-2C}, SW_{37-3C} to bypass C₃₇₋₂, C₃₇₋₃, while optionally closing SW_{37-2B}, SW_{37-3B} to avoid floating circuit nodes.

In the stage 3814, the switches SW_{37-0B}, SW_{37-4B} are closed to provide peak voltage to the circuit's output voltage, with V_{O37}=V_{DD37} at steady state. Also, for the reasons described above in the discussion of Variants I, J, the switch SW _{37-4A} and switches SW_{37-1C}, SW_{37-2C}, SW_{37-3C} on the bypass interconnection 3717b and switches SW_{37-1B}, SW_{37-2B}, SW_{37-3B} on the NDE interconnection 3717a (essentially, as shown in FIG. 38-B2, all the other switches except switches SW_{37-0A}, SW_{1A}, SW_{2A}, SW_{3A}) are also closed (at the circuit designer's option) to avoid floating circuit nodes at peak without causing additional power loss at stage 3814. As noted above, closing SW_{37-0A}, SW_{37-4A} is enough; closing the others is optional.

### Variant L (Circuit 3700/Methodology 3900): Adding Stages to Variant K

FIGS. 39A1-39C-3 illustrate the methodology 3900 for operating the driver 3700 during stages of associated complete driving cycles, in which FIG. 39A-1, 39A-2 show charts 3950a, 3950b of representations of sequential functional snapshots of the circuit 3700 during application of the methodology 3900. FIGS. 39B-1A, 39B-1B, 39B-2 are tables 3960a, 3960b, 3965, respectively, detailing the stages 3901-3930 of the methodology 3900, with FIG. 39B-2 listing the switches that are open rather than closed (due to the larger number of closed switches than open switches in each stage); and FIGS. 39C-1-39C-3 graphically present the results of simulations of the operation of the methodology 3900 on the driver 3700.

As with the methodology 3800, the methodology 3900 also demonstrates a switching pattern and methodology operation that is almost identical to the methodology 3800, a set of stages having been added to increase the nstep for methodology 3900. In particular:
stages 3904, 3928 were added to insert the output voltage [V_{O37}°=°(V₃₇₋₁°+°V₃₇₋₂)] between [V_{O37}°=°(V₃₇₋₂)] (stages 3903, 3929) and [V_{O37}°=°(V₃₇₋₃)] (stages 3905, 3927), and
stages 3913, 3919 were added to insert the output voltage [V_{O37}°=°V_{DD37}°−°(V₃₇₋₁°+°V₃₇₋₂)] between [V_{O37}°=°V_{DD37}°−°(V₃₇₋₃)] (stages 3912, 3920) and [V_{O37}°=°V_{DD37}°−°(V₃₇₋₂)] (stages 3914, 3918), The methodology 3900 stages were renumbered to accommodate the additional stages.

### Comparison of Variants K, L

The comparison chart 3969 in FIG. 39D shows the differences between the methodologies 3800, 3900, with the stages of methodology 3800 shown in regular font and the stages of methodology 3900 shown in italics, with the additional stages of methodology 3900 shown in rows with double lined (thick, thin) borders.

Capacitor Reference Rail/Capacitor Configuration: Variants K, L demonstrate batch 1 switching reference rail types with a hybrid capacitor configuration, because their patterns start with certain stages referencing the negative rail, then switch to the positive rail, then return to a negative rail switching pattern until its output voltage decreases back to ground.

Stacked Capacitor Voltage Operation: Variants K, L demonstrate a hybrid (+ or −) capacitor voltage operation, because each of the methodologies 3800, 3900 cause the output voltage of the driver 3700 to connect to a stack of NDEs at some stages in the methodologies, and to a single NDE at other stages.

nstep: The nstep for Variant K equals 13 (applying 13 stages 3802-3814 to driver 3700 to drive the output voltage to peak, and applying 13 stages 3815-3826, 3801 to return the output voltage to ground); and the nstep for Variant L equals 15 (applying 15 stages 3902-3916 to the driver 3700 to drive the output voltage to peak, and applying 15 stages 3917-3930, 3901 to return the output voltage to ground).

Adapted versions of the methodologies 3800, 3900 for a 2-NDE version of the circuit 3400, in which n=2, would both generate nstep=7, a 1-NDE version, in which n=1, would both generate nstep=3, and, by extrapolation, an n-NDE version of the driver 3700 would generate nstep=n(n+1)+1 for the methodology 3800 and would generate nstep=2⁽ⁿ⁺¹⁾−1 for the methodology 3900.

Vstep: For the methodology 3800, nstep°=13 and V_{DD37}=nstep*Vstep, so Vₛₜₑₚ=V_{DD37}/13. For the methodology 3900, nstep°=15 and V_{DD37}=nstep*Vstep, so Vstep=V_{DD37}/15.

Capacitor Voltage (Vᵢ): Variants K, L differ in the NDE capacitor output voltages they produce with the common driver 3700 because of the difference in their number of stages in their methodologies 3800, 3900, which result in a difference in their nsteps and in the amount of V_{O37} generated by the methodology stages in which only their individual NDEs (C₃₇₋₁, C₃₇₋₂, C₃₄₋₃) are accessed.

Variant K: linear with Vᵢ=(i)(Vₛₜₑₚ). Variant K's batch 1 switching methodology references the negative rail in a first NDE-accessing switching set of stage 3802-3807) and in the last NDE-accessing switching set (stages 3821-3826); and its stages reference the positive rail, namely the second NDE-accessing switching set (stages 3806-3813) and the third NDE-accessing switching set (stages 3815-3820), with stage 3801 providing grounding and stage 3814 providing peak voltage V_{DD37}.

The fixed switching methodology 3800 as applied to the driver 3700 is defined to allow access to one of more NDEs at each of its stages, with each switch associated with the NDEs (SW_{37-1B} associated with NDE C₃₇₋₁, SW_{37-2B} associated with NDE C₃₇₋₂, and SW_{37-3B} associated with NDE C₃₇₋₃) when open blocking its NDE from contributing its capacitor voltage to the driver's output terminal, and when closed providing a path for its NDE's capacitor voltage to the driver's output terminal. The capacitor voltage provided by the selected NDEs will equal the capacitor voltage provided during the last previously applied stage plus the change in output voltage.

Referring to FIGS. 38B-1A, 38B-1B (with V₃₇₋ᵢ being Vᵢ for the i^{th} NDE in the driver 3700) and with nstep°=13 and Vstep=(1/13)V_{DD37}:
at stages 3802, 3826, V_{O37}°=V₃₇₋₁=°(1/13)V_{DD37}=°Vₛₜₑₚ°→°V₃₇₋₁°=(1)Vₛₜₑₚ;
at stages 3803, 3825, V_{O37}°=V₃₇₋₂°=°(2/13)V_{DD37}=°(2)[(1/13)V_{DD37}]°=(2)Vₛₜₑₚ°→°V₃₇₋₂=(2)Vₛₜₑₚ;
at stages 3804, 3824, V_{O37}°=V₃₇₋₃°=°(3/13)V_{DD37}=(3)[(1/13)V_{DD37}]°=(3)Vₛₜₑₚ°→°V₃₇₋₃=(3)Vₛₜₑₚ.

Thus, the capacitor voltages [V(₃₇₋₁), V(₃₇₋₂), V(₃₄₋₃) of the NDEs of its driver 3700 increase linearly when methodology 3800 is applied to driver 3700. V₃₇₋₁=1, V₃₇₋₂=2, V₃₇₋₃=3, means that V=°(i)Vₛₜₑₚ for each NDE in the driver 3700. This can be confirmed in the remaining stages 3805-3813, 3815-3823 of the methodology 3800.

Therefore, in Variant I, Vᵢ is linear, and Vᵢ=(i)(Vₛₜₑₚ), with i referring to the i-th capacitor in the driver 3700. Generally, Vᵢ=(k_{K})i·Vₛₜₑₚ and k_{K}°=°1.

Variant L: binary with Vᵢ=[2⁽ⁱ⁻¹⁾](Vₛₜₑₚ)]. Variant L differs from Variant K by its methodology having four additional stages than the Variant K methodology 3500. Like Variant K, Variant L also has a batch 1 switched reference rail methodology, with its stages tracking the stages of the Variant K's methodology 3500, except for its additional stages 3904, 3928 and stages 3913, 3919. Referring to FIGS. 39B-1A, 39B-1B, 39-B2, with V₃₇₋ᵢ being V for the i^{th} NDE in the driver 3700 and with nstep°=15 and Vₛₜₑₚ=(1/15)V_{DD37}:
at stages 3902, 3930, V_{O37}°=V₃₇₋₁=°(1/15)V_{DD37}=°Vₛₜₑₚ°→°V₃₇₋₁°=(1)Vₛₜₑₚ;
at stages 3903, 3929, V_{O37}°=V₃₇₋₂°=°(2/15)V_{DD37}=°(2)[(1/15)V_{DD37}]°=(2)Vₛₜₑₚ°→°V₃₇₋₂=(2)Vₛₜₑₚ;
at stages 3905, 3927, V_{O37}°=V₃₇₋₃°=°(4/15)V_{DD37}=(4)[(1/15)V_{DD37}]°=(4)Vₛₜₑₚ°→°V₃₇₋₃=(4)Vₛₜₑₚ.

Therefore, V(₃₇₋₁), V(₃₇₋₂), V(₃₇₋₃) for NDEs (C₃₇₋₁, C₃₇₋₂, C₃₇₋₃, respectively, of the three NDEs of its driver 3700 increase, but not linearly, when methodology 3900 is applied to driver 3700. This can be confirmed in the remaining stages of the methodology 3900 in stages 3904, 3906°-°3915, 3917-3926, and 3928.

Therefore, in Variant L, Vᵢ, the terminal voltage of the i-th NDE in the driver 3700 applying the methodology 3900, is calculated to be V₃₇₋₁=(l)Vₛₜₑₚ, V₃₇₋₂=(2)Vₛₜₑₚ, V₃₇₋₃=(4)Vₛₜₑₚ. Therefore, the methodology 3900 causes the NDEs of its driver 3700 to produce output voltages that increase by an order of 2. Generally, V₁=[2⁽ⁱ⁻¹⁾](Vₛₜₑₚ)], with i referring to the i-th capacitor in the driver 3700. As with Variant J, the binary step sizes of Variant L make it potentially useful to designers of digital-to-analog converters (DACs) and analog-to-digital converters (ADCs), which typically make use of binary weighted reference voltages as part of their operation.

Switching distinctions: Adding additional stages to a methodology increases nstep and reduces Vstep when the amount of voltage that a circuit may generate remains constant. It may also increase the amount of time to operate a circuit through a complete voltage driving cycle. It may also increase the cost of production of the driver. Reducing the number of stages in a circuit and its nstep could make the driver less expensive and less time-intensive to operate.

Variant MIN with Driving System 4000: Methodologies with Equivalent Functionalities

The capacitive element driver system 4000 (also known as a driving system or a driver) in Variants M, N is a system of driver cells that operate together to form an output voltage that increases from ground to peak voltage in order to drive a capacitive element. The driver 4000, which was disclosed as driving circuit [wxy] in the earlier-filed application at Section “FIGS. 22M-2A1(A1)-22M-2A2: 3-Cell Driving Circuit.” As will be discussed below, Variants M, N have identical drivers 4000, [wxy], and methodologies that are functionally identical but in certain stages, implement their functionalities using different sets of switch closures.

In the earlier-filed application, various embodiments of the drivers 4000, [wxy] and their associated switching methodologies have been disclosed, such as:
2-cell driver (cells 2101-1, 2101-2, with three driver cells [w], [x], [y], each with one NDE), and methodology 2220 (FIG. 22M-1A);
driver [vwxy] with four 1-NDE driver cells [v], [w], [x], [y], and methodology 2240 (FIG. 22M-2B 1);
driver [ab] with a 1-NDE cell [2], a 2-NDE cell [b], and methodology 2260 (FIG. 22M-3A);
driver [mn] with a 2-NDE cell [m], a 1-NDE cell [n], and methodology 2270 (FIG. 22M-4A);
driver [mnp] with 2-NDE cells [m], [n], 3-NDE cell [p], and methodology 2280 (FIG. 22M-5A1);
driver 2300 with K driver cells, with each driver cell 2301-i (i being a positive integer and 1≤i≤K) having a selected number n[i] of NDEs, and methodology 2400 (FIG. 23A, 24A-24B-3).

Any one of the disclosed drivers may be used in a system of driver cells, but, for simplicity's sake and ease of description, driver 4000, with its three driver cells [w], [x], [y], each with one NDE and four switches, has been used here. However, is to be understood any of the circuit designs described herein, including circuits 700A, 780, 77C-1, 700C-2, 700F, 700D, 700E, 700G, 700H, 2900, 3400, 3700, whether their NDEs are connected in series or in parallel, or whatever the number of NDEs, or switches, may also operate as a cell in a capacitive element driver system such as in Variants M, N, in which one or more cells are attachable directly or indirectly between an external voltage source and a capacitive element, to form a capacitive element driving circuit.

Returning to FIG. 40, the driver system 4000/[wxy] has three single-NDE driver cells [w], [x], [y], each with one NDE and four switches, with:
a first driver cell [w] with a first input terminal electrically connectable directly or indirectly to the positive terminal 4026 of an external voltage source 4020 and a second input terminal electrically connectable directly or indirectly to the negative terminal 4028 of an external voltage source,
a third driver cell [y] having a third cell output terminal 4052-y electrically connectable directly or indirectly to the capacitive element C_{O[wxy]} that the circuit [xyz] is arranged to drive, and a second driver cell [x] attachable directly or indirectly between the driver cells [w], [y], with an input terminal 4054-x attachable directly or indirectly to the output terminal 4052-w of the driver [w] and an output terminal 4052-x attachable directly or indirectly to the input terminal 4054-y of the driver [y].

Each of the cells [w], [x], [y], which are shown in detail as driver 400 (FIG. 4) and cell 2101-2 (FIG. 22A), has a first pair of switches (SW_{w[0]}, SW_{w[1]}), (SW_{x[0]}, SW_{x[1]}), (SW_{y[0]}, SW_{y[1]}) disposed on the cells [w], [x], [y], in series on the negative rail 4018-w, 4018-x, 4018-y, respectively, and a second pair of switches (SW_{w[2]}, SW_{w[3]}), (SW_{x[2]}, SW_{x[3]}), (SW_{y[2]}, SW_{y[3]}) disposed on the cells [w], [x], [y], in series on the positive rail 4016-w, 4016-x, 4016-y, respectively. The driver cells [w], [x], [y], may also have an NDE C_{w}, Cₓ, C_{y}, respectively, for storing and transferring additional energy for driving the capacitive element C_{O[wxy]} between the two voltage levels, with the NDEs electrically connectable between a common node 4051-w, 4051-x, 4051-y, respectively, of the first pair of switches and a common node 4053-w, 4053-x, 4053-y of the second pair of switches. The driver 4000/[wxy] has a voltage source 4020 to provide a source voltage V_{DD[wxy]} to the driver 4000 to drive a capacitive element C_{O[wxy]}, and as having an output terminal 4052-y to provide an output voltage V_{O[wxy]} to the input 4054-c of C_{O[wxy]}.

The capacitive element driver systems described above may have more than one driver cell electrically connected, with each cell arranged to transfer energy from its input terminal to its output terminal through application of its own switching sequence methodology on its own capacitors and switches. In the embodiment shown in FIG. 40, driver 4000 has three one-NDE cells [w], [x], [y] connected in series. A capacitive element driver 400 (FIG. 4) is one embodiment of a one-NDE cell with 4 switches. A driving system with two one-NDE, four-switch cell is shown in FIG. 21, and a driving system with K cells, each cell of which has at least one NDE is shown in FIG. 23A.

### Variant M (Driver 4000, Methodologies 500, 2220):

In Variants M, N, the driver [wxy]/4000 may be operated using the either of the methodologies 2220, 4100 (Variants M, N respectively) for the systems, and earlier disclosed methodologies for application to a driver with a single NDE.

FIG. 5G illustrates the switching methodology 500 for driving the driver 400 during the stages of a complete V_{O4} driving cycle. Under the methodology 500, the driver 400 is switched in six stages:
stage 501(1) delivers ground to the output of the cell 400 by closing switches SW_{4[0]}, SW_{4[1]} to bypass the NDE C_{S4} on the negative rail (described earlier herein as a bypass or “b” stage);
stages 501(2), 501(6) deliver V_{O4}=V_{CS4}=[(1/3)V_{DD4}] by closing SW_{4[0]}, SW_{4[2]} to access C_{S4} from the negative rail (described earlier in this application as a “+” stage);
stages 501(3), 501(5) deliver V_{O4}=(V_{DD4}°−°V_{CS4})°=[(2/3)V_{DD4}] by closing SW_{4[1]}, SW_{4[3]} to access C_{S4} from the positive rail (described earlier in this application as a “−” stage);
In stage 501(4), delivers peak voltage V_{DD4} to the output of the cell 400 by closing switches SW_{4[2]}, SW_{4[3]} to bypass the NDE C_{S4} on the positive rail (another “b” stage); with the operations of the complete V_{O4} driving cycle represented by (b, +, −, b, +, −).

FIGS. 22M-1A-22M-2A2 illustrate the methodology 2220 for operating a driver [wxy] during the stages of a complete driving V_{O[wxy]} cycle, disclosed earlier in this application at Section FIGS. 22M-2A 1(A1)-22M-2A2: 3-Cell Driving Circuit, The figures that show the methodology Variant M include the following:

FIGS. 22M-2A1(A1), FIGS. 22M-2A1(A2) are switching charts 2222(a), 2222(b), detailing the switch closures occurring at stages 2221(01)-2221(54) of the methodology 2220. FIG. 22M-2A1(B) is a sequence pattern chart 2225 detailing the closures patterns of switch sets on the driver [wxy] and the circuit's output voltages during application of the stages 2221(01)-2221(54) on the driver [wxy]. And FIG. 22M-2A2 shows the phases of and switching patterns in the methodology 2220.

The sequential functional snapshots of the driver 4000 during application of the methodology 4100, which are shown in the charts 4155a-4155d of FIGS. 41A-1 to 41A-4. The charts 4155a-4155d may also be used as a representation of sequential functional snapshots of the driver [wxy] because driver 4000 has the same topology as the driver [wxy] and their associated methodologies 2220, 4100 share the same functionality, stage by stage, during application of the methodology 2220, 4100 on the drivers [wxy], 4000.

The documents that describe the methodology 4100 include the following:
FIGS. 41B-IA, 41B-1B are switching patterns charts 4160a, 4160b, detailing the stages 4101-4154 of the methodology 4100, noting that switching patterns charts 4160a, 4160b are analogous to and provide the same functionality as, but different from, switching patterns charts 2222(a), 2222(b)];
FIG. 41B-1C is an additional switching patterns chart 4165, detailing the references of the driver's circuit rails by methodology stage;
FIG. 41B-1D is a sequence pattern chart 4175 detailing the switch sets that are closed on the driver 4000 and the circuit's output voltages during application of the stages 2221(1)-2221(54); and
Because Variants M, N are functionally identical, the phases of and switching patterns in the methodology 4100 are identical to the phases of and switching patterns in the methodology 2220, which are shown in FIG. 22M-2A2.

Variant M's methodology 2220 shown in the switching charts 2222(a), 2222(b) in FIGS. 22M-2A1(A1), 22M-2A1(A2) respectively, details the closed switches and output voltages of the driver 4000 during application of its stages 2221(1)-2221(54).

FIG. 22M-2A1(B) is a sequence pattern chart 2225 detailing the switch sets that are closed on the driver 4000 and the circuit's output voltages during application of the stages 2221(1)-2221(54); and

FIG. 22M-2A2 shows the phases of and switching patterns in the methodology 2220.

FIGS. 41B-1A, 41B-1B are switching charts 4160a, 4160b, detailing the stages 2221(01)-2221(54) of the methodology 2220. The figures related to the methodology 4100 may also be used to describe the methodology 2220, because as discussed further below, they share the same functionality, stage by stage.

In the methodology 2220, voltage output increments in a step-wise manner by opening and closing selected switches to apply voltage from selected cells while preventing other cells from contributing voltage to the driving circuit output, and, once the voltage that is being output from the circuit is equal to the supply voltage for the circuit [wxy],hd V_{DD[wxy]}), the stages of the process may be performed in reverse order to reduce the voltage output, again in a step-wise manner, back to an output voltage of V[y] at the Stage 2221(54).

The output voltage of the circuit [wxy] may be driven to ground with an application of the first stage, Stage 2221(1), of the V_{O[wxy]} driving cycle. Each of the three cells operate to drive through a complete voltage driving cycle, with each cell remaining at a selected stage until the cell following it in the driver performs a complete voltage driving cycle. When the following cell's cycle from ground to peak voltage to ground is completed, the cell transitions to its next stage, and the following cell's cycle begins anew. The switching patterns for a complete cycle for each cell is shown in enhanced borders around the cells in complete cycle switch activation set in FIG. 22M-2A1.

In stage 2221(01), the driver's output voltage is driven to ground. And the pattern (b, +, −, b, +, −), a complete V_{Oy} voltage cycle, is applied numerous times to the driver 4000 while the voltage source and cells [w], [x] provide their voltages V_{DD[wxy]}, Vₓ, V_{y} to the input of cell [y] to contribute to the increase in cell [y] output voltage V_{Oy} (which, in this case, is the driver 4000 V_{O[wxy]}) to values beyond its own V_{y}, (in nstep=27 increments of Vstep=1). The (b, +, −, b, +, −) is repeated until peak voltage is achieved at the output terminal during stage 2221(28).

At stage 2221(28), the switching pattern (b, +, −, b, +, −) is performed numerous times in reverse order, again with the voltage source and cells [w], [x] providing their voltages V_{DD[wxy]}, Vₓ, V_{y} to the input of cell [y] to contribute to the decrease in cell [y] output voltage V_{Oy} until grounding is achieved at a subsequent application of stage 2221(01).

As shown in FIGS. 22M-2A1(A2), 41B-1D, the 54 stages of the switching patterns of the methodologies 2220, 4100 start by referencing the negative rail for the 1^{st} through 14^{th} stages then they reference the positive rail for the 15^{th} through 41^{st} stages, then return to a negative rail switching pattern for the remainder of the stages in their cycles (the 42^{nd} through 54^{th} stages). The references of the rails by stage may be seen in FIG. 41B-1C.

The complete V_{O[wxy]} driving cycle of the methodologies 2221, 4100 is applied to the cells [w], [x], [y] of the driver 4000 in the following manner, with Cell [y]'s complete 6-stage V_{Oy} driving cycle applied to the cell [y] numerous times in order until peak voltage is achieved, and then in reverse order until the output voltage is grounded.

In tandem, cell [x]'s complete 18-stage V_{Ox} driving cycle is applied to the cell [x], with each operation in the V_{Ox} driving cycle being applied for the duration of three methodology 2220 stages (except for the first bypass operation, which is applied during only two stages [2221(01), 2221(02)] but in subsequent applications of the cycle will be applied for the duration of three stages, with the inclusion of the V_{Ow} driving cycle's last stage [2221(54)], which is also a bypass operation). The application of the V_{Ox} driving cycle will be performed until peak voltage is achieved, upon which and thereafter the operations of the V_{Ox} driving cycle are applied in reverse order until grounding is achieved (with the peak bypass operation performed on the three stages 2221(27)-2221(29) and the last bypass operation performed on stages 2221(54)-2221(02)].

Also, in tandem, cell [w]'s complete 54-stage V_{Ow} driving cycle is applied to the cell [w], with each operation in the V_{Ow} driving cycle being applied for the duration of nine methodology 2220 stages (except for the first bypass operation, which is applied during only five stages [2221(01)-2221(05)] but in subsequent applications of the cycle will be applied for the duration of nine stages, with the inclusion of the V_{Ow} driving cycle's last four stages [2221(51)-2221(54)], which are also bypass operations). The application of the V_{Ow} driving cycle will be performed until peak voltage is achieved, upon which and thereafter the operations of the V_{Ow} driving cycle are applied in reverse order until grounding is achieved (with the peak bypass operation performed on the nine stages 2221(24)-2221(32) and the last bypass operations performed on stages 2221(51)-2221(05)].

As disclosed above, each cell may receive its input voltage from the output terminal of another driver cell to which the cell is electrically attached or, if it is first in line of the cells in the driver system, from the system voltage source itself. Further, the cell's output terminal may be arranged to output the cell's output voltage to the input terminal of the driver cell following it in the series of cells in the driver system, or, if it is last in line of the cells in series in the driver system, to the capacitive element which the series of cells is arranged to drive. When the circuits 2700, 2900, 3400, 3700 or another suitable circuit of the circuit designer's choice are arranged to serve as cells in the capacitive element driver systems described above, the substituted circuits may operate similarly.

Variant N (Circuit [wxy], Methodology 4100):

As noted above, the methodologies 2220, 4100 share the same functionality, stage by stage, with the only difference between them being that in certain stages that, when applied to the driver 4000, bypass the NDEs in one or both of the cells [x], [y], one of the NDE-bypass switch sets ([2],[3]), ([0],[1]) is substituted for the other NDE-bypass switch set.

In the circuit 4000 to which both methodologies are applied, the cells [w], [x], [y] are connected in series between the voltage source 4020 and the capacitive element C_{O[wxy]} that is driven by the driving system 4000. In the cell [w], which is directly connected to the voltage source 4020, the positive rail NDE-bypass switch set ([2],[3]) causes the peak voltage at the voltage source's positive terminal 426 to be applied to the output terminal 4052-w of the cell [w], and the negative rail NDE-bypass switch set ([0],[1]) causes ground at the voltage source's negative terminal 4028 to be applied to the output terminal 4052-w.

In the cells [x], [y], both of which are connected to the output terminal of the cell preceding it in the series, the closure of either NDE-bypass switch sets, ([2],[3]) or ([0],[1]) in the cells [x], [y] causes a bypass of its NDEs, forwarding the voltage at the output terminal of the preceding cell (4052-w, 4052-x, respectively) to be applied to the input terminal of its following component (cell 4054-y, capacitive element 4054-C, respectively), resulting in the distinct NDE-bypass switch sets ([2],[3]), ([0],[1]) providing the same voltage in the cells [x], [y], and therefore resulting in the distinct NDE-bypass switch sets ([2],[3]), ([0],[1]) providing the same functionality to the stages that bypass the cells [x], [y] in the methodologies 2220, 4100.

The selection of which NDE-bypass switch set to use when a bypass of the cell [x] or cell [y] is desired is the only difference between the methodologies 2220, 4100, so the methodologies are functionally equivalent (they both forward the voltage at the output terminal of the preceding cell to be applied to the input terminal of its following component). While the differences between them are shown in the comparison chart 4169 in FIG. 41D, they cannot be seen in the sequential functional snapshots of the circuit 4000 shown in charts 4155a-4155d, so the charts 4155a-4155d may also be used to describe the methodology 2220. Therefore, the description of how the methodology 4100 is applied to driver 4000 will not be repeated here.

However, the comparison chart 4169 in FIG. 41C shows the differences between the methodologies 2220, 4100, with the manner of showing the differences presented by:
methodology 2220 stages presented in italic font, and methodology 4100 stages in regular font;
the stages in both methodologies that differ by methodology presented in bolded font;
the cells containing the differences having double lined (thick, thin) borders; and
the cells showing switches closed in adjacent stages that do not differ by methodology in regular font.

The differences between the methodologies 2220, 4100 include:
in both cells [x], [y] at the 10^{th}/46^{th} stages, the positive rail NDE-bypass switch set is closed in the methodology 4100, while the negative rail NDE-bypass switch set is closed in the methodology 2220;
in cell [x], at 11^{th}/45^{th} and 18^{th}/38^{th} stages, the negative rail NDE-bypass switch set is closed in methodology 4100, while positive rail NDE-bypass switch set is closed in the methodology 2220; and
in cell [y], at the 16^{th}/40^{th} and 25^{th}/31^{st} stages, the negative rail NDE-bypass switch set is closed in the methodology 4100, while the positive rail NDE-bypass switch set is closed in the methodology 2220.

None of these differences constitutes a different functionality because the positive rail for each cell [x], [y] shares its source voltage with its negative rail, with the input voltages of each cell constituting the output voltage of the immediately preceding cell. Therefore, during a bypass operation, the input voltage on the positive rail for the cell is identical to input voltage on the negative rail for the cell, rendering the output voltage of the cell during either bypass equal to the same input voltage, irrespective of its transmittal on the positive or negative rail.

### Comparison of Variants M, N

Capacitor Reference Rail/Capacitor Configuration: Variants M, N both demonstrate batch 1 switching reference rail types with a hybrid capacitor configuration, because their switching patterns start with certain stages referencing the negative rail, then switch to the positive rail, then return to a negative rail switching pattern until its output voltage decreases back to ground. Because the drivers' cells are connected in series, they both have a hybrid capacitor configuration.

During the stages applied by the methodologies 2220, 4100, the stages of the cell [y] perform alternate 1 switching of reference rails, in large part because its complete V_{Oy} driving cycle is only six stages with nstep=3 (to drive a 1-NDE cell). If there were more NDEs in its cell and more stages in its methodology's driving cycle, cell [y] and its methodology V[y] could be defined to have another kind of reference rail switching type.

Stacked Capacitor Voltage Operation: Variants M, N demonstrate a hybrid capacitor configuration, because each of the methodologies 2220, 4100 cause the output voltage of the driver 4000 to connect to a stack of NDEs at some stages in the methodologies, and to a single NDE at other stages.

nstep: The nstep for Variants M, N equals 27 [applying 27 stages (2221(02)-2221(28), 4102-4128) to driver 4000 to drive its output voltage to peak, and applying 27 stages (2221(29)-2221(54), 2221(01), 4129-4154, 4101) to return the output voltage to ground].

Adapted versions of the methodologies 2220, 4100 follow:
a 2-NDE version of the driver 4000 is described above as the driver 2100 (FIG. 21), with two cells in series, each cell having one NDE, and its associated methodology 2200 (FIGS. 22A-22M-1B) may be applied to the driver 2100, with the methodology 2200 having 18 stages and an nstep=9;
a 1-NDE version of the driver 4000, in which n=1, is described above as the driver 400 (FIG. 4), which has one cell with one NDE, and its associated methodology 500 (FIG. 5G) may be applied to the driver 400, with the methodology 500 having 6 stages and an nstep=3;
a 4-NDE version of the driver 4000 is described above as the driving circuit [vwxy], with 4 cells in series, each cell having one NDE, and its associated methodology 2240 (FIGS. 22M-2B1,-2B2) to be applied to the driver [vwxy], with the methodology 2240 having 162 stages and an nstep=81;
one n-NDE version of the driver 4000 is the driver 2300 (FIG. 23A) with K driver cells (FIG. 23B), and with each cell 2301-i (i being a positive integer and 1≤i≤K) having a selected number n[i] of NDEs, and its associated methodology 2400 (FIG. 24A-24B-3) to be applied to the driver 2300, with the methodology 2300 having (2·Πᵢ₌₁^{K}[2·n[i]+1]) stages and an nstep=(2·Πᵢ₌₁^{K}[2·n[i]+1]−1);
another n-NDE version of the driver 2300 (FIG. 23A) has K driver cells, with each cell having 1 NDE would have K NDEs, one in each cell, and its associated methodology would have (2·Πᵢ₌₁^{K}[2·n[i]+1]) stages, with an nstep=(2·Πᵢ₌₁^{K}[2·n[i]+1]−1). Therefore, the number of stages in a version of the driver 2300 with one NDE per cell would have 2·Πᵢ₌₁^{K}[2·n[i]+1]=2·Πᵢ₌₁^{K}[2(1)+1]=2·Πᵢ₌₁^{K}[3]=2(3^{K}) stages, with an nstep=(3^{K})−1.

Vstep: With V_{DD}=(nstep)(Vstep) and Variant M/N's nstep°=27, Variant M/N's V_{DD[wxy]}=(nstep)(Vstep)=(27)(Vstep), and Vstep=(1/27)V_{DD[wxy]}.

Capacitor Voltage (Vᵢ): The batch 1 switching methodologies 2220, 4100 reference the negative rail in a first NDE-accessing switching set of stages [2221(02)-2221(14), 4102-4114] and in the last NDE-accessing switching set [2221(42)-2221(54), 4142-4154]; and its stages reference the positive rail, namely the second NDE-accessing switching set (stages [2221(15)-2221(41), 4115-4141], with stages [2221(01), 4101] providing grounding and stages [2221(28), 4128] providing peak voltage V_{DD[xyz]}.

The hybrid capacitor configuration of the methodologies 2220, 4100 as applied to the driver 4000 is defined to allow numerous but small increments of output voltage change,
with the driving system's output voltage at each stage in the drive of the output voltage to peak equal to the output voltage provided during the last previously applied stage plus the change in output voltage that is equal to the driver's Vstep, and
with the driving system's output voltage at each stage in the drive of the output voltage back to ground equal to the output voltage provided during the last previously applied stage minus the change in output voltage that is equal to the driver's Vstep.

It may also be noted that the methodologies 4100, with each of its three cells having one NDE and four switches may be compared to the Variant E, F, G, H driver 2900 having three NDEs and seven switches. Both drivers have the same number of NDEs; however, despite the driver 2900 having 4 different methodologies associated therewith, the disclosed methodologies have 14 stages, V_{DD29}=nstep=7, and a linear Vᵢ, with the value of Vᵢ, varying depending on the switching type and capacitor reference rail (1 or 2) of the methodology as applied to the driver 2900.

While numerous methodologies could be designed to apply to the driver 2900, Variants E, F, G, H have 14 stages, and if V_{DD29}=nstep=7,
in the methodologies that start switching referencing the negative rail, V₂₉₋₁ is equal to 1 or 2, V₂₉₋₂ ranges from 2 to 4, and V₂₉₋₃ ranges from 3 to 6, and
in the one methodology that starts switching referencing the positive rail, V₂₉₋₁=6, V₂₉₋₂=5, and V₂₉₋₃=4.

By contrast, the methodologies 2220, 4100 of Variants M, N have 54 stages, with nstep°=27 and V_{DD[wxy]}=(27)Vₛₜₑₚ, V[y]=(1)Vₛₜₑₚ; V[x]=(3)Vₛₜₑₚ; and V[w]=(9)Vₛₜₑₚ.

Therefore, NDE count may not be a significant factor in determining which circuit or methodology to select; other considerations, such as production cost, operation cost and/or speed, overall system efficiency, component life, repair/replacement cost, heating control may be more dispositive.

The choice of which NDE-bypass switch sets ([2],[3]), ([0],[1]) to use in a selected methodology may be left to the designer of driver circuitry, to maintain the closure of switches in adjacent stages, to prevent the closure of the same switches in adjacent stages, or to distribute the frequency that a switch is closed, or other quality control reason.

The two switch sets are functionally equivalent at the conceptual diagram level. In real implementation, there may be preferences of one set over the other, many of them implementation dependent details, and may be left to designer of the driver circuitry. Some considerations include (1) generally (but not always) low side switches (close to GND) are easier to drive than high side switches (close to V_{DD}), and (2) using one set may lead to a more regular pattern of control signals for the switches, which may be simpler to generate than less regular patterns of switch control signals.

### 10. General

The capacitive element driver disclosed herein may be formed of any type of transistor, including but not limited to a Metal Oxide Semiconductor Field Effect Transistor (MOSFET), a Gallium Nitride Field Effect Transistor (GaN-FET), a Silicon Carbide Field Effect Transistor (SiC-FET), a Junction Field Effect Transistor (JFET), or an Insulated Gate Bipolar Transistor (IGBT). Further, the capacitive element driver disclosed herein may be used to drive electrostatic actuators, electroactive polymer actuators, piezoelectric actuators, electroluminescent lighting/display devices, plasma display, smart film/glass based on liquid crystal technology, ultrasonic transducers, piezoelectric actuators, electronic paper displays (E-paper), and multiferroic/magnetoelectric devices.

The foregoing descriptions have been presented for purposes of illustration. They are not exhaustive and do not limit the invention to the precise forms or embodiments disclosed. In addition, although the disclosed components have been described above as being separate units, one of ordinary skill in the art will recognize that functionalities provided by one or more units may be combined. As one of ordinary skill in the art will appreciate, one or more units may be optional and may be omitted from implementations in certain embodiments. For example, in one configuration, the control processor and/or the capacitive elements, including without limitation items 730A, 730C, 730D, 730E, 1730, 1840, could be integrated into a capacitive element driver, or some or all of them could be separate electronic or electrical components that are electrically connected or connectable to the capacitive element driver. In another configuration, the control processor, control path system, and the capacitive element driver could be integrated with a voltage source and a capacitive element as separate electronics. In other embodiments, the capacitive driving circuit may form the entirety of the “capacitive element driver,” with, for non-limiting example, voltage source(s) and/or the controller being electrically connected to terminals of the driver.

Modifications and adaptations of the invention will be apparent to those skilled in the art from consideration of the specification and practice of the disclosed embodiments. For example, it can be seen that the non-dissipative elements in a capacitive element driver 700A need not be limited to being electrically connected in a series configuration. For example, while one terminal of the non-dissipative element in the driver 700A is electrically and directly connected to one of the switches in the driver 700A, the second terminal of the non-dissipative element may be connected to another node between the nodes 705A[1] and 705A[n+1]. Similarly, the non-dissipative elements in a capacitive element drivers 700C-1, 700C-2, 700F need not be limited to being electrically connected in a series configuration, and while one terminal of the non-dissipative element in the drivers is electrically and directly connected to one of the switches in the driver, the second terminal of the non-dissipative element may be connected to another node between the nodes between the NDEs in the driver. The voltages at such nodes will have the same average values as in the non-dissipative element series configuration of the drivers 700A, 700C.

In this application, numerous circuit methodology systems are disclosed, some circuits disclosed with only one methodology associated with it. It may be understood that the circuit/methodology systems described here are not the only systems. Variants of these disclosed systems are within the spirit and scope of the inventions disclosed herein. While only one methodology has been disclosed for certain of the circuits, it is contemplated that a system designer may develop more than one methodology for any given circuit, based on performance and output requirements for the system.

For example, while Variants C, D, discussed in detail above, have been disclosed as having stacked Capacitor Configurations and Batch 1, Alternate 2 switched Capacitor Reference Rails, respectively, in their respective methodologies 2700 (FIG. 27B-1) 2800 (FIG. 28B-1), a system designer may develop alternative methodologies for the driver 780 (FIG. 7B), modeled on the methodologies associated with the Variants E, F, G, H, with their non-stacked Capacitor Configuration and their respective Batch 1, Batch 2, Alternate 1, Alternate 2 switched Capacitor Reference Rails, respectively. A developer could design at least two more Variants P, Q for the driver 780, in which the alternative methodologies would have the same stacked Capacitor Configurations and stages as Variants C, D, but with Batch 2, Alternate 1 switched Capacitor Reference Rails. For example, a designer could provide Variant P, Q with Batch 2, Alternate 1 switched Capacitor Reference Rails, with the stages of the new methodologies arranged in different orders than the methodologies of Variants C, D. For example, the orders of the stages could be modeled on the order of the stages in Variants F, G, respectively, which have Batch 2, Alternate 1 switched Capacitor Reference Rails.

While the circuit variants disclosed herein have three NDEs, it is to be understood that the circuits may have any number of NDEs, including greater or less than thee NDEs, with the disclosed methodologies to be modified to fit the number of NDEs in the associated circuit, with the modifications apparent to those of ordinary skill in the art of circuit design. Further, while the methodologies disclosed here are described as being applied to the circuits disclosed herein, it is to be understood that the methodologies may be applied to a wide variety of circuits, with modifications to fit the desired circuit or application apparent to those of ordinary skill in the art of circuit design.

Further, while many of the methodologies disclosed here that are associated with the same circuit are defined with the same number of stages in their complete driving cycles, it is not required. For example, methodology 3500, which is associated with circuit 3400, has 14 stages in its complete driving cycle, while methodology 3600, also associated with circuit 3400, has 16 stages in its complete driving cycle. A comparison of methodologies 3500, 3600 shows that the number of changes may be different, causing differences in the amount of voltage outputted at each stage; also, combinations of switch closures may be used to produce the output voltages according to different calculations. Similarly, methodologies 3800, 3900, associated with circuit 3700, have different numbers of stages, amounts of voltage outputted by stage, and combinations of switch closures to produce the output voltages according to different calculations. As noted above, a switching controller may be electrically connectable to a circuit's plurality of switches to control the operation of the switches to open and close in combinations in the sequence of switching stages, the sequence of switching stages is arranged to provide step-wise transfer of the energy to the capacitive element, and the capacitive element driver may be arranged to drive the capacitive element from a high voltage level to a low voltage level or from a low voltage level to a high voltage level.

Further, a system designer may choose to input multiple methodology options into the controller to make the methodologies accessible and useable on the circuit by the controller given specific performance and output requirements for the circuit system, with the system designer providing the controller with the ability to choose among different methodologies or to modify a methodology to accommodate requirements, for example, changing a 6-switch methodology for a circuit into a methodology for a 5 switch circuit by closing one of the six switches for the duration of application of the 6-switch methodology on the circuit.

In addition, the controller may be provided an input system for a user to select among methodologies, or to input instruction for the controller to make the selection itself, based on input or known performance and output requirements for the circuit system. The input system may also allow for a user to modify methodologies, or to input instruction for the controller to make the modifications itself, to input instruction for the controller to make the modifications or selections itself, based on input or known performance and output requirements for the circuit system.

In one example, as noted earlier, a first methodology may be used to bring the driver to steady state (or near steady state), then a second methodology having a greater number of stages may be used to drive the capacitive element throughout steady state. Providing the feature of selectively switching methodology switch may allow the driver to act as an NDE pre-charger, which may save time in bringing the system to steady state performance. While, in the short time that the first methodology operates, the driver will not be achieving optimal energy conservation, the speedier attainment of steady state performance may outweigh the temporary loss of energy efficiency.

In addition, for simplicity of description, the embodiments of the circuits 700F, 2700, 2900, 3400, 3700 have been shown herein as a stand-alone circuit for governing switching in circuits containing only three (3) non-dissipative elements. The extension of the circuits and methodologies into embodiments for governing switching in circuits having fewer or more than three non-dissipative storage elements may be seen:
in the extension of the one non-dissipative element driving circuit 400 shown in FIG. 4 above into the three non-dissipative element driving circuit 780 of FIG. 7B with its associated switching methodology 2700 shown in the charts 2750, 2760, 2765 of FIGS. 27-A, 27-B1, 27-B2, respectively, and its associated switching methodology 2800 of FIGS. 28-A, 28-B1, 28-B2, respectively;
further in the extension of driving circuit 780/methodology 88 into the n non-dissipative element driving circuit 700C-1 of FIG. 7C-1, with its associated switching methodology disclosed above in the Section entitled “Capacitive Element Drivers 700C-1, 700C-2”; and
even further in the extension of the multiple NDE driving circuit 700C-1 and associated methodology 88 into the generalized multi-cell driving circuit 2300 shown in FIG. 23A with its associated switching methodology 2400 of FIGS. 24A-24B-3.

Modifications and adaptations of the invention will be apparent to those skilled in the art from consideration of the specification and practice of the disclosed embodiments. It is intended that the specification and examples be considered as exemplary only, with a true scope and spirit of the invention being indicated by the following claims.

1. A capacitive element driver for driving a capacitive element between voltage levels, the capacitive element comprising an element having capacitive functionality and the voltage supplied to the capacitive element driver by a voltage source, the capacitive element driver comprising:
a plurality of switches having:
a first switch electrically connectable in series directly or indirectly between a first terminal of the voltage source and an input terminal of the capacitive element, and
a second switch electrically connectable in series directly or indirectly between a second terminal of the voltage source and the input terminal of the capacitive element; and
a non-dissipative element arranged to store and transfer energy for driving the capacitive element between the voltage levels, wherein the non-dissipative element is electrically connectable directly or indirectly:
at a first end to a first node between the first terminal of the voltage source and the input terminal of the capacitive element, and
at a second end to a second node between the second terminal of the voltage source and the input terminal of the capacitive element;
wherein the plurality of switches is arranged to open or close in combinations in a sequence of switching stages to step-wise transfer the energy to the capacitive element, the sequence of switching stages further comprising a switching pattern having a voltage change portion arranged to cause a change in an output voltage of the capacitive element driver during application thereof on the capacitive element driver.

2. The capacitive element driver of claim 1, wherein the non-dissipative element comprises a plurality of non-dissipative elements electrically connectable in parallel or in series directly or indirectly:
at a first end to the first node, and
at a second end to the second node.

3. The capacitive element driver of claim 2, wherein the non-dissipative elements are disposed and electrically connectable in series directly or indirectly between the first node and the second node.

4. The capacitive element driver of claim 2, wherein the non-dissipative elements are disposed and electrically connectable in parallel directly or indirectly between the first node and the second node

5. The capacitive element driver of claim 1,
wherein the voltage levels comprise a first voltage level and a second voltage level, and
wherein the switching pattern further comprises:
a first switching pattern that is arranged to open and close at least one of the plurality of switches in a first combination of the switching stages for driving the capacitive element from the first voltage level to the second voltage level, and
a second switching pattern that is arranged to open and close the at least one of the plurality of switches in a second combination of the switching stages for driving the capacitive element from the second voltage level to the first voltage level.

6. The capacitive element driver of claim 5, wherein the switching stages in the second combination of switching stages are identical to but organized in reverse order from the switching stages in the first combination of switching stages.

7. The capacitive element driver of claim 5,
further comprising a first reference rail path comprising a path of electrical interconnection between the first terminal of the voltage source and the input terminal of the capacitive element through the first node, and a second reference rail path comprising a path of electrical interconnection between the second terminal of the voltage source and the input terminal of the capacitive element through the second node;
wherein the switching pattern is further arranged to open or close the plurality of switches to cause the driver to electrically connect the non-dissipative element with the first reference rail path or the second reference rail path.

8. The capacitive element driver of claim 7, wherein the switching pattern is further arranged to access the first reference rail path or the second reference rail path in a selected reference rail pattern:
with one reference rail pattern that is arranged to open or close the plurality of switches to cause the driver to electrically connect the non-dissipative element with the first reference rail for a first number of stages; and
with another reference rail pattern that is arranged to open or close the plurality of switches to cause the driver to electrically connect the non-dissipative element with the second reference rail for a second number of stages.

9. The capacitive element driver of claim 7, wherein the selected reference rail pattern in the second switching pattern is identical to but organized in reverse order from the selected reference rail pattern in the first switching pattern.

10. The capacitive element driver of claim 1, further comprising:
a first switching methodology in which selected switches are activated and deactivated in a first sequence of a first number of switching stages to step-wise transfer the energy to the capacitive element in a driving cycle in which the output voltage of the capacitive element driver is driven from a first voltage level to a second voltage level, and then back to the first voltage level,
a second switching methodology in which the selected switches are activated and deactivated in a second sequence of a second number of switching stages to step-wise transfer the energy to the capacitive element in a driving cycle in which the output voltage of the capacitive element driver is driven from a first voltage level to a second voltage level, and then back to the first voltage level, with the second number of switching stages being different than the first number of switching stages;
wherein the second switching methodology is arranged to provide a different amount of energy efficiency than the first switching methodology.

11. The capacitive element driver of claim 10, wherein the capacitive element driver is further arranged to apply the first switching methodology or the second switching methodology to control transfer of the energy to the capacitive element in the driving cycle.

12. The capacitive element driver of claim 11, wherein the capacitive element driver is further arranged to apply the first switching methodology for a first number of the driving cycles and to apply the second switching methodology for a second number of the driving cycles.

13. The capacitive element driver of claim 12:
wherein the second number of switching stages is greater than the first number of switching stages, and
wherein the capacitive element driver is further arranged to begin operation by applying the first switching methodology as a driver pre-charger, and to apply the second switching methodology after the capacitive element driver achieves a steady state of operation.

14. The capacitive element driver of claim 1,
wherein the voltage change portion of the switching pattern further comprises an addition portion arranged to cause addition of voltage to an input voltage of the capacitive element driver during application thereof on the capacitive element driver; and
wherein the switching pattern further comprises a bypass portion:
arranged to be applied to the capacitive element driver after application of the addition portion on the capacitive element driver, and
arranged to cause bypassing of the capacitive element driver during application thereof on the capacitive element driver.

15. A driver cell in a capacitive element driving circuit electrically connectable between a capacitive element and a voltage source arranged to supply a selected voltage to the capacitive element driving circuit, the capacitive element comprising an element having capacitive functionality, and the driver cell arranged to drive the capacitive element between two voltage levels,
wherein the driver cell comprises:
a first input terminal electrically connectable directly or indirectly to a first terminal of the voltage source;
an output terminal electrically connectable directly or indirectly to an input terminal of the capacitive element;
a second input terminal electrically connectable directly or indirectly to a second terminal of the voltage source;
a plurality of switches further having
a first switch electrically connectable in series between the first input terminal of the driver cell and the output terminal of the driver cell, and
a second switch electrically connectable in series between the second input terminal of the driver cell and the output terminal of the driver cell; and
a non-dissipative element arranged to store and transfer energy for driving the capacitive element between the two voltage levels, wherein the non-dissipative element is electrically connectable:
at a first end to a first node between the first input terminal and the output terminal, and
at a second end to a second node between the second input terminal and the output terminal;
wherein the plurality of switches is arranged to open or close in combinations in a sequence of switching stages while maintaining an average voltage level value of the non-dissipative element unchanged over time, the sequence of switching stages further comprising a switching pattern having a voltage change portion arranged to cause a change in an output voltage of the capacitive element driver during application thereof on the capacitive element driver.

16. The driver cell of claim 15, wherein the switches are arranged to open or close in combinations to step-wise transfer the energy to the capacitive element.

17. A capacitive element driver for driving a capacitive element between two voltage levels, the capacitive element comprising an element having capacitive functionality, and the capacitive element driver comprising a first circuit having:
a first circuit first voltage-receiving connection electrically connectable directly or indirectly to a first terminal of a voltage source for receiving the selected voltage from the voltage source;
a first circuit voltage-outputting connection electrically connectable directly or indirectly to an input terminal of the capacitive element;
a first circuit second voltage-receiving connection electrically connectable directly or indirectly to a second terminal of the voltage source; and
a first circuit non-dissipative element arranged to store and transfer energy for driving the capacitive element between the two voltage levels, wherein the first circuit non-dissipative element is electrically connectable:
at a first end to a first circuit first node between the first circuit first voltage-receiving connection and the first circuit voltage-outputting connection, and
at a second end to a first circuit second node between the first circuit second voltage-receiving connection and the first circuit voltage-outputting connection;
wherein the first circuit is arranged to step-wise transfer energy directly or indirectly to the capacitive element from a first high voltage level to a first low voltage level or from the first low voltage level to the first high voltage level; and
wherein the first circuit is arranged to perform the step-wise transfer through operation of a first sequence of switching stages on the first circuit non-dissipative element, the first sequence of switching stages further comprising a switching pattern having a voltage change portion arranged to cause a change in an output voltage of the capacitive element driver during application thereof on the capacitive element driver.

18. The capacitive element driver of claim 17,
wherein the voltage change portion further comprises a subtraction portion arranged to cause subtraction of voltage from an input voltage of the first circuit during application thereof on the first circuit; and
wherein the switching pattern further comprises a bypass portion:
arranged to be applied to the first circuit after application of the subtraction portion on the first circuit, and
arranged to cause bypassing of the first circuit during application thereof on the first circuit.

19. The capacitive element driver of claim 18, wherein the switching pattern further has a second subtraction portion:
arranged to be applied to the first circuit after application of the bypass portion on the first circuit, and
arranged to cause another subtraction of voltage from the input voltage of the first circuit during application thereof on the first circuit.

20. The capacitive element driver of claim 17,
wherein the switching pattern further comprises a bypass portion arranged to cause bypassing of the first circuit during application thereof on the first circuit; and
wherein the voltage change portion of the switching pattern further comprises an addition portion:
arranged to be applied to the first circuit after application of the bypass portion on the first circuit, and
arranged to cause addition of voltage to an input voltage of the first circuit during application thereof on the first circuit.

21. The capacitive element driver of claim 20, wherein the switching pattern further comprises a second addition portion:
arranged to be applied to the first circuit before application of the bypass portion on the first circuit, and
arranged to cause another addition of voltage to the input voltage of the first circuit during application thereof on the capacitive element driver.

22. A process for driving a capacitive element between two voltage levels, the process comprising:
disposing and electrically connecting a non-dissipative element in a capacitive element driver directly or indirectly to a first node between a first terminal of a voltage source for the driver circuit and an input of the capacitive element, and to a second node between a second terminal of the voltage source and the input of the capacitive element;
storing energy in the non-dissipative element; and
operating the first capacitive element driver through a sequence of switching stages,
wherein operating the sequence on the driver comprises:
outputting a set of voltage steps with a selected number of voltage steps,
transferring the energy in through the set of voltage steps, with the transferring occurring directly or indirectly to the capacitive element from a high voltage level to a low voltage level or from the low voltage level to the high voltage level, and
causing a change in an output voltage of the capacitive element driver during application on the capacitive element driver of a voltage change portion of a switching pattern in the first sequence.

23. The process of claim 22,
wherein the non-dissipative element comprises a plurality of non-dissipative elements; and
wherein the storing the energy in the non-dissipative element comprises storing the energy in the plurality of the non-dissipative elements which are electrically connectable in parallel or in series directly or indirectly at a first end at the first node, and at a second end at the second node.

24. The process of claim 23, further comprising electrically connecting the plurality of the non-dissipative elements in series.

25. The process of claim 23, further comprising electrically connecting the plurality of the non-dissipative elements in parallel.

26. The process of claim 22, wherein operating the capacitive element driver through the sequence of switching stages further comprises improving energy efficiency of operation of the capacitive element driver by increasing the selected number of the voltage steps in the set of voltage steps.

27. The process of claim 22, further comprising reducing an amount of time for the capacitive element driver to achieve a steady state of operation by pre-charging the capacitive element driver.

28. The process of claim 22, further comprising pre-charging the capacitive element driver by decreasing the selected number of the voltage steps in the first set of voltage steps.

29. The process of claim 22, further comprising pre-charging the capacitive element driver by changing the sequence of switching stages in the set of voltage steps.
